(19) United States
(12) Patent Application Publication
(10) Pub. No.: US 2007/0103059 A1
(43) Pub. Date: May 10, 2007

(54) Composition and polymer light-emitting device

(75) Inventors: Yoshiaki Tsubata, Tsukuba-shi (JP); Satoshi Mikami, Tsukuba-shi (JP); Chizu Sekine, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, TOKYO (JP)

(21) Appl. No.: 10/556,771

(22) PCT Filed: May 14, 2004
(86) PCT No.: PCT/JP04/06902

§ 371 Date: Apr. 10, 2006

(30) Foreign Application Priority Data
May 16, 2003 (JP) 2003-139013
Sep. 12, 2003 (JP) 2003-321519

(51) Int. Cl. H01L 51/00; H01J 1/62; C08L 25/02

(52) U.S. Cl. 313/504; 257/40; 257/E51.02; 525/241; 349/6

(57) ABSTRACT

A composition comprising a polymer compound having a polystyrene reduced number-average molecular weight of 10³-10⁸, and a compound showing light-emission from triplet excited state, and said polymer compound comprises a repeating unit of the following formula (1); and a polymer complex compound having visible light-emission in the solid state, and including a repeating unit of the above formula (1), a repeating unit selected from the above formulas (12) and (13), and a metal complex structure showing light-emission from triplet excited state: 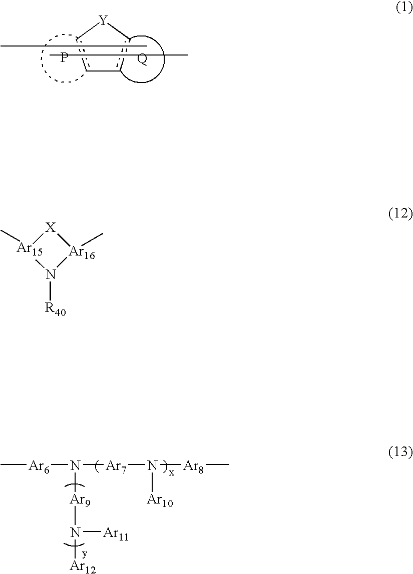
wherein, Ring P and Ring Q represent an aromatic ring, Y represents —O—, —S—, etc.; Ar₁₅ and Ar₁₆ represent a trivalent aromatic hydrocarbon group or a trivalent heterocyclic group; R₄₀ represents an alkyl group, etc.; X represents a single bond, etc.; Ar₆, Ar₇, Ar₈, and Ar₉ represent an arylene group, etc.; Ar₁₀, Ar₁₁, and Ar₁₂ represent aryl group, etc.; and x and y each independently represent 0 or 1, and 0≦x+y≦1.

### TECHNICAL FIELD

The present invention relates to a composition containing a polymer compound and a compound showing light-emission from triplet excited state, a polymer complex compound, and a polymer light-emitting device (hereinafter, sometimes referred to as polymer LED).

### BACKGROUND TECHNOLOGY

It has been known that a device using a compound showing light-emission from triplet excited state for the light emitting layer (hereinafter sometimes referred to as a triplet light-emission compound) has high light emitting efficiency.

And when a triplet light-emission compound is used for a light emitting layer, it is usually used as a composition in which a matrix is added to this compound.

As the composition in which a polymer compound is used as the matrix added to the triplet light-emission compound, for example, a composition is disclosed, in which 2,8,12,17-tetraethyl-3,7,13,18-tetramethylporphyrin which is a triplet light-emission compound is added to a polymer compound comprising a fluorenediyl group as a repeating unit. (APPLIED PHYSICS LETTERS, 80, 13, 2308 (2002))

However, the light emitting efficiency of the device using the above composition for a light emitting layer was still insufficient.

### DISCLOSURE OF THE INVENTION

The object of the present invention is to provide a composition containing a polymer compound and a compound showing light-emission from triplet excited state, and the device comprising said composition as a light emitting layer of a light-emitting device is excellent in light emitting efficiency.

That is, the present invention relates to a composition containing a polymer compound whose polystyrene reduced number average molecular weight of 10³-10⁸, and a compound showing light-emission from triplet excited state, and said polymer compound has a repeating unit of the following formula (1). 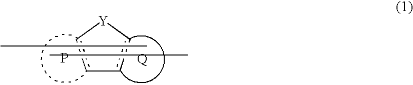
[wherein, Ring P and Ring Q each independently represent an aromatic ring, but Ring P may be either existent or non-existent. When Ring P is existent, two connecting bonds respectively are on Ring P and/or Ring Q, and when Ring P is non-existent, two connecting bonds respectively are on 5 membered ring containing Y, and/or Ring Q. On an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained. Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.].

Furthermore, the present invention relates to a polymer complex compound containing a repeating unit of the above formula (1), a repeating unit selected from the below formulas (12) and (13), and a metal complex structure showing light-emission from triplet excited state, and having visible light-emission in the solid state. 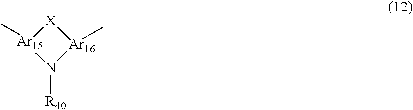
[wherein, Ar₁₅ and Ar₁₆ each independently represent a trivalent aromatic hydrocarbon group or a trivalent heterocyclic group, R₄₀ an alkyl group, alkoxy group, alkylthio group, alkylsilyl group, alkylamino group, aryl group which may have a substituent, or monovalent heterocyclic group. X represents a single bond, or following groups, 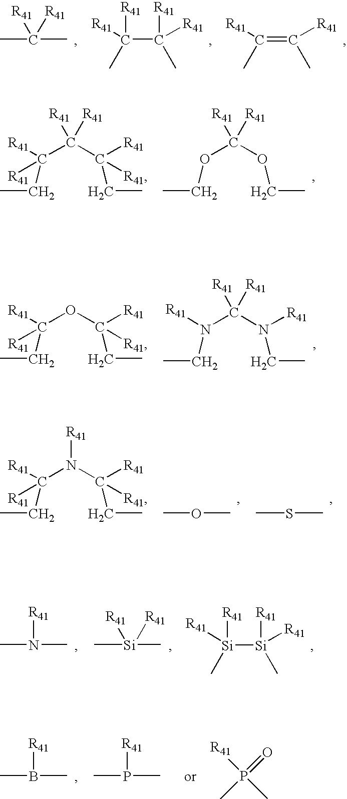
(wherein, R₄₁ each independently represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, a halogen atom, acyl group, acyloxy group, imino group, amide group, imide group, monovalent heterocyclic group, carboxyl group, substituted carboxyl group, or cyano group. When two or more R₄₁ exist, they may be the same or different), 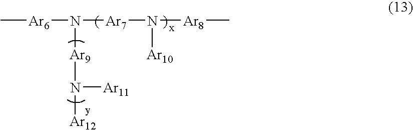
wherein, Ar₆, Ar₇, Ar₈, and Ar₉ each independently represent an arylene group or a divalent heterocyclic group. Ar₁₀, Ar₁₁, and Ar₁₂ each independently an aryl group or monovalent heterocyclic group. Ar₆, Ar₇, Ar₈, Ar₉, and Ar₁₀ may have a substituent. x and y each independently represent 0 or 1, and 0≦x+y≦1].

### BEST MODE FOR CARRYING OUT THE INVENTION

The polymer compound used for the present invention has a repeating unit of the above formula (1).

Of the above formula (1), examples of the aromatic ring in Ring P and Ring Q, include: an aromatic hydrocarbon ring such as a benzene ring, naphthalene ring, anthracene ring, tetracene ring, pentacene ring, pyrene ring, and phenanthrene ring; a heteroaromatic ring, such as a pyridine ring, bipyridine ring, phenanthroline ring, quinoline ring, iso quinoline ring, thiophene ring, furan ring, and pyrrole ring, etc. It is preferable that the aromatic ring is an aromatic hydrocarbon ring.

Y represents —O—, —S—, —Si(R₁)(R₂)—, —P(R₃)—, or —PR₄(═O)—. [R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.]. It is preferable that Y is —S— or —O—.

As the structure of the above formula (1), exemplified are: the structures of the below formula (1-1), (1-2) or (1-3); 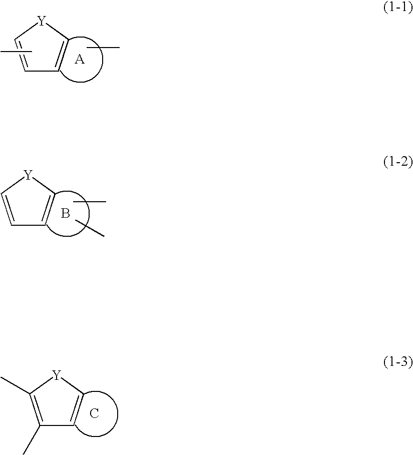
[wherein, Ring A, Ring B, and Ring C each independently represent an aromatic ring. Formulas (1-1), (1-2) and (1-3) may have substitutent selected form an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. Y represents the same meaning as the above.],
and the structures of the below formula (1-4) or (1-5); 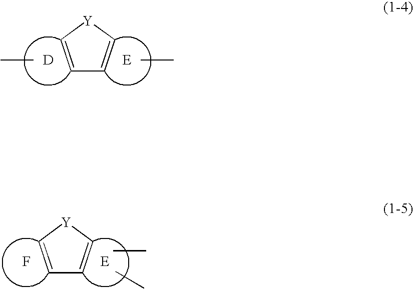
[wherein, Ring D, Ring E, Ring F, and Ring G each independently represent an aromatic ring which may have substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. Y represents the same meaning as the above.].

In the above formulas (1-1), (1-2), (1-3), (1-4) and (1-5), as the aromatic ring in Ring A, Ring B, Ring C, Ring D, Ring E, Ring F, and Ring G, exemplified are: aromatic hydrocarbon ring, such as a benzene ring, naphthalene ring, anthracene ring, tetracene ring, pentacene ring, pyrene ring and phenanthrene ring; heteroaromatic ring, such as pyridine ring, bipyridine ring, phenanthroline ring, quinoline ring, an iso quinoline ring, thiophene ring, furan ring, and pyrrole ring, etc.

Concrete examples of formula (1-1) include the followings. Furthermore, those of the followings having substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. In the formulas, the connecting bonds show that they may exist on the arbitrary positions of the aromatic ring.

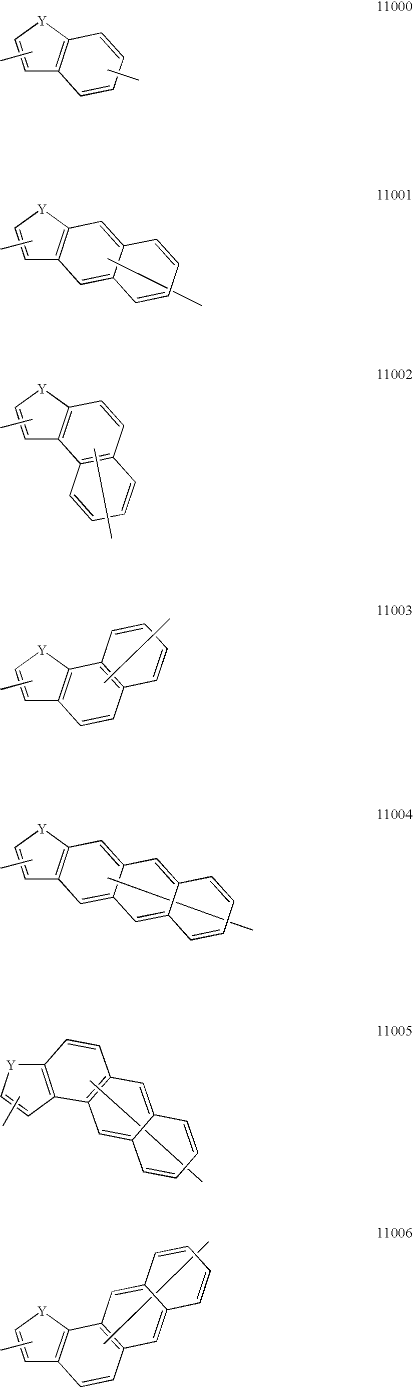

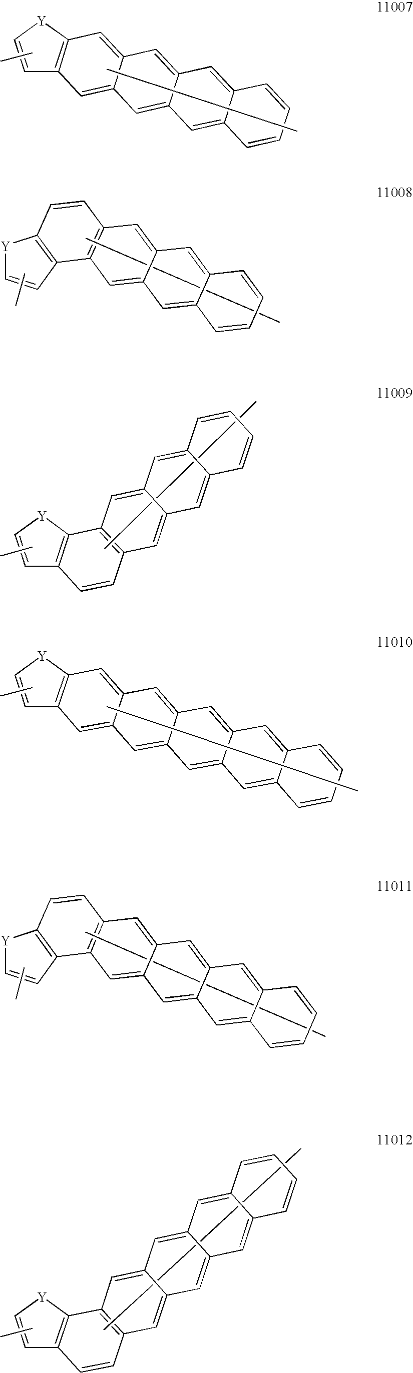

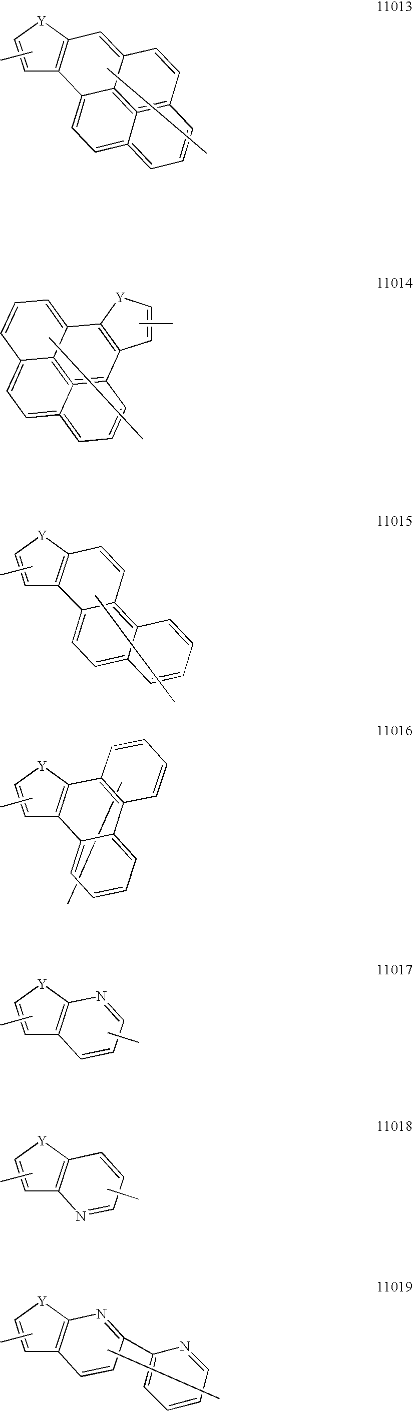

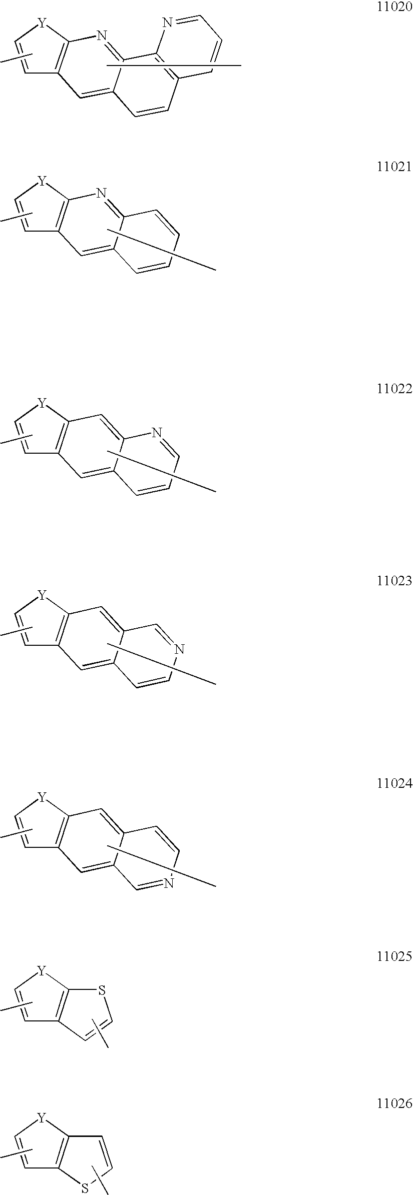

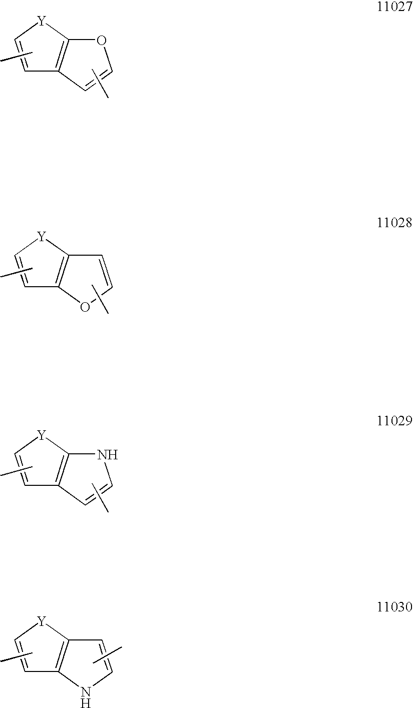

Concrete examples of formula (1-2) include the followings. Furthermore, those of the followings having substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. In the formulas, the connecting bonds show that they may exist on the arbitrary positions of the aromatic ring.

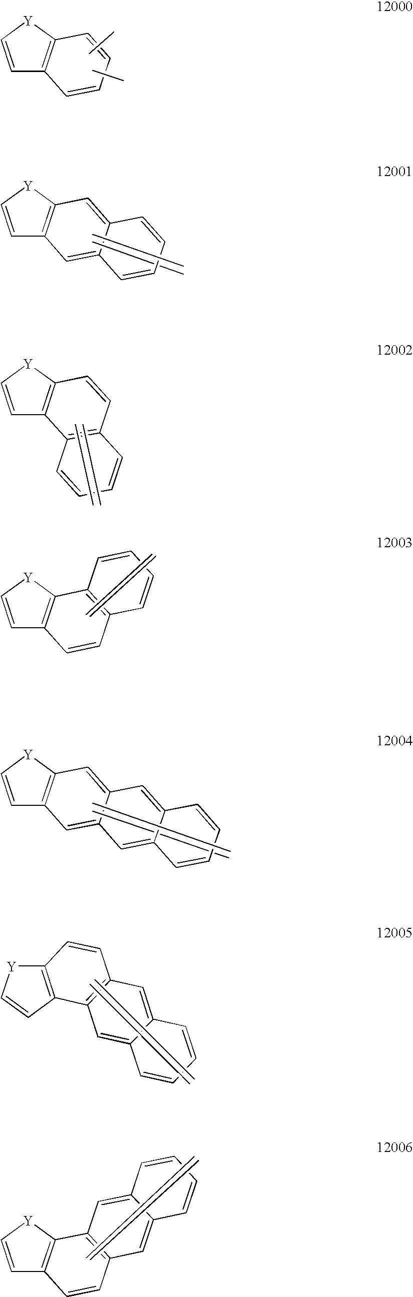

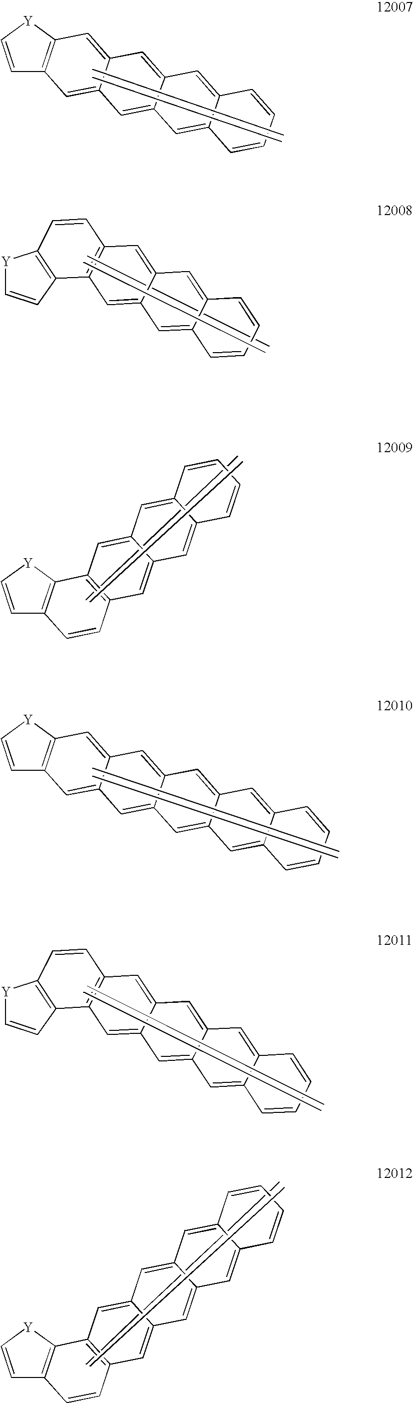

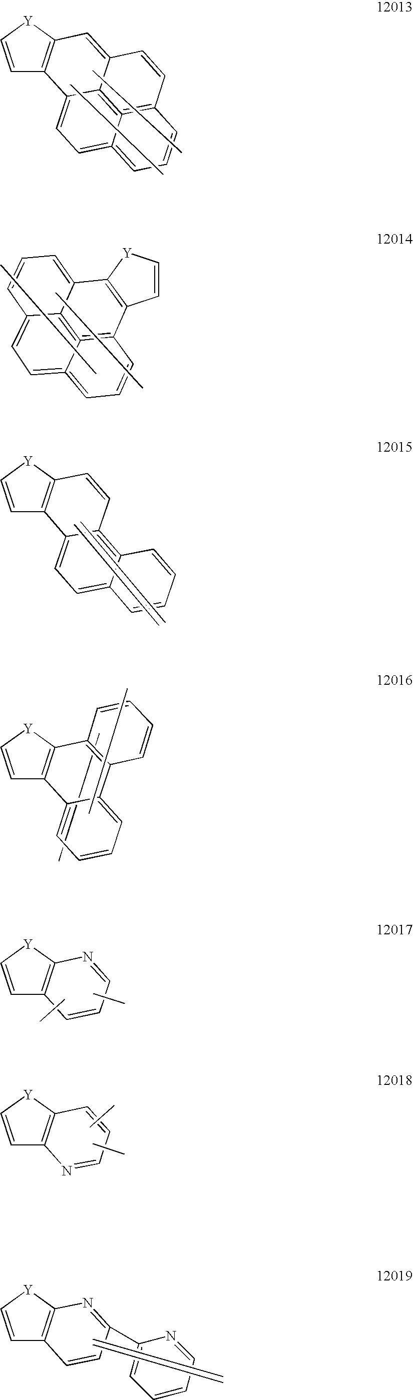

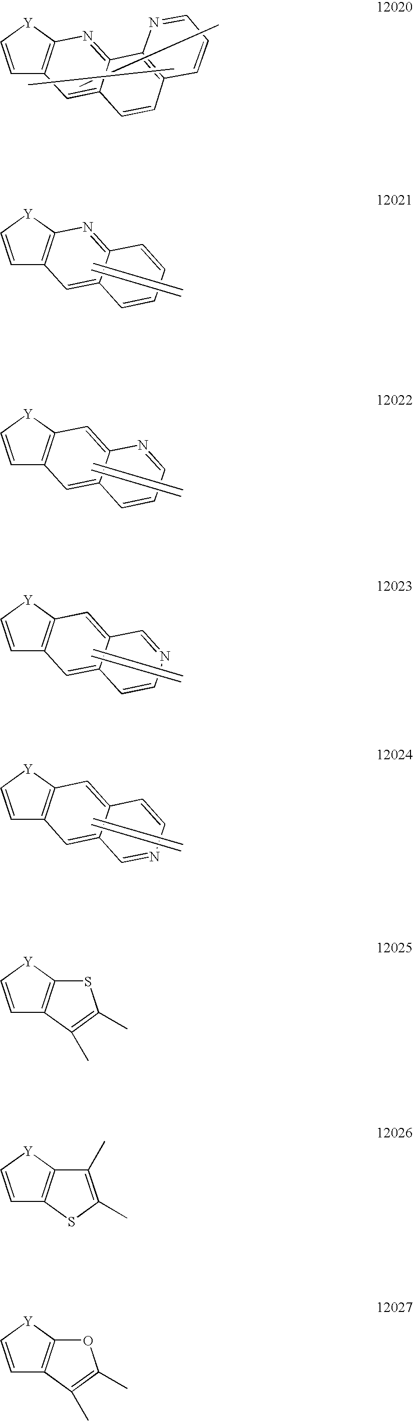

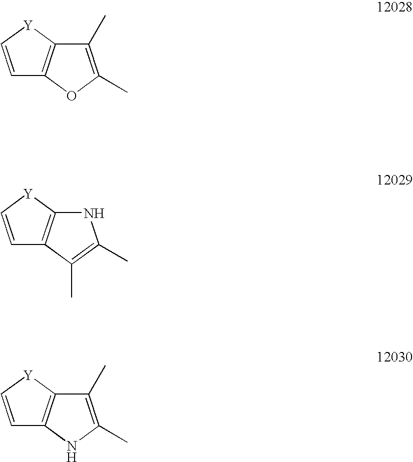

Concrete examples of formula (1-3) include the followings. Furthermore, those of the followings having substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. In the formulas, the connecting bonds show that they may exist on the arbitrary positions of the aromatic ring.

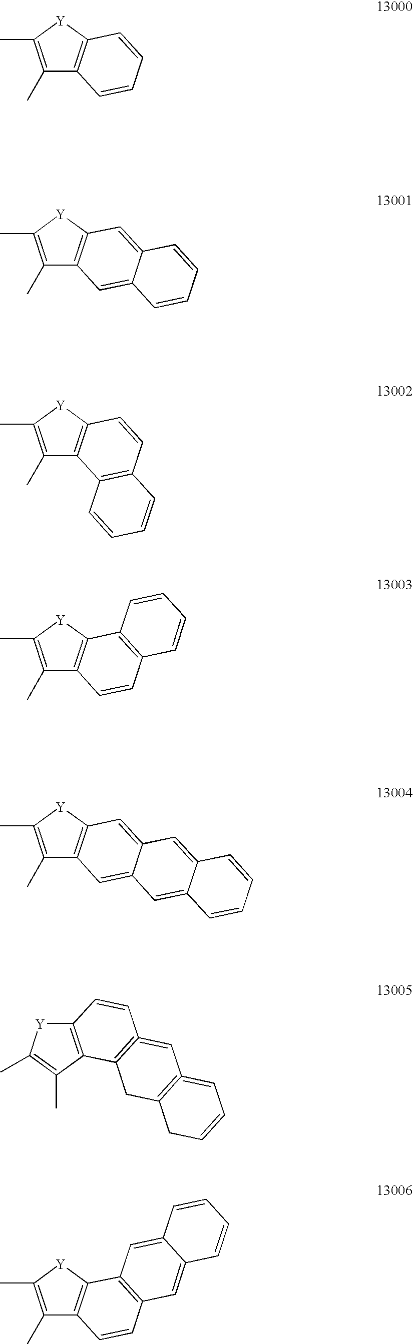

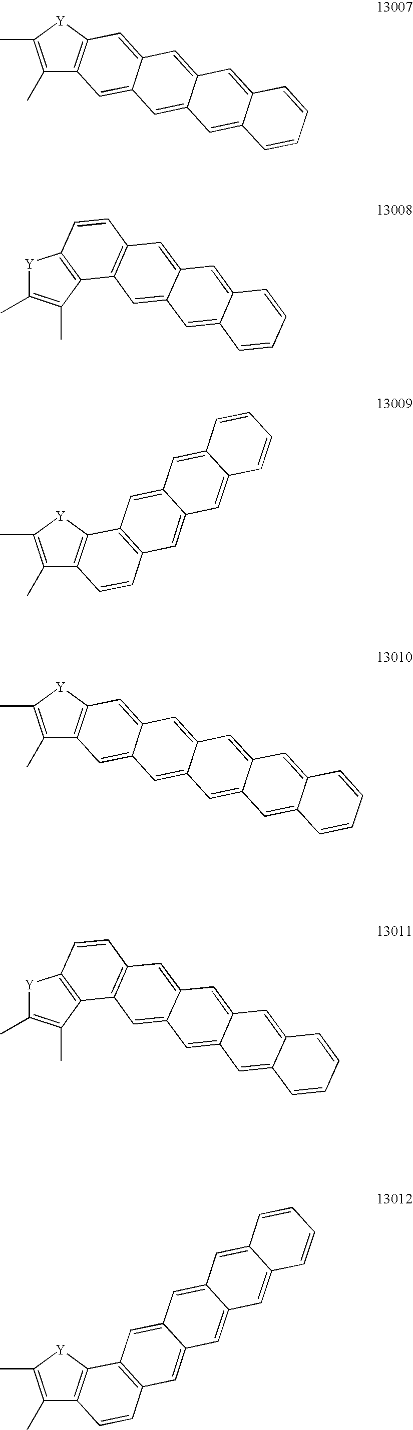

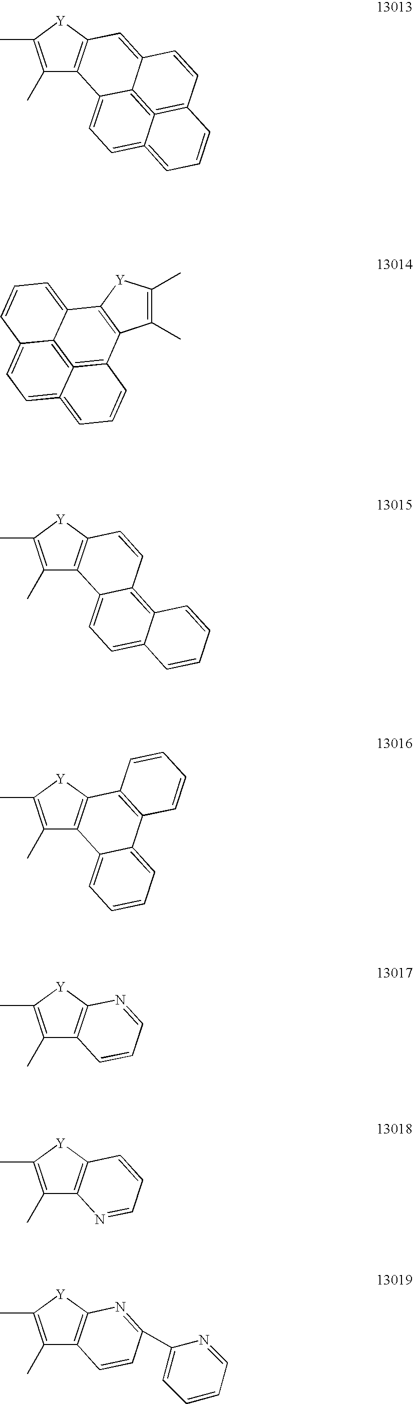

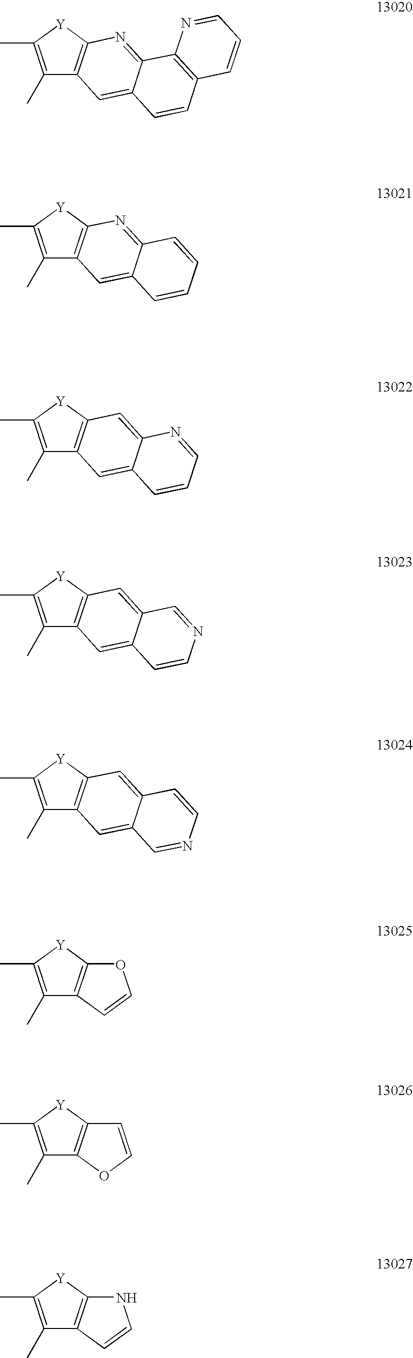

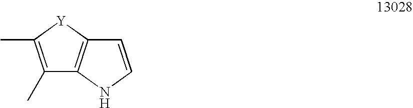

Concrete examples of formula (1-4) include the followings. Furthermore, those of the followings having substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. In the formulas, the connecting bonds show that they may exist on the arbitrary positions of the aromatic ring.

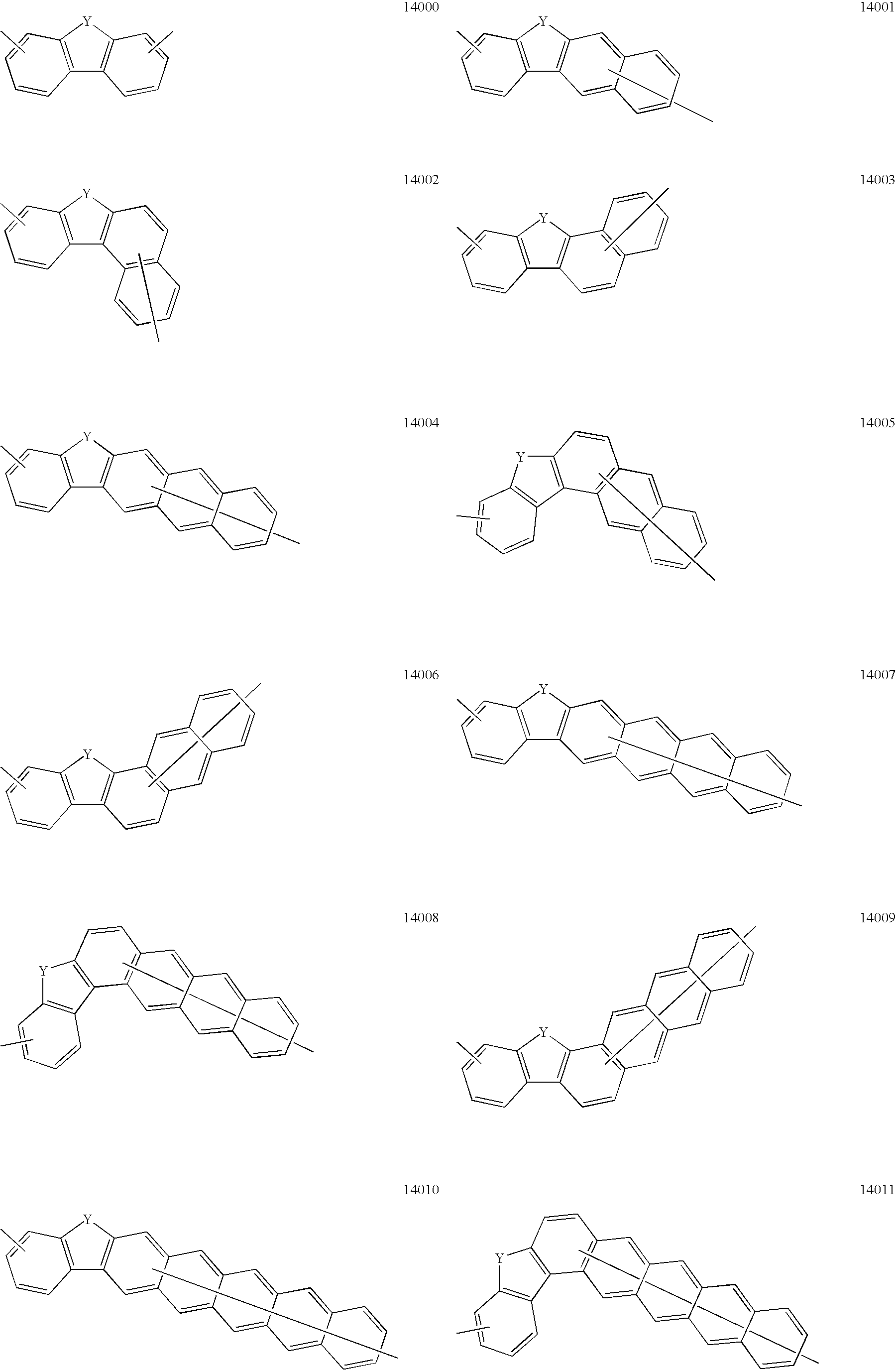

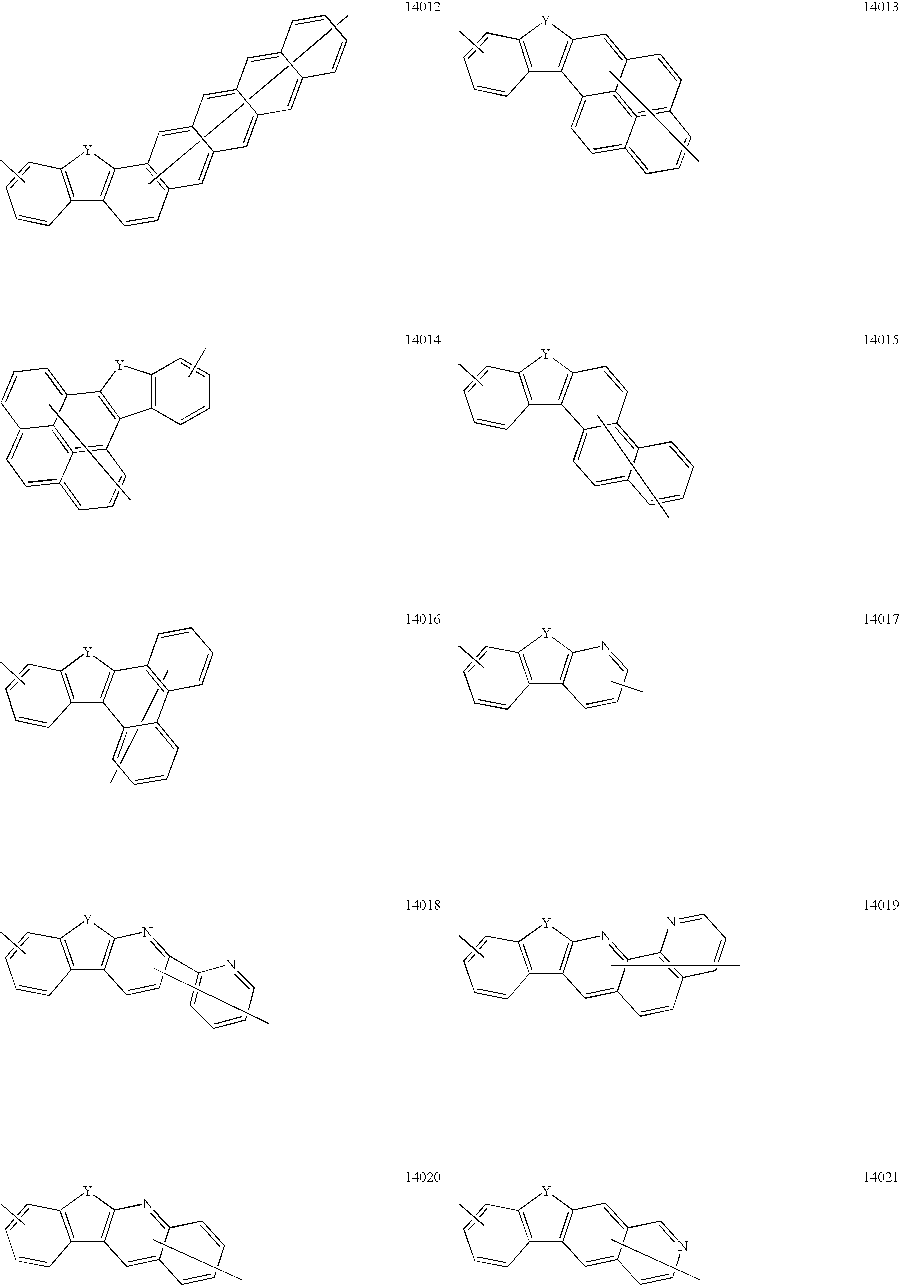

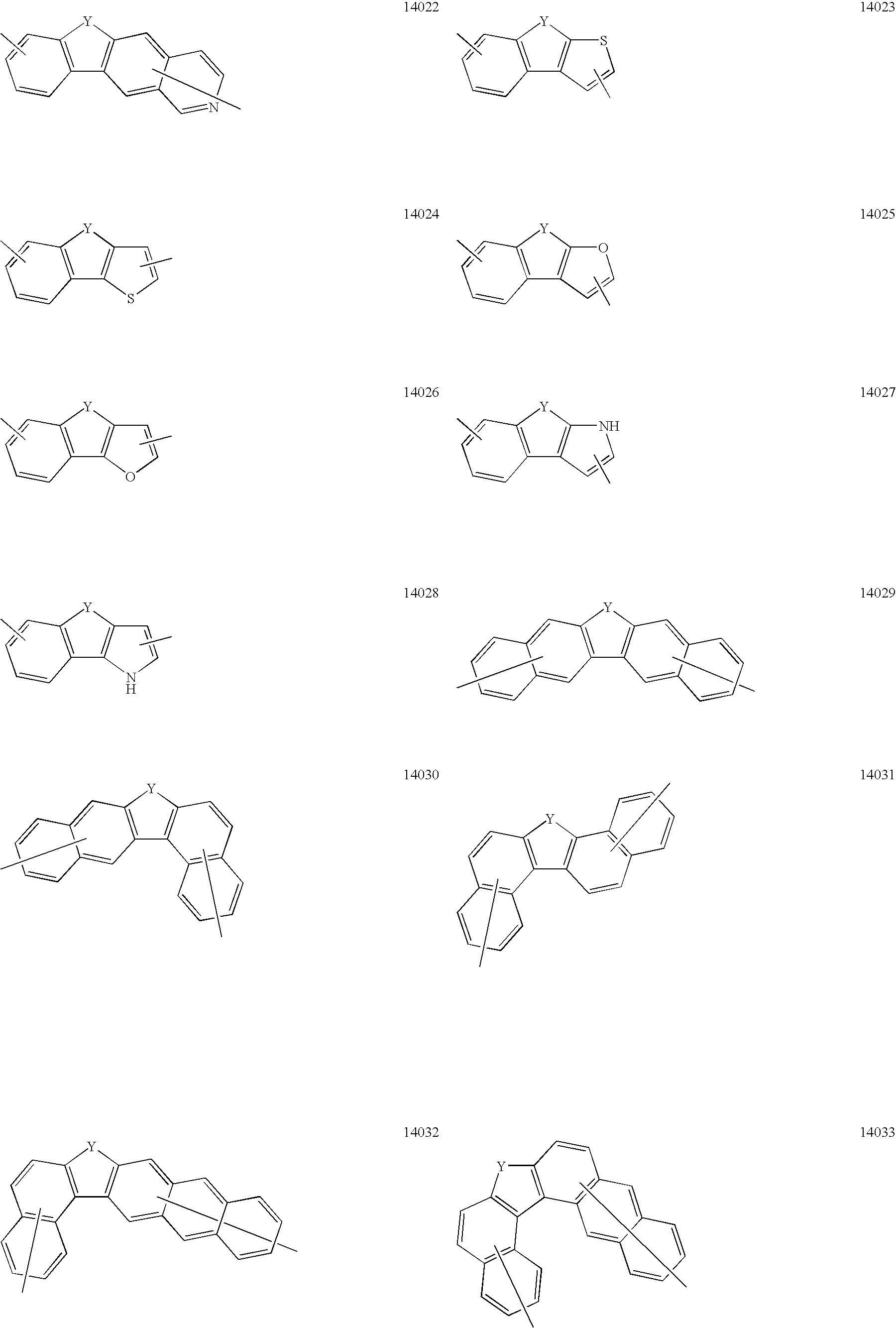

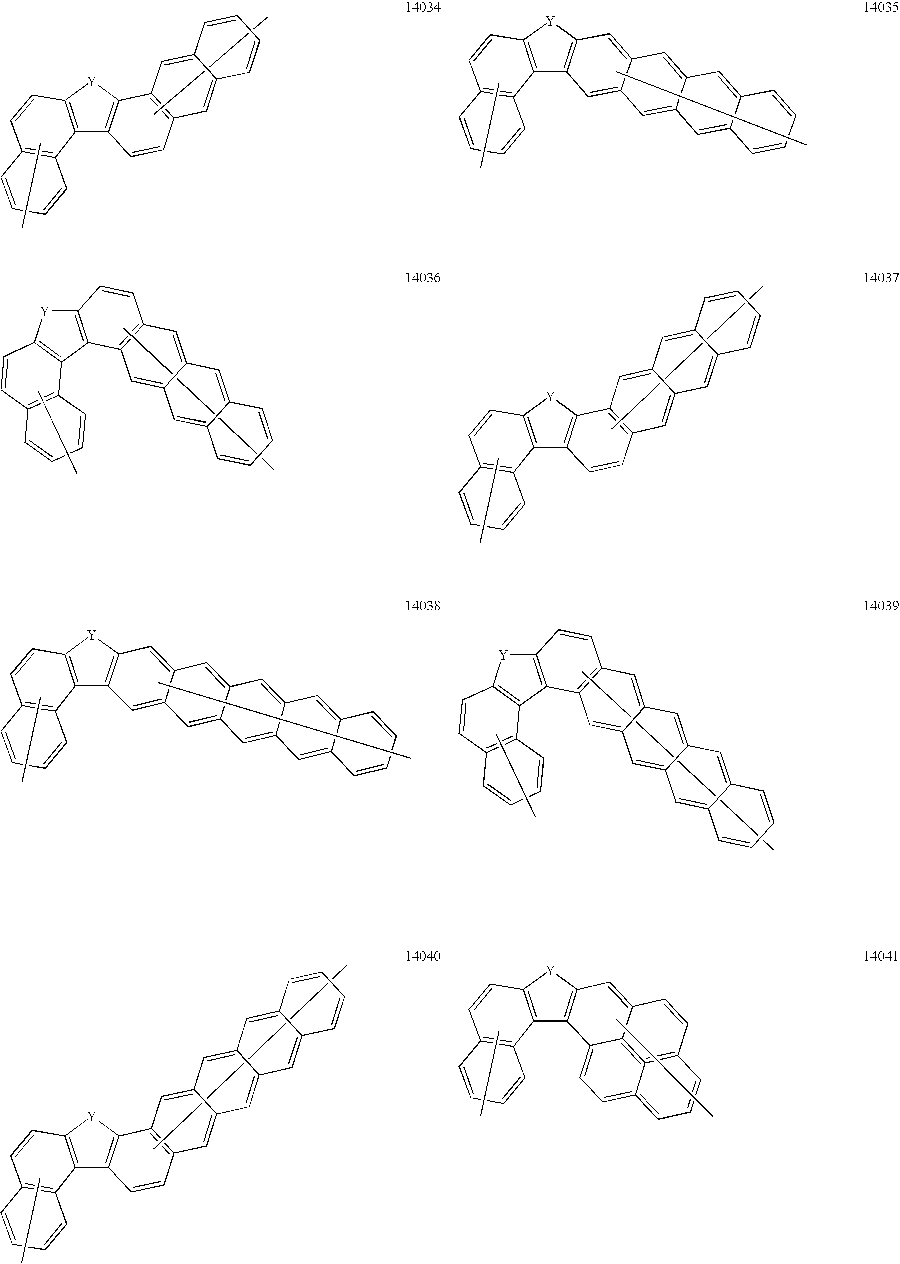

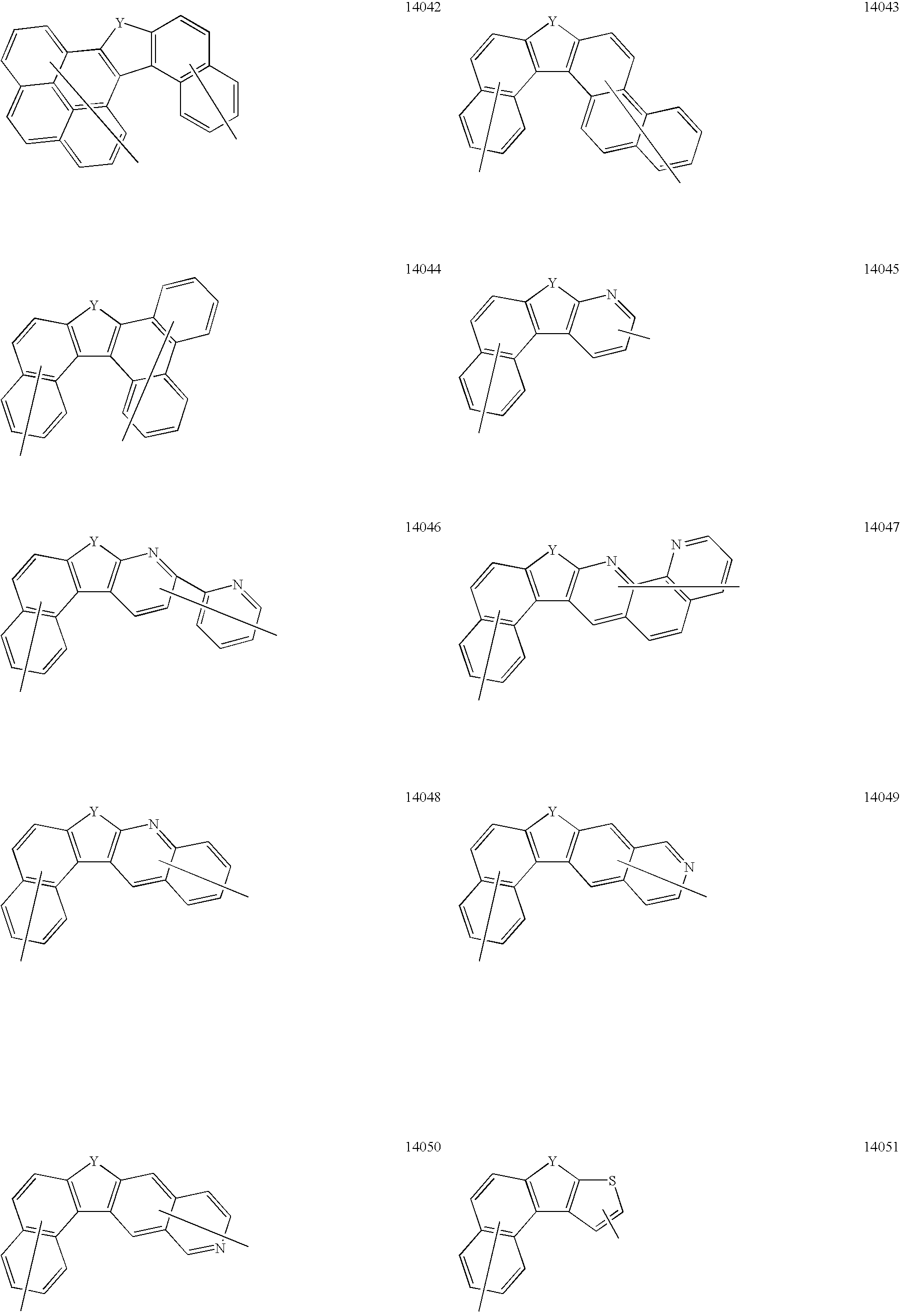

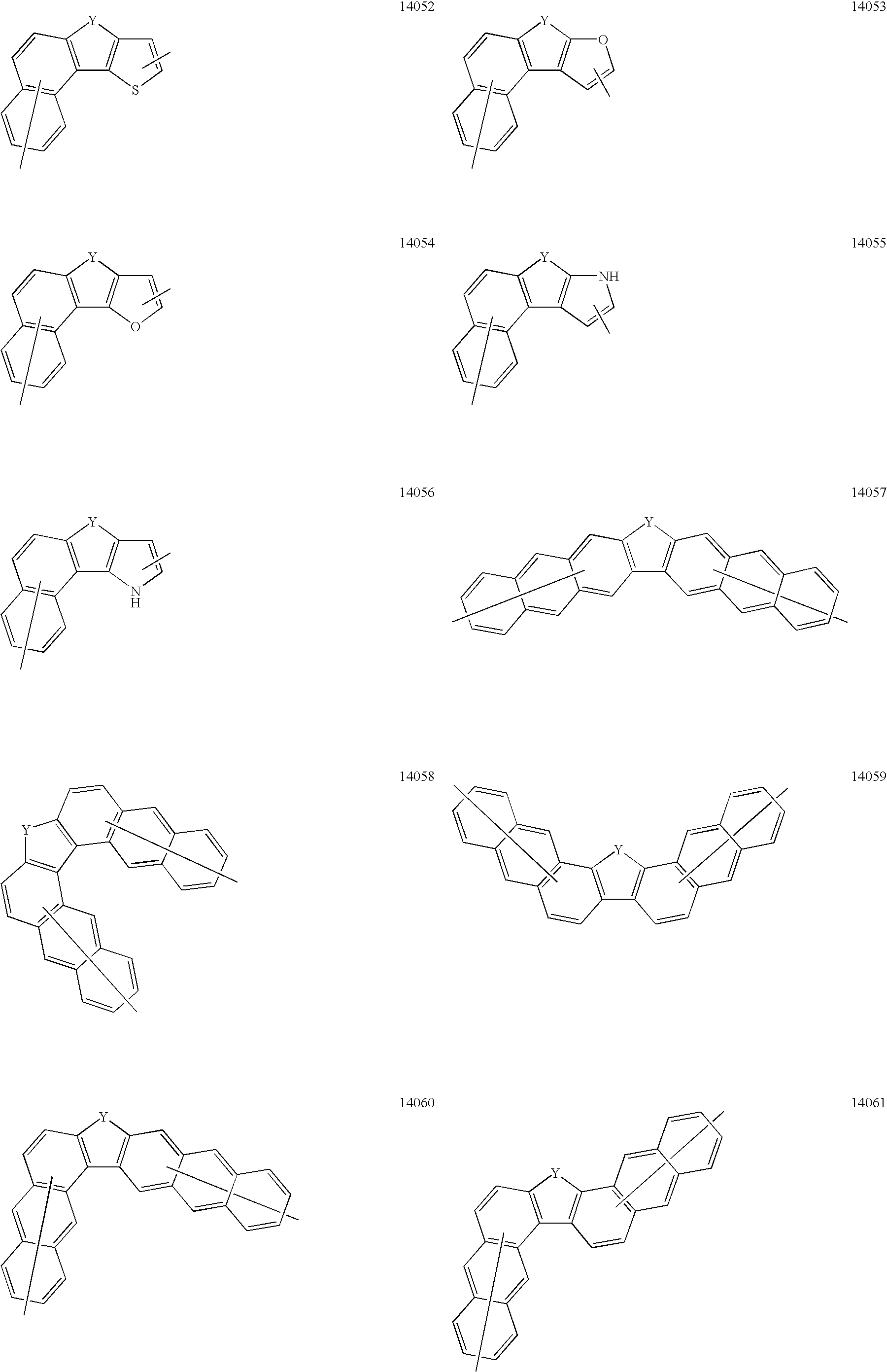

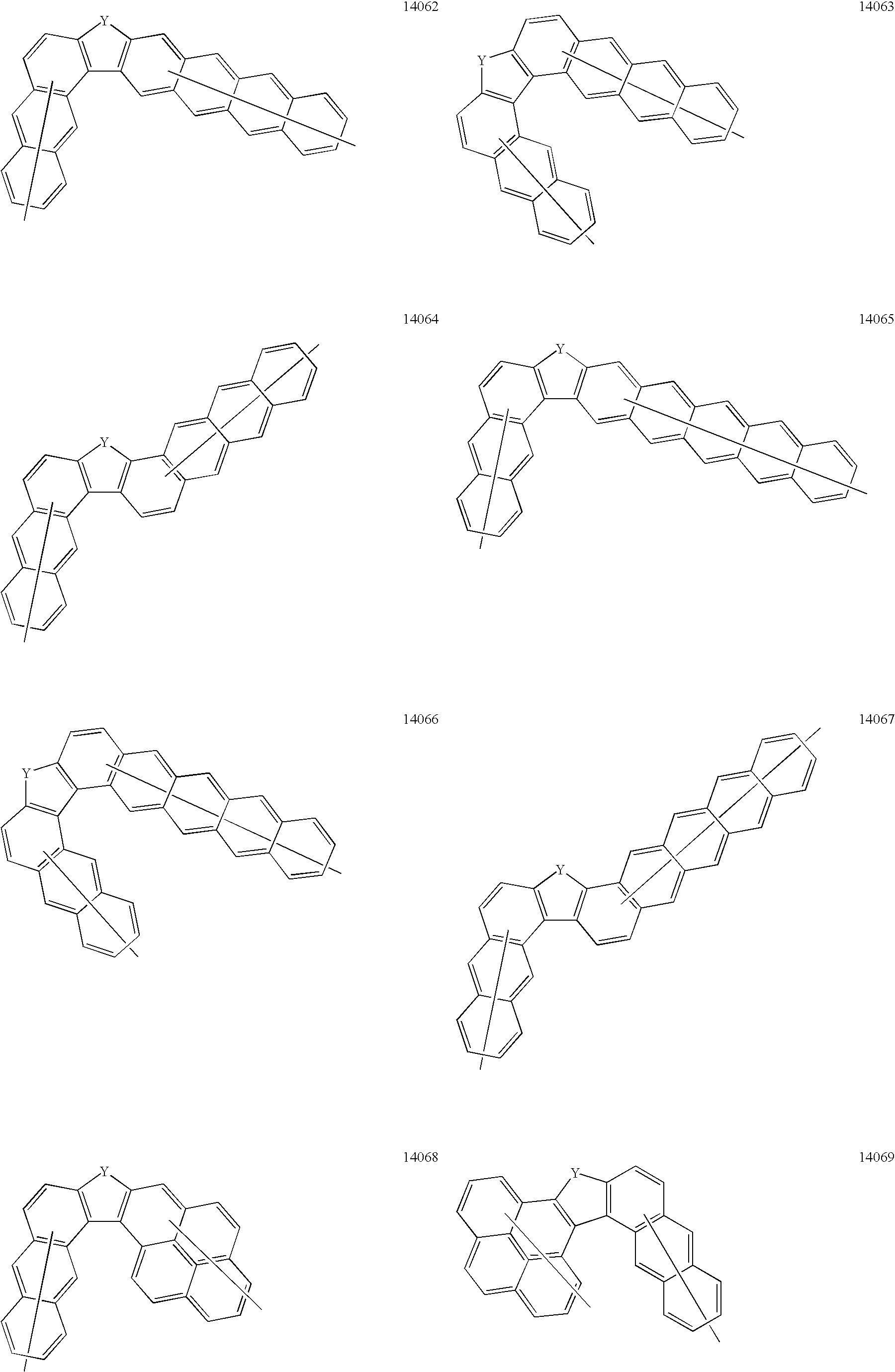

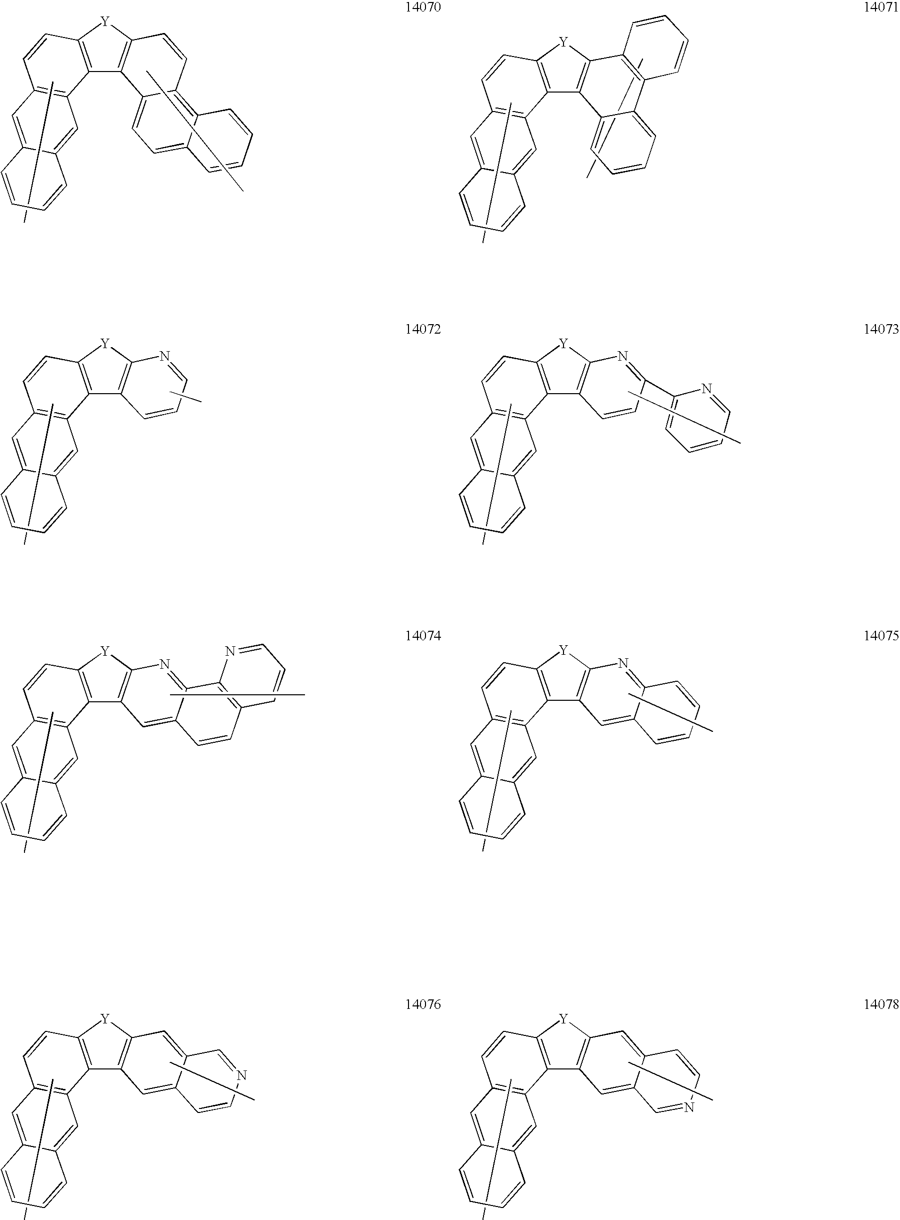

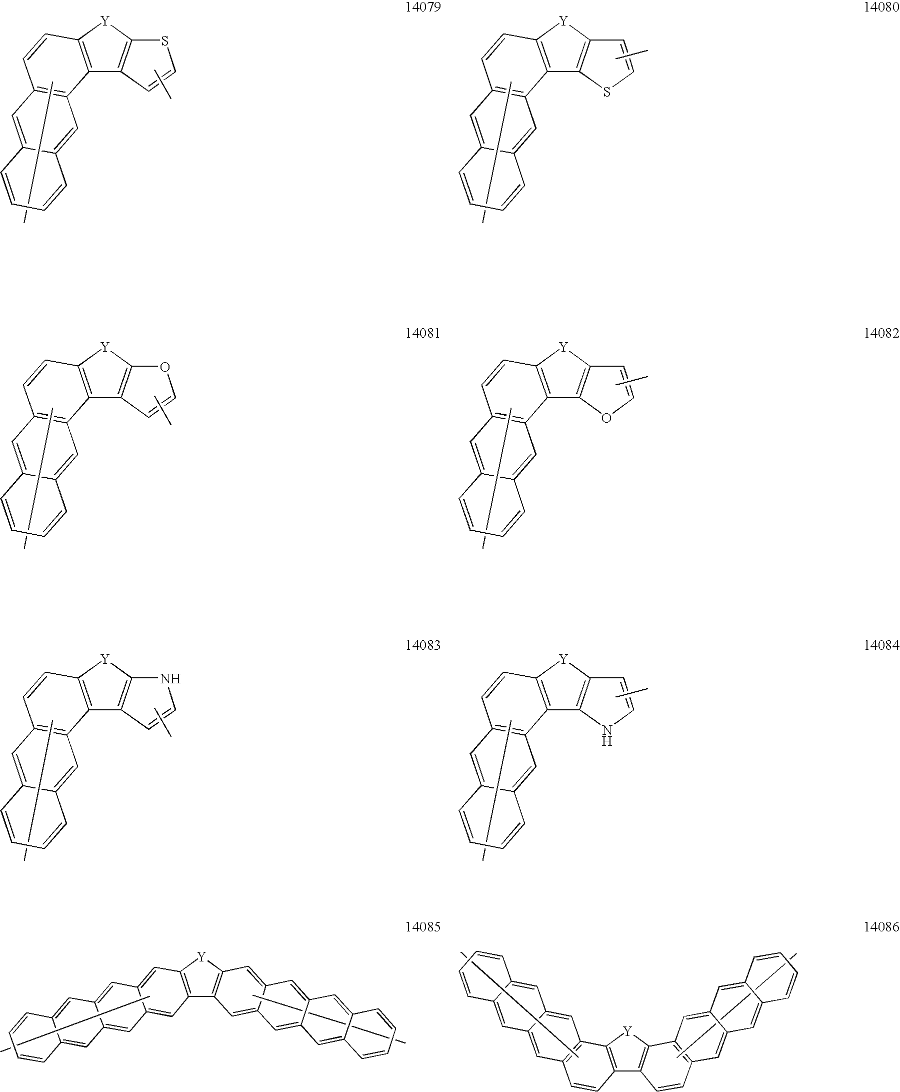

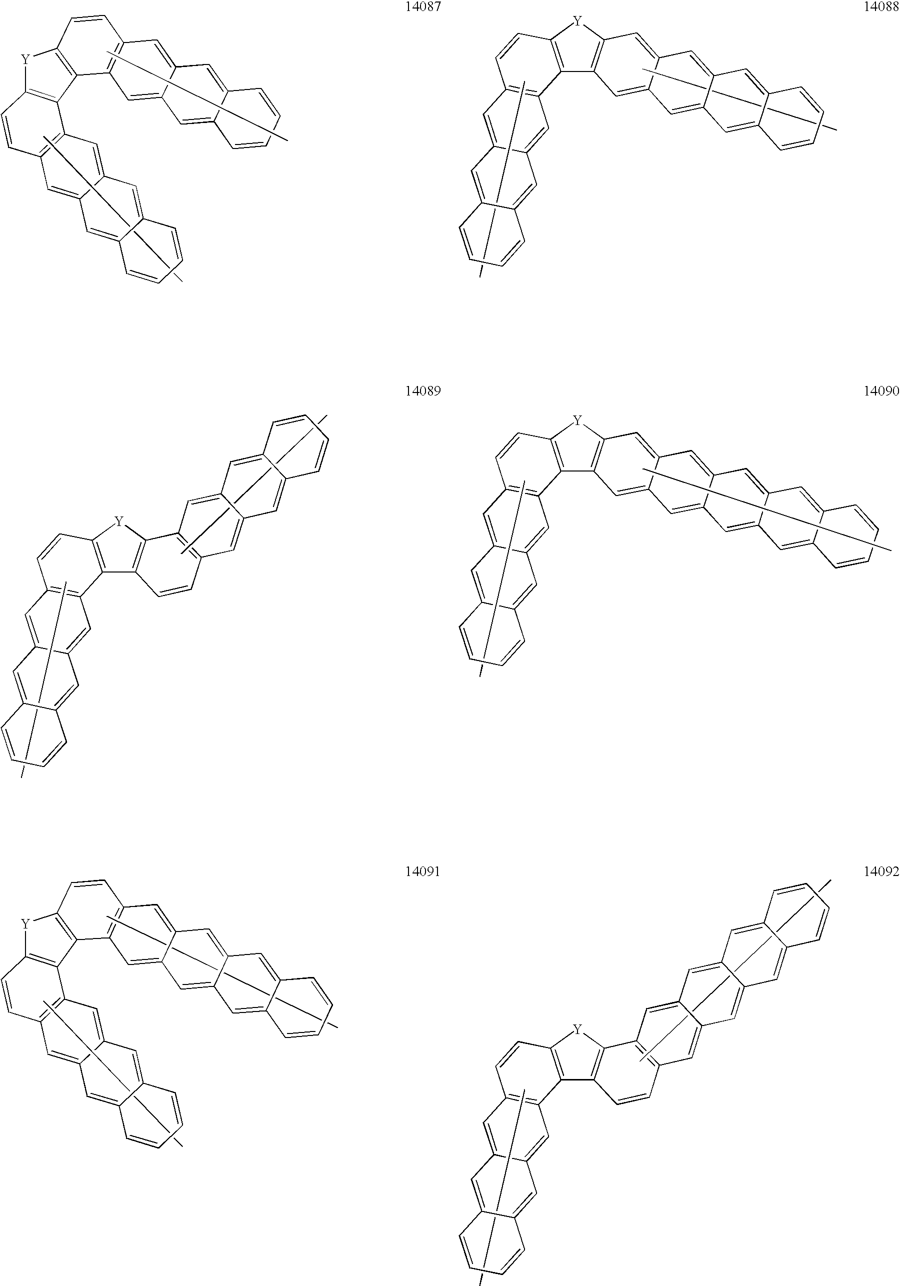

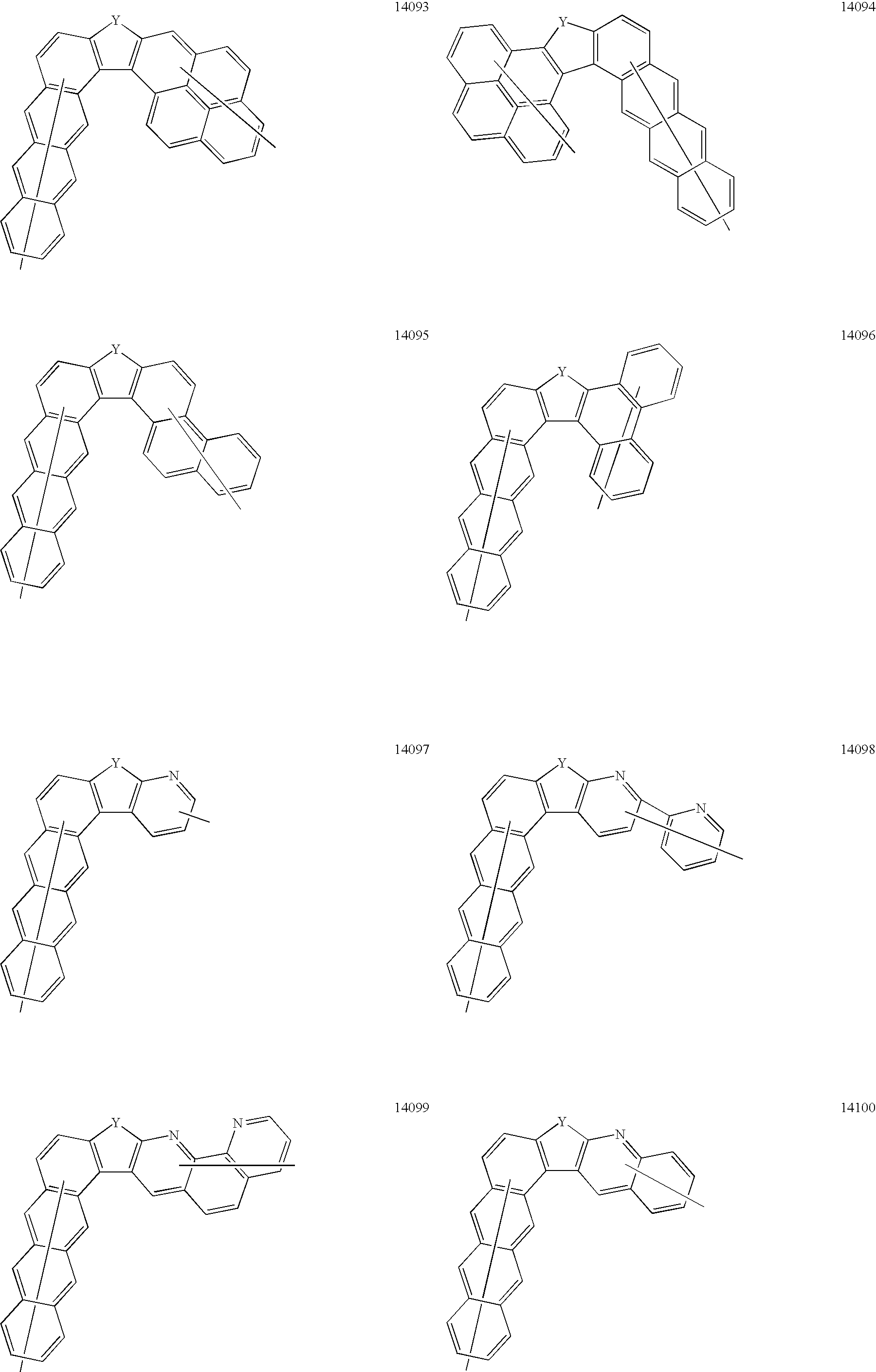

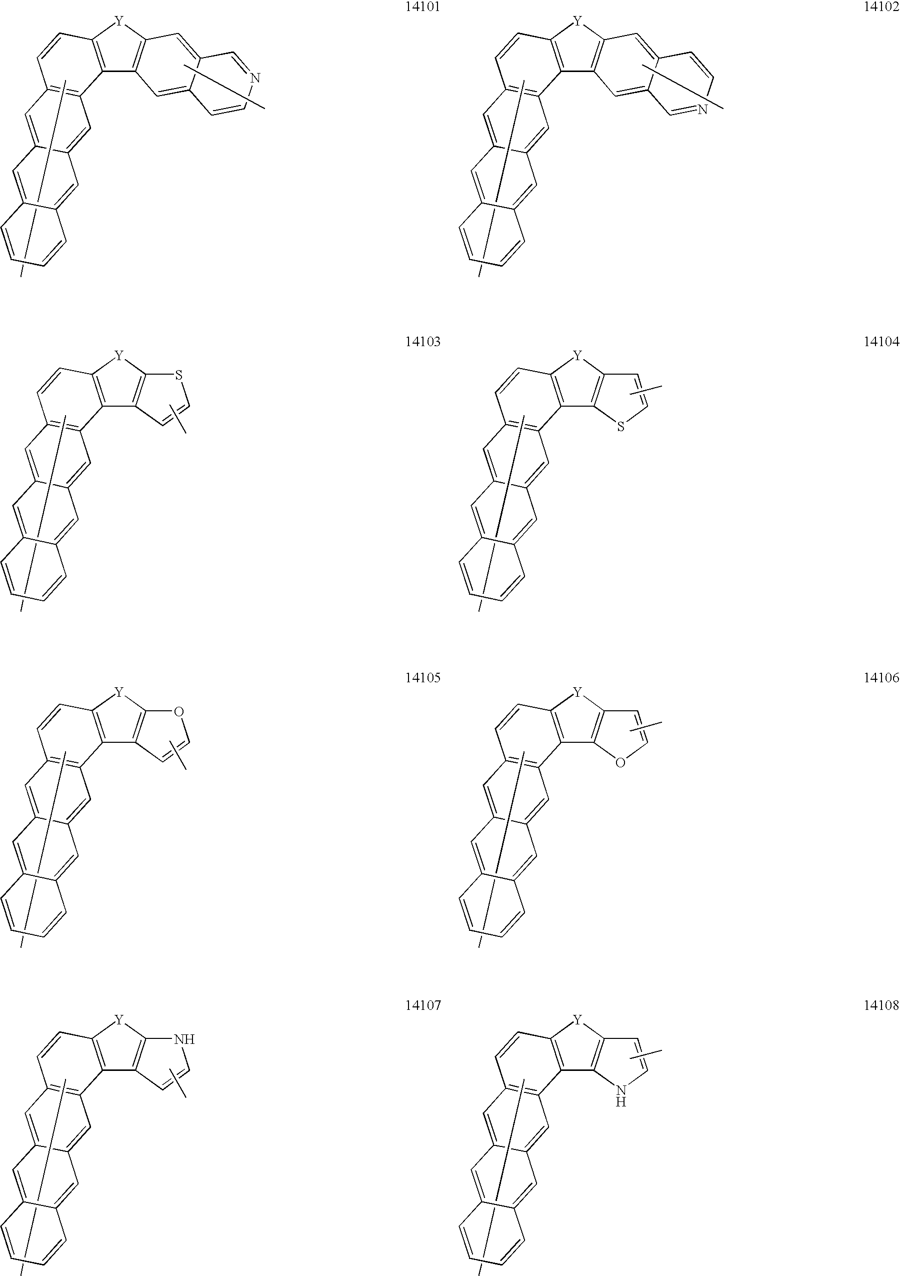

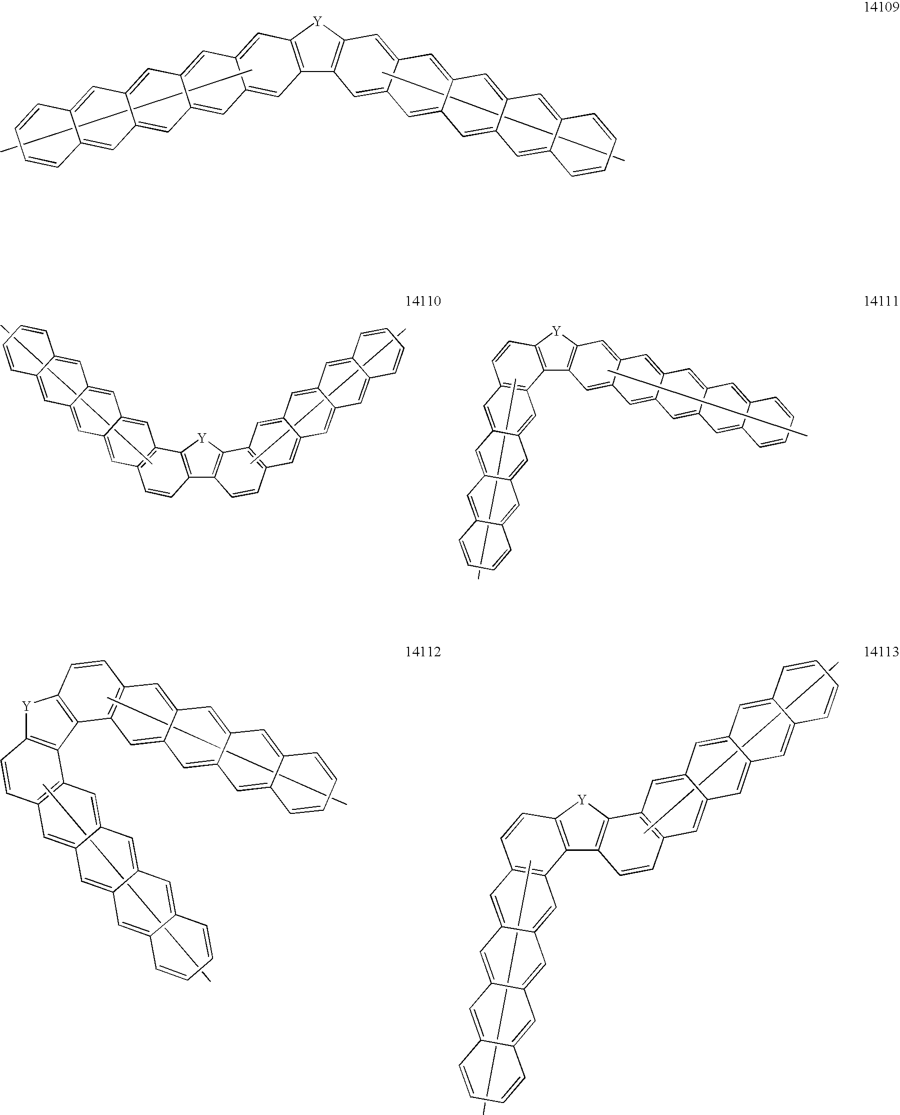

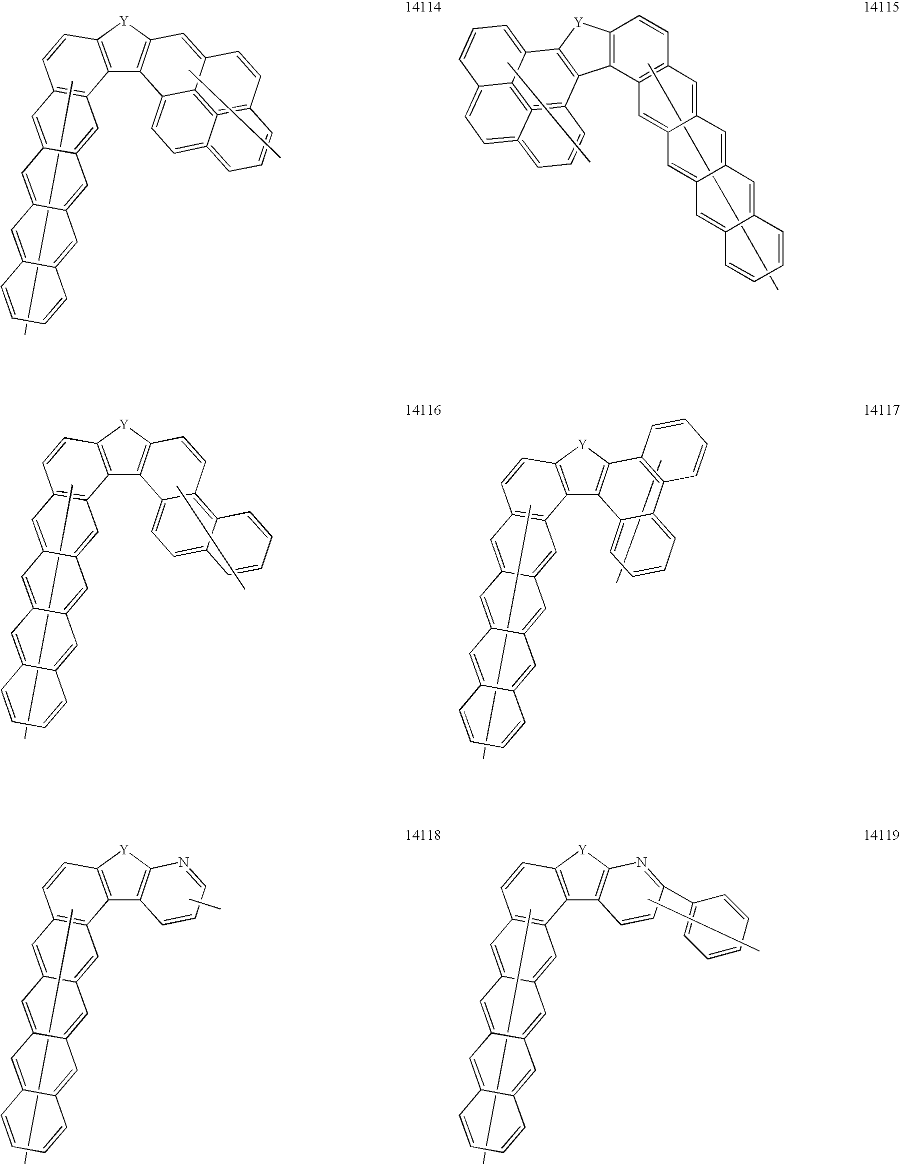

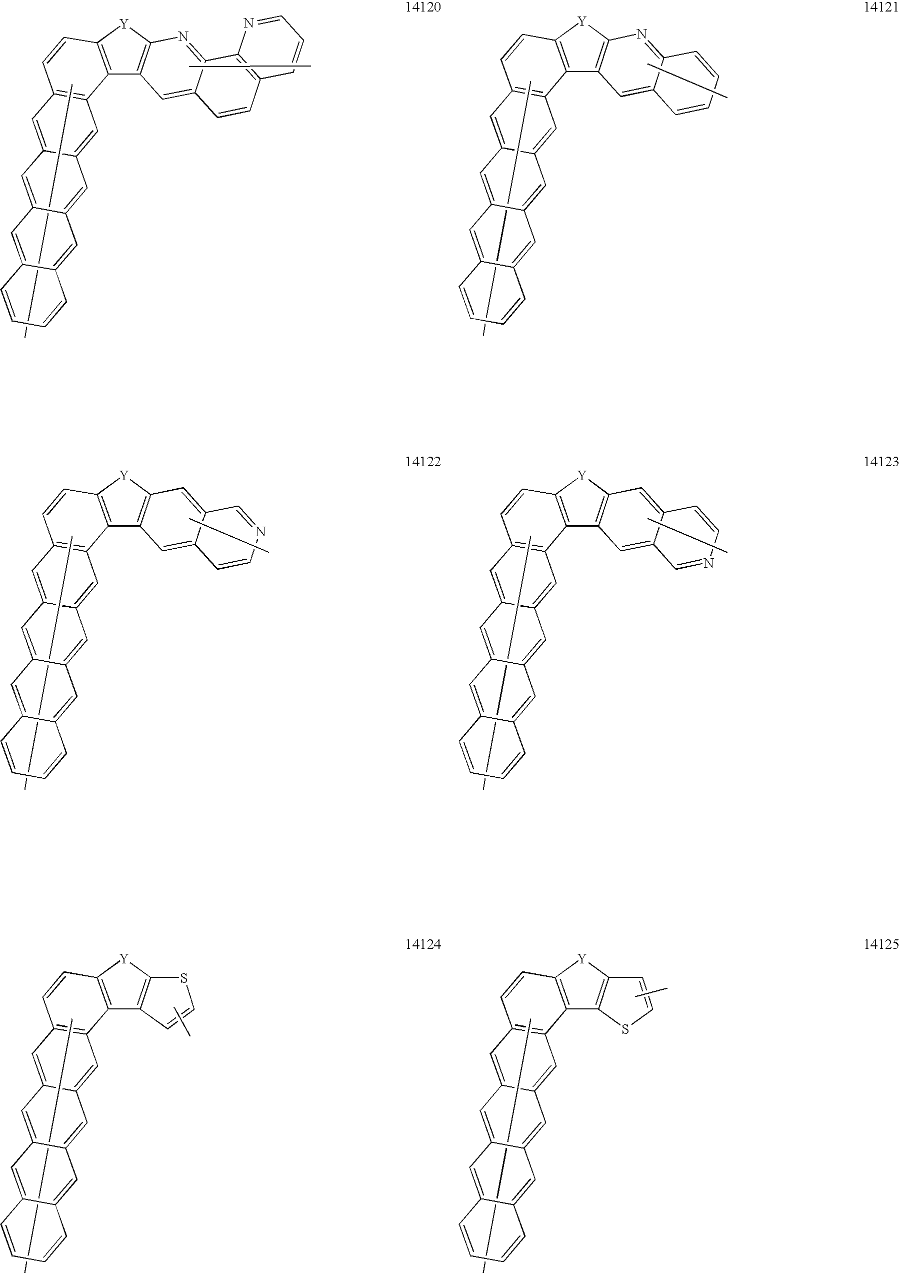

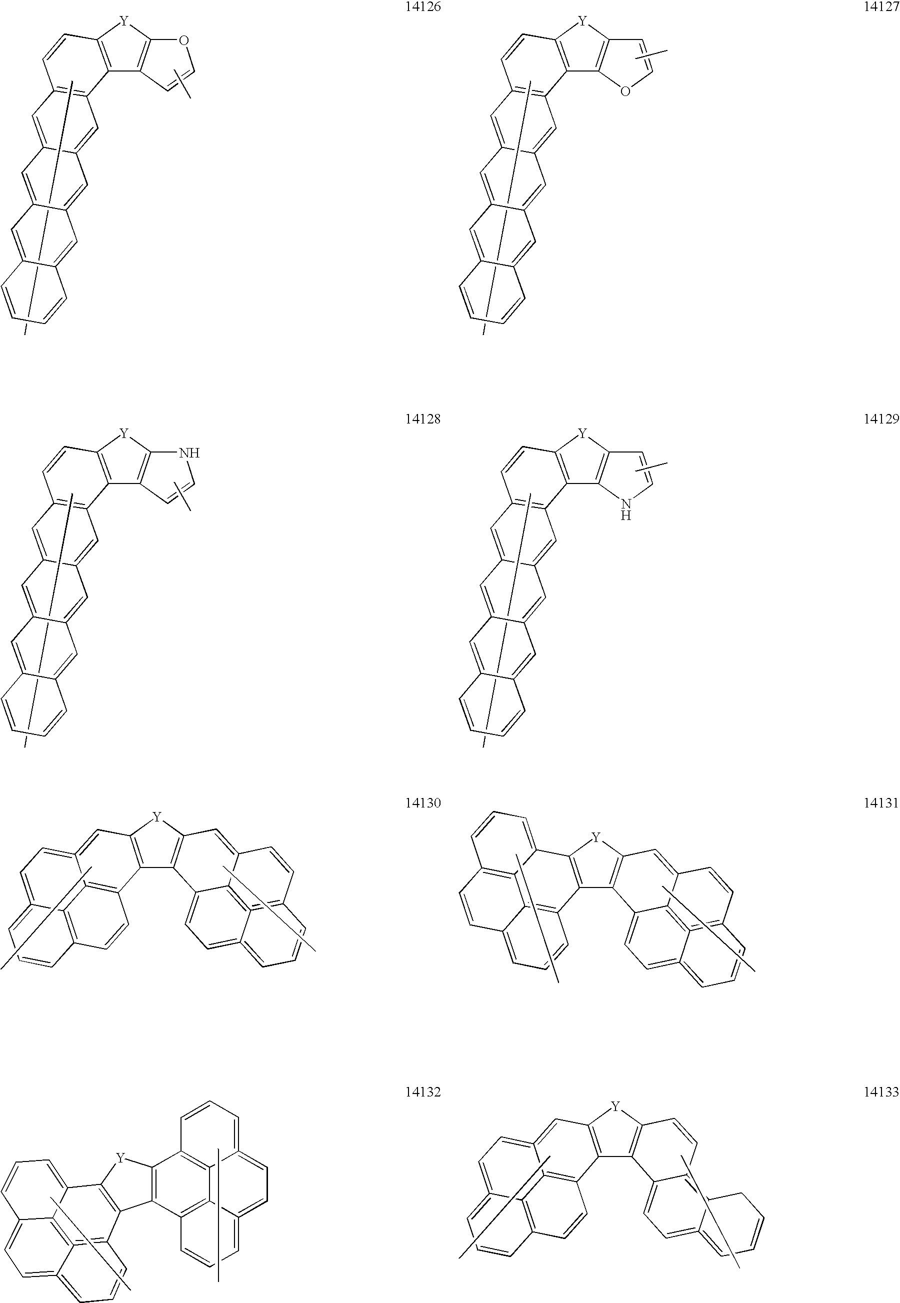

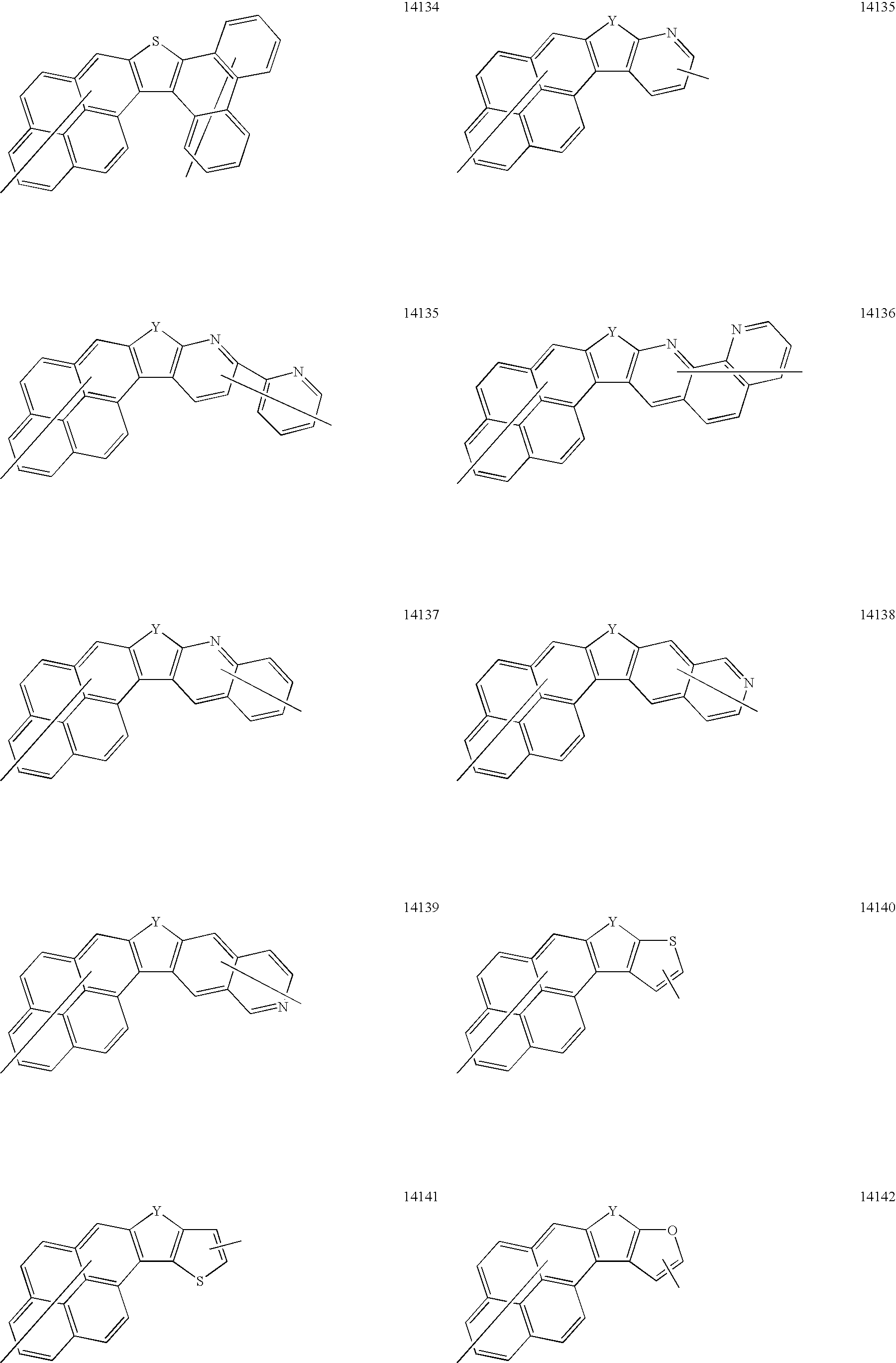

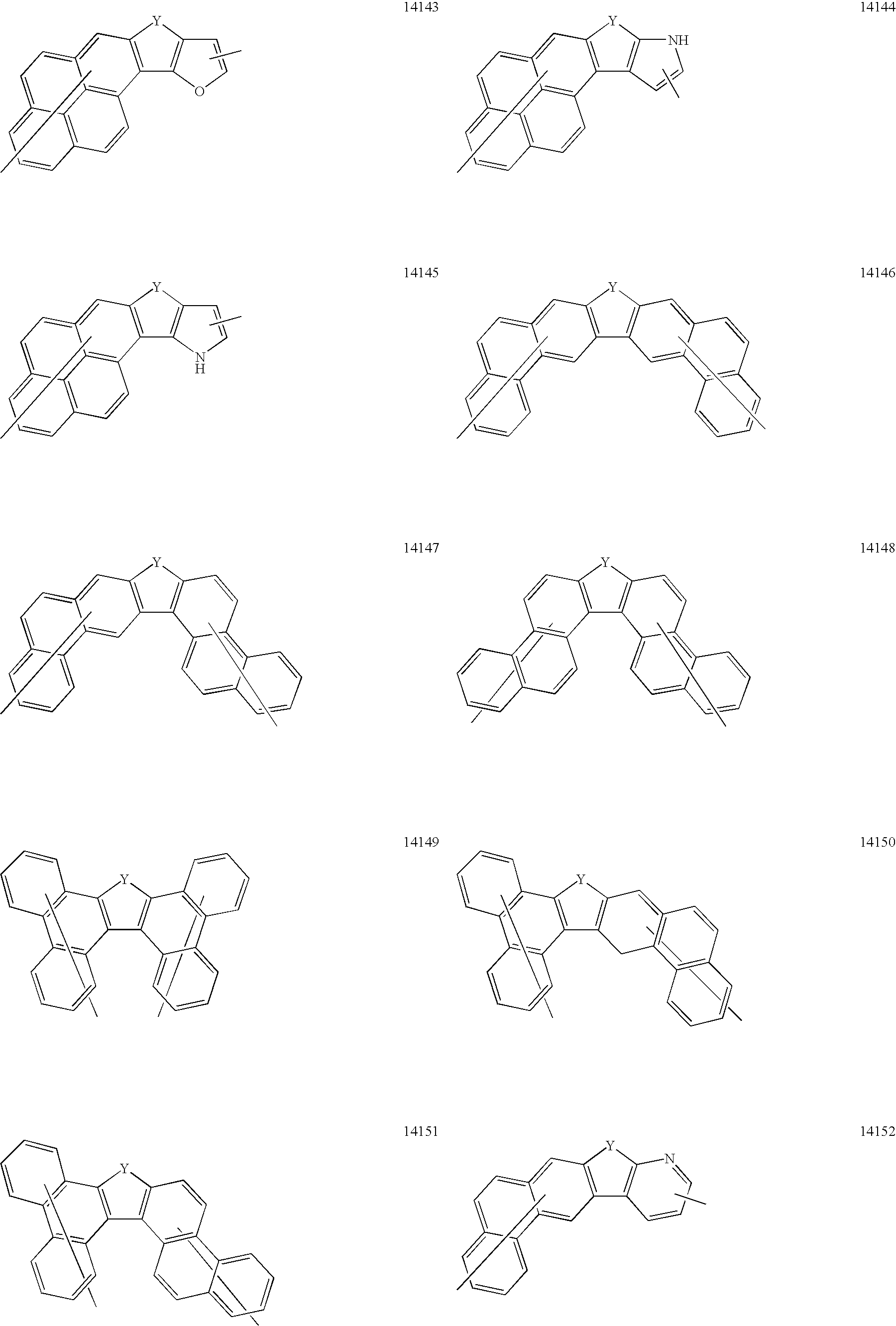

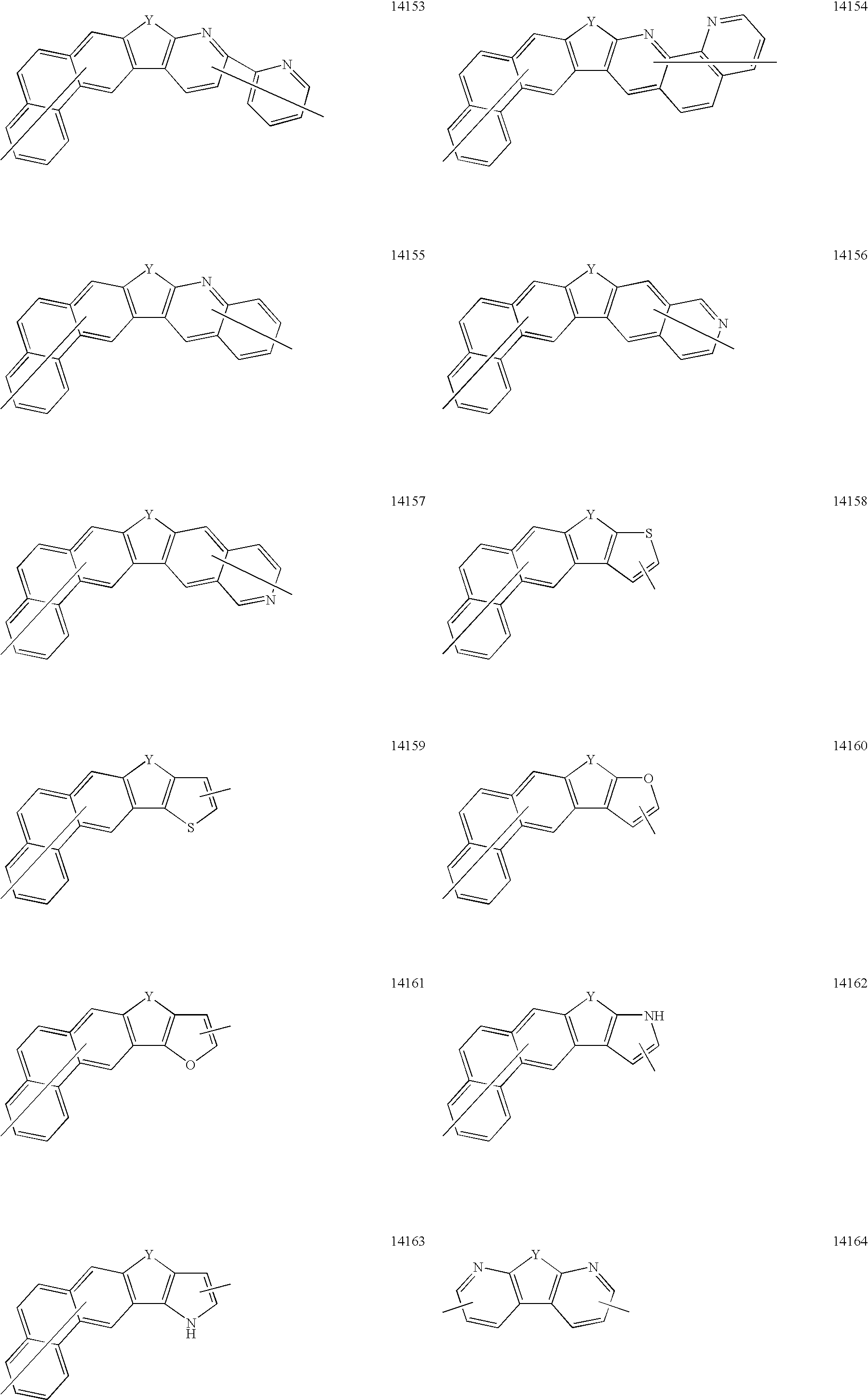

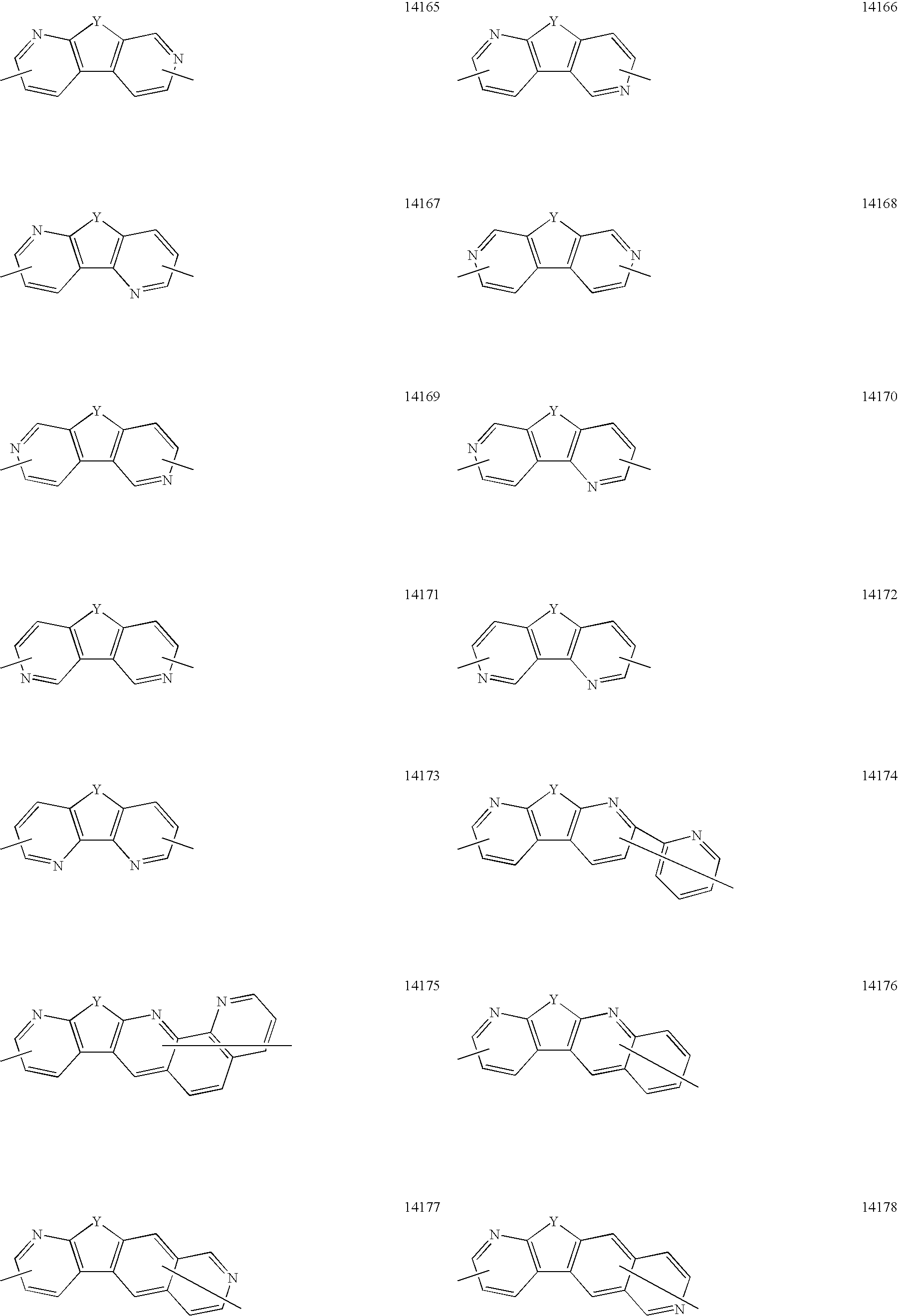

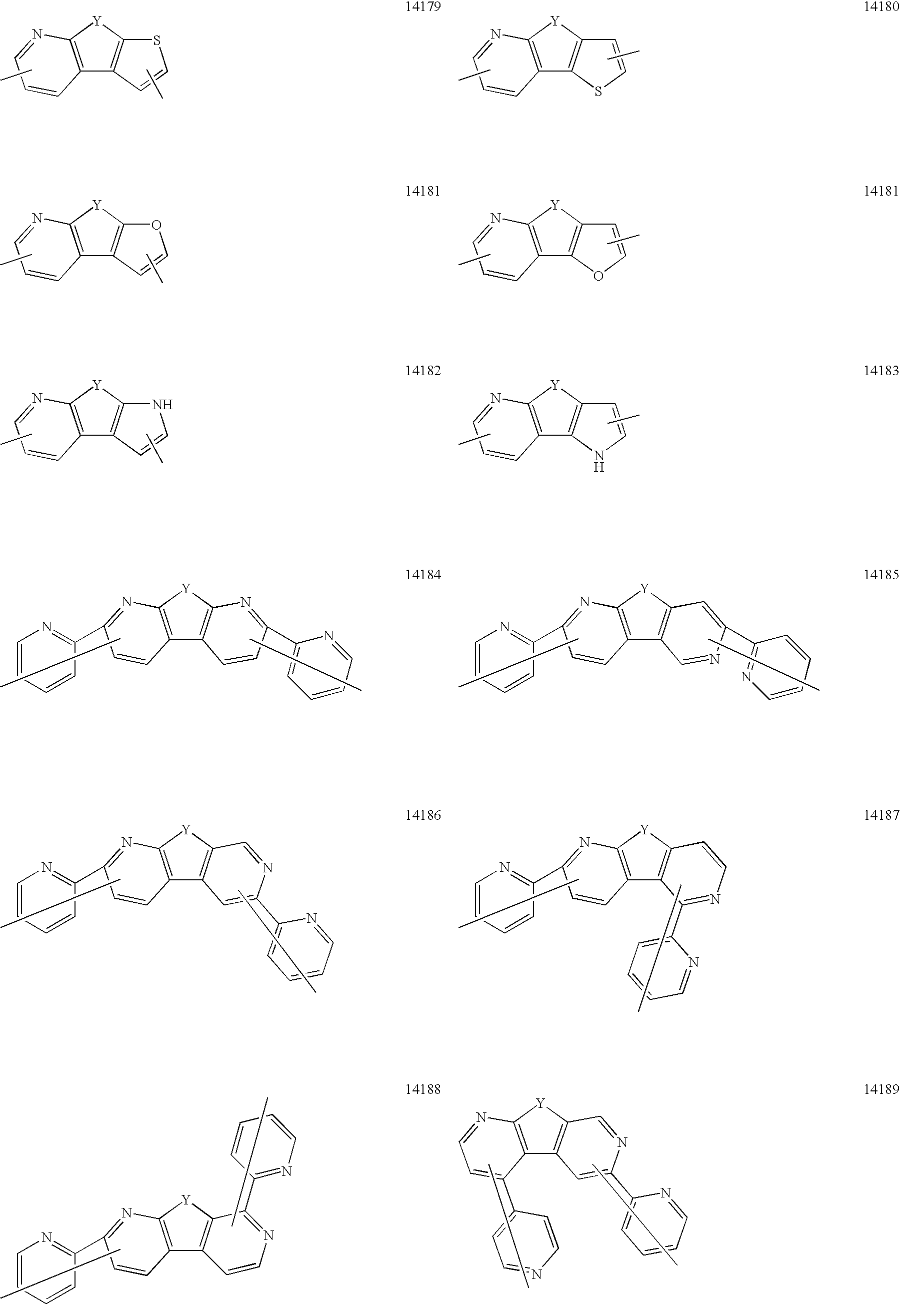

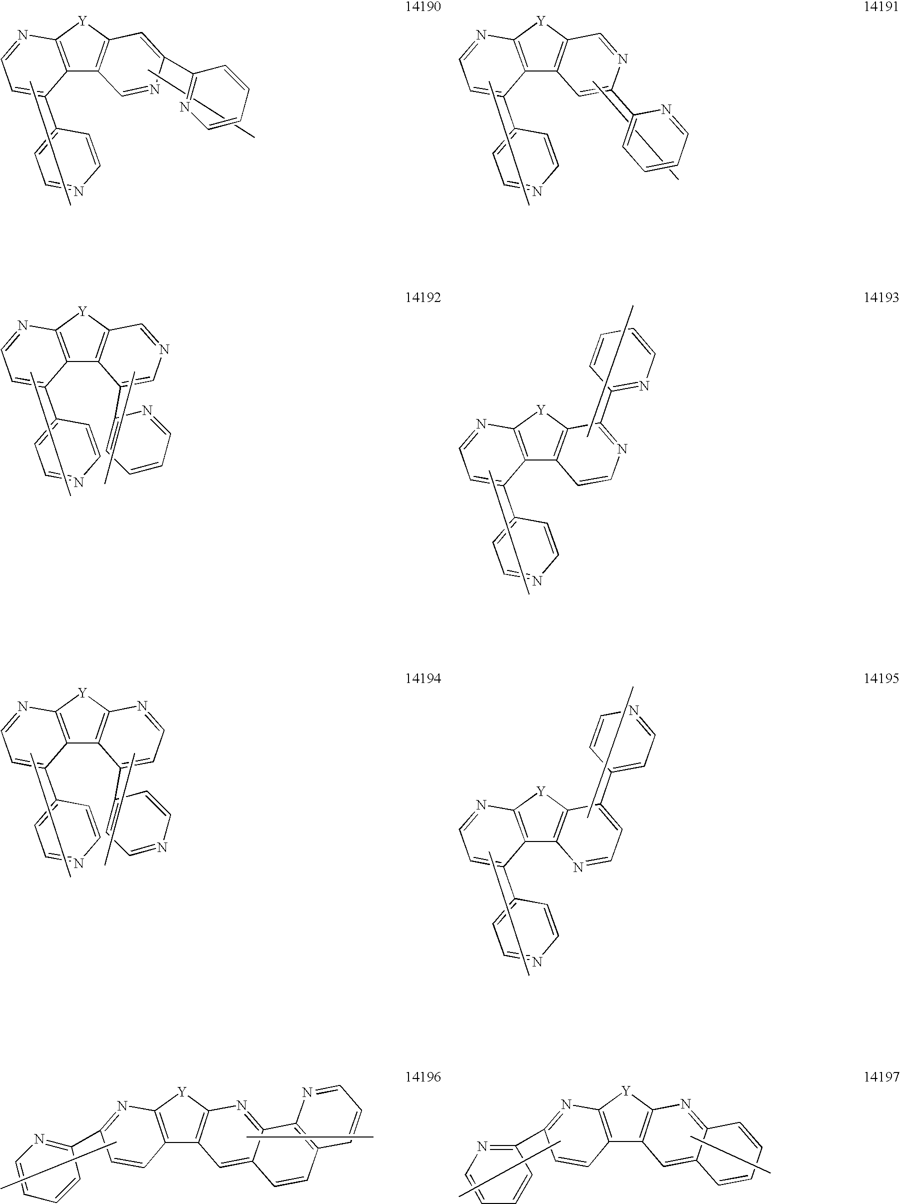

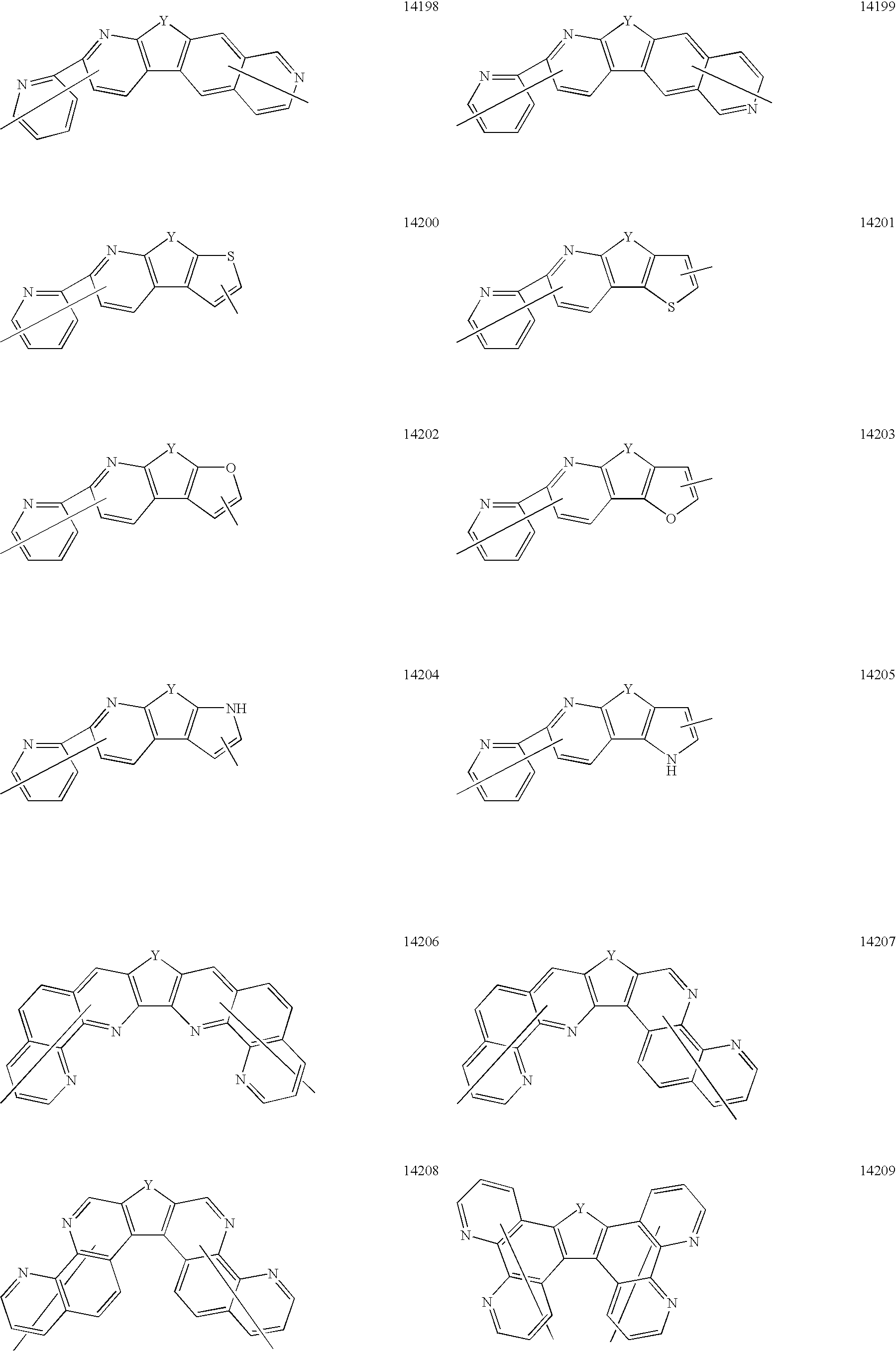

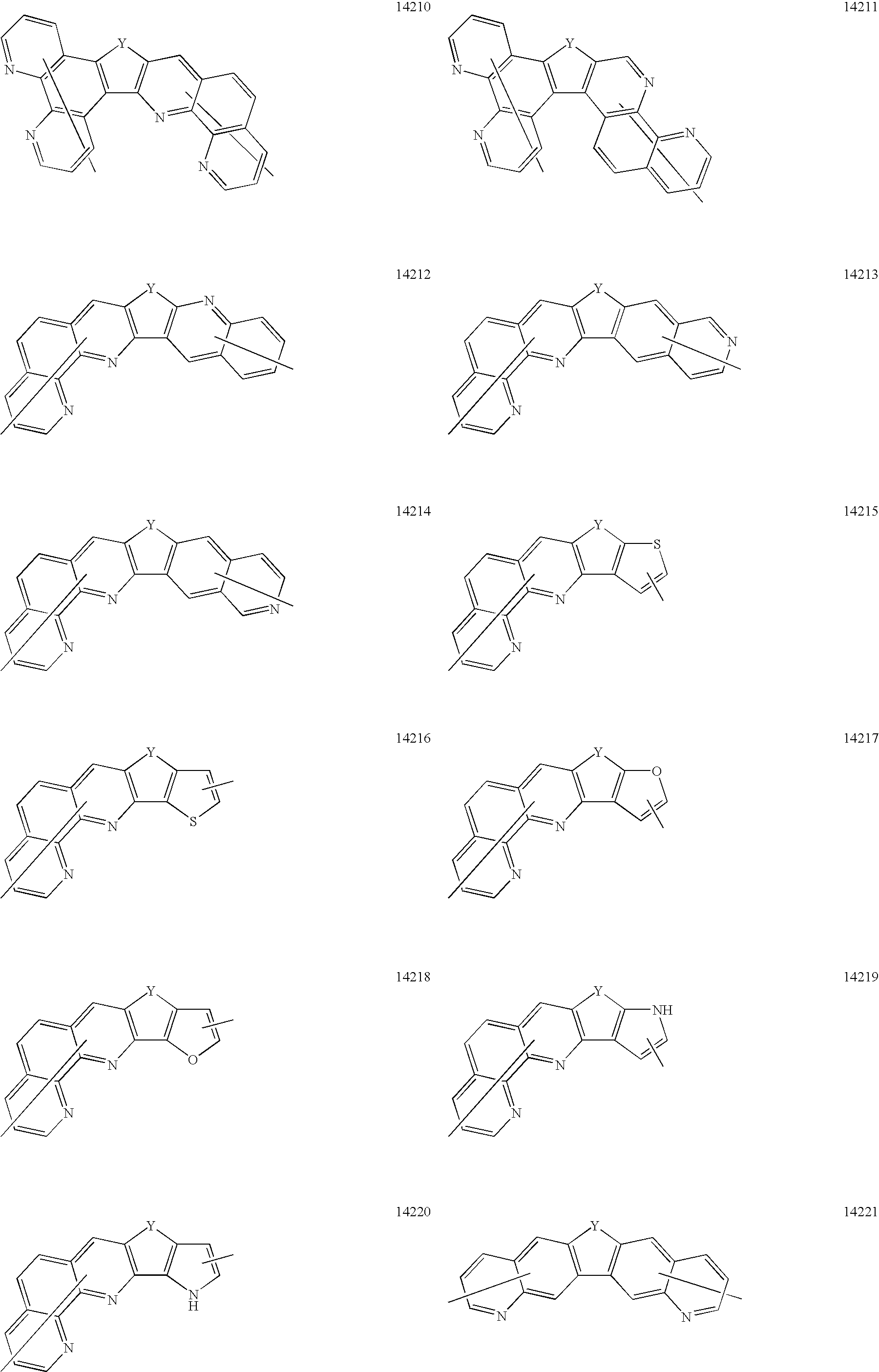

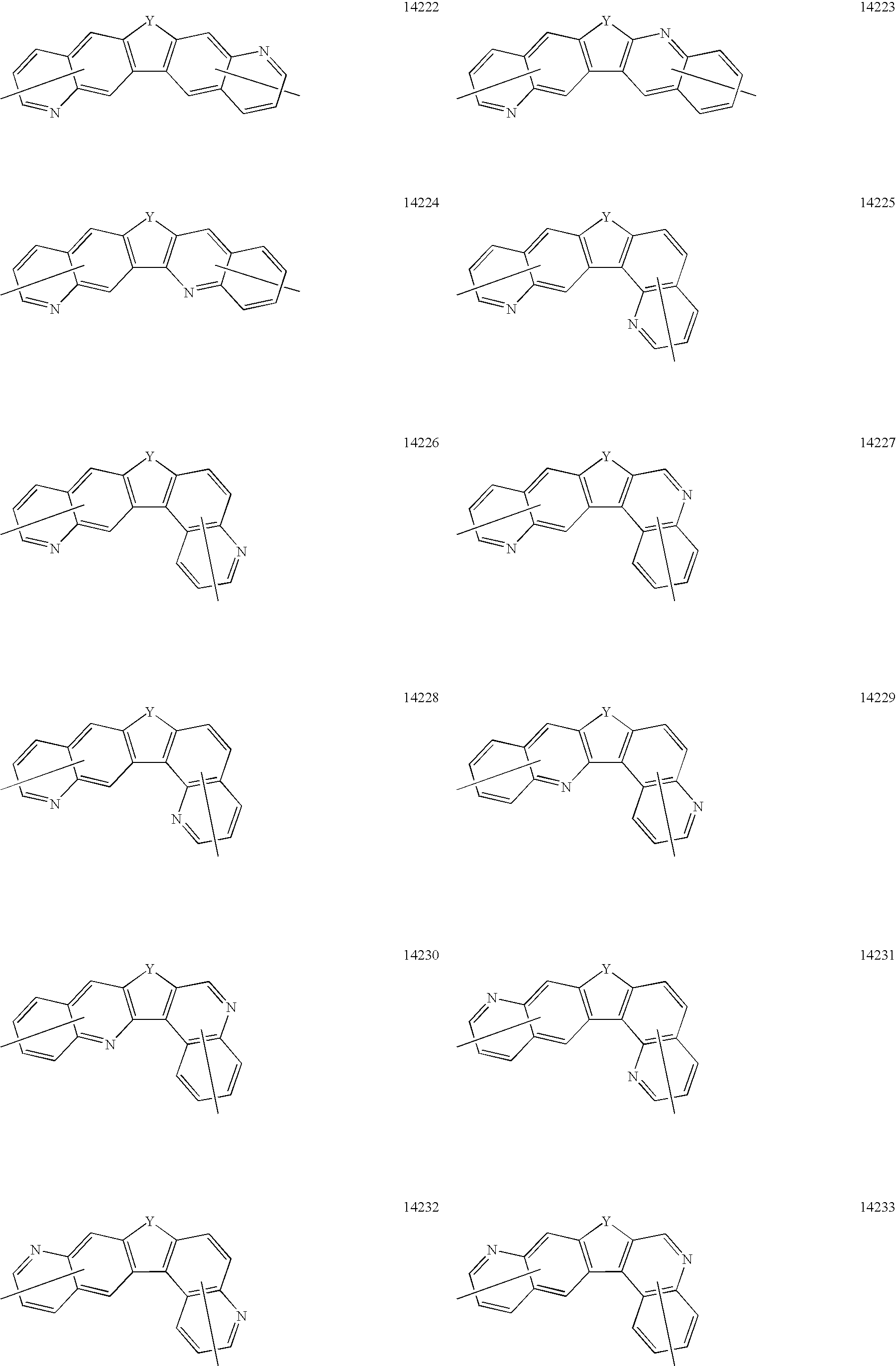

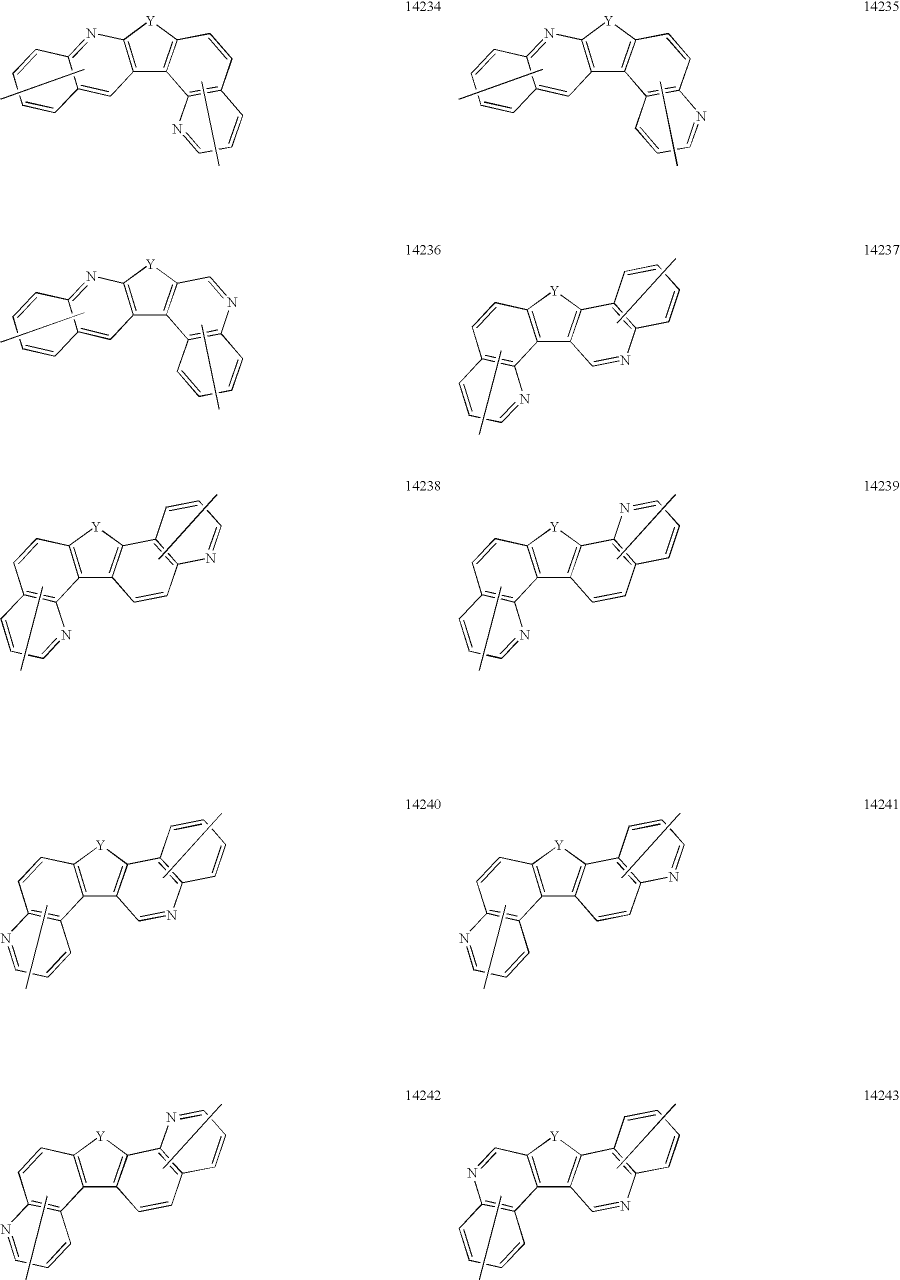

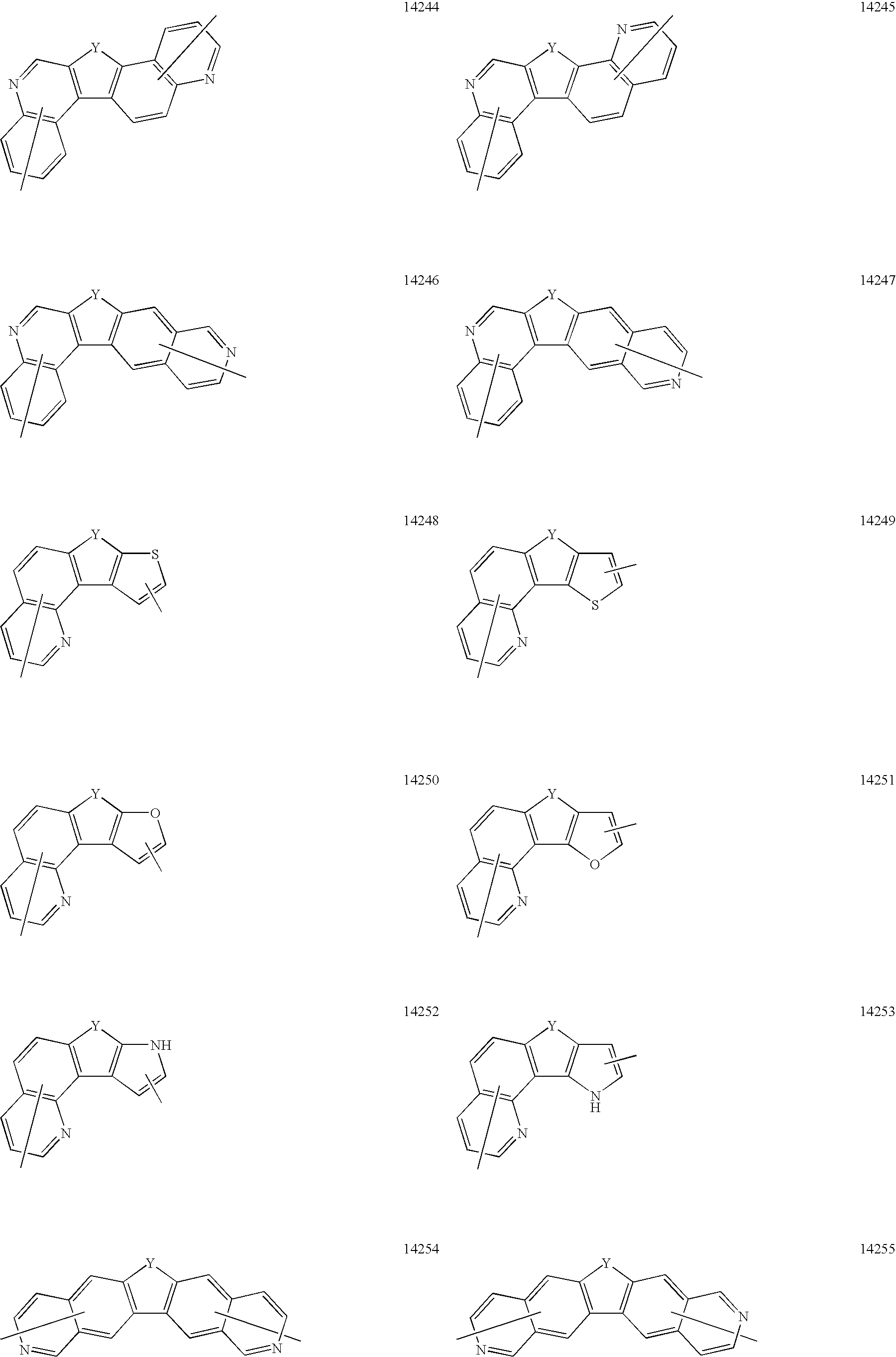

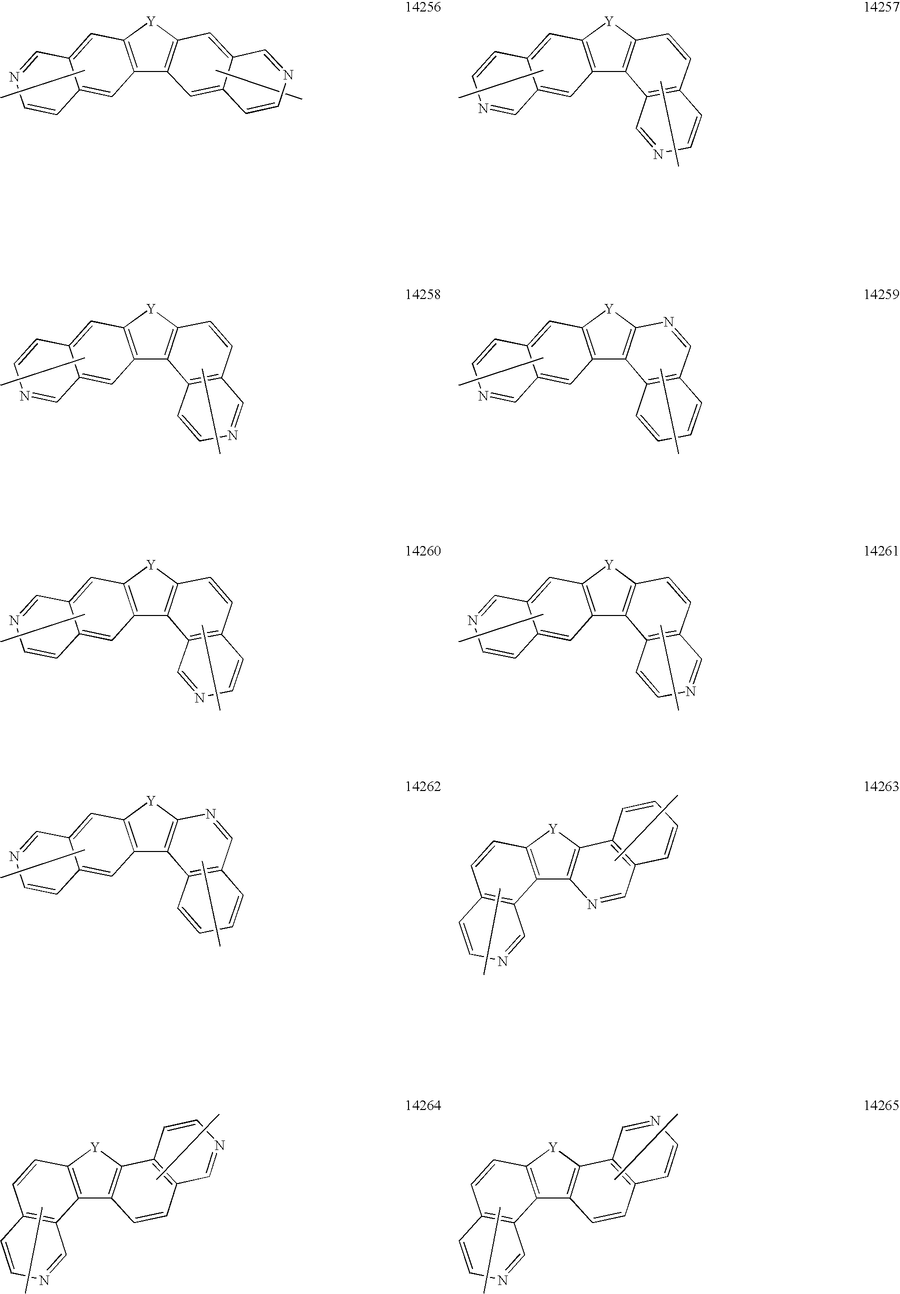

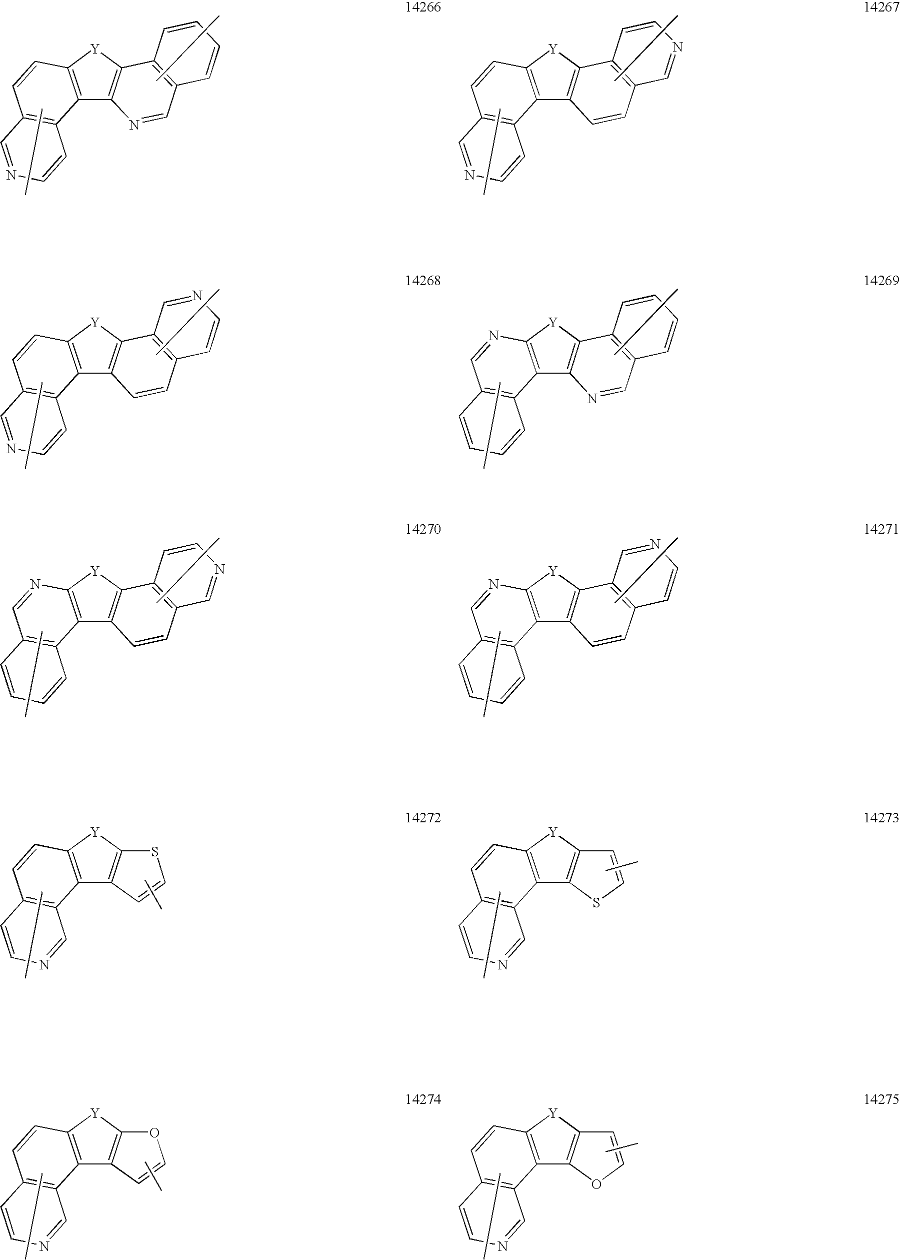

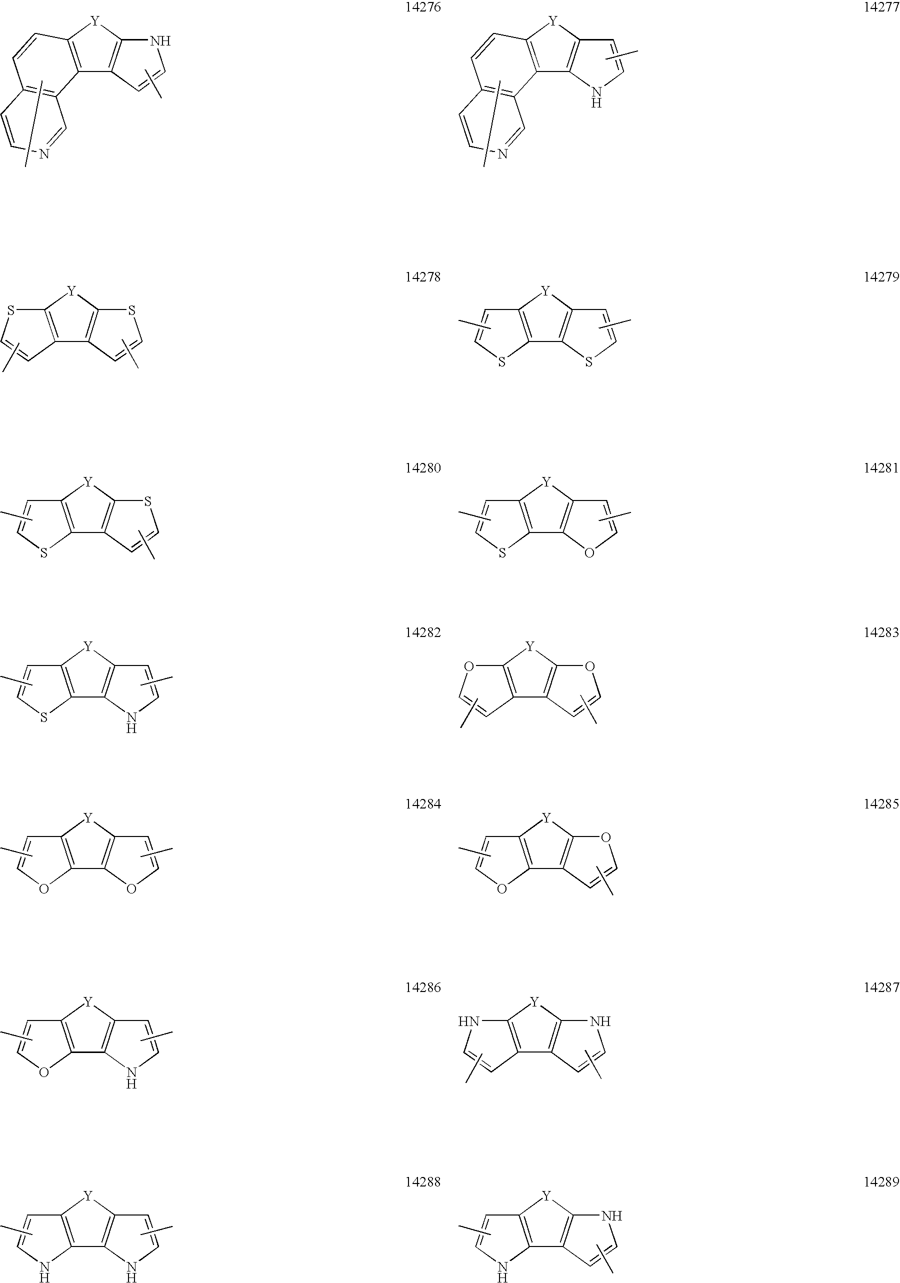

Concrete examples of formula (1-5) include the followings. Furthermore, those of the followings having substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. In the formulas, the connecting bonds show that they may exist on the arbitrary positions of the aromatic ring.

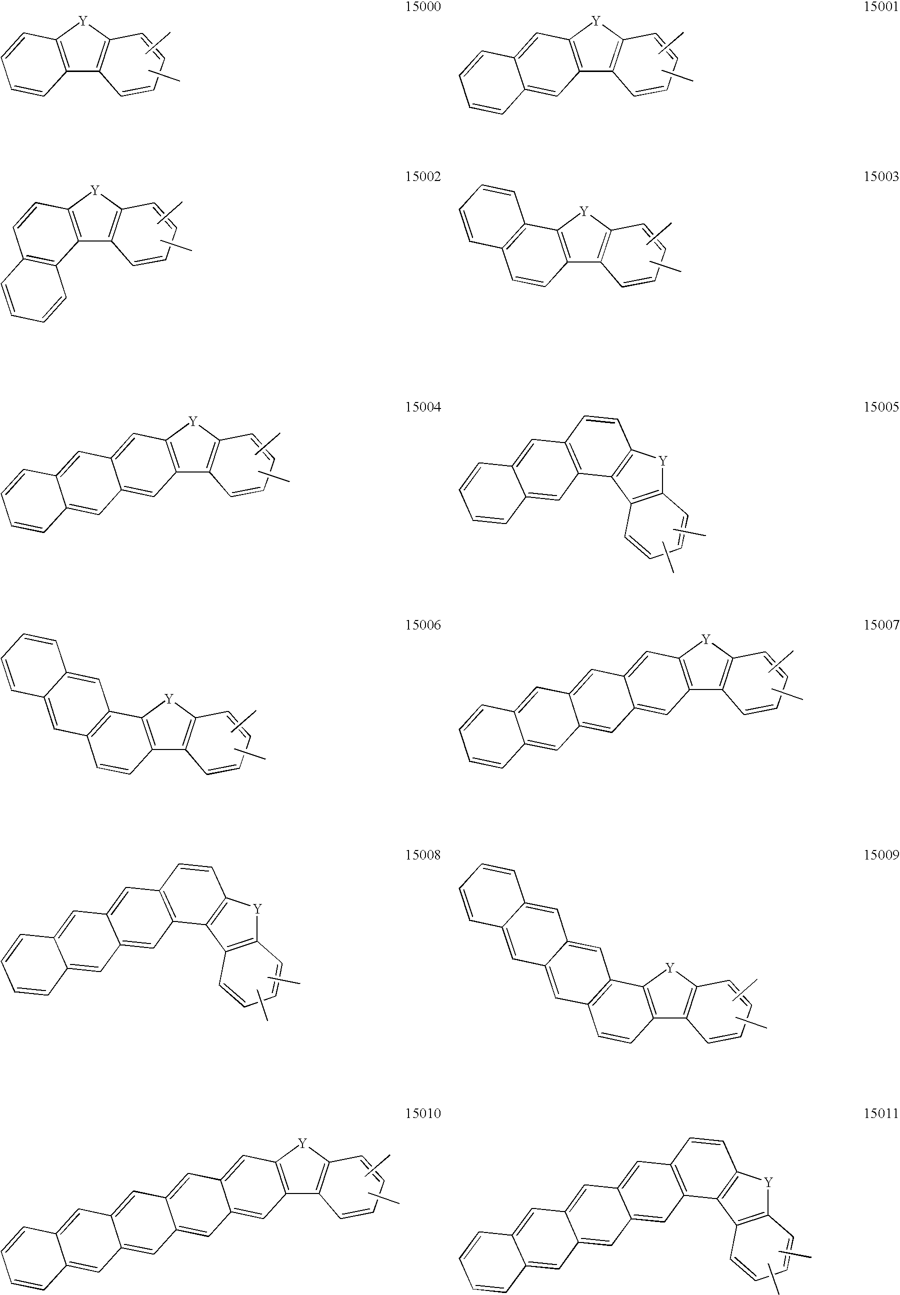

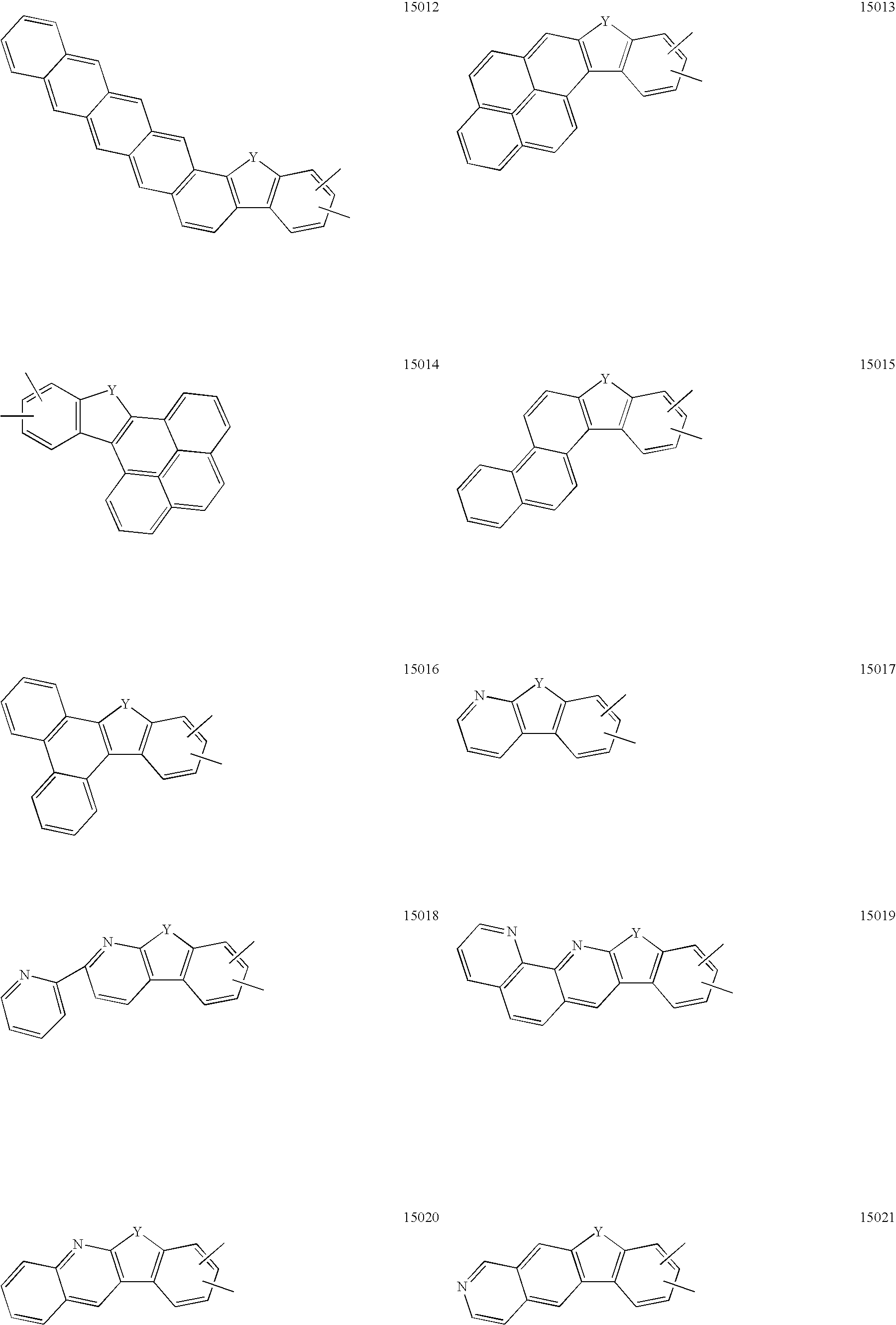

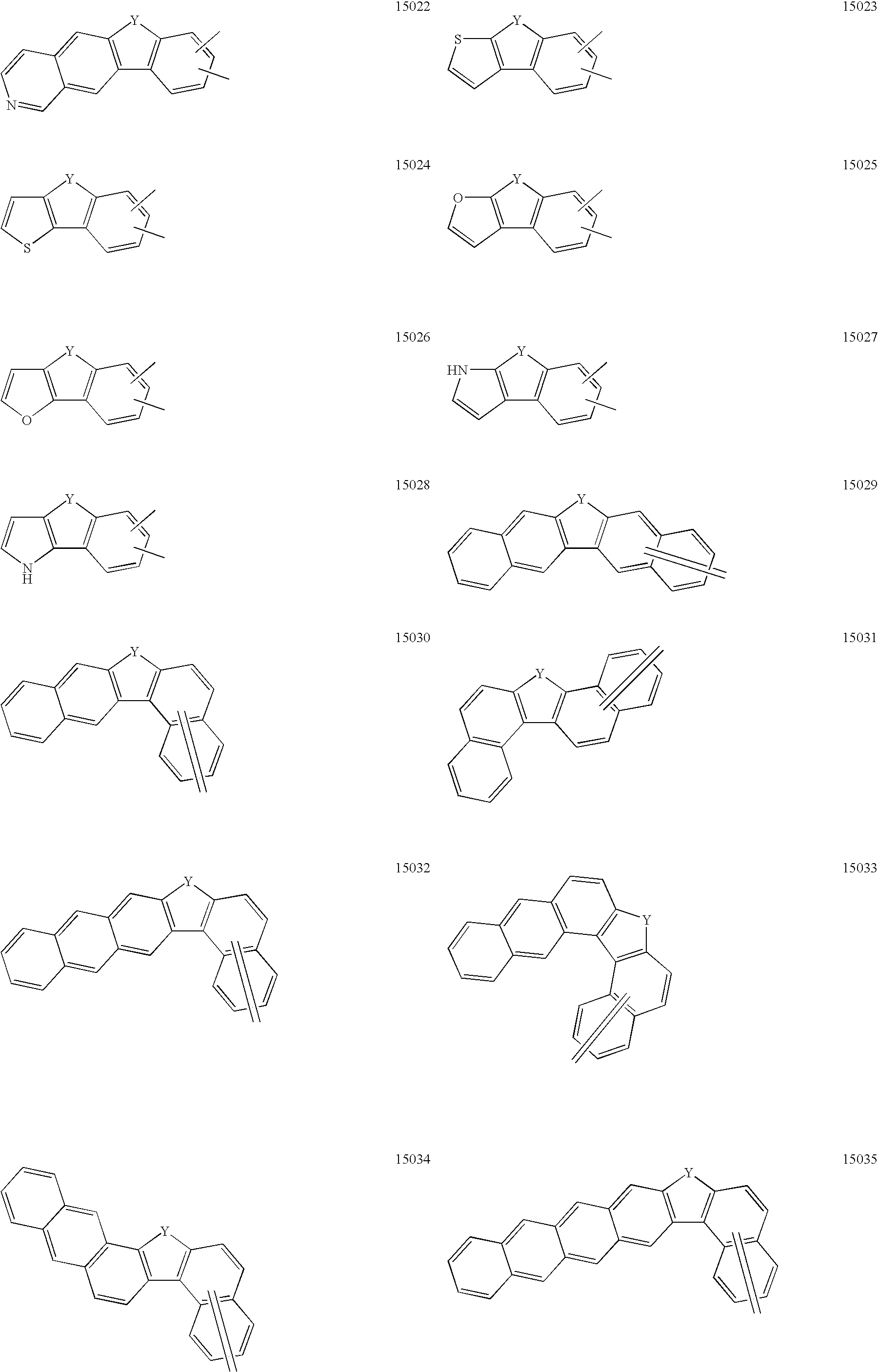

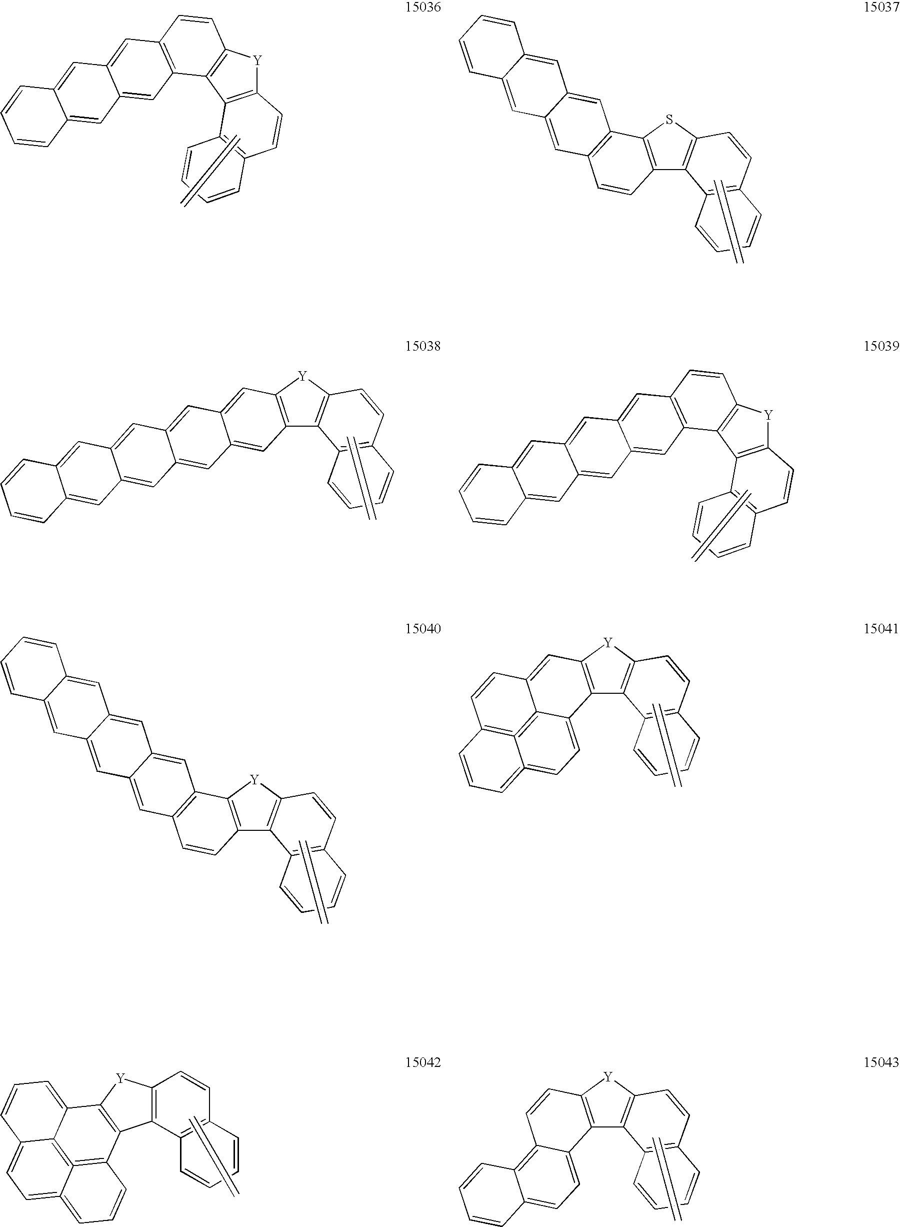

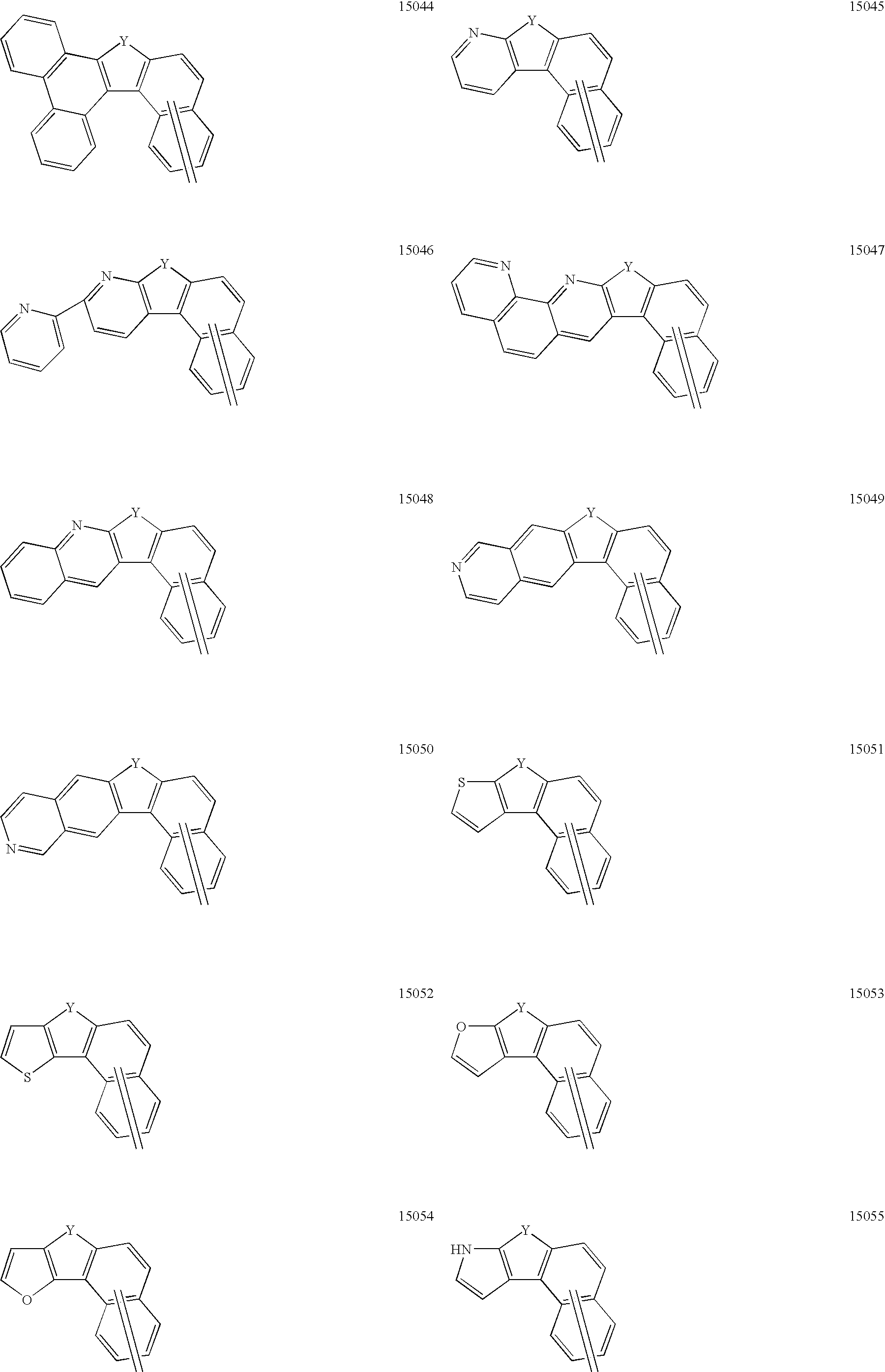

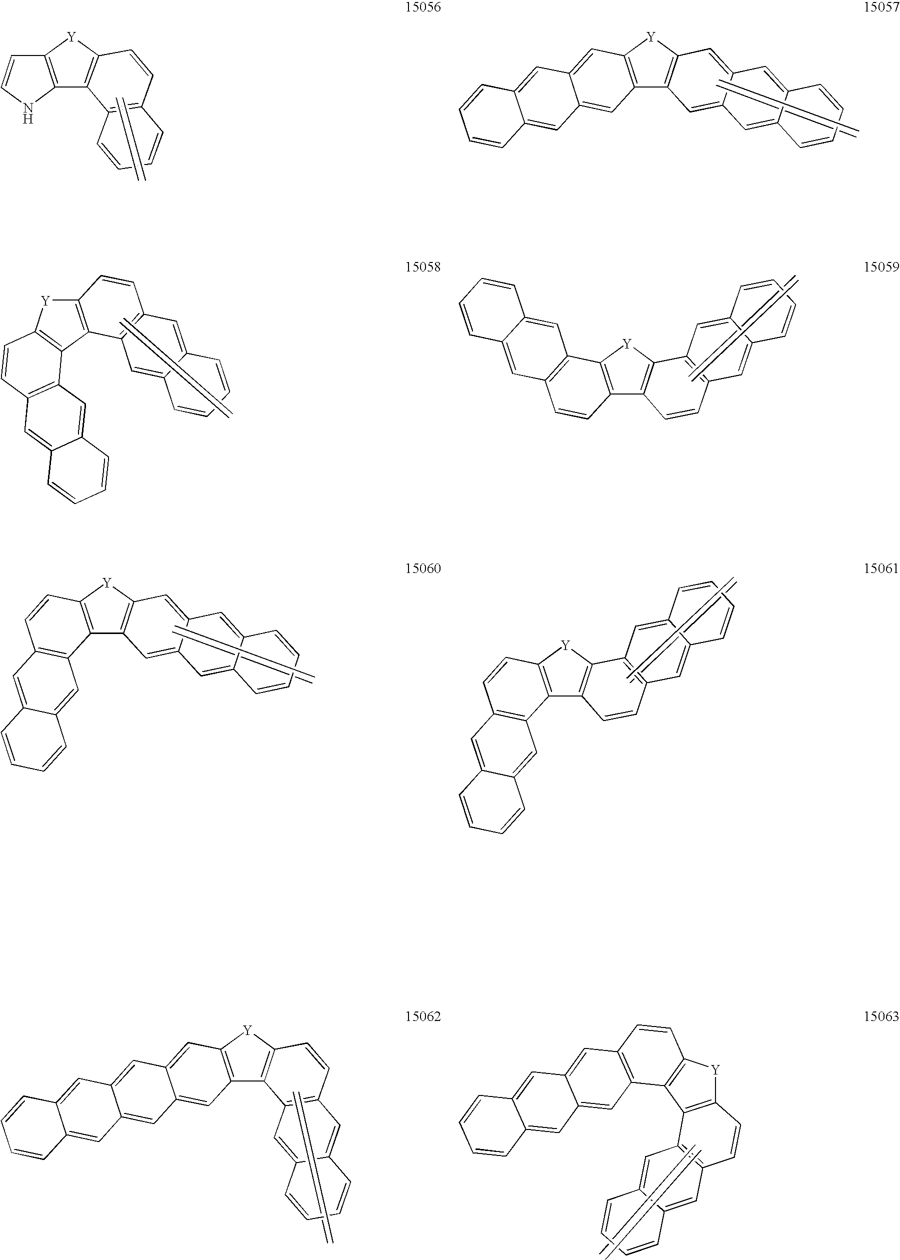

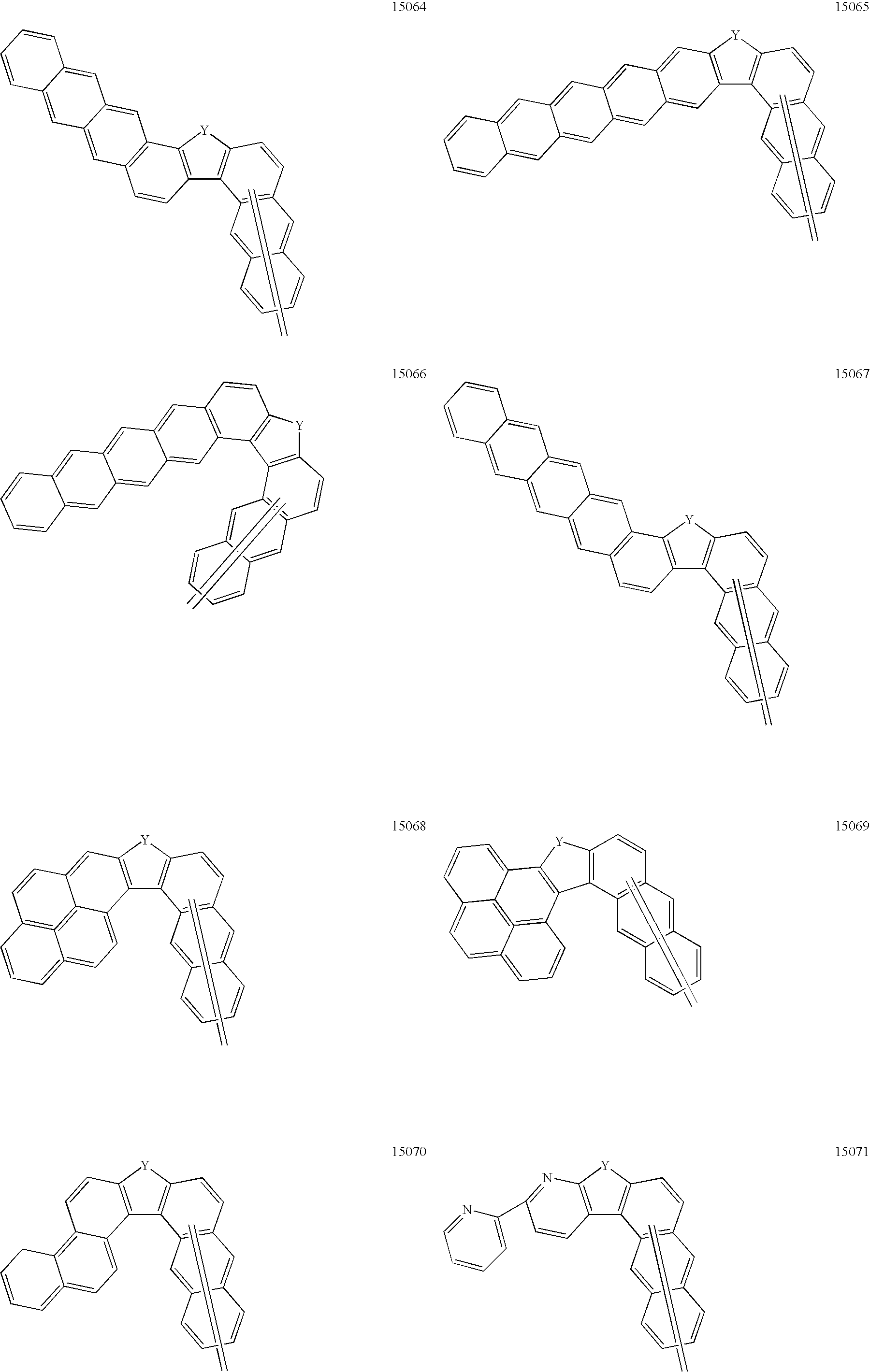

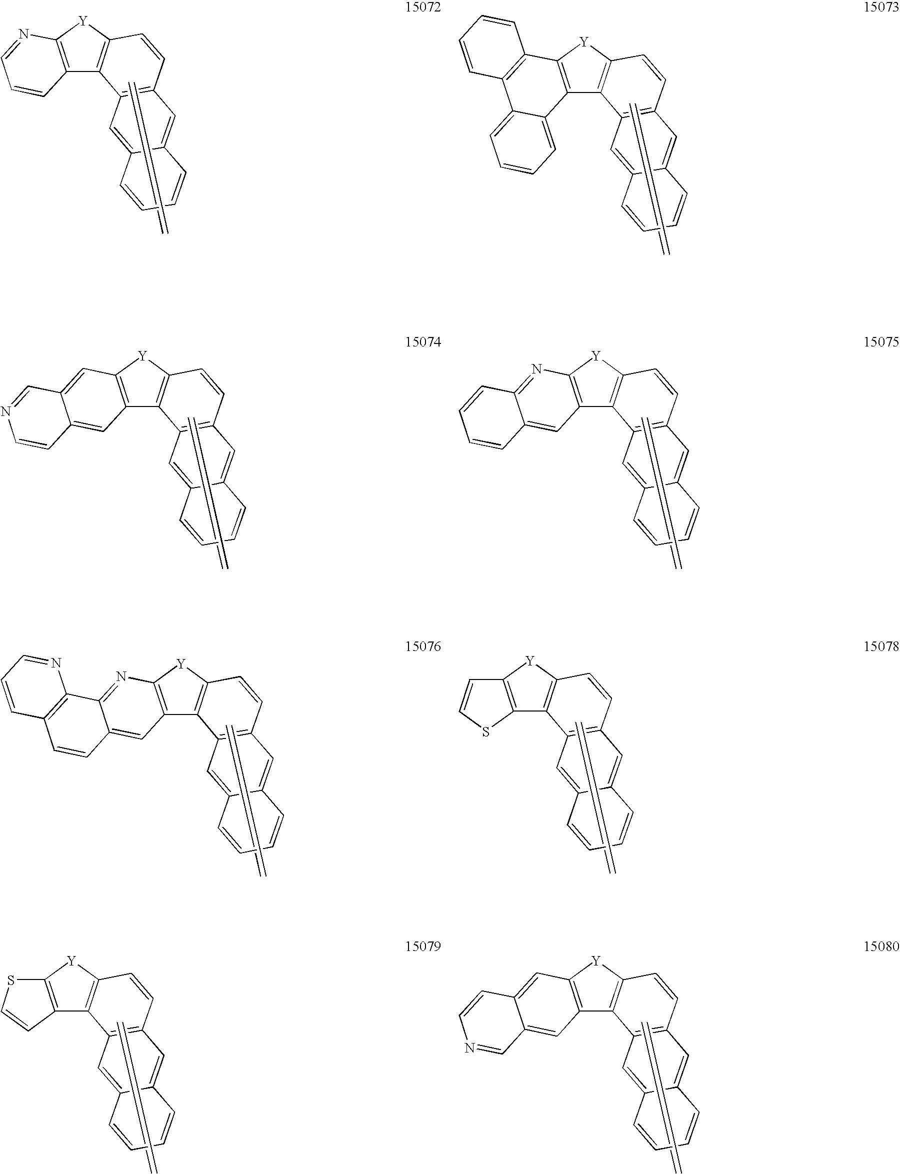

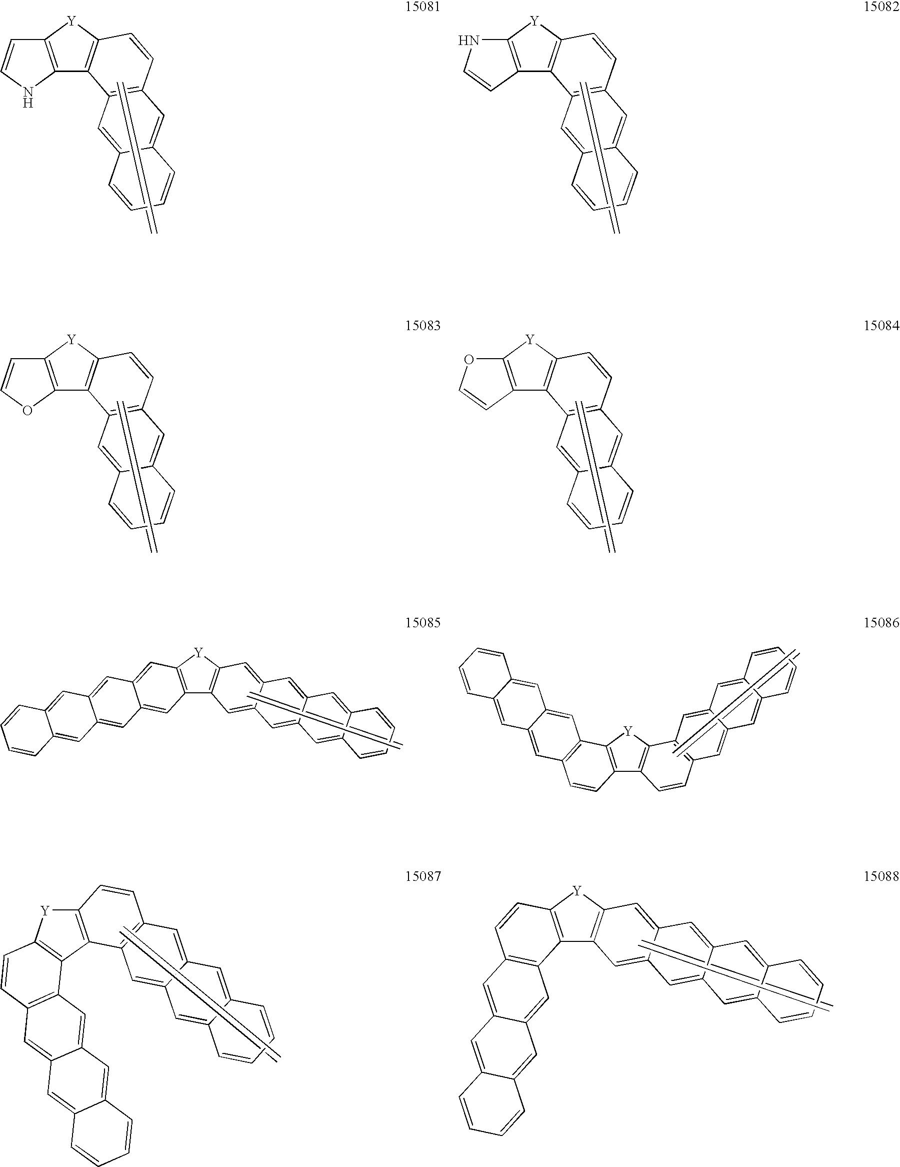

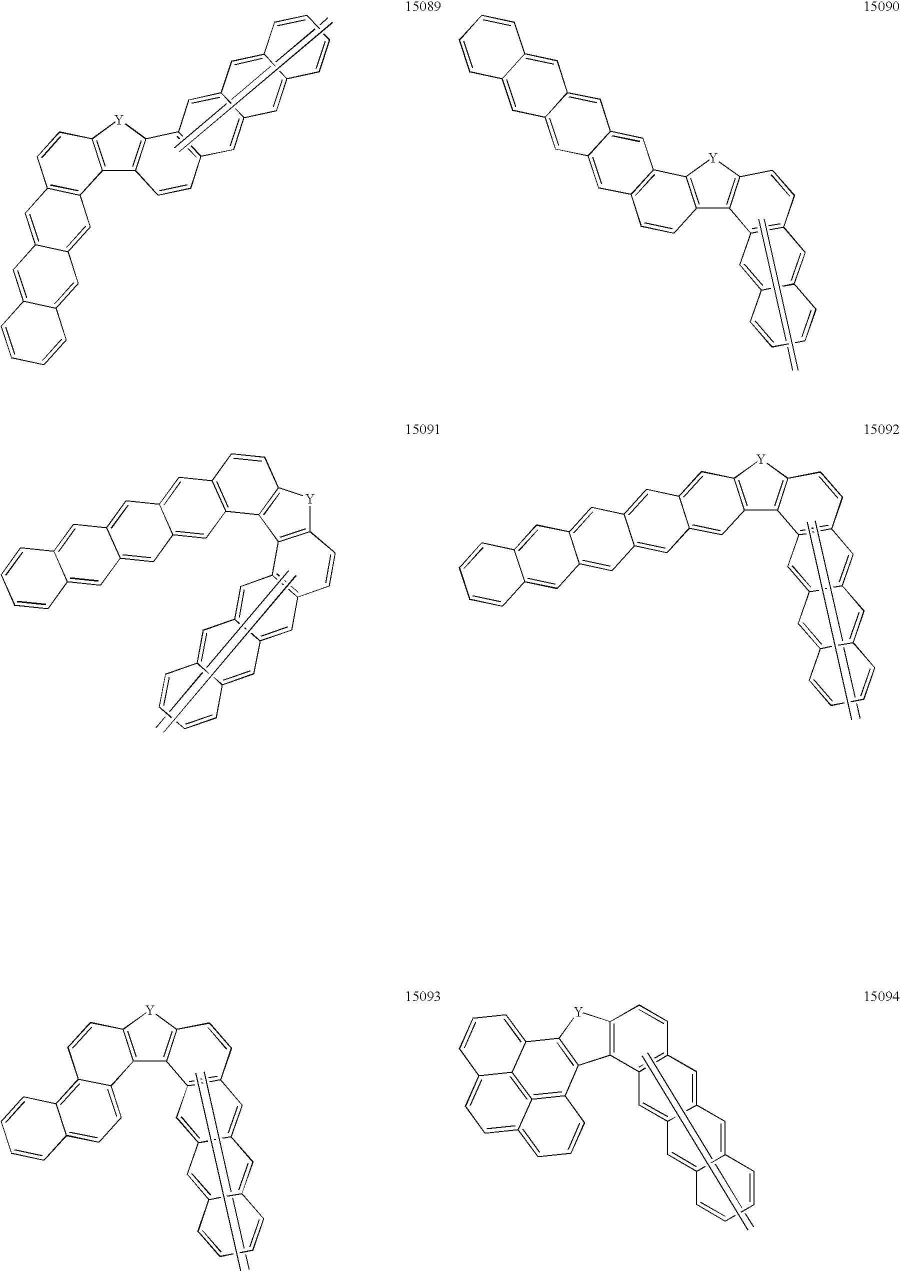

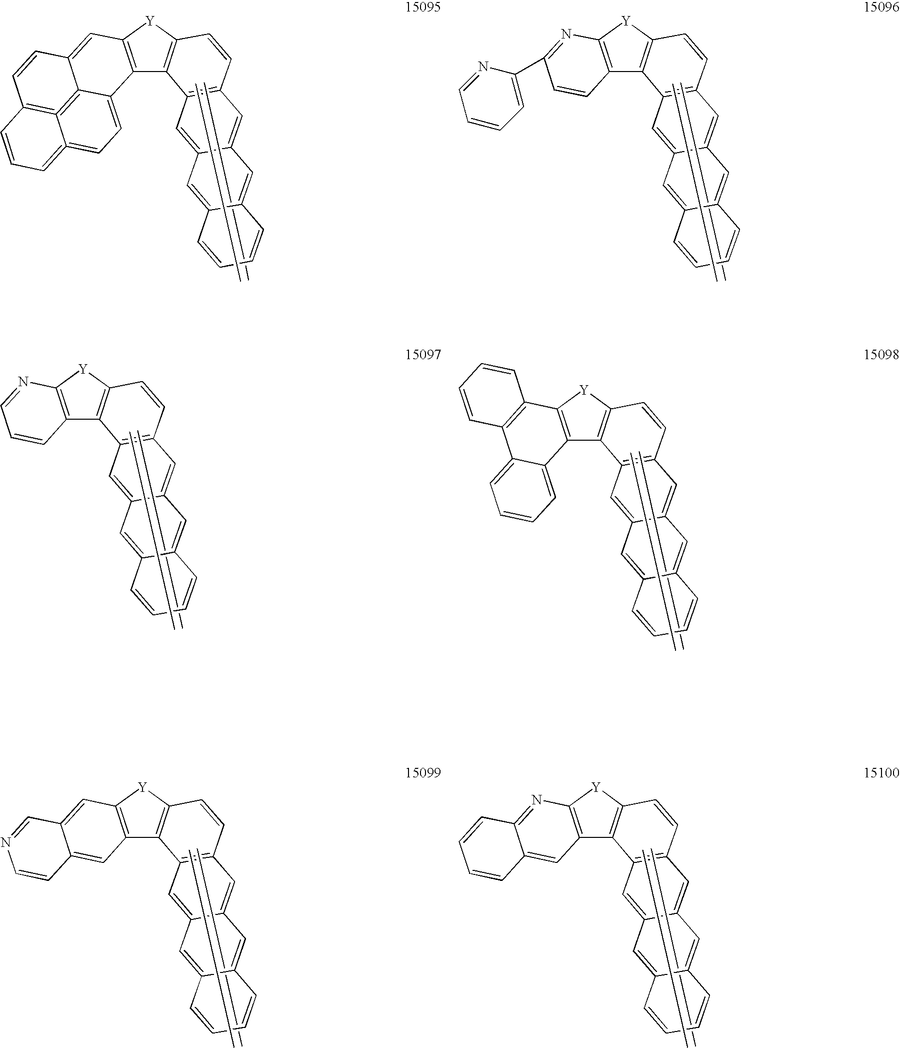

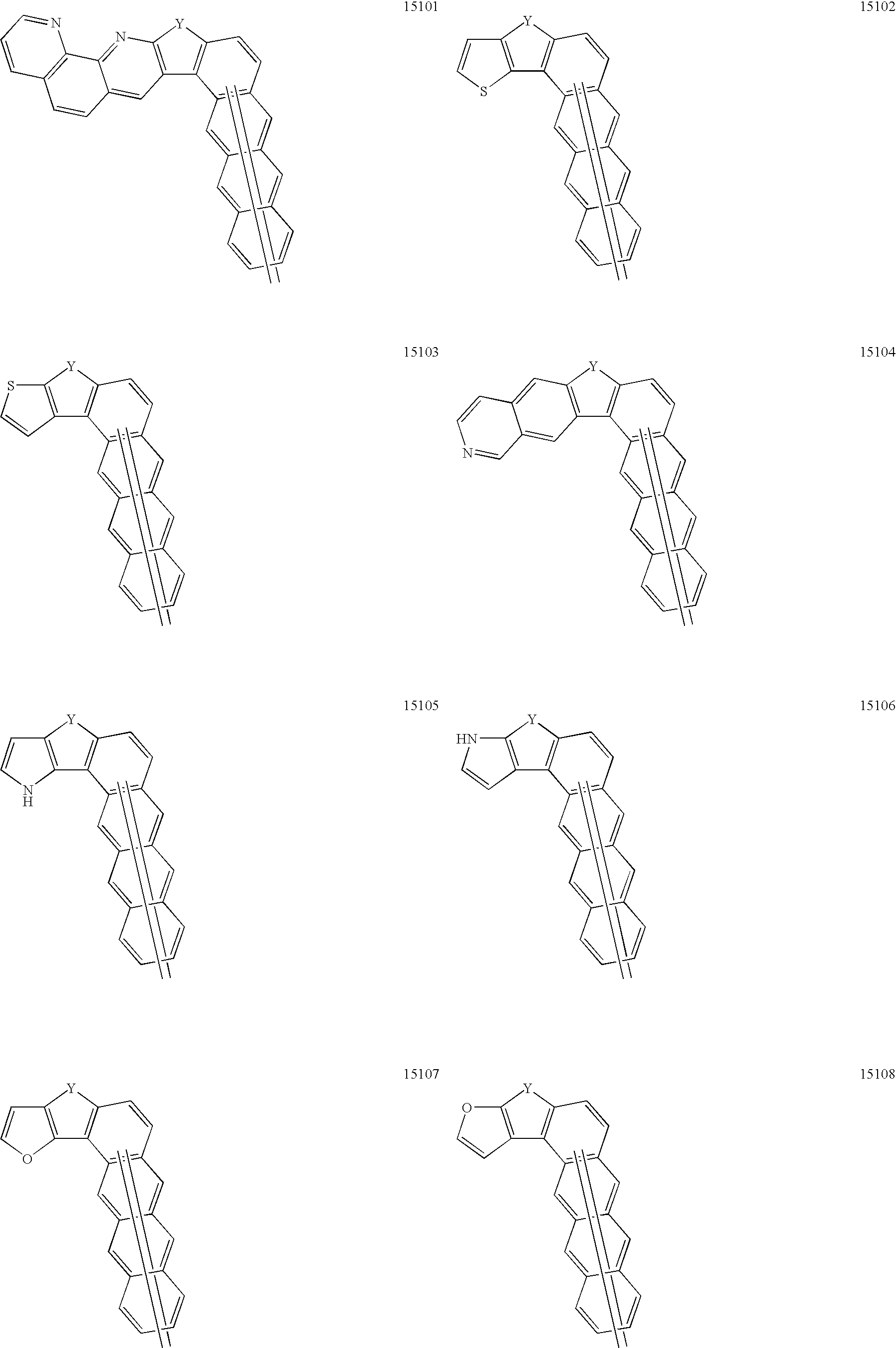

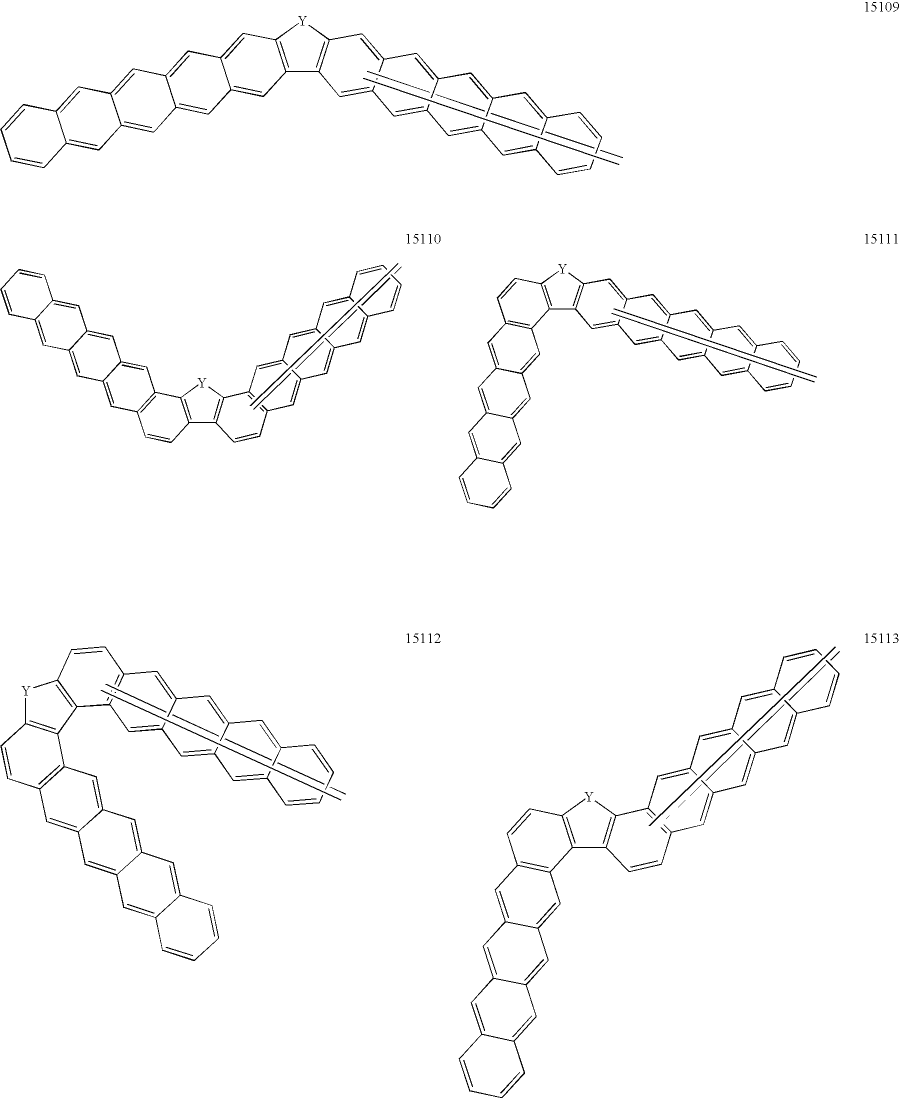

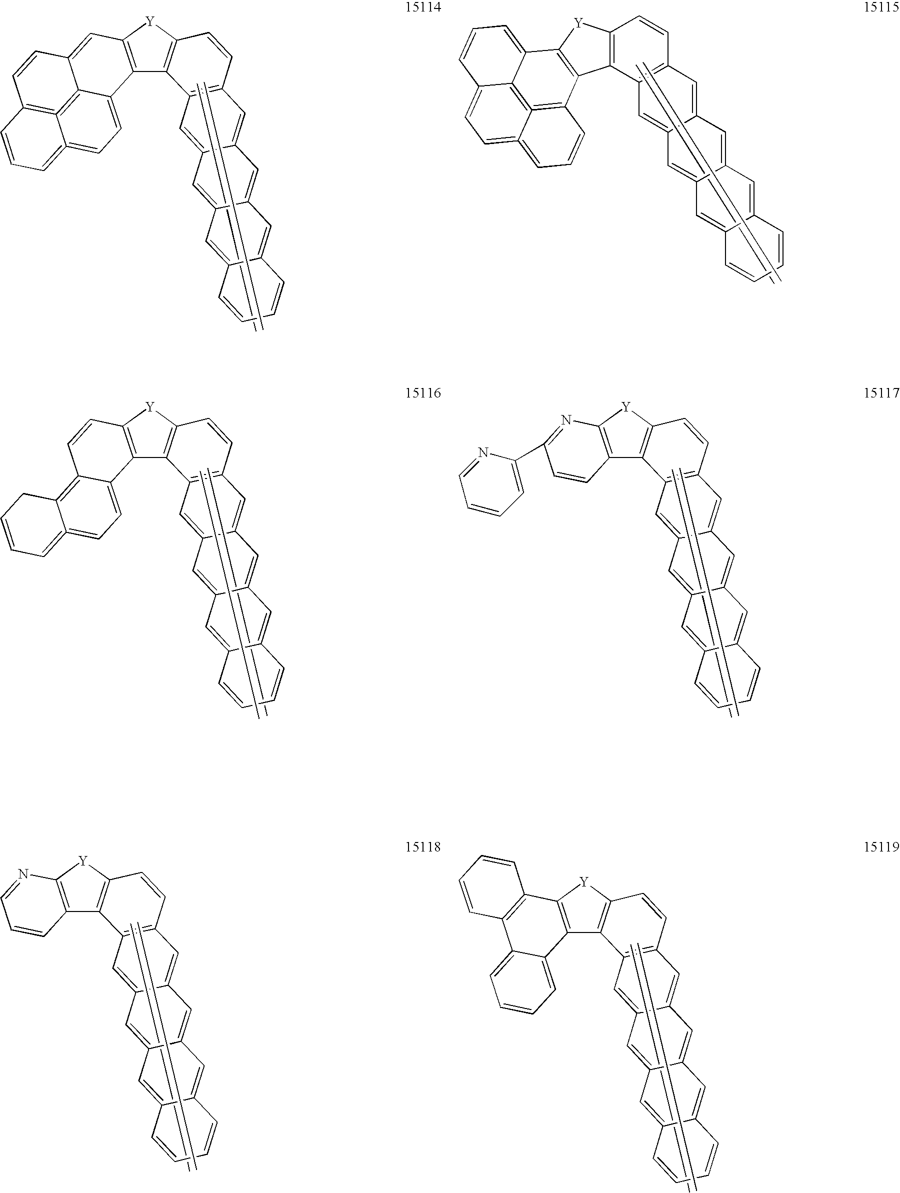

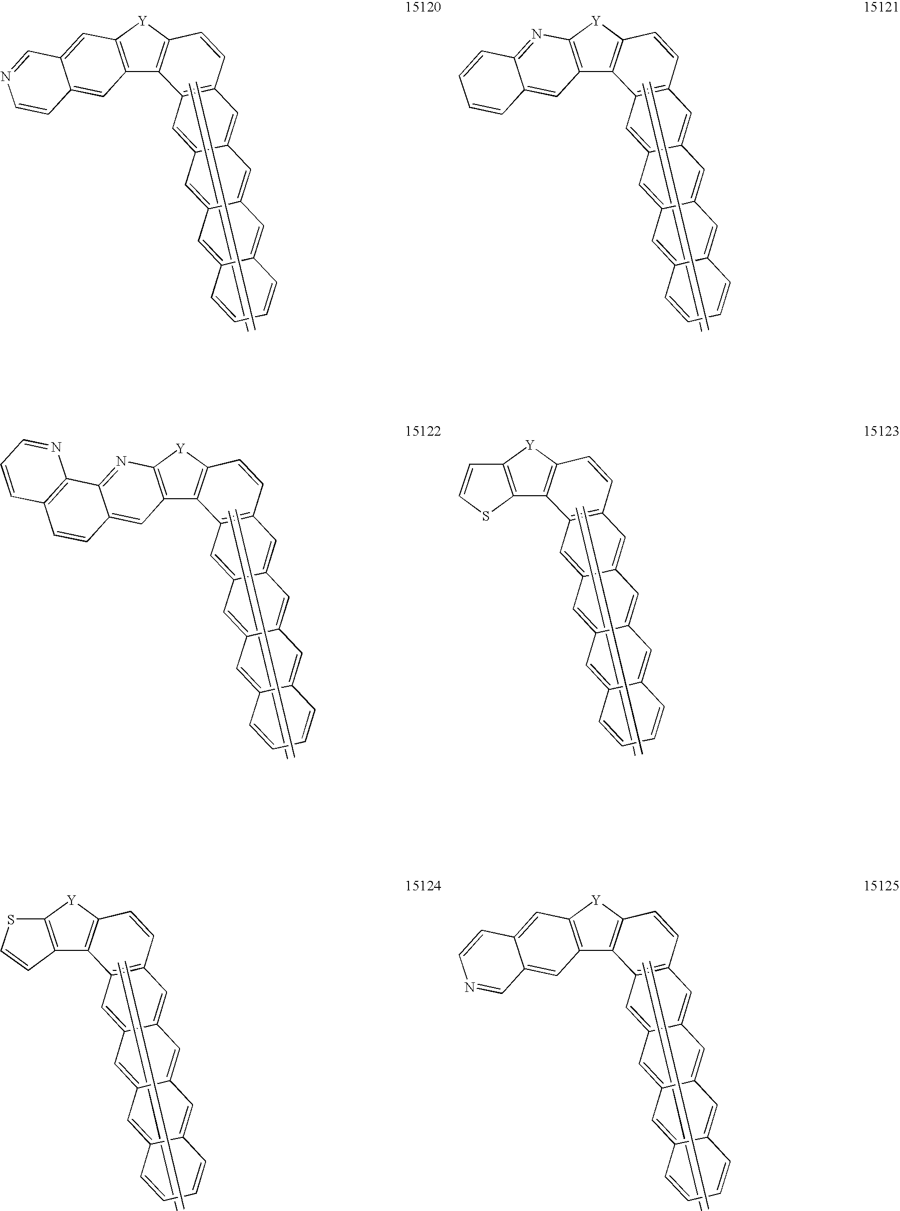

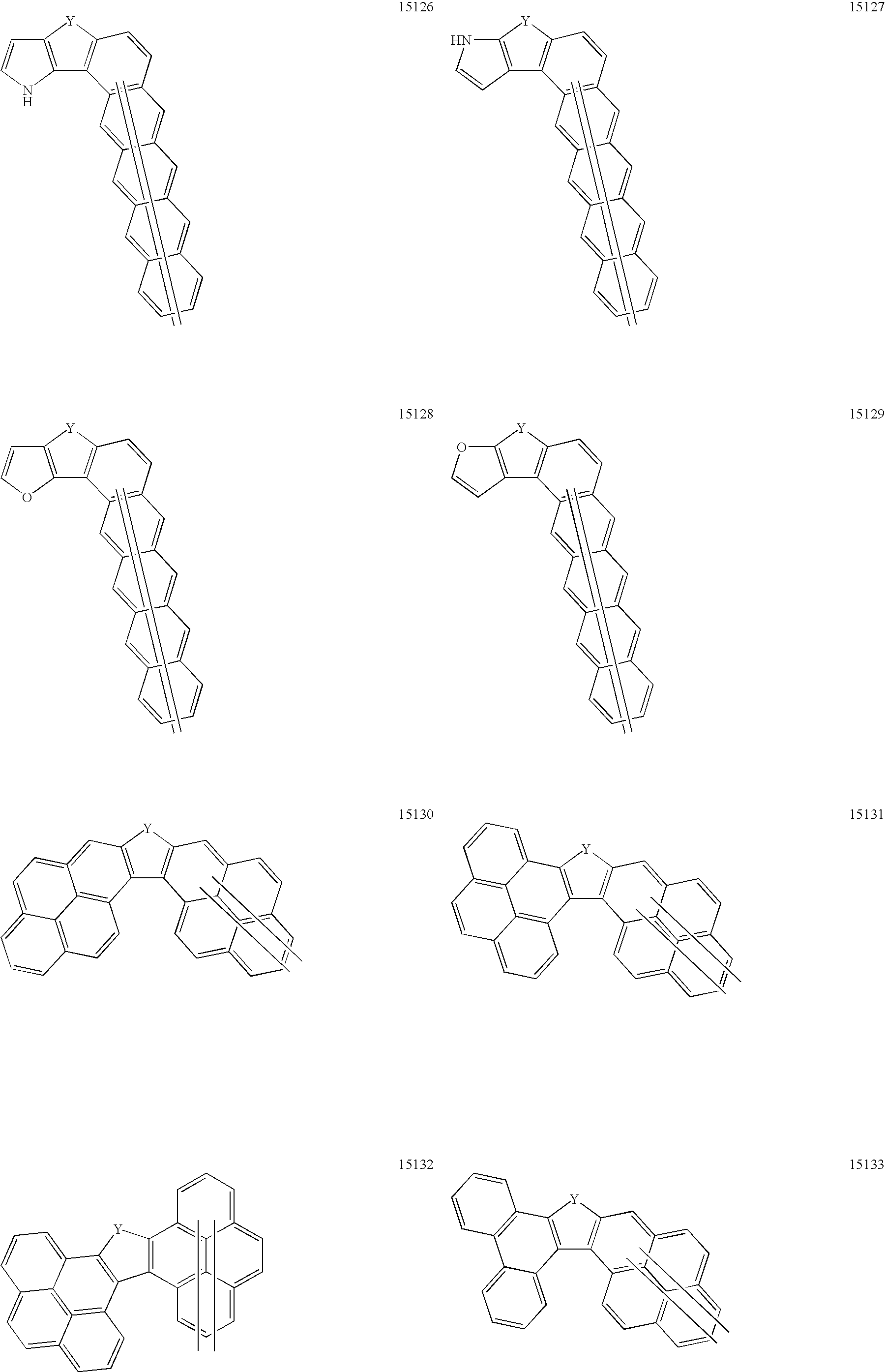

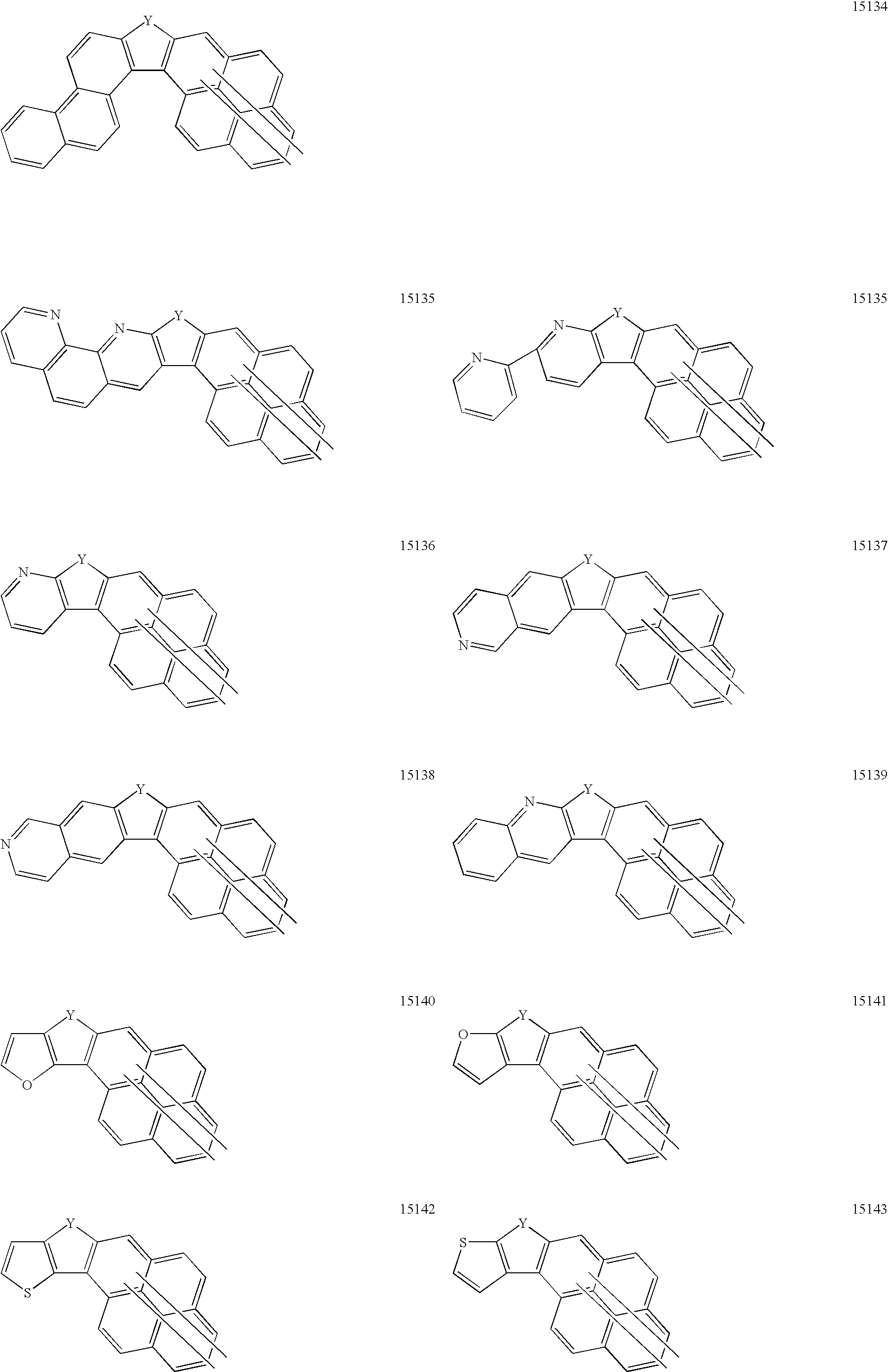

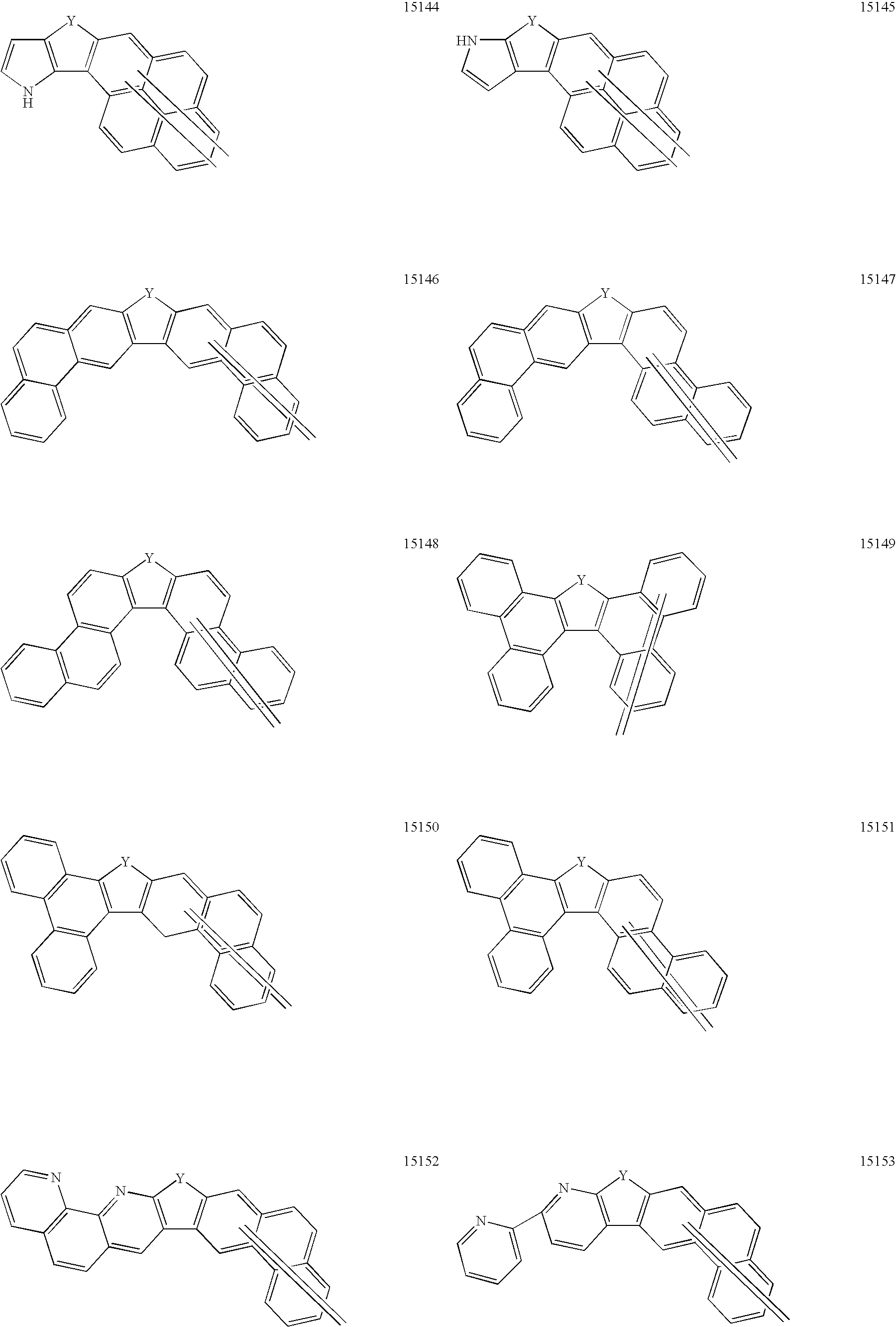

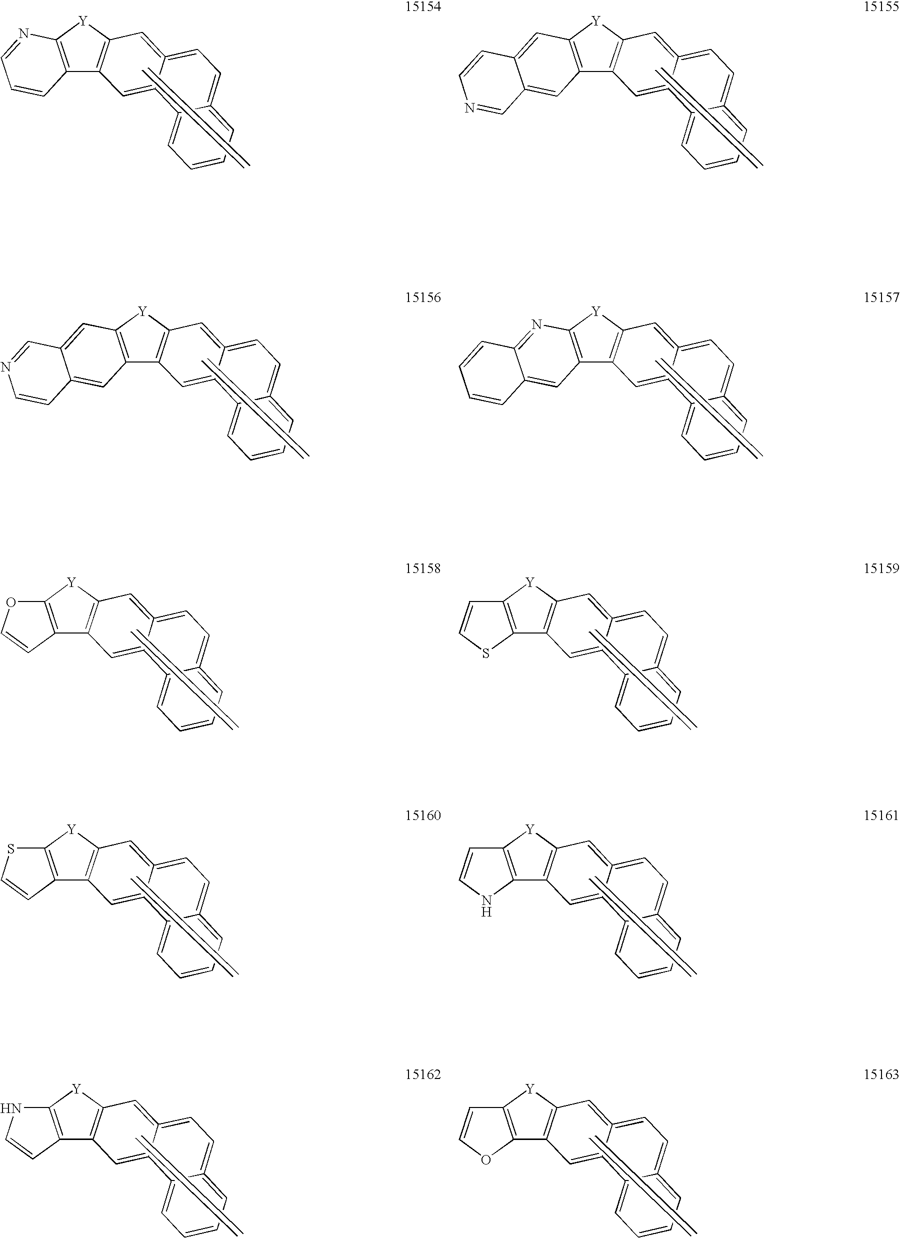

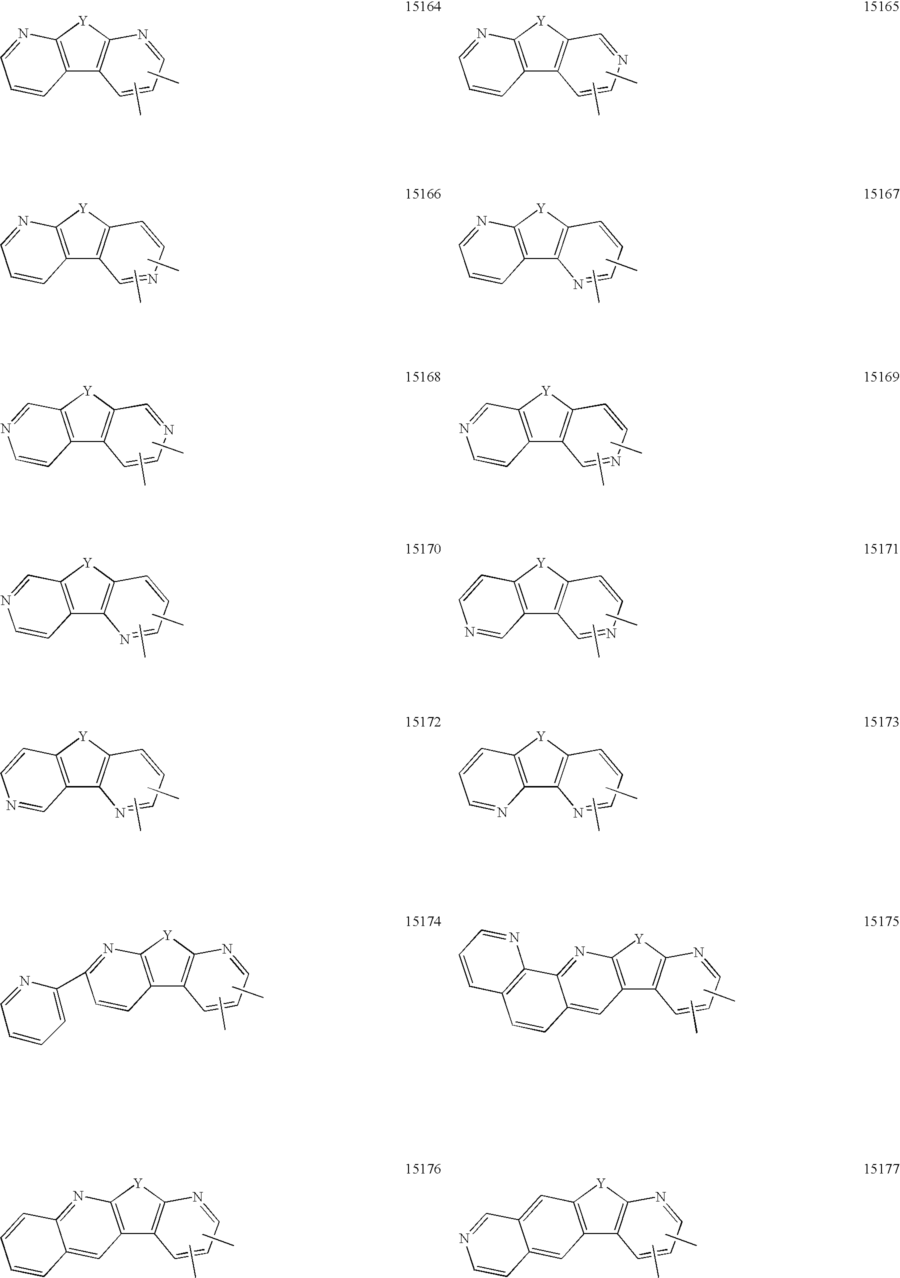

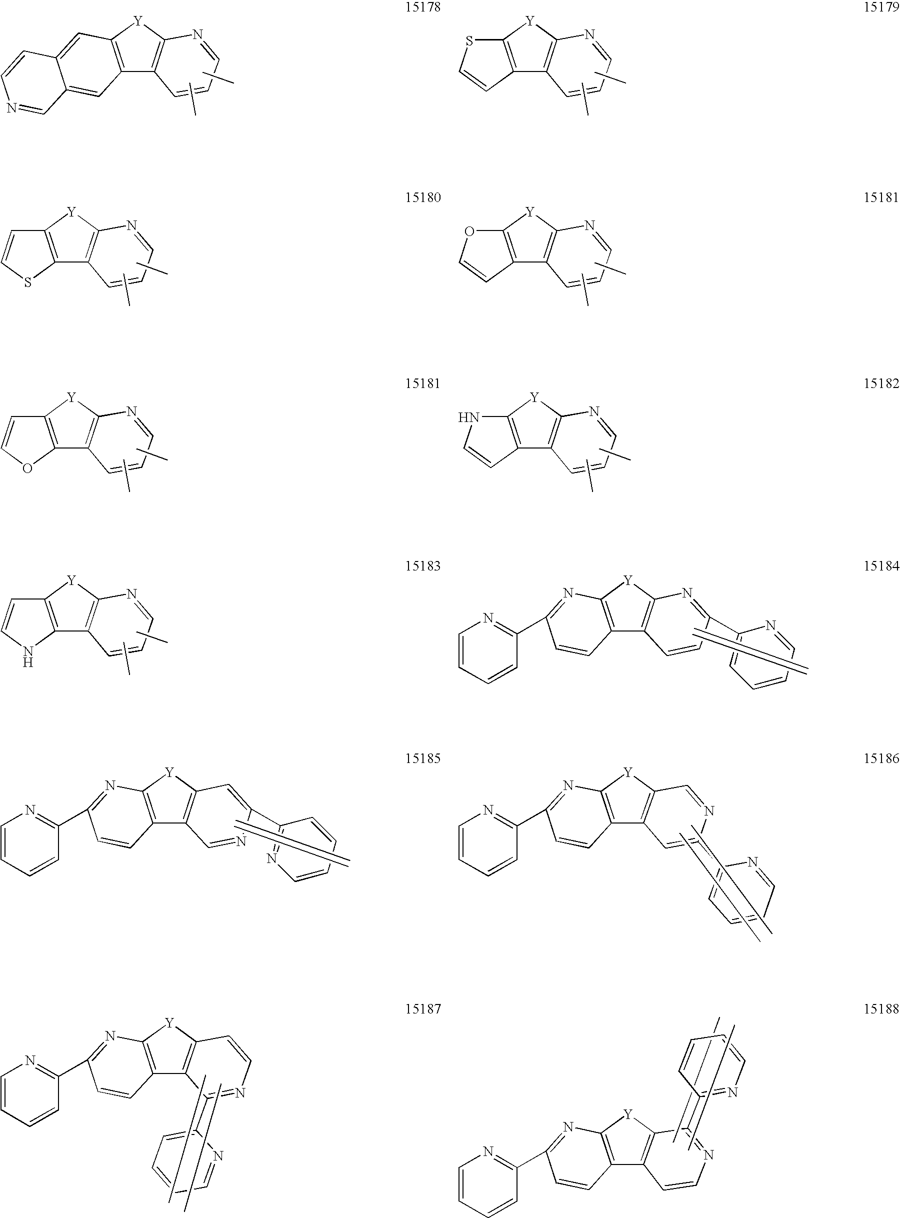

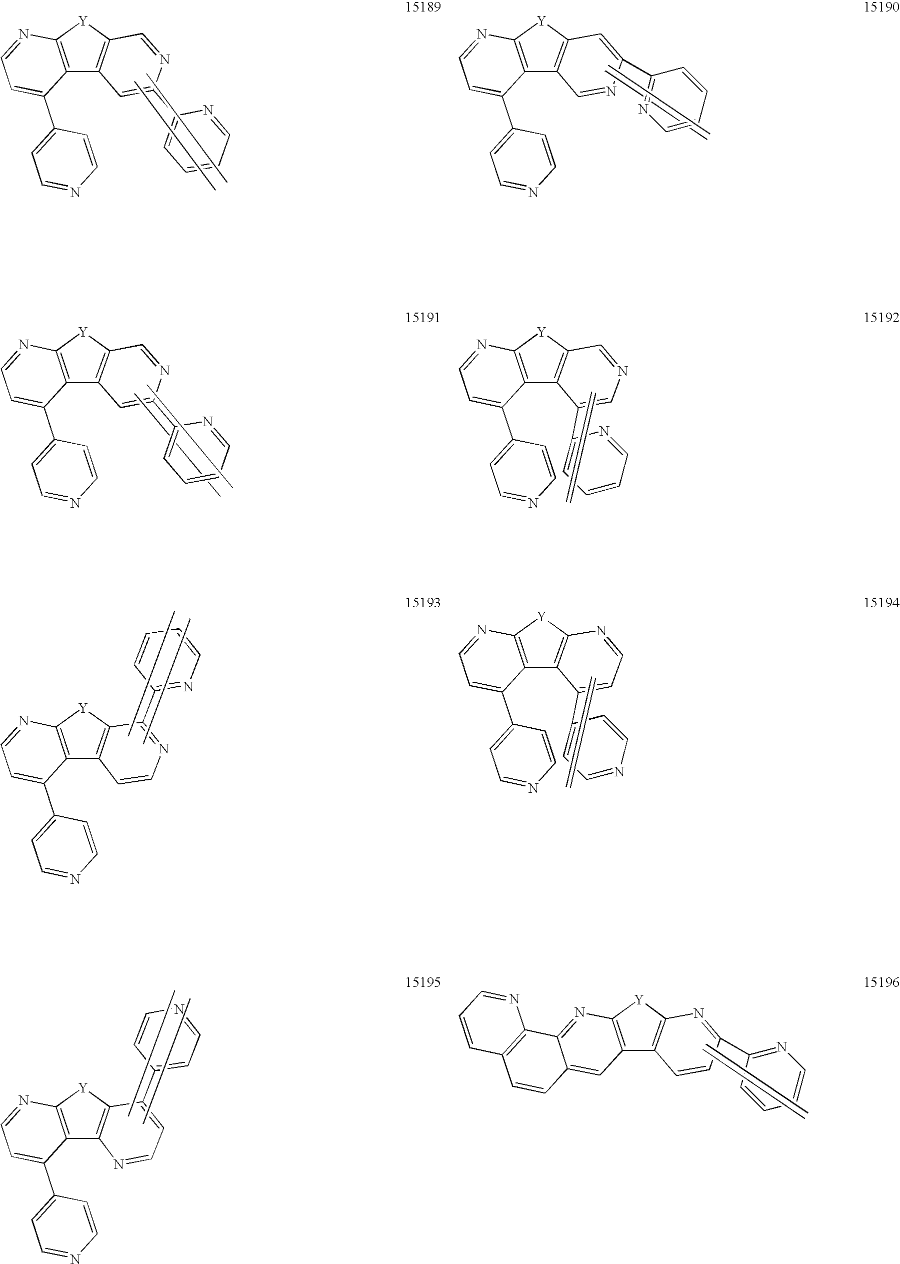

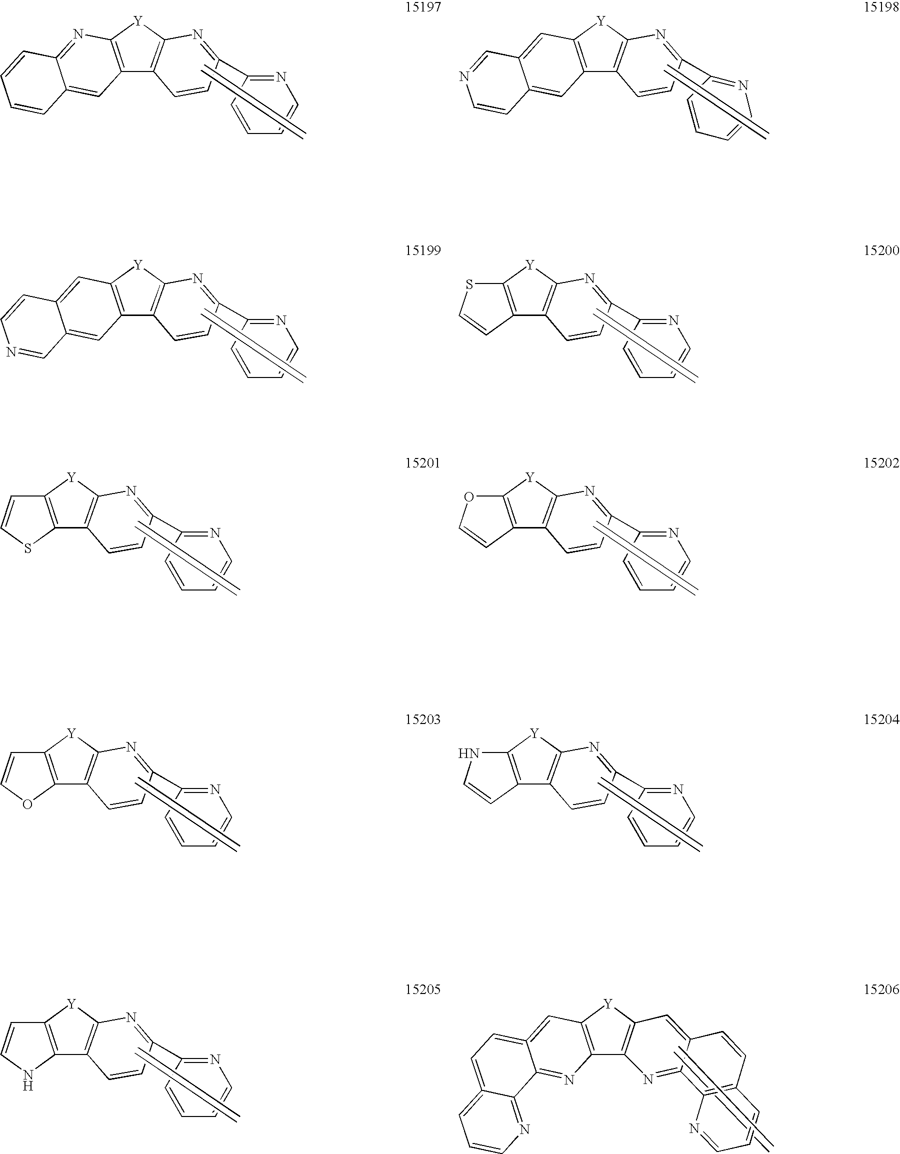

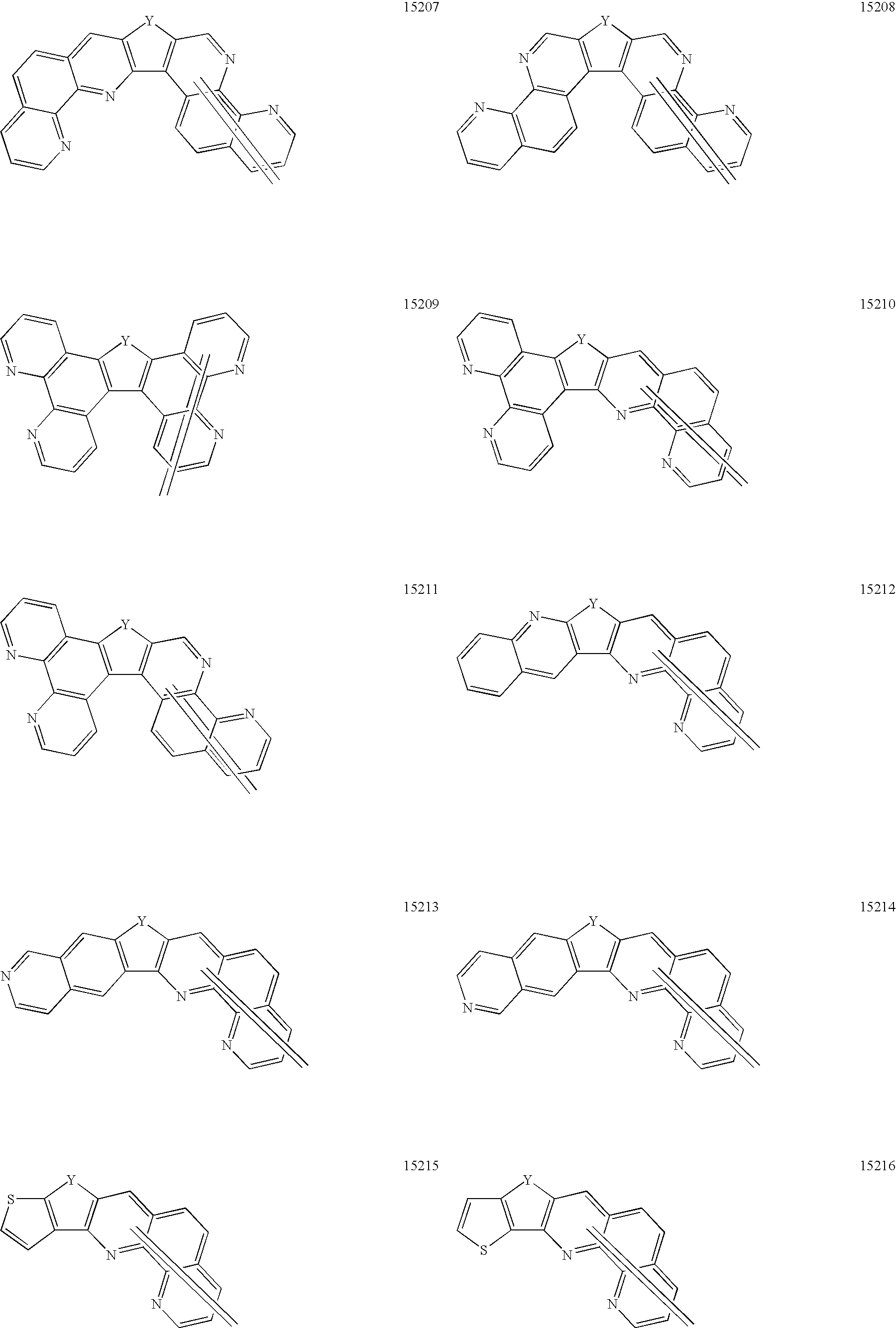

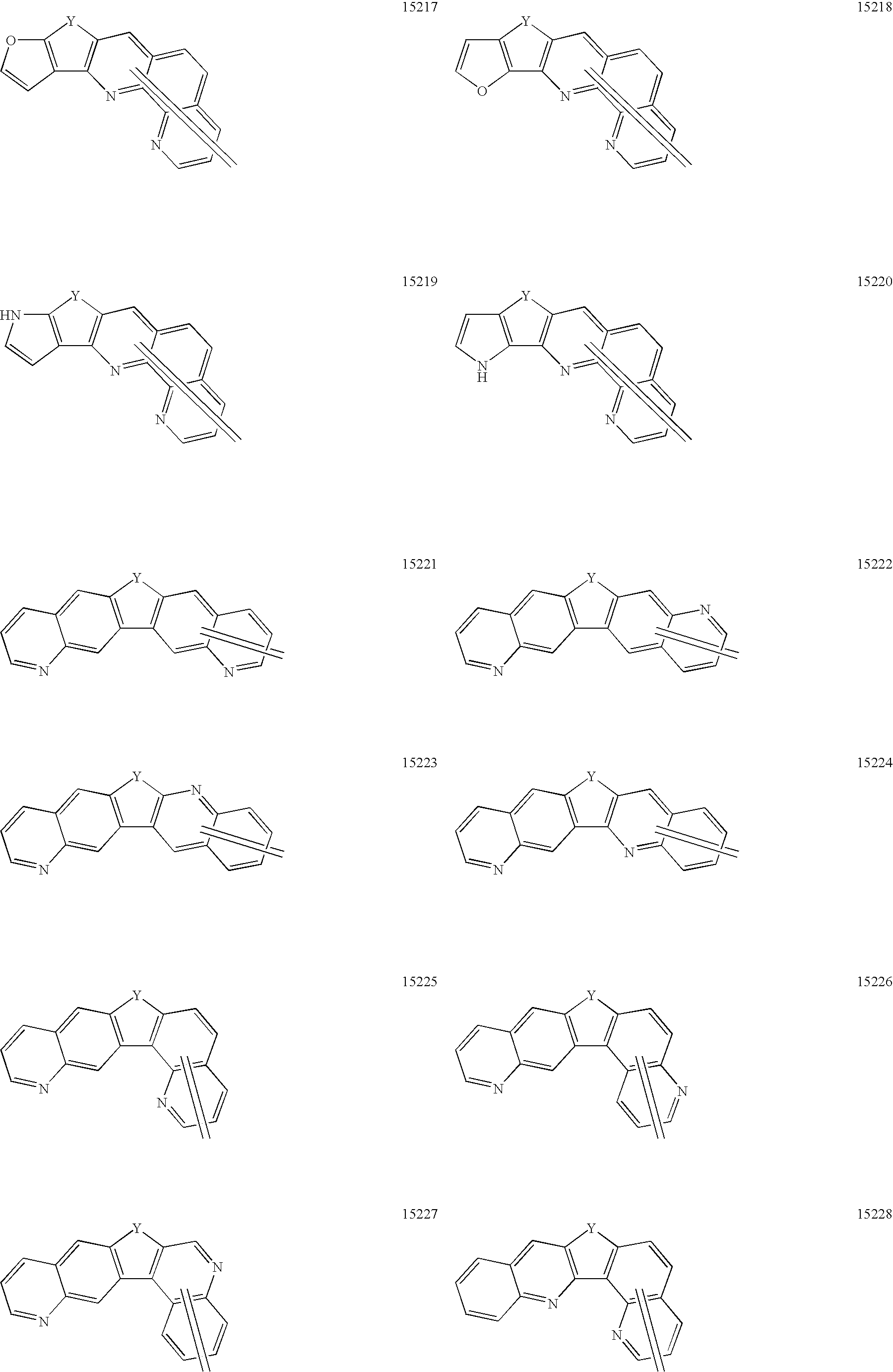

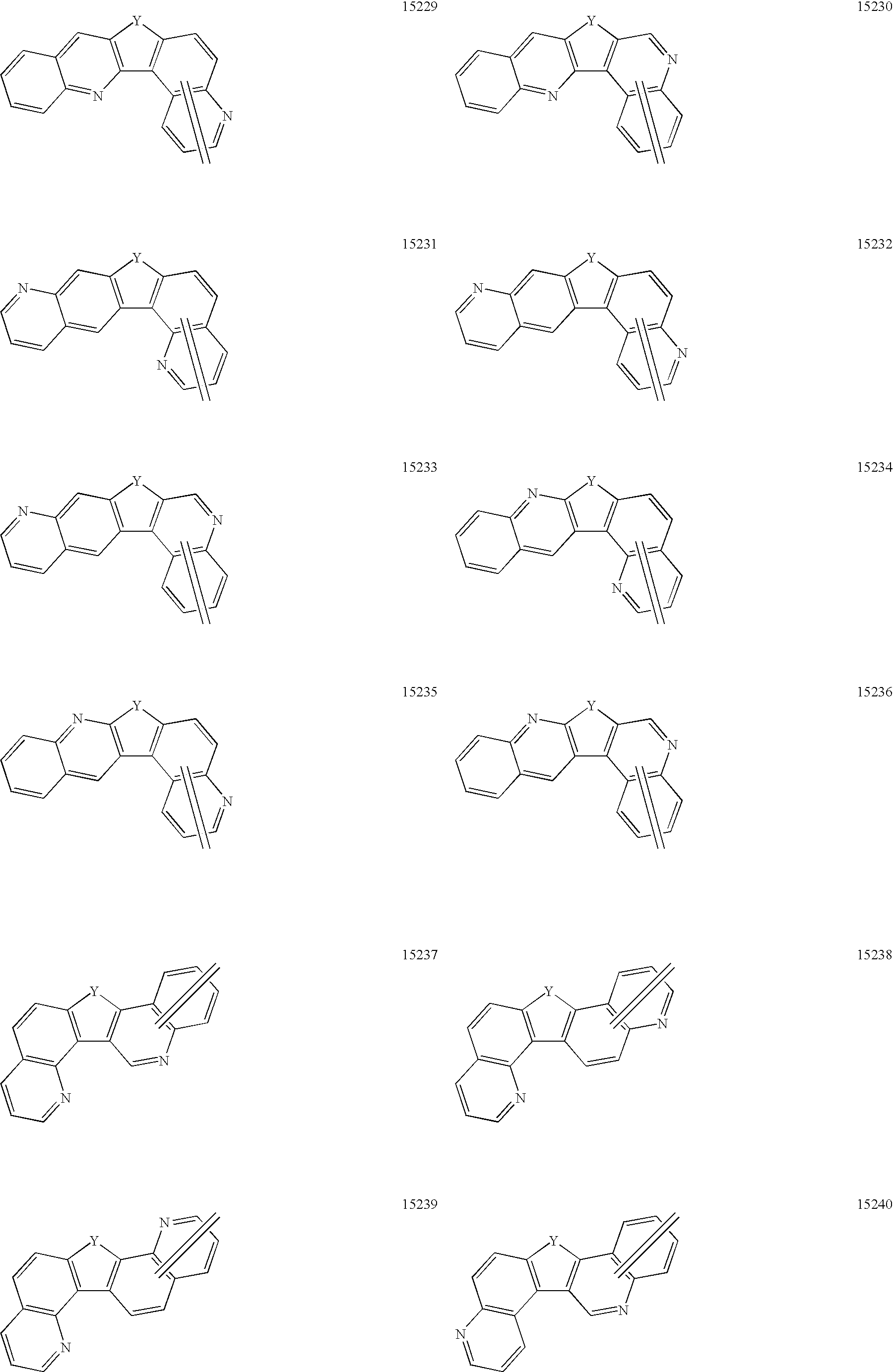

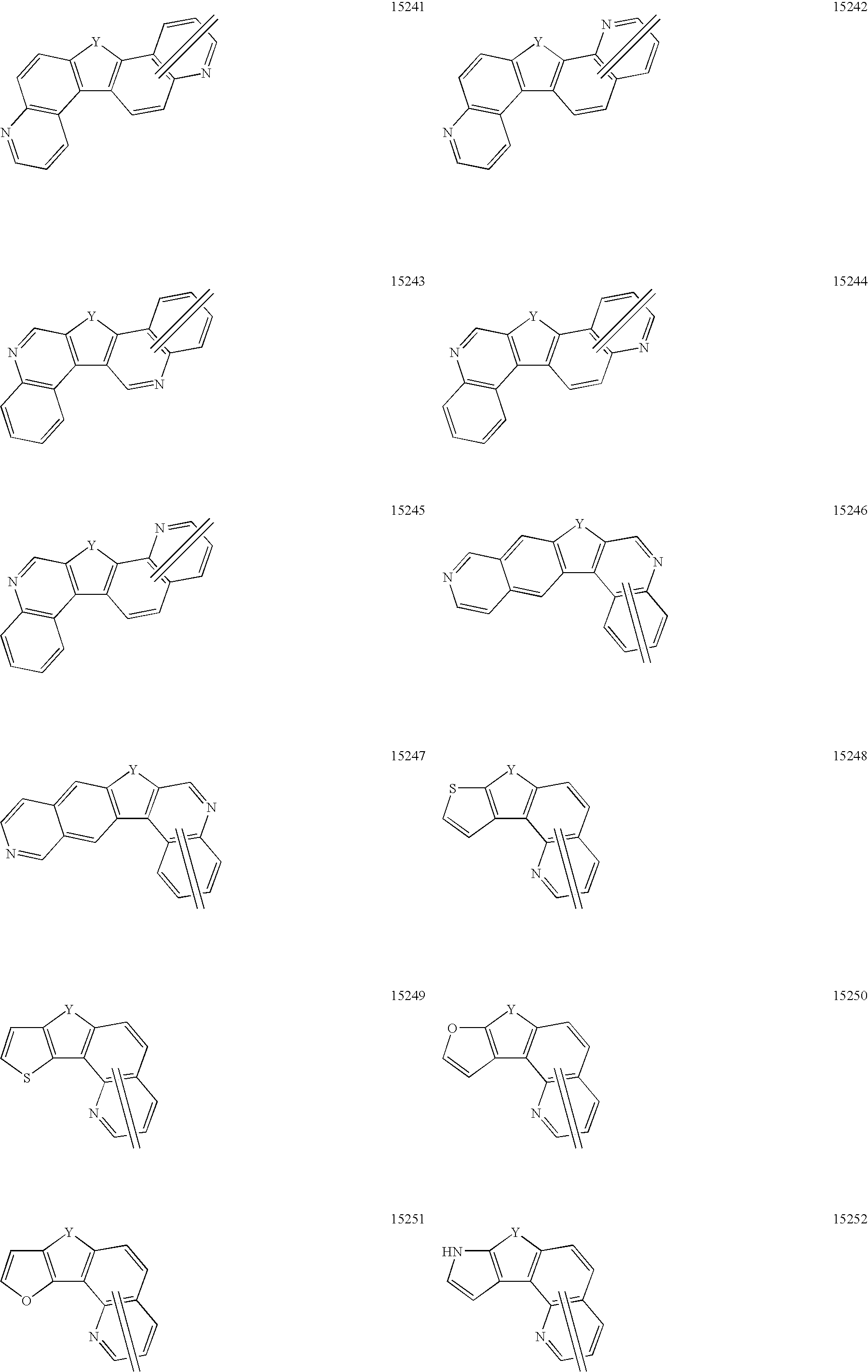

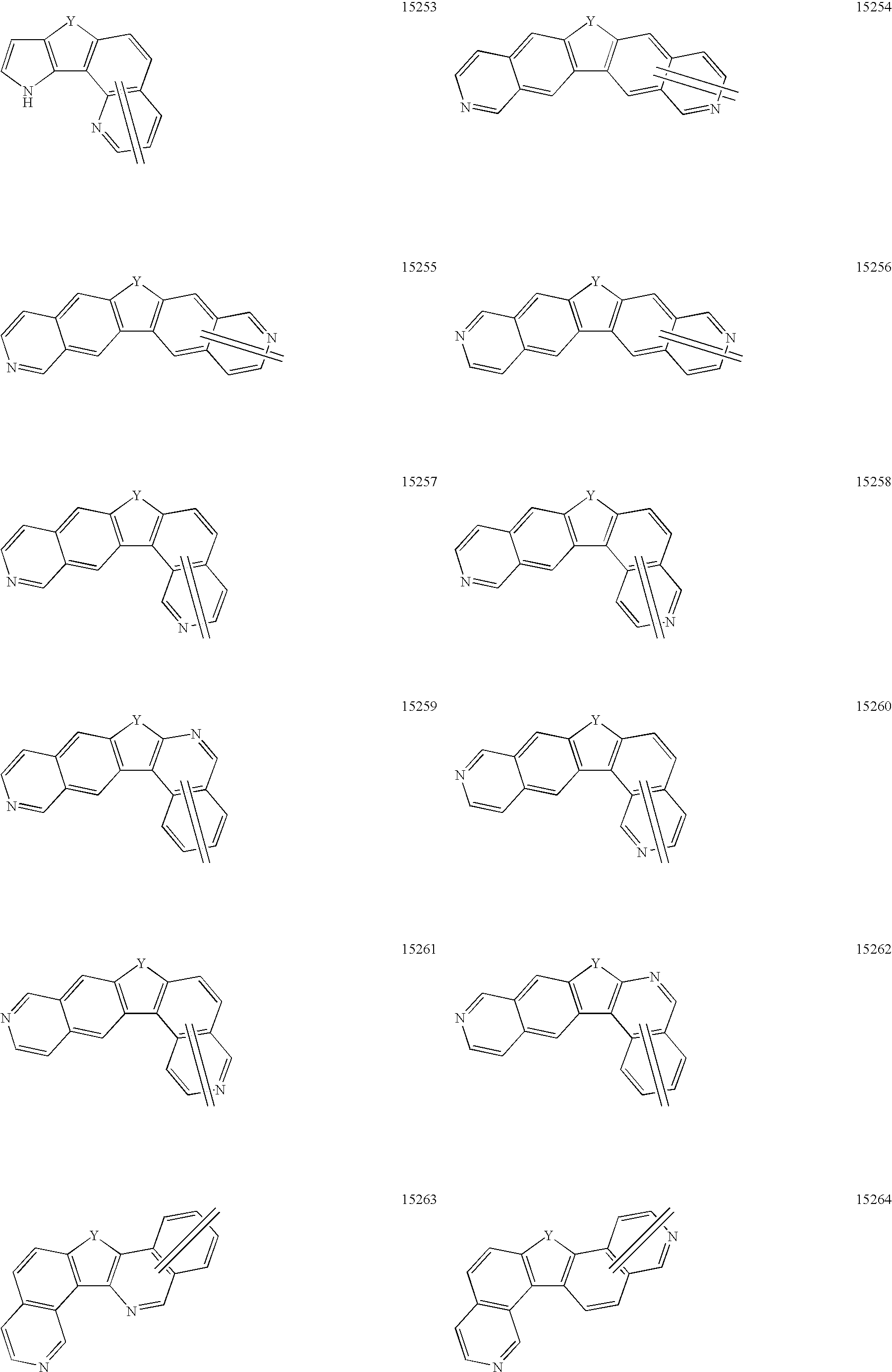

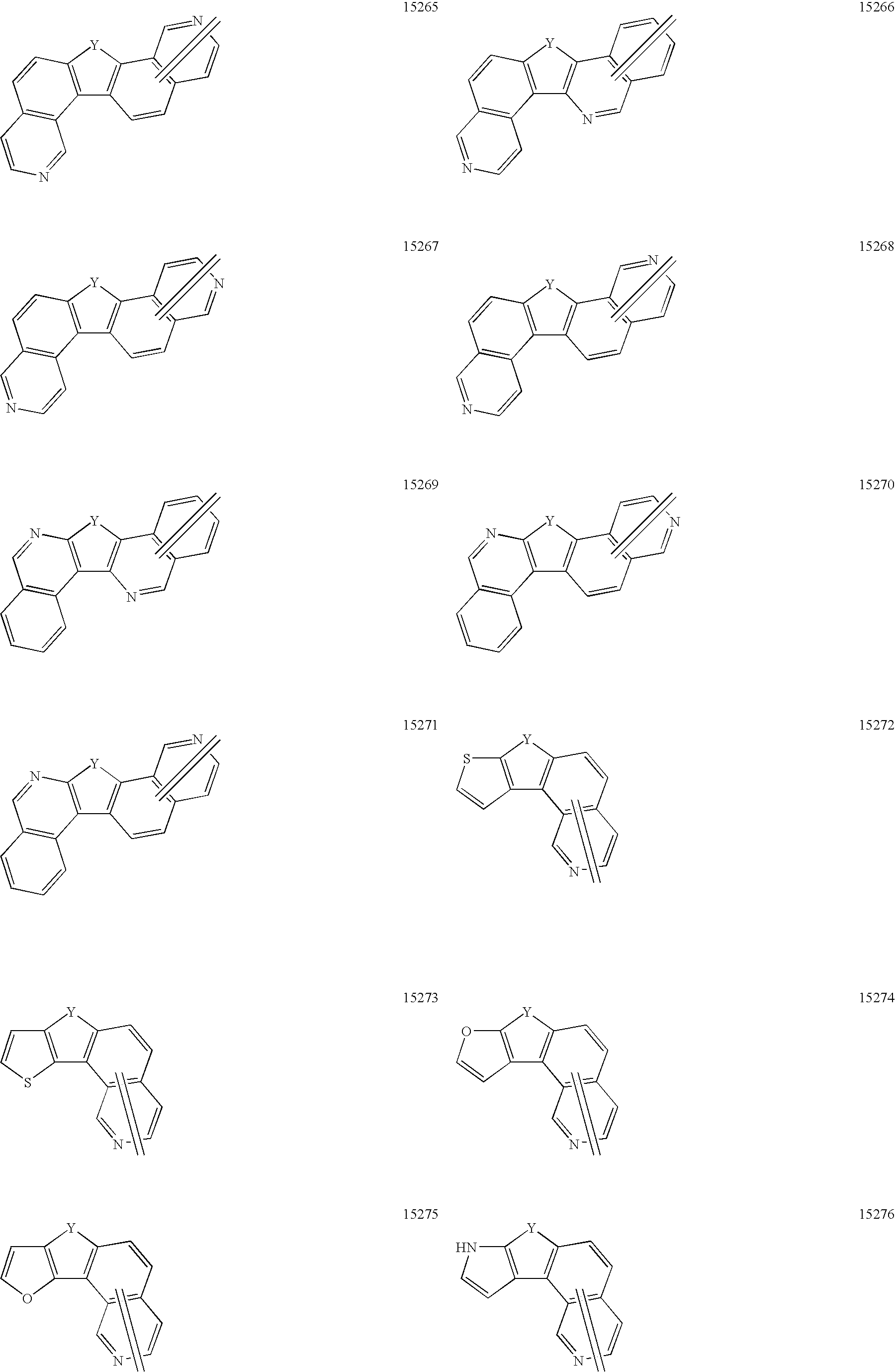

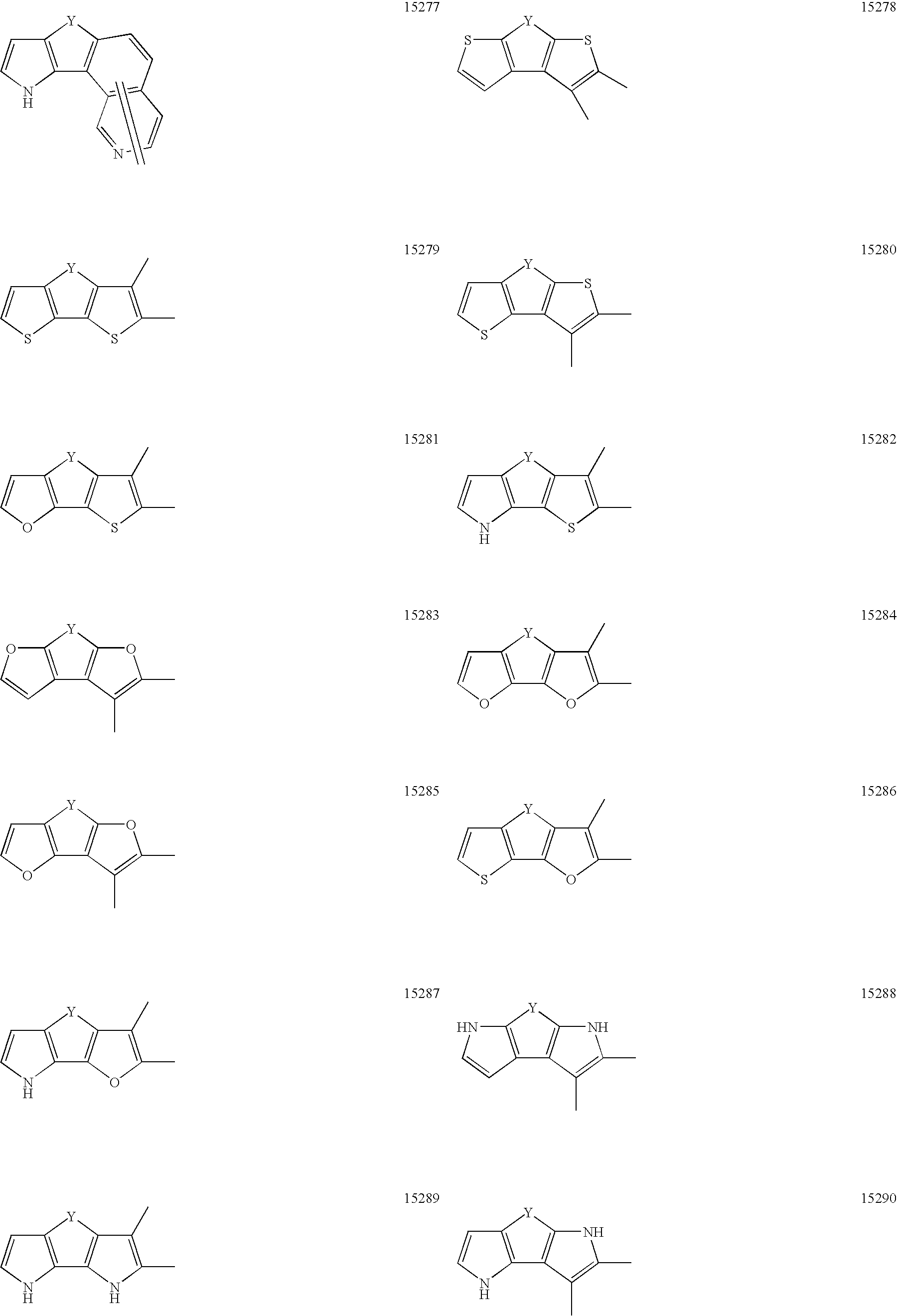

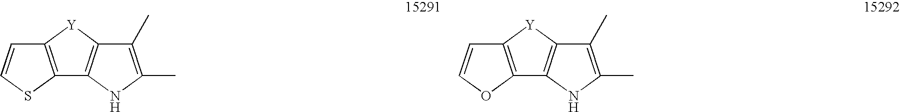

Among the above formula (1), (1-4) and (1-5) are preferable, (1-4) is more preferable, the below formula (1-6), (1-7), (1-8), (1-9) or (1-10) is still more preferable, and (1-6) is especially preferable. 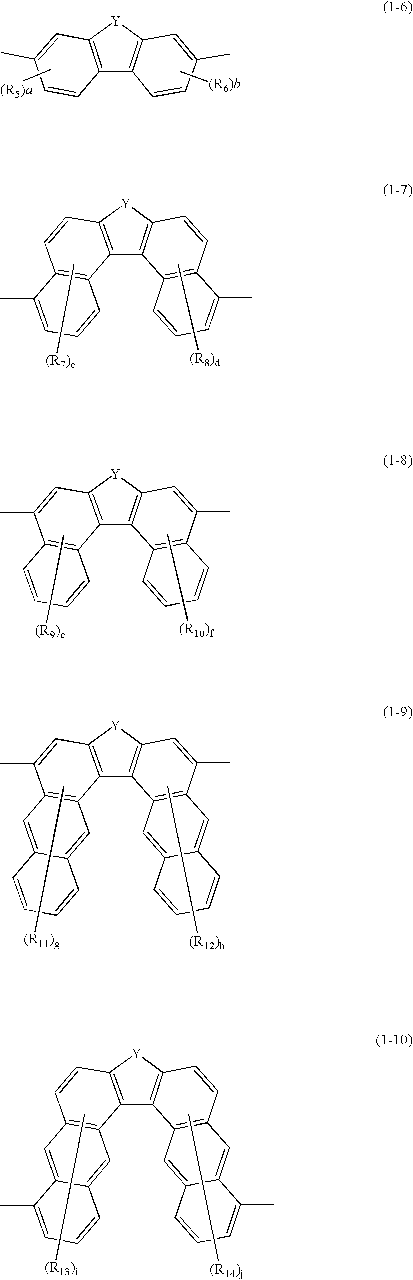
[wherein, R₅, R₆, R₇, R₈, R₉, R₁₀, R₁₁, R₁₂, R₁₃, and R₁₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group, or substituted carboxyl group. a and b each independently show an integer of 0-3. c, d, e, and f each independently show an integer of 0-5. g, h, i, and j each independently show an integer of 0-7. When R₅, R₆, R₇, R₈, R₉, R₁₀, R₁₁, R₁₂, R₁₃, and R₁₄ exist in plural, they may be the same or different. Y represents the same meaning as the above.].

Moreover, a+b, c+d, e+f, g+h, and i+j, is preferably 1 or more, in view of the solubility in a solvent.

The polymer compound used for the composition of the present invention may have further the repeating unit of the below formula (2), formula (3), formula (4), or formula (5). 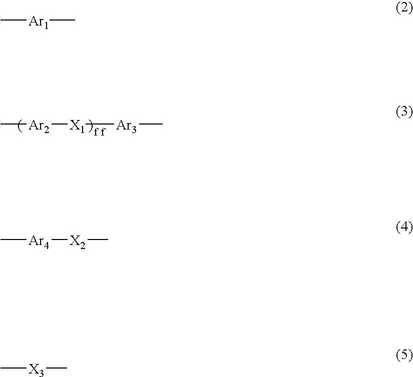
[wherein, Ar₁, Ar₂, Ar₃, and Ar₄ each independently represent an arylene group, a divalent heterocyclic group, or a divalent group having metal complex structure. X₁, X₂, and X₃ each independently represent —CR₁₅═CR₁₆—, —C≡C—, —N(R₁₇)—, or —(SiR₁₈R₁₉)m-. R₁₅ and R₁₆ each independently represent a hydrogen atom, alkyl group, aryl group, monovalent heterocyclic group, carboxyl group, substituted carboxyl group, or cyano group. R₁₇, R₁₈, and R₁₉ each independently represent a hydrogen atom, alkyl group, aryl group, monovalent heterocyclic group, arylalkyl group, or substituted amino group. ff shows 1 or 2. m shows an integer of 1-12. When two or more R₁₅, R₁₆, R₁₇, R₁₈, and R₁₉ exist, respectively, they may be the same or different.]

The arylene group is an atomic group in which two hydrogen atoms of an aromatic hydrocarbon are removed, and usually, the number of carbon atoms is about 6 to 60, and preferably 6 to 20. The aromatic hydrocarbon includes those having a condensed ring, an independent benzene ring, or two or more condensed rings bonded through groups, such as a direct bond or a vinylene group.

Examples of the arylene group include phenylene group (for example, following formulas 1-3), naphthalenediyl group (following formulas 4-13), anthracenylene group (following formulas 14-19), biphenylene group (following formulas 20-25), terphenyl-diyl group (following formulas 26-28), condensed ring compound group (following formulas 29-35), fluorene-diyl group (following formulas 36-38), stilbene-diyl (following formulas A-D), distilbene-diyl (following formulas E, F), etc. Among them, phenylene group, biphenylene group, and stilbene-diyl group are preferable.

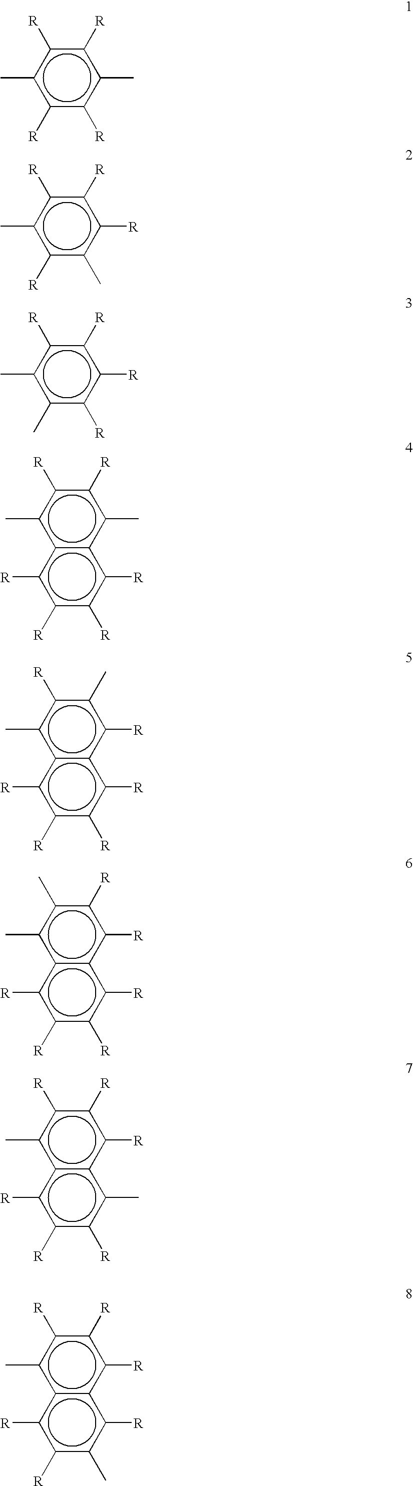

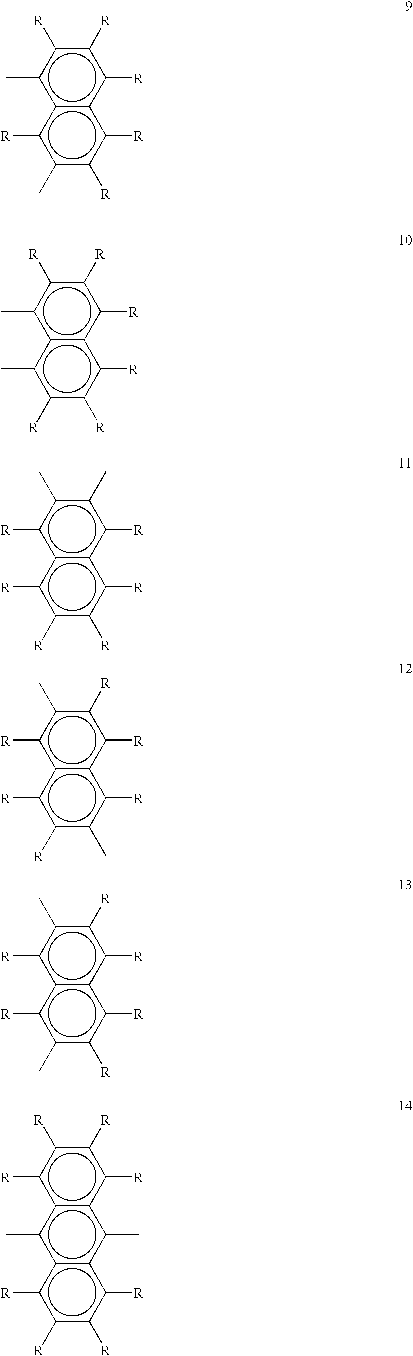

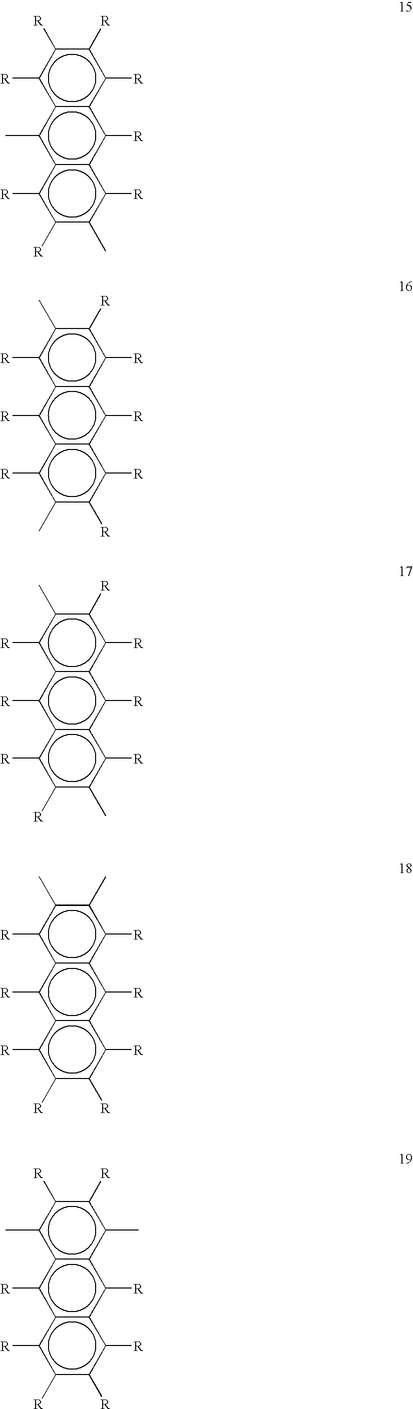

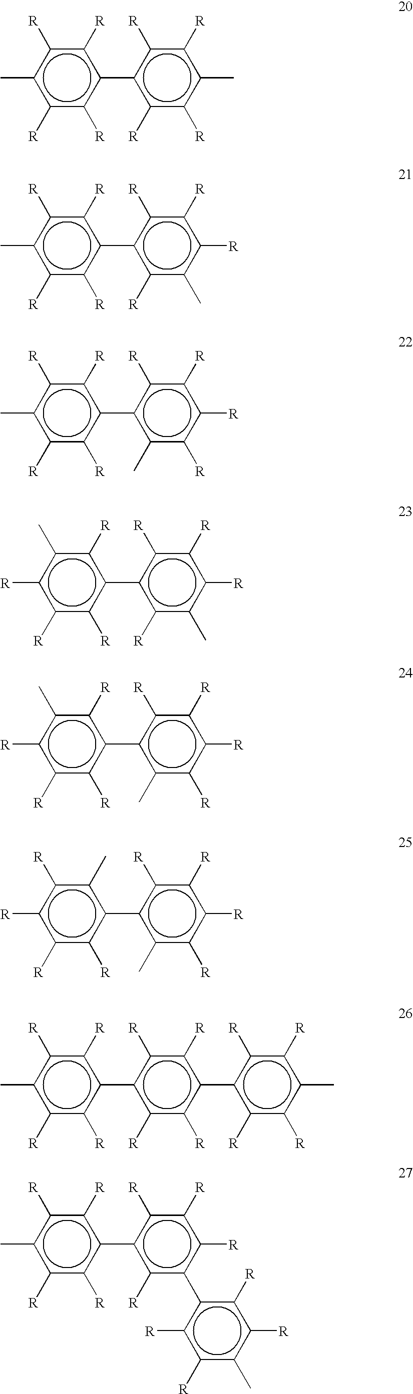

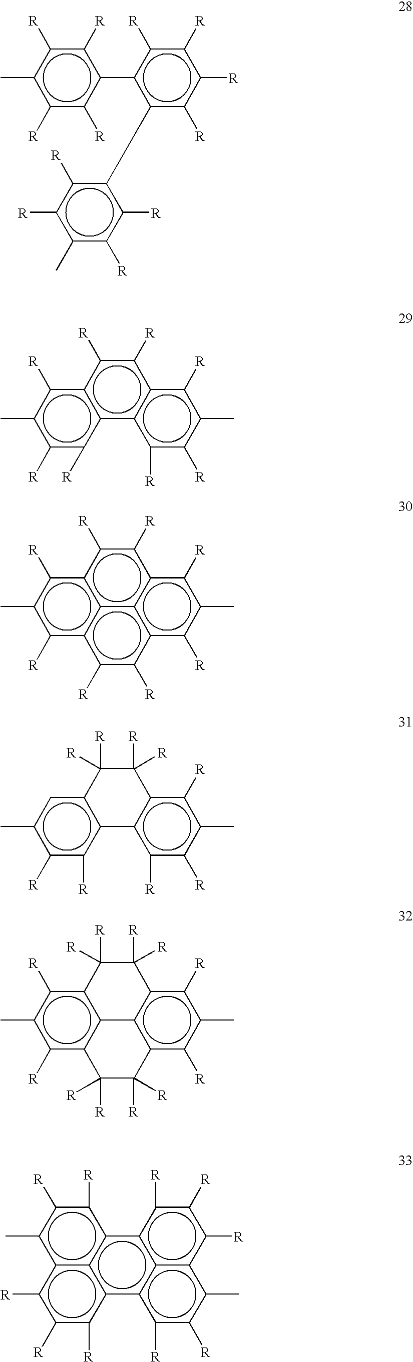

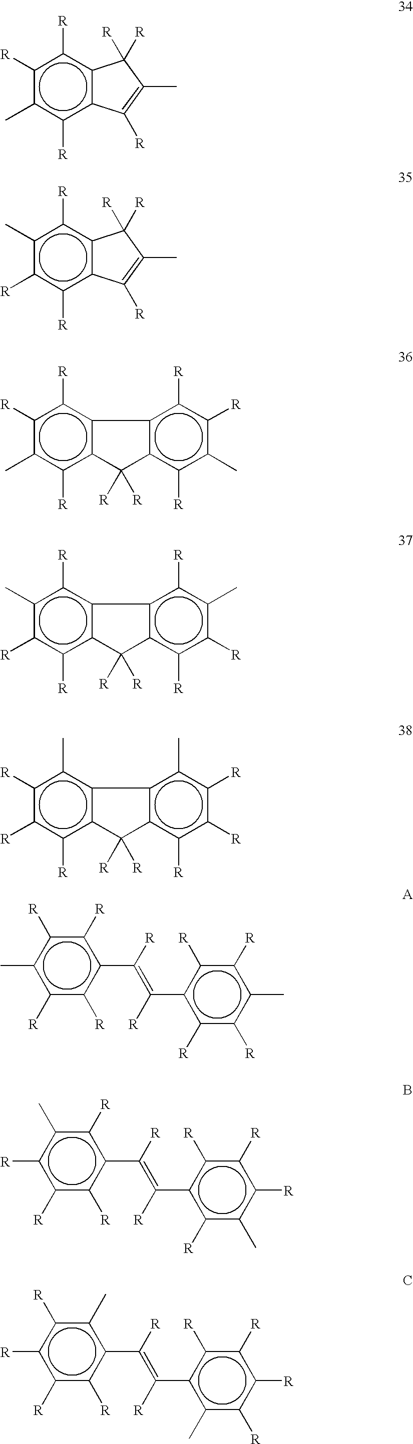

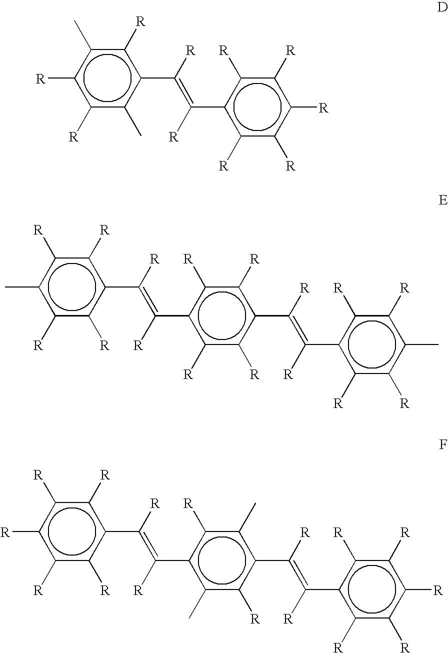

The divalent heterocyclic group means an atomic group in which two hydrogen atoms are removed from a heterocyclic compound, and the number of carbon atoms is usually about 3 to 60.

The heterocyclic compound means an organic compound having a cyclic structure in which at least one heteroatom such as oxygen, sulfur, nitrogen, phosphorus, boron, etc. is contained in the cyclic structure as the element other than carbon atoms.

Examples of the divalent heterocyclic groups include the followings.

Divalent heterocyclic groups containing nitrogen as a hetero atom; pyridine-diyl group (following formulas 39-44), diaza phenylene group (following formulas 45-48), quinolinediyl group (following formulas 49-63), quinoxalinediyl group (following formulas 64-68), acridinediyl group (following formulas 69-72), bipyridyldiyl group (following formulas 73-75), phenanthrolinediyl group (following formulas 76-78), etc.

Groups having a fluorene structure containing silicon, nitrogen, selenium, etc. as a hetero atom (following formulas 79-93).

5 membered heterocyclic groups containing silicon, nitrogen, sulfur, selenium, etc. as a hetero atom: (following formulas 94-98).

Condensed 5 membered heterocyclic groups containing silicon, nitrogen, selenium, etc. as a hetero atom: (following formulas 99-110),

5 membered heterocyclic groups containing silicon, nitrogen, sulfur, selenium, etc. as a hetero atom, which are connected at the a position of the hetero atom to form a dimer or an oligomer (following formulas 111-112);

5 membered ring heterocyclic groups containing silicon, nitrogen, sulfur, selenium, as a hetero atom is connected with a phenyl group at the a position of the hetero atom (following formulas 113-119); and

Groups of 5 membered ring heterocyclic groups containing nitrogen, oxygen, sulfur, as a hetero atom on to which a phenyl group, furyl group, or thienyl group is substituted (following formulas 120-125).

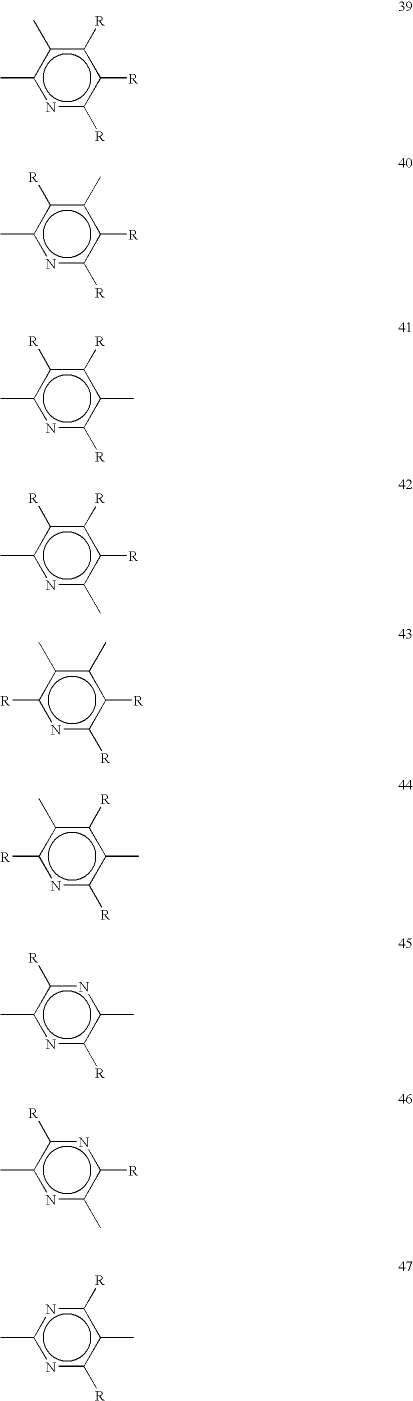

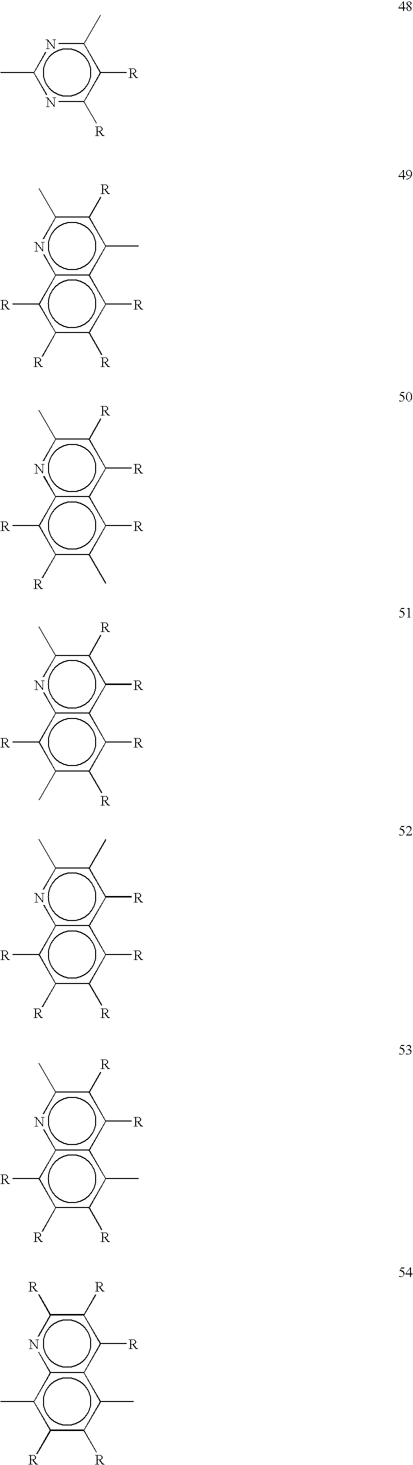

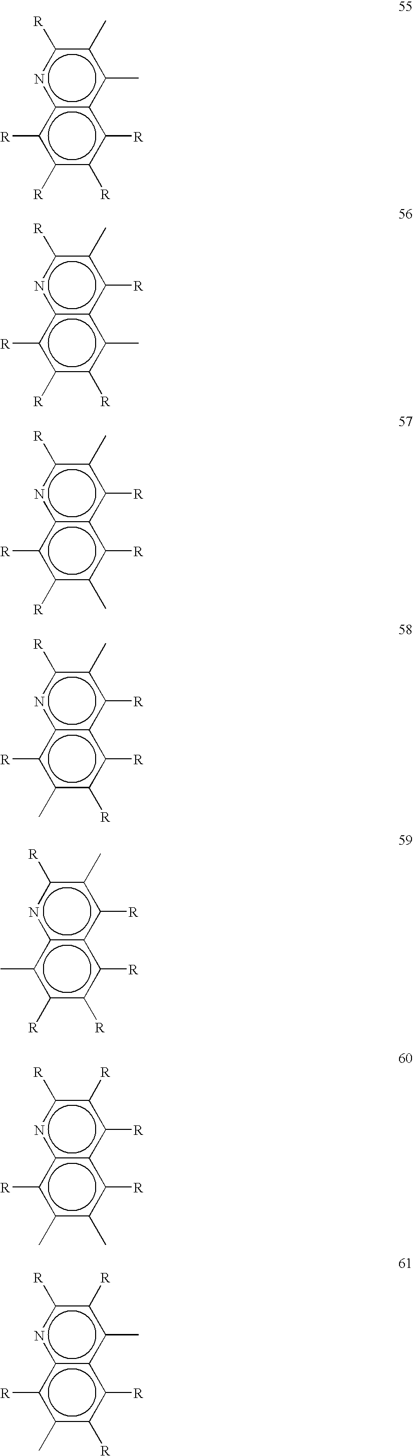

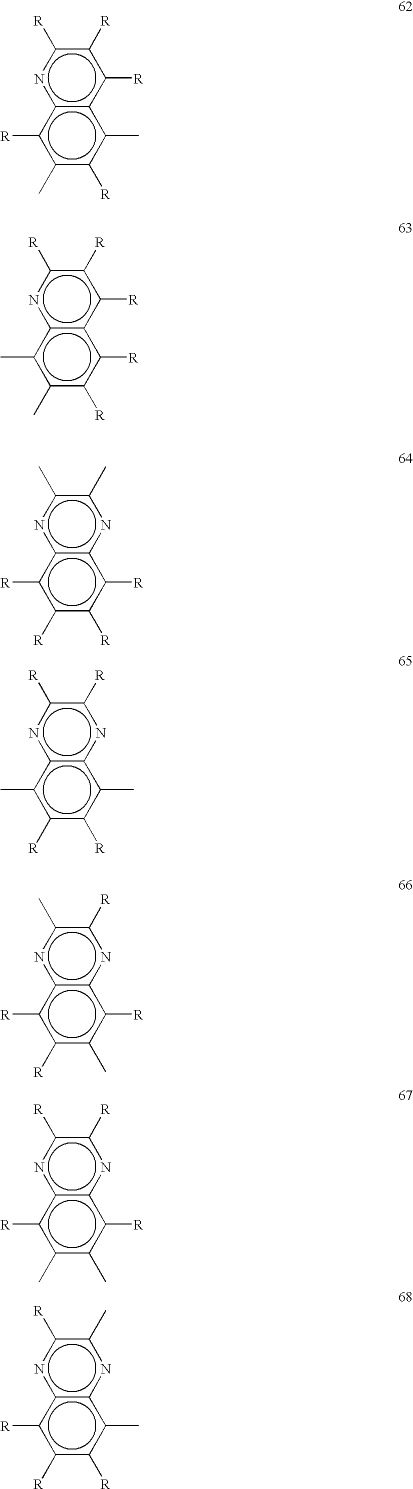

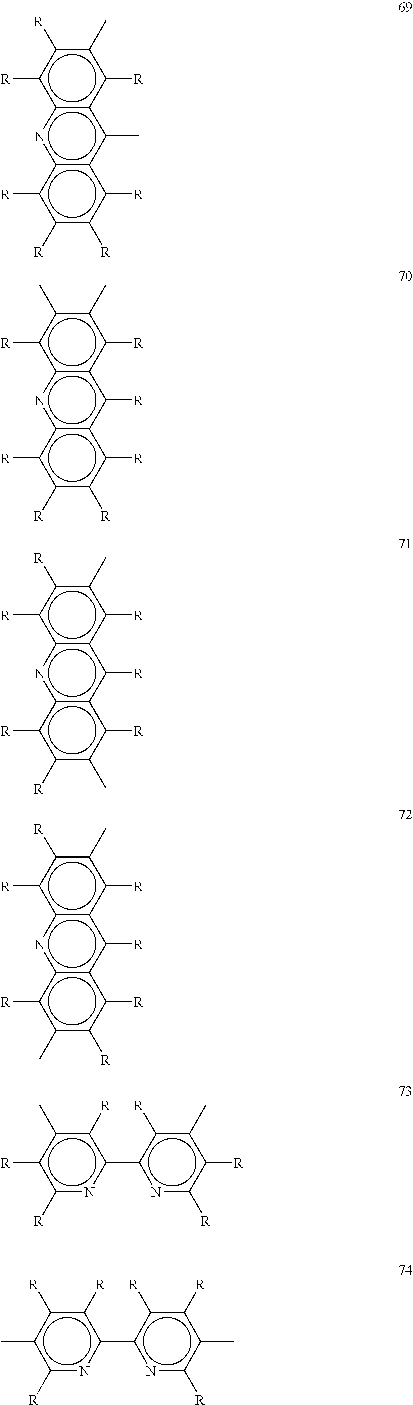

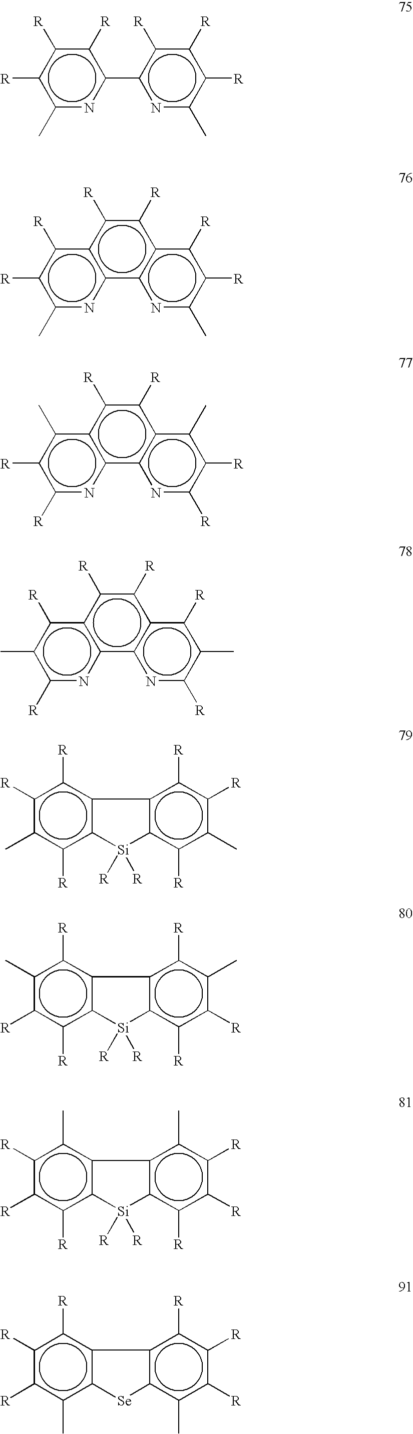

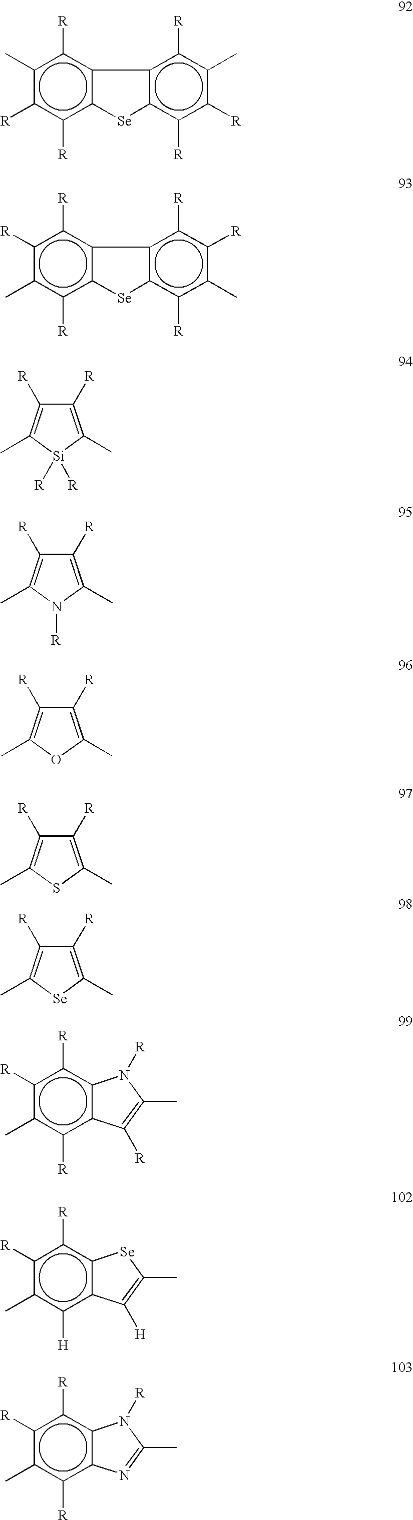

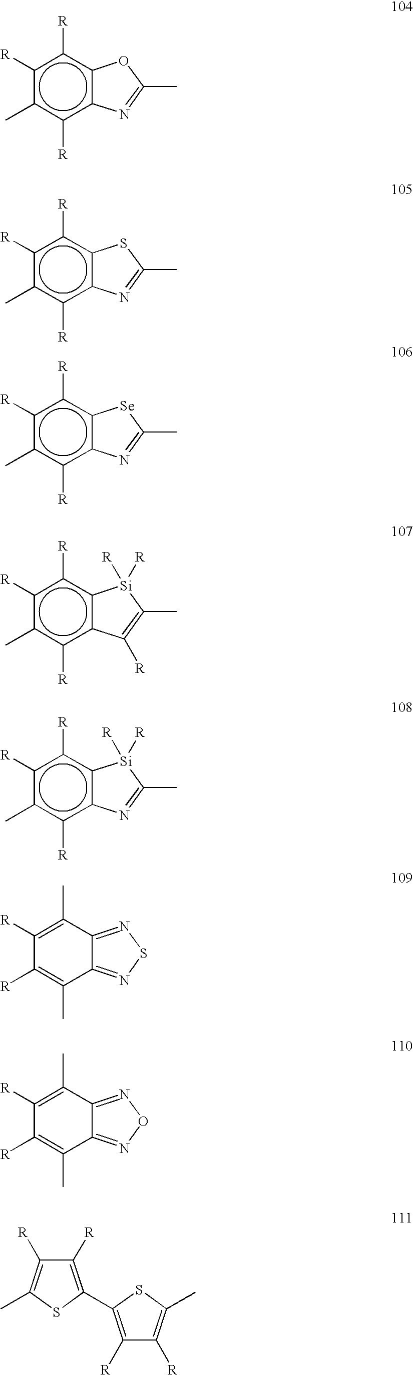

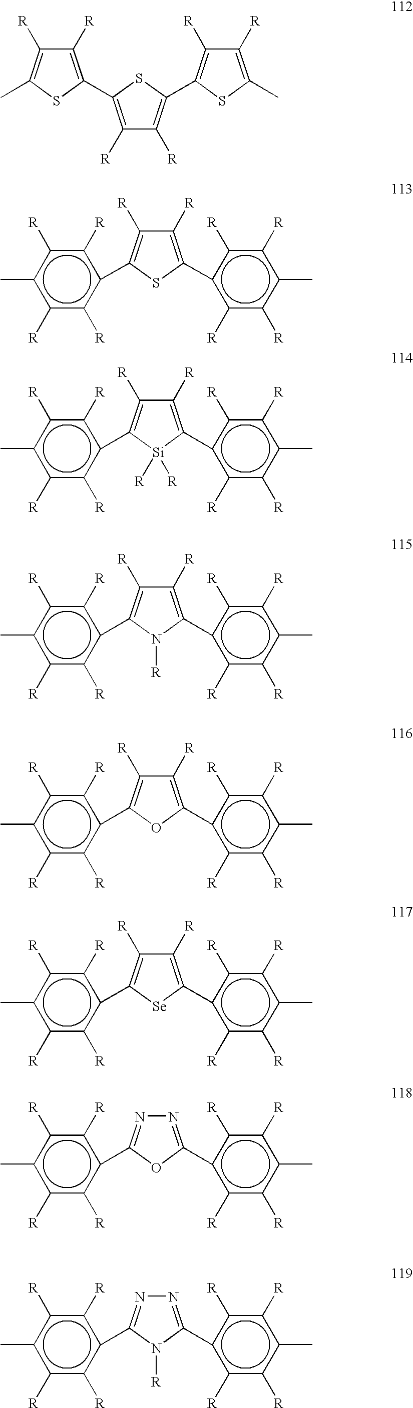

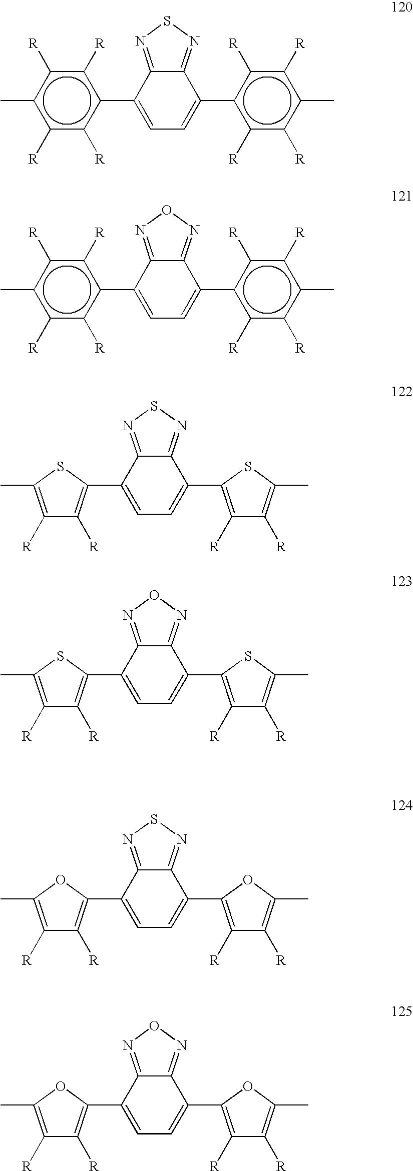

In the examples of the above formulas 1-125, Rs each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imine residue, amide group, acid imide group, monovalent heterocyclic group, carboxyl group, substituted carboxyl group, or cyano group. Carbon atom contained in the groups of formulas 1-125 may be substituted by a nitrogen atom, oxygen atom, or sulfur atom, and a hydrogen atom may be substituted by a fluorine atom.

As Ar₁ and Ar₄, an arylene group or a divalent heterocyclic group which is contained in all materials used as EL luminescence material from the former may be used, and it is preferable that the monomer does not inhibit triplet luminescence. Such materials are disclosed, for example, in WO99/12989, WO00/55927, WO01/49769A1 WO01/49768A2 and WO98/06773, U.S. Pat. No. 5,777,070, WO99/54385 WO00/46321, U.S. Pat. No. 6,169,163B1.

As the repeating unit of the above formula (2), a repeating unit of the below formula (6), (7), (8), (9), (10), or (11) is exemplified. 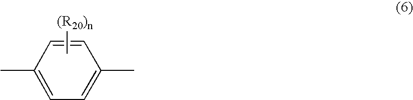
[wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. n shows an integer of 0-4. When two or more R₂₀ exist, they may be the same or different.]. 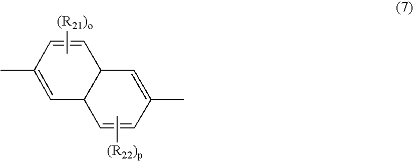
[wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. o and p each independently show an integer of 0-3. When two or more R₂₁ and R₂₂ exist, respectively, they may be the same or different.]. 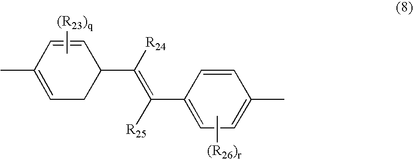
[wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. q and r each independently show an integer of 0-4. R₂₄ and R₂₅ each independently represent a hydrogen atom, alkyl group, aryl group, monovalent heterocyclic group, carboxyl group, substituted carboxyl group, or cyano group. When two or more R₂₃ and R₂₆ exist, respectively, they may be the same or different.]. 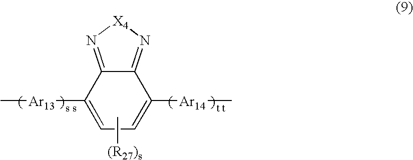
[wherein, R₂₇ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. s shows an integer of 0-2. Ar₁₃ and Ar₁₄ each independently represent an arylene group, divalent heterocyclic group, or divalent group having metal complex structure. ss and tt each independently show 0 or 1. X₄ shows O, S, SO, SO₂, Se, or Te. When two or more R₂₇ exist, them may be the same or different.]. 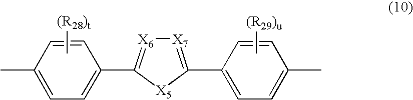
[wherein, R₂₈ and R₂₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. t and u each independently show an integer of 0-4. X₅ shows O, S, SO₂, Se, Te, N—R₃₀, or SiR₃₁R₃₂. X₆ and X₇ each independently show N or C—R₃₃. R₃₀, R₃₁, R₃₂, and R₃₃ each independently represent a hydrogen atom, alkyl group, aryl group, arylalkyl group, or monovalent heterocyclic group. When two or more R₂₈, R₂₉, and R₃₃ exist, respectively, they may be the same or different.]. 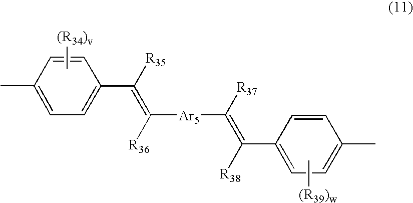
[wherein, R₃₄ and R₃₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. v and w each independently show an integer of 0-4. R₃₅, R₃₆, R₃₇, and R₃₈ each independently represent a hydrogen atom, alkyl group, aryl group, monovalent heterocyclic group, carboxyl group, substituted carboxyl group, or cyano group. Ar₅ represents an arylene group, a divalent heterocyclic group, or a divalent group having metal complex structure. When two or more R₃₄ and R₃₉ exist, respectively, they may be the same or different.].
As the structure of the above formula (2), structure of the below formula (12) are exemplified. 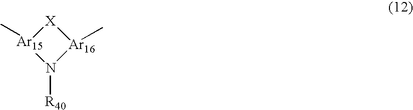
[wherein, Ar₁₅ and Ar₁₆ each independently represent a trivalent aromatic hydrocarbon group or a trivalent heterocyclic group, R₄₀ represents an alkyl group, alkoxy group, alkylthio group, alkylsilyl group, alkylamino group, and aryl group which may have substituent, or monovalent heterocyclic group. X represents a single bond or followings, 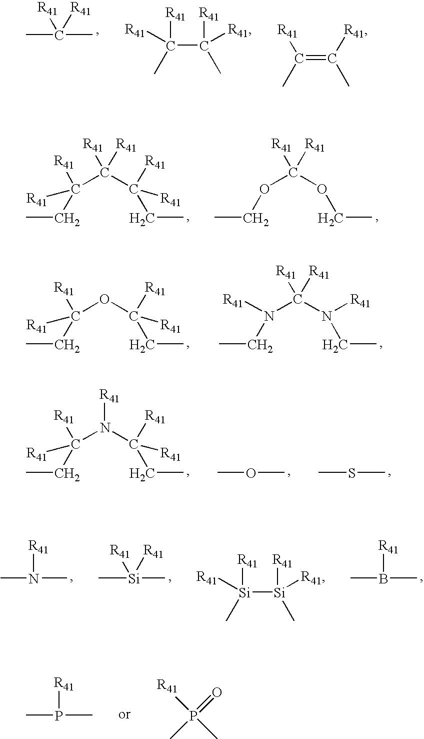
(wherein, R₄₁ each independently represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.). When two or more R₄₁ exist, they may be the same or different.

Ar₁₅ and Ar₁₆ each independently represent a trivalent aromatic hydrocarbon group or a trivalent heterocyclic group.

The trivalent aromatic hydrocarbon group means an atomic group in which three hydrogen atoms are removed from a benzene ring or a condensed ring. In the below examples, among the three connecting bonds, connecting bonds in ortho position connect, respectively to X and N, in formula (12), (12-1), (12-3) and (12-4).

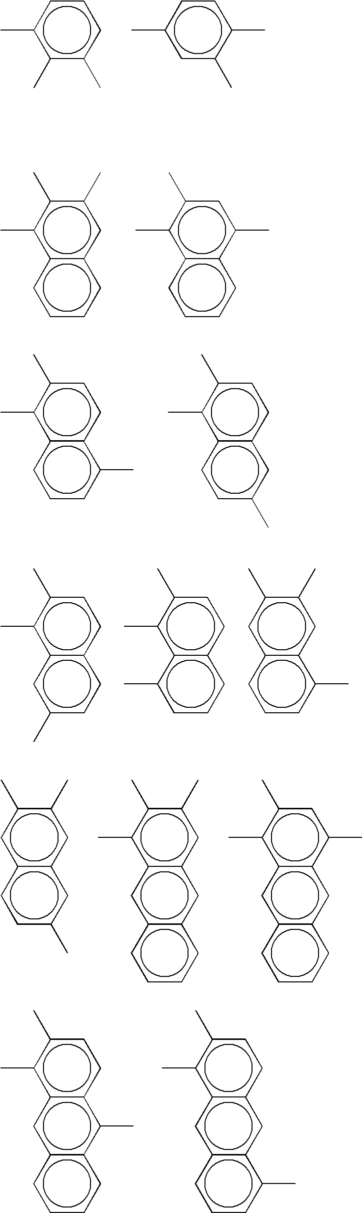

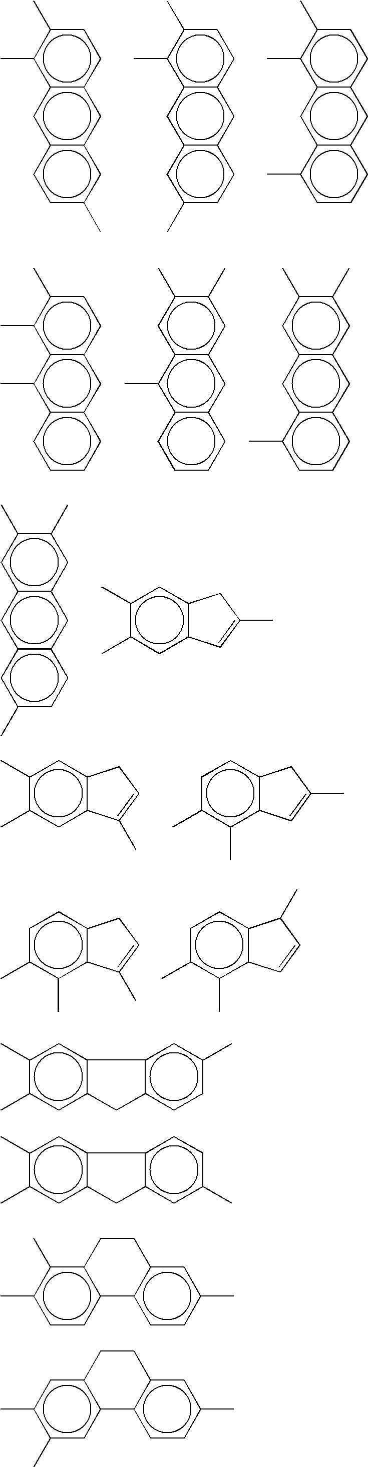

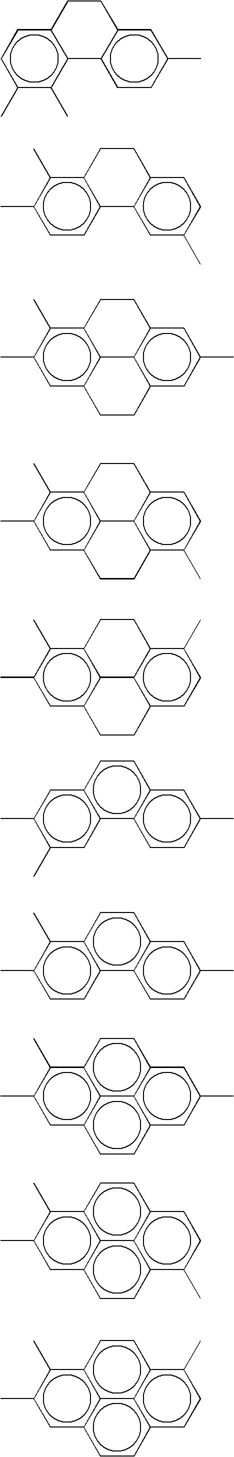

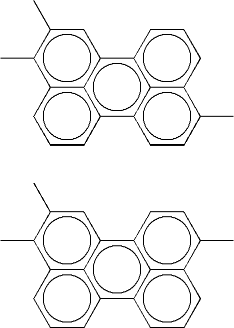

The above trivalent aromatic hydrocarbon group may have one or two substituents or more on the aromatic ring. Examples of the substituent include a halogen atom, alkyl group, alkyloxy group, alkylthio group, alkylamino group, aryl group, aryloxy group, arylthio group, arylamino group, arylalkyl group, arylalkyloxy group, arylalkylthio group, arylalkylamino group, acyl group, acyloxy group, amide group, imino group, substituted silyl group, substituted silyloxy group, substituted silylthio group, substituted silylamino group, monovalent heterocyclic group, arylalkenyl group, arylalkynyl group, or cyano group.

The number of the carbon atoms which constitute the ring of the trivalent aromatic hydrocarbon group, is usually 6 to 60, and preferably, 6 to 20.

The trivalent heterocyclic group means a remaining atomic group in which three hydrogen atoms are removed from a heterocyclic compound.

The heterocyclic compound means an organic compound having a cyclic structure in which at least one heteroatom such as oxygen, sulfur, nitrogen, phosphorus, boron, etc. is contained in the cyclic structure as the element other than carbon atoms.

As the examples of the trivalent heterocyclic group, followings are exemplified. In the below examples, among the three connecting bonds, connecting bonds in ortho position connect, respectively to X and N, in formula (12), (12-1), (12-3) and (12-4).

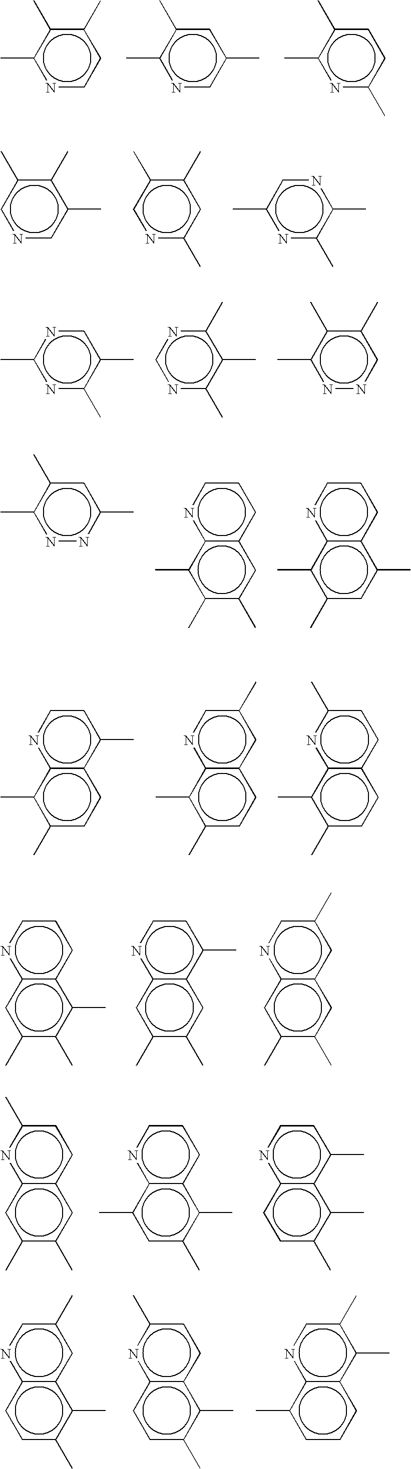

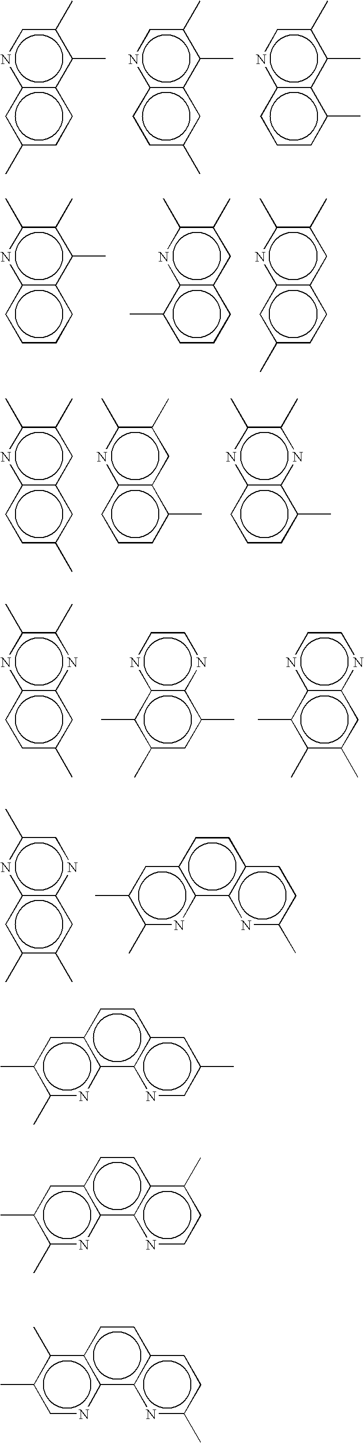

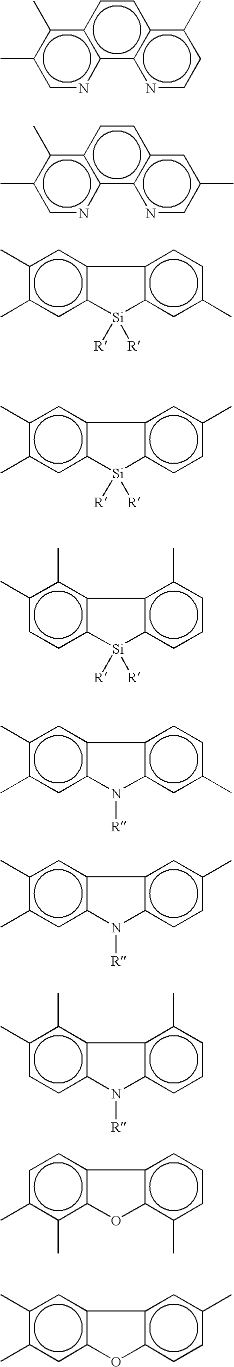

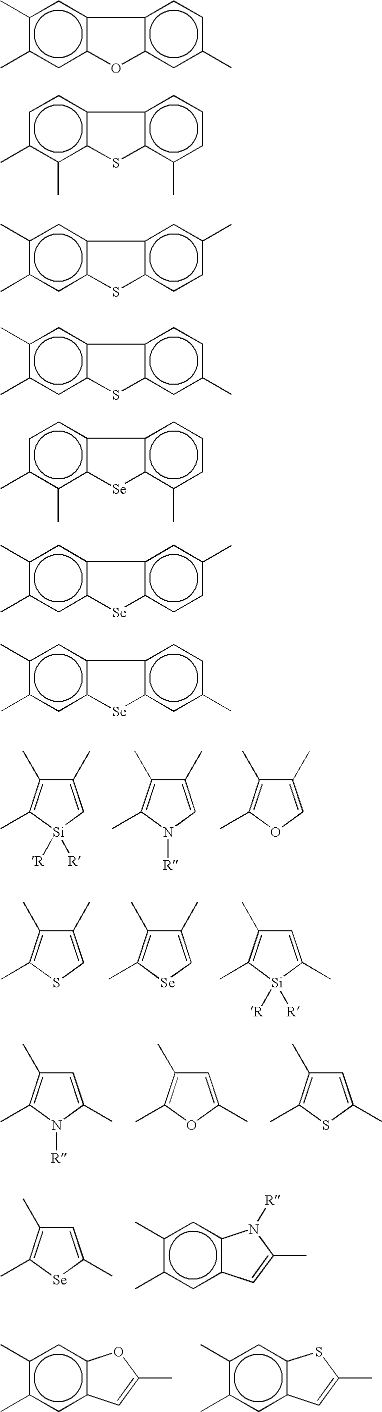

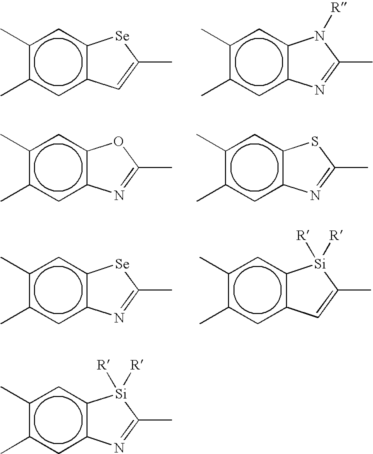

The above trivalent heterocyclic group may have one or more substituents on the ring. Examples of the substituent include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, and cyano group.

The number of the carbon atoms which constitute the ring of the trivalent heterocyclic group is usually 4 to 60, and preferably, 4 to 20.

In the above formula, R′ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imino group, amide group, imide group, monovalent heterocyclic group, carboxyl group, substituted carboxyl group, or cyano group.

R″ each independently represents a hydrogen atom, alkyl group, aryl group, arylalkyl group, substituted silyl group, acyl group, or monovalent heterocyclic group.

In formula (12), X represents a single bond, or following groups: 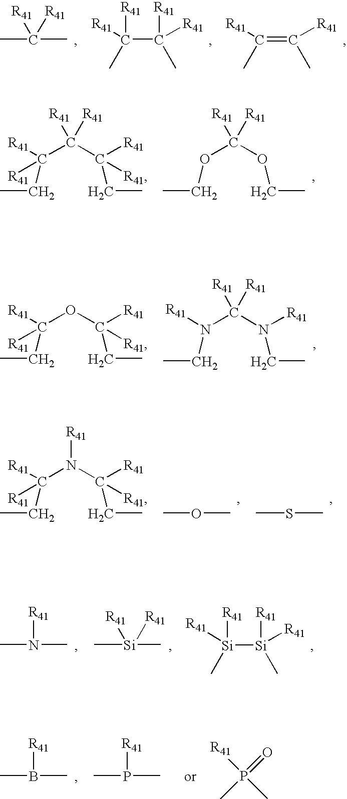
(wherein, R₄₁ each independently represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group. When two or more R₄₁s exist, they may be the same or different.).

Among them, preferables are a single bond, and

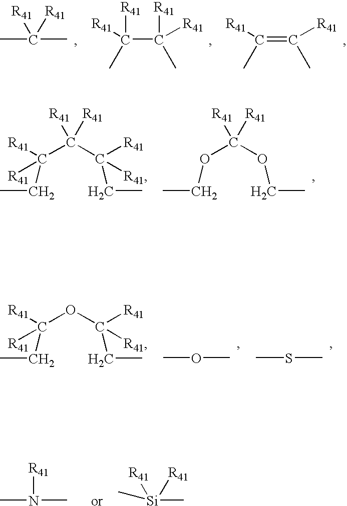

Single bond is more preferable.

Among the repeating units of the above formula (12), formula (12-1), (12-2), (12-3), (12-4), (12-5), and (12-6) are preferable, and (12-1), (12-4), (12-5), and (12-6) are more preferable, and formula (12-6) is further preferable. 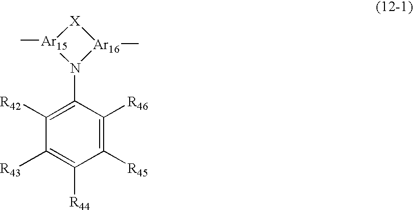
[wherein, X, Ar₁₅ and Ar₁₆ represent the same meaning as the above. R₄₂, R₄₃, R₄₄, R₄₅, and R₄₆ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.]. 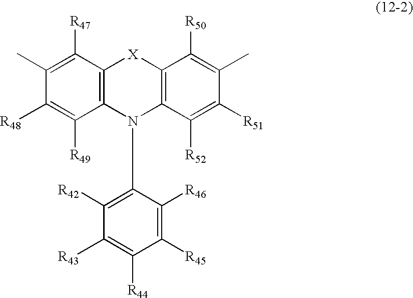
[wherein, R₄₂, R₄₃, R₄₄, R₄₅, R₄₆ and X represent the meaning as the above. R₄₇, R₄₈, R₄₉, R₅₀, R₅₁, and R₅₂ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.]. 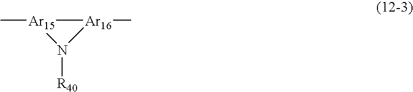
[wherein, R₄₀, Ar₁₅ and Ar₁₆ represent the same meaning as the above.] 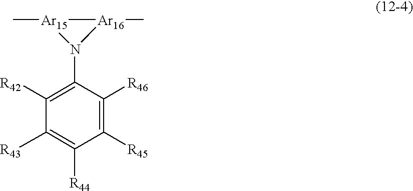
[wherein, R₄₂, R₄₃, R₄₄, R₄₅, R₄₆, Ar₁₅ and Ar₁₆ represent the same meaning as the above.] 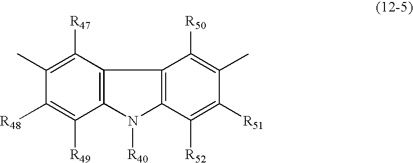
[wherein, R₄₀, R₄₇, R₄₈, R₄₉, R₅₀, R₅₁ and R₅₂ represent the same meaning as the above.] 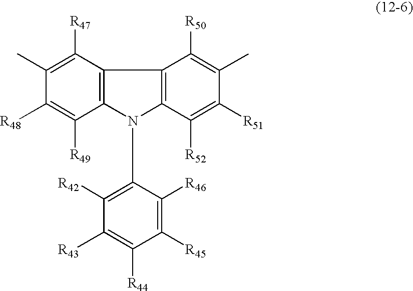
[wherein, R₄₂, R₄₃, R₄₄, R₄₅, R₄₆, R₄₇, R₄₈, R₄₉, R₅₀, R₅₁ and R₅₂ represent the same meaning as the above.].

As the repeating units of the above formula (3), the repeating units of the below formula (13) are exemplified. 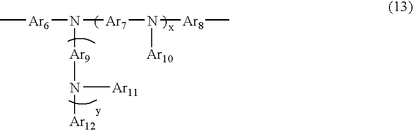
[wherein, Ar₆, Ar₇, Ar₈, and Ar₉ each independently represent an arylene group or a divalent heterocyclic group. Ar₁₀, Ar₁₁, and Ar₁₂ each independently represent an aryl group or a monovalent heterocyclic group. Ar₆, Ar₇, Ar₈, Ar₉, and Ar₁₀ may have substituent. x and y each independently represent 0 or 1, and 0≦x+y≦1.].

In Ar₆, Ar₇, Ar₈ and Ar₉ of a formula (13), the arylene group is an atomic group in which two hydrogen atoms are removed from an aromatic hydrocarbon, and usually, the number of carbon atoms is about 6 to 60, and preferably 6 to 20. The aromatic hydrocarbon includes those containing a benzene ring, a condensed ring, and two or more of independent benzene rings or condensed rings bonded through a group such as a direct bond, a vinylene group or the like.

Examples of the arylene group include: phenylene group (for example, above formulas 1-3), naphthalene diyl group (above formulas 4-13), anthracene-diyl group (above formulas 14-19), biphenyl-diyl group (above formulas 20-25), terphenyl-diyl group (above formulas 26-28), condensed-ring compound group (above formulas 29-35), fluorene-diyl group (above formulas 36-38), stilbene-diyl (above formulas A-D), distilbene-diyl (above formulas E, F), etc. Among them, phenylene group, biphenylene group, and stilbene-diyl group are preferable.

The divalent heterocyclic group means an atomic group in which two hydrogen atoms are removed from a heterocyclic compound, and the number of carbon atoms is usually about 3 to 60.

The heterocyclic compound means an organic compound having a cyclic structure in which at least one heteroatom such as oxygen, sulfur, nitrogen, phosphorus, boron, arsenic, etc. is contained in the cyclic structure as the element other than carbon atoms.

Examples of the divalent heterocyclic group include followings.

Divalent heterocyclic groups containing nitrogen as a hetero atom; pyridine-diyl group (above formulas 39-44), diaza phenylene group (above formulas 45-48), quinolinediyl group (above formulas 49-63), quinoxalinediyl group (above formulas 64-68), acridinediyl group (above formulas 69-72), bipyridyldiyl group (above formulas 73-75), phenanthrolinediyl group (above formulas 76-78), etc.

Groups having a fluorene structure containing silicon, nitrogen, selenium, etc. as a hetero atom (above formulas 79-93).

5 membered heterocyclic groups containing silicon, nitrogen, sulfur, selenium, etc. as a hetero atom: (above formulas 94-98).

Condensed 5 membered heterocyclic groups containing silicon, nitrogen, selenium, etc. as a hetero atom: (above formulas 99-108).

5 membered heterocyclic groups containing silicon, nitrogen, sulfur, selenium, etc. as a hetero atom, which are connected at the a position of the hetero atom to form a dimer or an oligomer (above formulas 109-113); and

5 membered ring heterocyclic groups containing silicon, nitrogen, sulfur, selenium, as a hetero atom is connected with a phenyl group at the a position of the hetero atom (above formulas 113-119).

Condensed 5 membered heterocyclic groups containing oxygen, nitrogen, sulfur, etc. as a hetero atom, and having a phenyl group, furyl group, and thienyl group as a substituent (above formulas 120-125).

Among the structure of the above formula (13), the structure of the below formula (13-1) is preferable. 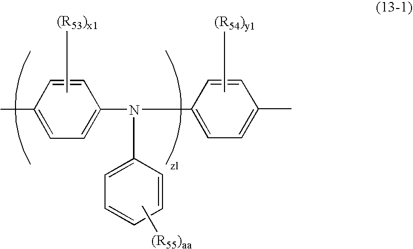
[wherein, R₅₃, R₅₄, and R₅₅ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, acid imide group, monovalent heterocyclic group, carboxyl group, substituted carboxyl group or cyano group. x₁ and y1 each independently represent an integer of 0-4. z1 represents an integer of 1-2. aa represents an integer of 0-5.].

As R₅₅ in the above formula (13-1), alkyl group, alkoxy group, aryl group, aryloxy group, arylalkyl group, arylalkoxy group, and substituted amino group are preferable. As the substituted amino group, diaryl amino group is preferable, and diphenyl amino group is further preferable.

As for a preferable combination in the above, combination of the above formula (1-6), and the above formulas (5), (7), (8) or (11) is preferable, and the combination of formula (1-6), and formula (8), (11) is more preferable.

In the structure of the above formula (1-6), it is more preferable that Y is S atom or O atom.

As for a preferable combination in the above, combination of the above formula (1-6), and the above formula (12-2), (12-5) (12-6) or (13-1) is preferable, and the combination of formula (1-6), and formula (12-6), (13-11) is more preferable.

In the structure of the above formula (1-6), it is more preferable that Y is S atom or O atom.

The above formulas (1) to (13), (12-1) to (12-6), (13-1), (1-1) to (1-10), and groups shown by the above exemplified formula, such as an alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acid imide group, monovalent heterocyclic group, and substituted carboxyl group represent the same meaning as above.

The alkyl group may be any of linear, branched or cyclic. The number of carbon atoms is usually about 1 to 20, preferably 3 to 20, and specific examples thereof include methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group, etc.; and pentyl group, hexyl group, octyl group, 2-ethyl hexyl group, decyl group, and 3,7-dimethyloctyl group are preferable.

The alkoxy group may be any of linear, branched or cyclic. The number of carbon atoms is usually about 1 to 20, preferably 3 to 20, and specific examples thereof include methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethyl hexyloxy group, nonyloxy group, decyloxy group, 3,7-dimethyl octyloxy group, lauryloxy group, trifluoromethoxy group, pentafluoroethoxy group, perfluorobutoxy group, perfluorohexyloxy group, perfluorooctyloxy group, methoxymethyloxy group, 2-methoxyethyloxy group, etc.; and pentyloxy group, hexyloxy group, octyloxy group, 2-ethylhexyloxy group, decyloxy group, and 3,7-dimethyl octyloxy group are preferable.

The alkylthio group may be any of linear, branched or cyclic. The number of carbon atoms is usually about 1 to 20, preferably 3 to 20, and specific examples thereof include methylthio group, ethylthio group, propylthio group, i-propylthio group, butylthio group, i-butylthio group, t-butylthio group, pentylthio group, hexylthio group, cyclo hexylthio group, heptylthio group, octylthio group, 2-ethyl hexylthio group, nonylthio group, decylthio group, 3,7-dimethyloctylthio group, laurylthio group, trifluoromethylthio group, etc.; and pentylthio group, hexylthio group, octylthio group, 2-ethyl hexylthio group, decylthio group, and 3,7-dimethyloctylthio group are preferable.

The aryl group has usually about 6 to 60 carbon atoms, preferably 7 to 48, and specific examples thereof include phenyl group, C₁-C₁₂ alkoxyphenyl group (C₁-C₁₂ represents the number of carbon atoms 1-12. Hereafter the same), C₁-C₁₂ alkylphenyl group, 1-naphtyl group, 2-naphtyl group, 1-anthracenyl group, 2-anthracenyl group, 9-anthracenyl group, pentafluorophenyl group, etc., and C₁-C₁₂ alkoxyphenyl group and C₁-C₁₂ alkylphenyl group are preferable. The aryl group is an atomic group in which one hydrogen atom is removed from an aromatic hydrocarbon. The aromatic hydrocarbon includes those having a condensed ring, an independent benzene ring, or two or more condensed rings bonded through groups, such as a direct bond or a vinylene group.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethyl hexyloxy, nonyloxy, decyloxy, 3,7-dimethyloctyloxy, lauryloxy, etc.

Concrete examples of C₁-C₁₂ alkyl phenyl group include methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group, etc.

The aryloxy group has the number of carbon atoms of usually about 6 to 60, preferably 7 to 48, and concrete examples thereof include phenoxy group, C₁-C₁₂ alkoxyphenoxy group, C₁-C₁₂ alkyl phenoxy group, 1-naphtyloxy group, 2-naphtyloxy group, pentafluorophenyloxy group, etc.; and C₁-C₁₂ alkoxyphenoxy group and C₁-C₁₂ alkylphenoxy group are preferable.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethyl hexyloxy, nonyloxy, decyloxy, 3,7-dimethyloctyloxy, lauryloxy, etc.

Concrete examples of C₁-C₁₂ alkylphenoxy group include methylphenoxy group, ethylphenoxy group, dimethylphenoxy group, propylphenoxy group, 1,3,5-trimethylphenoxy group, methylethylphenoxy group, i-propylphenoxy group, butyl phenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group, etc.

The arylthio group has the number of carbon atoms of usually about 6 to 60, preferably 7 to 48, and concrete examples thereof include phenylthio group, C₁-C₁₂ alkoxyphenylthio group, C₁-C₁₂ alkylphenylthio group, 1-naphthylthio group, 2-naphthylthio group, pentafluorophenylthio group, etc.; C₁-C₁₂ alkoxy phenylthio group and C₁-C₁₂ alkyl phenylthio group are preferable.

The arylalkyl group has the number of carbon atoms of usually about 7 to 60, preferably 7 to 48, and concrete examples thereof include phenyl-C₁-C₁₂alkyl group, C₁-C₁₂alkoxy phenyl-C₁-C₁₂ alkyl group, C₁-C₁₂ alkylphenyl-C₁-C₁₂ alkyl group, 1-naphtyl-C₁-C₁₂ alkyl group, 2-naphtyl-C₁-C₁₂ alkyl group etc.; and C₁-C₁₂ alkoxyphenyl-C₁-C₁₂ alkyl group and C₁-C₁₂ alkyl phenyl-C₁-C₁₂ alkyl group are preferable.

The arylalkoxy group has the number of carbon atoms of usually about 7 to 60, preferably 7 to 48, and concrete examples thereof include: phenyl-C₁-C₁₂alkoxy groups, such as phenylmethoxy group, phenylethoxy group, phenylbutoxy group, phenylpentyloxy group, phenylhexyloxy group, phenylheptyloxy group, and phenyloctyloxy group; C₁-C₁₂alkoxyphenyl-C₁-C₁₂ alkoxy group, C₁-C₁₂alkylphenyl-C₁-C₁₂alkoxy group, 1-naphtyl-C₁-C₁₂ alkoxy group, 2-naphtyl-C₁-C₁₂ alkoxy group etc.; and C₁-C₁₂ alkoxyphenyl-C₁-C₁₂ alkoxy group and C₁-C₁₂ alkylphenyl-C₁-C₁₂ alkoxy group are preferable.

The arylalkylthio group has the number of carbon atoms of usually about 7 to 60, preferably 7 to 48, and concrete examples thereof include: phenyl-C₁-C₁₂ alkylthio group, C₁-C₁₂ alkoxy phenyl-C₁-C₁₂ alkylthio group, C₁-C₁₂ alkylphenyl-C₁-C₁₂ alkylthio group, 1-naphtyl-C₁-C₁₂ alkylthio group, 2-naphtyl-C₁-C₁₂ alkylthio group, etc.; and C₁-C₁₂ alkoxy phenyl-C₁-C₁₂ alkylthio group and C₁-C₁₂ alkylphenyl-C₁-C₁₂ alkylthio group are preferable.

The arylalkenyl group has the number of carbon atoms of usually about 7 to 60, preferably 7 to 48, and concrete examples thereof include: phenyl-C₂-C₁₂ alkenyl group, C₁-C₁₂ alkoxy phenyl-C₂-C₁₂ alkenyl group, C₁-C₁₂ alkyl phenyl-C₂-C₁₂ alkenyl group, 1-naphtyl-C₂-C₁₂ alkenyl group, 2-naphtyl-C₂-C₁₂alkenyl group, etc.; and C₁-C₁₂ alkoxy phenyl-C₂-C₁₂alkenyl group, and C₂-C₁₂alkyl phenyl-C₁-C₁₂ alkenyl group are preferable.

The arylalkynyl group has the number of carbon atoms of usually about 7 to 60, preferably 7 to 48, and concrete examples thereof include: phenyl-C₂-C₁₂ alkynyl group, C₁-C₁₂ alkoxy phenyl-C₂-C₁₂ alkynyl group, C₁-C₁₂ alkylphenyl-C₂-C₁₂ alkynyl group, 1-naphtyl-C₂-C₁₂alkynyl group, 2-naphtyl-C₂-C₁₂alkynyl group, etc.; and C₁-C₁₂ alkoxyphenyl-C₂-C₁₂ alkynyl group, and C₁-C₁₂ alkylphenyl-C₂-C₁₂ alkynyl group are preferable.

The substituted amino group means a amino group substituted by 1 or 2 groups selected from an alkyl group, aryl group, arylalkyl group, or monovalent heterocyclic group, and said alkyl group, aryl group, arylalkyl group, or monovalent heterocyclic group may have substituent. The substituted amino groups has usually about 1 to 60, preferably 2 to 48 carbon atoms, without including the number of carbon atoms of said substituent. Concrete examples thereof include methylamino group, dimethylamino group, ethylamino group, diethylamino group, propylamino group, dipropylamino group, i-propylamino group, diisopropylamino group, butylamino group, i-butyl amino group, t-butylamino group, pentylamino group, hexyl amino group, cyclohexylamino group, heptylamino group, octyl amino group, 2-ethylhexylamino group, nonylamino group, decyl amino group, 3,7-dimethyloctylamino group, laurylamino group, cyclopentylamino group, dicyclopentyl amino group, cyclohexyl amino group, dicyclohexylamino group, pyrrolidyl group, piperidyl group, ditrifluoromethylamino group, phenylamino group, diphenylamino group, C₁-C₁₂ alkoxyphenylamino group, di(C₁-C₁₂ alkoxyphenyl)amino group, di(C₁-C₁₂ alkylphenyl) amino group, 1-naphtylamino group, 2-naphtylamino group, pentafluorophenylamino group, pyridylamino group, pyridazinylamino group, pyrimidylamino group, pyrazylamino group, triazylamino group phenyl-C₁-C₁₂ alkylamino group, C₁-C₁₂ alkoxyphenyl-C₁-C₁₂alkylamino group, C₁-C₁₂ alkyl phenyl-C₁-C₁₂ alkylamino group, di(C₁-C₁₂ alkoxyphenyl-C₁-C₁₂ alkyl)amino group, di(C₁-C₁₂ alkylphenyl-C₁-C₁₂ alkyl)amino group, 1-naphtyl-C₁-C₁₂ alkylamino group, 2-naphtyl-C₁-C₁₂ alkylamino group, etc.

The substituted silyl group means a silyl group substituted by 1, 2 or 3 groups selected from an alkyl group, aryl group, arylalkyl group, or monovalent heterocyclic group. The substituted silyl group has usually about 1 to 60, preferably 3 to 48 carbon atoms. Said alkyl group, aryl group, arylalkyl group, or monovalent heterocyclic group may have substituent.

Concrete examples of the substituted silyl group include trimethylsilyl group, triethylsilyl group, tripropylsilyl group, tri-i-propylsilyl group, dimethyl-i-propylsilyl group, diethyl-i-propylsilyl group, t-butylsilyldimethylsilyl group, pentyldimethylsilyl group, hexyldimethylsilyl group, heptyl dimethylsilyl group, octyldimethylsilyl group, 2-ethyl hexyl-dimethylsilyl group, nonyldimethylsilyl group, decyl dimethylsilyl group, 3,7-dimethyloctyl-dimethylsilyl group, lauryldimethylsilyl group, phenyl-C₁-C₁₂ alkylsilyl group, C₁-C₁₂ alkoxyphenyl-C₁-C₁₂ alkylsilyl group, C₁-C₁₂ alkyl phenyl-C₁-C₁₂ alkylsilyl group, 1-naphtyl-C₁-C₁₂ alkylsilyl group, 2-naphtyl-C₁-C₁₂ alkylsilyl group, phenyl-C₁-C₁₂ alkyl dimethylsilyl group, triphenylsilyl group, tri-p-xylylsilyl group, tribenzylsilyl group, diphenylmethylsilyl group, t-butyldiphenylsilyl group, dimethylphenylsilyl group, etc.

As the halogen atom, a fluorine atom, a chlorine atom, a bromine atom, and an iodine atom are exemplified.

The acyl group has usually about 2 to 20 carbon atoms, preferably 2 to 18 carbon atoms, and concrete examples thereof include acetyl group, propionyl group, butyryl group, isobutyryl group, pivaloyl group, benzoyl group, trifluoro acetyl group, pentafluorobenzoyl group, etc.

The acyloxy group has usually about 2 to 20 carbon atoms, preferably 2 to 18 carbon atoms, and concrete examples thereof include acetoxy group, propionyloxy group, butyryloxy group, isobutyryloxy group, pivaloyloxy group, benzoyloxy group, trifluoroacetyloxy group, pentafluorobenzoyl oxy group, etc.

Imine residue is a residue in which a hydrogen atom is removed from an imine compound (an organic compound having —N═C— is in the molecule. Examples thereof include aldimine, ketimine, and compounds whose hydrogen atom on N is substituted with an alkyl group etc.), and usually has about 2 to 20 carbon atoms, preferably 2 to 18 carbon atoms. As the concrete examples, groups represented by below structural formulas are exemplified.

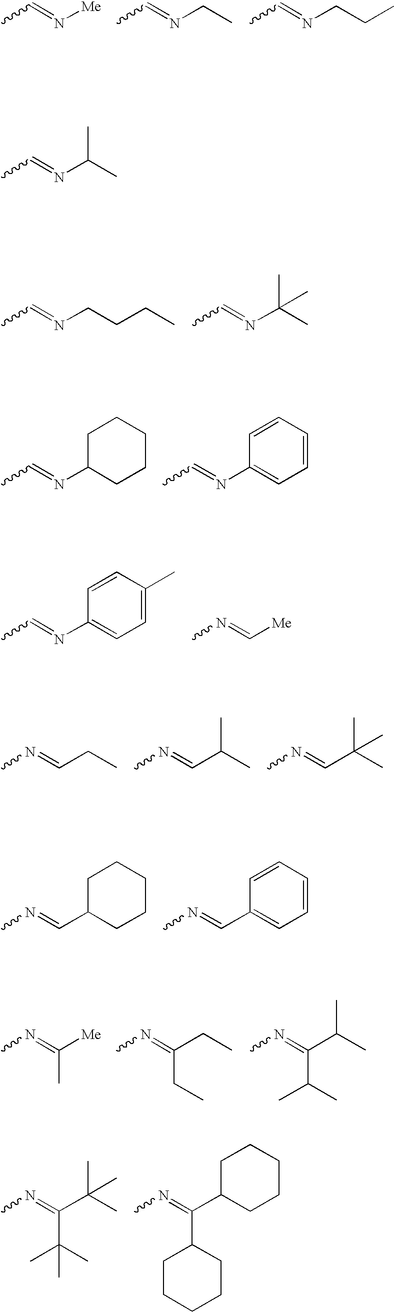

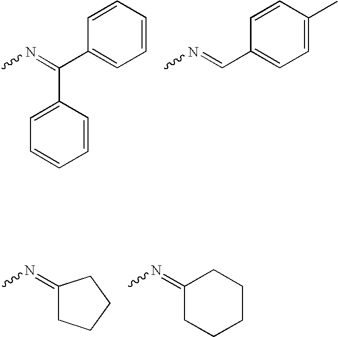

The amide group has usually about 2 to 20 carbon atoms, preferably 2 to 18 carbon atoms, and specific examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoro acetamide group, dipentafluorobenzamide group, etc.

Examples of the acid imide group include residual groups in which a hydrogen atom connected with nitrogen atom is removed, and have usually about 2 to 60 carbon atoms, preferably 2 to 48 carbon atoms. As the concrete examples of acid imide group, the following groups are exemplified.

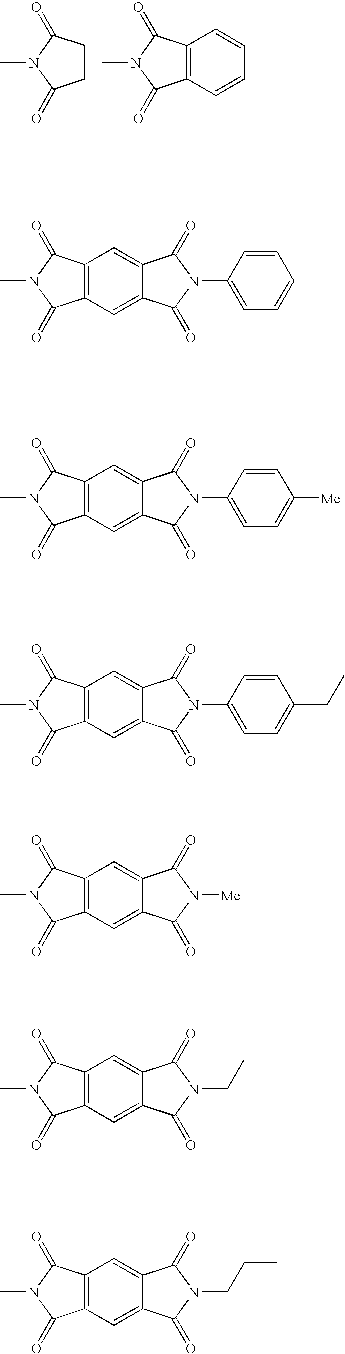

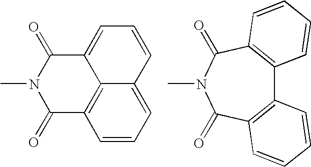

The monovalent heterocyclic group means an atomic group in which a hydrogen atom is removed from a heterocyclic compound, and the number of carbon atoms is usually about 4 to 60, preferably 4 to 20. The number of carbon atoms of the substituent is not contained in the number of carbon atoms of a heterocyclic group. The heterocyclic compound means an organic compound having a cyclic structure in which at least one heteroatom such as oxygen, sulfur, nitrogen, phosphorus, boron, etc. is contained in the cyclic structure as the element other than carbon atoms. Concrete examples thereof include thienyl group, C₁-C₁₂ alkylthienyl group, pyroryl group, furyl group, pyridyl group, C₁-C₁₂ alkylpyridyl group, piperidyl group, quinolyl group, isoquinolyl group, etc.; and thienyl group, C₁-C₁₂ alkylthienyl group, pyridyl group, and C₁-C₁₂ alkylpyridyl group are preferable.

The substituted carboxyl group means a carboxyl group substituted by alkyl group, aryl group, arylalkyl group, or monovalent heterocyclic group, and has usually about 2 to 60, preferably 2 to 48 carbon atoms. Concrete examples thereof include methoxy carbonyl group, ethoxycarbonyl group, propoxycarbonyl group, i-propoxycarbonyl group, butoxycarbonyl group, i-butoxy carbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxy carbonyl group, phenoxycarbonyl group, naphtoxycarbonyl group, pyridyloxycarbonyl group, etc. Said alkyl group, aryl group, arylalkyl group, or monovalent heterocyclic group may have substituent. The number of carbon atoms of said substituent is not contained in the number of carbon atoms of the substituted carboxyl group.

Among the above, in the groups containing an alkyl, they may be any of linear, branched or cyclic, or may be the combination thereof. In case of not linear, isoamyl group, 2-ethylhexyl group, 3,7-dimethyloctyl group, cyclohexyl group, 4-C₁-C₁₂ alkylcyclohexyl group, etc., are exemplified. Moreover, the tips of two alkyl chains may be connected to form a ring. Furthermore, a part of methyl groups and methylene groups of alkyl, may be replaced by a group containing hetero atom, or a methyl or methylene group substituted by one or more fluorine. As the hetero atoms, an oxygen atom, a sulfur atom, a nitrogen atom, etc., are exemplified.

Furthermore, in the examples of the substituents, when an aryl group or a heterocyclic group is included in the part thereof, they may have one or more substituents.

In order to improve the solubility in a solvent, it is preferable that Ar₁, Ar₂, Ar₃ and Ar₄ have substituent, and one or more of them include an alkyl group or alkoxy group having cyclic or long chain. Examples thereof include. cyclopentyl group, cyclohexyl group, pentyl group, isoamyl group, hexyl group, octyl group, 2-ethylhexyl group, decyl group, 3,7-dimethyloctyl group, pentyloxy group, isoamyloxy group, hexyloxy group, octyloxy group, 2-ethylhexyloxy group, decyloxy group, and 3,7-dimethyloctyloxy group.

Two substituents may be connected to form a ring. Furthermore, a part of carbon atom of the alkyl may be replaced by a group containing a hetero atom, and examples of the hetero atom include an oxygen atom, a sulfur atom, a nitrogen atom, etc.

Furthermore, the end group of polymer compound used for the present invention may also be protected with a stable group since if a polymerization active group remains intact, there is a possibility of reduction in light emitting property and life-time when made into an device. Those having a conjugated bond continuing to a conjugated structure of the main chain are preferable, and there are exemplified structures connected to an aryl group or heterocyclic compound group via a carbon-carbon bond. Specifically, substituents described as Chemical Formula 1 in JP-A-9-45478 are exemplified.

The polymer compound used for the present invention may also be a random, block or graft copolymer, or a polymer having an intermediate structure thereof, for example, a random copolymer having block property. From the viewpoint for obtaining a polymer compound having high fluorescent quantum yield, random copolymers having block property and block or graft copolymers are preferable than complete random copolymers. Further, a polymer having a branched main chain and more than three terminals, and a dendrimer may also be included.

The polymer compound used for the present invention, it is preferable that the polystyrene reduced number average molecular weights is 10³-10⁸, and more preferably 10⁴-10⁷.

Next, the manufacture method of the polymer compound used for the composition of the present invention will be explained.

Specifically, a monomer having polymerization active groups is dissolved in an organic solvent according to necessity, and can be reacted using alkali or appropriate catalyst, at a temperature between the boiling point and the melting point of the organic solvent.

Known methods which can be used are described in: Organic Reactions, Volume 14, page 270-490, John Wiley & Sons, Inc., 1965; Organic Syntheses, Collective Volume VI, page 407-411, John Wiley & Sons, Inc., 1988; Chemical Review (Chem. Rev.), Volume 95, page 2457 (1995); Journal of Organometallic Chemistry (J. Organomet. Chem.), Volume 576, page 147 (1999); and Macromolecular Chemistry, Macromolecular Symposium (Makromol. Chem., Macromol. Symp.), Volume 12th, page 229 (1987).

In the manufacture method of the polymer compound used for the composition of the present invention, known condensation reactions can be used as the method of carrying out condensation polymerization. As the method of condensation polymerization, in case of producing double bond, for example, a method described in JP-A-5-202355 is exemplified.

That is, exemplified are: a polymerization by Wittig reaction of a compound having formyl group and a compound having phosphonium-methyl group, or a compound having formyl group and phosphonium-methyl group; polymerization by Heck reaction of a compound having vinyl group and a compound having halogen atom; polycondensation by dehydrohalogenation method of a compound having two or more monohalogenated-methyl groups; polycondensation by sulfonium-salt decomposition method of a compound having two or more sulfonium-methyl groups; polymerization by Knoevenagel reaction of a compound having formyl group and a compound having cyano group; and polymerization by McMurry reaction of a compound having two or more formyl groups.

When a polymer compound of the present invention has a triple bond in the main chain by condensation polymerization, for example, Heck reaction can be used.

In case of producing neither a double bond nor a triple bond, exemplified are: a method of polymerization by Suzuki coupling reaction from corresponding monomer; a method of polymerization by Grignard reaction; a method of polymerization by Ni(0) complex; a method of polymerization by oxidizers, such as FeCl₃; a method of electrochemical oxidization polymerization; and a method by decomposition of an intermediate polymer having a suitable leaving group.

Among these, a polymerization by Wittig reaction, a polymerization by Heck reaction, a polymerization by Knoevenagel reaction, a method of polymerization by Suzuki coupling reaction, a method of polymerization by Grignard reaction, and a method of polymerization by nickel zero-valent complex are preferable, since it is easy to control the structure.

When the reactive substituent in the raw monomer for the polymer compound used for the present invention is a halogen atom, alkylsulfonate group, arylsulfonate group, or arylalkylsulfonate group, a manufacture method by condensation polymerization in the existence of nickel-zero-valent-complex is preferable.

As the raw compound, a dihalogenated compound, bis (alkylsulfonate) compound, bis(arylsulfonate) compound, bis (arylalkylsulfonate) compound, or halogen-alkylsulfonate compound, halogen-arylsulfonate compound, halogen-arylalkylsulfonate compound, alkylsulfonate-arylsulfonate compound, alkylsulfonate-arylalkylsulfonate compound are exemplified.

Moreover, When the reactive substituent in the raw monomer for the polymer compound used for the present invention is a a halogen atom, alkylsulfonate group, arylsulfonate group, arylalkylsulfonate group, boric-acid group, or boric acid ester group, it is preferable that the ratio of the total mol of a halogen atom, alkylsulfonate group, arylsulfonate group, and arylalkylsulfonate group, with the total of boric-acid group and boric acid ester group is substantially 1 (usually in the range of 0.7 to 1.2), and the manufacture method is a condensation polymerization using a nickel catalyst or a palladium catalyst.

Concrete examples of the combination of raw compounds include combinations of a dihalogenated compound, bis (alkylsulfonate) compound, bis (arylsulfonate) compound or bis(arylalkylsulfonate) compound, with a diboric acid compound, or diboric acid ester compound.

Moreover, halogen-boric-acid compound, halogen-boric acid ester compound, alkylsulfonate-boric-acid compound, alkylsulfonate-boric acid ester compound, arylsulfonate-boric-acid compound, arylsulfonate-boric acid ester compound, arylalkylsulfonate-boric-acid compound, and arylalkylsulfonate-boric acid ester compound are exemplified.

It is preferable that the organic solvent used is subjected to a deoxygenation treatment sufficiently and the reaction is progressed under an inert atmosphere, generally for suppressing a side reaction, though the treatment differs depending on compounds and reactions used. Further, it is preferable to conduct a dehydration treatment likewise. However, this is not applicable in the case of a reaction in a two-phase system with water, such as a Suzuki coupling reaction.

For the reaction, alkali or a suitable catalyst is added. It can be selected according to the reaction to be used. It is preferable that the alkali or the catalyst can be dissolved in a solvent used for a reaction. Example of the method for mixing the alkali or the catalyst, include a method of adding a solution of alkali or a catalyst slowly, to the reaction solution with stirring under an inert atmosphere of argon, nitrogen, etc. or conversely, a method of adding the reaction solution to the solution of alkali or a catalyst slowly.

When the polymer compounds of the present invention are used for a polymer LED, the purity thereof exerts an influence on light emitting property, therefore, it is preferable that a monomer is purified by a method such as distillation, sublimation purification, re-crystallization and the like before being polymerized. Further, it is preferable to conduct a purification treatment such as re-precipitation purification, chromatographic separation and the like after the polymerization.

Next, the compound (triplet light-emission compound) showing light-emission from triplet excited state used for the composition of the present invention will be explained. The compound showing light-emission from triplet excited state includes a complex in which phosphorescence light-emission is observed, and also a complex in which fluorescence light-emission is observed in addition to the phosphorescence light-emission.

In the triplet light-emission compound, as a complex compound (triplet light-emitting complex compound), a metal complex compound which has been used as a low molecular weight EL light-emission material from the former is exemplified.

These are disclosed by, for example, Nature, (1998) 395, 151; Appl. Phys. Lett. (1999), 75(1), 4; Proc. SPIE-Int. Soc. Opt. Eng. (2001), 4105 (Organic Light-Emitting Materials and Devices IV, 119; J. Am. Chem. Soc., (2001), 123, 4304; Appl. Phys. Lett., (1997), 71(18), 2596; Syn. Met., (1998), 94(1), 103; Syn. Met., (1999), 99(2), 1361; Adv. Mater., (1999), 11 (10), 852, etc.

The center metal of a complex emitting triplet luminescence is usually an atom having an atomic number of 50 or more, and is a metal manifesting a spin-orbital mutual action on this complex and showing a possibility of the intersystem crossing between the singlet state and the triplet state.

As the center metal of a complex emitting triplet luminescence, for example, rhenium, iridium, osmium, scandium, yttrium, platinum, gold, and europium such as lanthanoids, terbium, thulium, dysprosium, samarium, praseodymium, and the like, are exemplified, and iridium, platinum, gold and europium are preferable, iridium, platinum and gold are particularly preferable, and iridium is the most preferable.

As the ligand of a triplet light-emitting complex compound, for example, 8-quinolinol and derivatives thereof, benzoquinolinol and derivatives thereof, 2-phenyl-pyridine and derivatives thereof, 2-phenyl-benzothiazole and derivatives thereof, 2-phenyl-benzoxazole and derivatives thereof, porphyrin and derivatives thereof, and the like are exemplified.

Examples of the triplet light-emitting complex compound include followings.

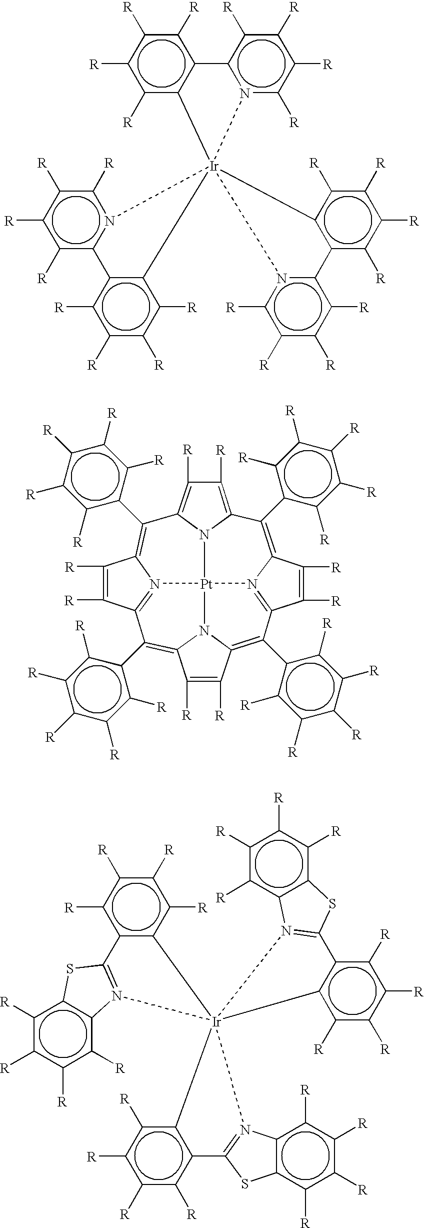

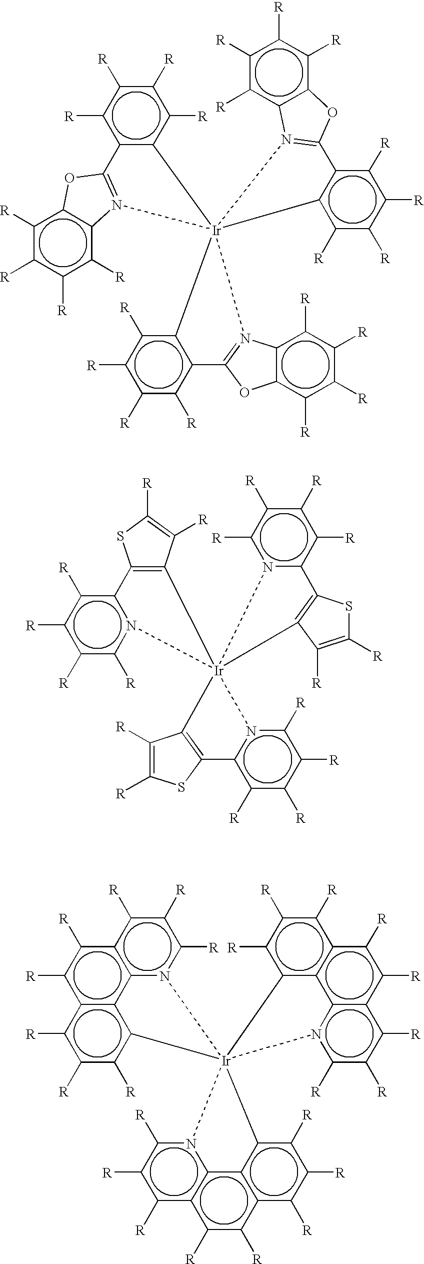

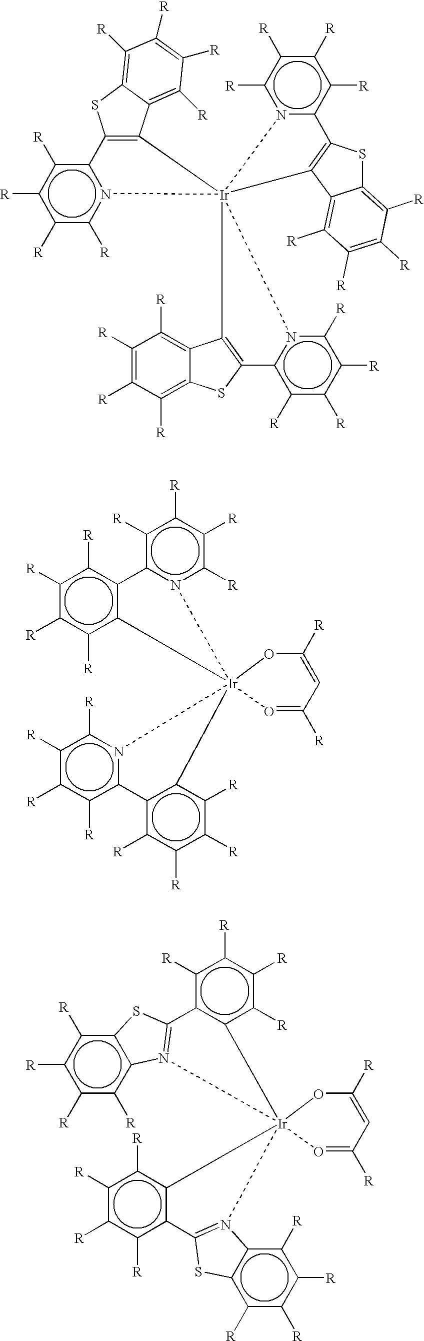

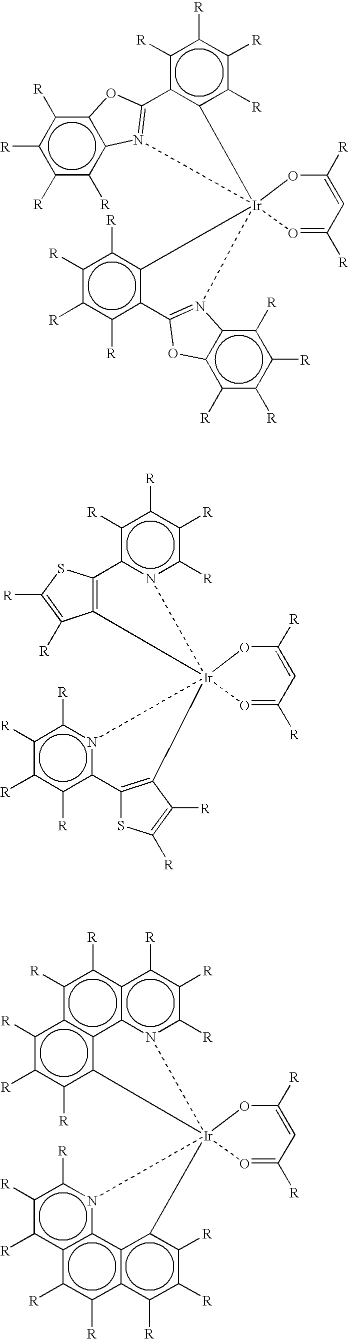

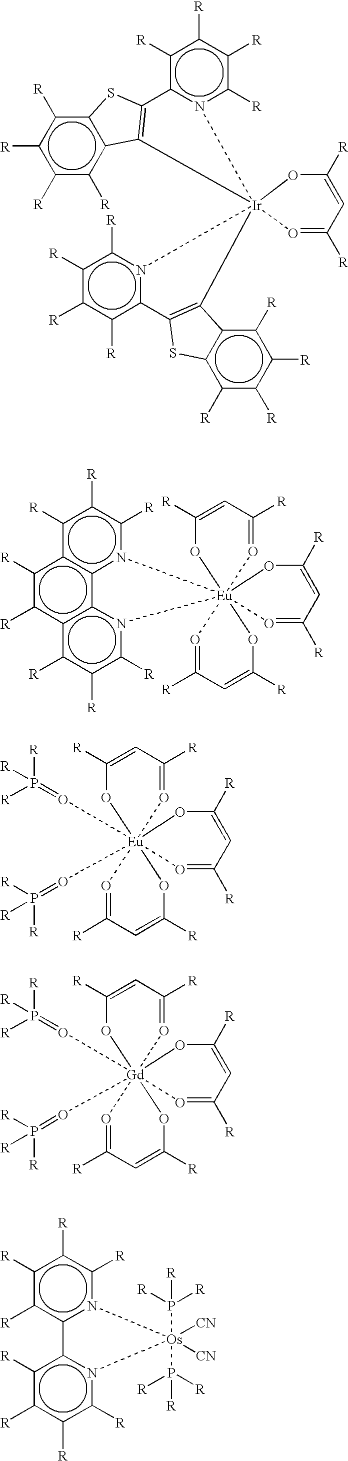

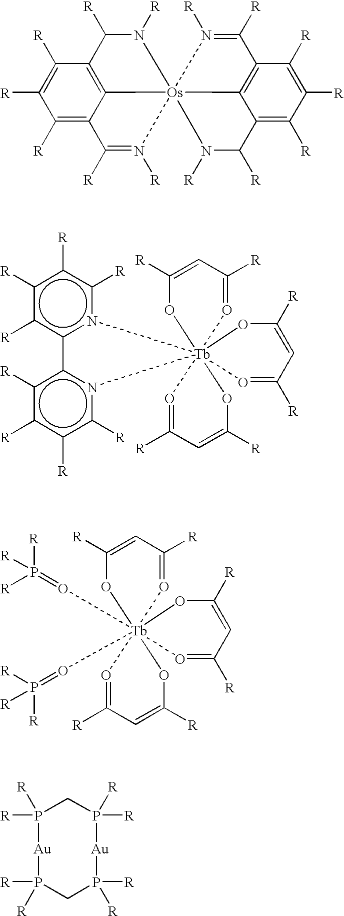

wherein, R each independently represents a group selected from a hydrogen atom, alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group, and cyano group. In order to improve the solubility in a solvent, alkyl group and alkoxy group are preferable, and it is preferable that the repeating unit including substituent has a form of little symmetry.

As the triplet light-emitting complex compound, still in detail, the structures of the below formula (15) are exemplified.
(H)ₒ₁-M-(K)ₘ₁ (15)

Wherein, K represents: a ligand containing an atom which bonds with one or more M selected from a nitrogen atom, oxygen atom, carbon atom, sulfur atom, and phosphorus atom; a halogen atom; or a hydrogen atom. Furthermore, o1 represents an integer of 0-5, and m1 represents an integer of 1-5.

As the ligand containing an atom which bonds with one or more M selected from a nitrogen atom, oxygen atom, carbon atom, sulfur atom, and phosphorus atom, an alkyl group, alkoxy group, acyloxy group, alkylthio group, alkylamino group, aryl group, aryloxy group, arylthio group, arylamino group, arylalkyl group, arylalkoxy group, arylalkylthio group, arylalkylamino group, sulfonate group, cyano group, heterocyclic ligand, a carbonyl compound, ether, amine, imine, phosphine, phosphite, and sulfide are exemplified. The bond of this ligand with M may be a coordinate bond or a covalent bond. Moreover, it may be a multi-dentate ligand combined thereof.

The alkyl group may be any of linear, branched or cyclic, and may have substituent. The number of carbon atoms is usually about 1 to 20. Concrete examples thereof include methyl group, ethyl group, propyl group, i-propyl group, butyl group, i-butyl group, t-butyl group, pentyl group, hexyl group, cyclohexyl group, heptyl group, Octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group, etc.; and pentyl group, hexyl group, octyl group, 2-ethylhexyl group, decyl group, and 3,7-dimethyl octyl group are preferable.

The alkoxy group may be any of linear, branched or cyclic, and may have substituent. The number of carbon atoms is usually about 1 to 20. Concrete examples thereof include methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group, lauryloxy group, trifluoro methoxy group, pentafluoroethoxy group, perfluorobutoxy group, perfluorohexyl group, perfluorooctyl group, methoxymethyloxy group, 2-methoxyethyloxy group, etc.; and pentyloxy group, hexyloxy group, octyloxy group, 2-ethylhexyloxy group, decyloxy group, and 3,7-dimethyloctyloxy group are preferable.

The acyloxy group has usually about 2 to 20 carbon atoms, and concrete examples thereof include acetyloxy group, trifluoroacetyloxy group, propionyloxy group, and benzoyl oxy group. As the sulfoneoxy group, benzene sulfoneoxy group, p-toluene sulfoneoxy group, methane sulfoneoxy group, ethane sulfoneoxy group, and trifluoromethane sulfoneoxy group are exemplified.

The alkylthio group may be any of linear, branched or cyclic, and may have substituent. The number of carbon atoms is usually about 1 to 20. Concrete examples thereof include methylthio group, ethylthio group, propylthio group, and i-propylthio group, butylthio group, i-butylthio group, t-butylthio group, pentylthio group, hexylthio group, cyclohexylthio group, heptylthio group, octylthio group, 2-ethylhexylthio group, nonylthio group, decylthio group, 3,7-dimethyloctylthio group, laurylthio group, trifluoromethylthio group, etc.; and pentylthio group, hexylthio group, octylthio group, 2-ethyl hexylthio group, decylthio group, and 3,7-dimethyl octylthio group are preferable.

The alkylamino group may be any of linear, branched or cyclic, and may be monoalkylamino group or dialkylamino group. The number of carbon atoms is usually about 1 to 40. Concrete examples thereof include methylamino group, dimethyl amino group, ethylamino group, diethylamino group, propylamino group, dipropylamino group, i-propylamino group, diisopropyl amino group, butylamino group, i-butylamino group, t-butyl amino group, pentylamino group, hexylamino group, cyclohexyl amino group, heptylamino group, octylamino group, 2-ethyl hexylamino group, nonylamino group, decylamino group, 3,7-dimethyloctylamino group, laurylamino group, cyclopentyl amino group, dicyclopentylamino group, cyclohexylamino group, dicyclohexylamino group, pyrrolidyl group, piperidyl group, ditrifluoromethylamino group, etc.; and pentylamino group, hexylamino group, octylamino group, 2-ethylhexylamino group, decylamino group, and 3,7-dimethyloctylamino group are preferable.

The aryl group may have substituent, and the number of carbon atoms is usually about 3 to 60, and concrete examples thereof include phenyl group, C₁-C₁₂ alkoxyphenyl group (C₁-C₁₂ means the number of carbon atoms 1-12. Hereinafter the same), C₁-C₁₂ alkylphenyl group, 1-naphtyl group, 2-naphtyl group, pentafluorophenyl group, pyridyl group, pyridazinyl group, pyrimidyl group, pyrazyl group, triazyl group, etc.; and C₁-C₁₂ alkoxyphenyl group and C₁-C₁₂ alkylphenyl group are preferable.

The aryloxy group may have substituent on the aromatic ring, and the number of carbon atoms is usually about 3 to 60. Concrete examples thereof include phenoxy group, C₁-C₁₂ alkoxyphenoxy group, C₁-C₁₂ alkylphenoxy group, 1-naphtyloxy group, 2-naphtyloxy group, pentafluorophenyloxy group, pyridyloxy group, pyridazinyloxy group, pyrimidyloxy group, pyrazyloxy group, triazyloxy group, etc.; and C₁-C₁₂ alkoxyphenoxy group and C₁-C₁₂ alkylphenoxy group are preferable.

The arylthio group may have substituent on the aromatic ring, and the number of carbon atoms is usually about 3 to 60. Concrete examples thereof include phenylthio group, C₁-C₁₂ alkoxyphenylthio group, C₁-C₁₂ alkylphenylthio group, 1-naphthylthio group, 2-naphthylthio group, pentafluoro phenylthio group, pyridylthio group, pyridazinylthio group, pyrimidylthio group, pyrazylthio group, triazylthio group, etc.; and C₁-C₁₂ alkoxyphenylthio group and C₁-C₁₂ alkyl phenylthio group are preferable.

The arylamino group may have substituent on the aromatic ring, and the number of carbon atoms is usually about 3 to 60. Concrete examples thereof include phenyl amino group, diphenylamino group, C₁-C₁₂ alkoxyphenylamino group, di(C₁-C₁₂ alkoxyphenyl) amino group, di(C₁-C₁₂ alkylphenyl) amino group, 1-naphtylamino group, 2-naphtylamino group, pentafluoro phenylamino group, pyridylamino group, pyridazinylamino group, pyrimidylamino group, pyrazylamino group, triazylamino group, etc.; and C₁-C₁₂ alkylphenylamino group and di(C₁-C₁₂ alkyl phenyl)amino group are preferable.

The arylalkyl group may have substituent on the aromatic ring, and the number of carbon atoms is usually about 7 to 60. Concrete examples thereof include phenyl-C₁-C₁₂ alkyl group, C₁-C₁₂ alkoxyphenyl-C₁-C₁₂ alkyl group, C₁-C₁₂ alkyl phenyl-C₁-C₁₂ alkyl group, 1-naphtyl-C₁-C₁₂ alkyl group, 2-naphtyl-C₁-C₁₂ alkyl group etc.; and C₁-C₁₂ alkoxy phenyl-C₁-C₁₂ alkyl group and C₁-C₁₂ alkylphenyl-C₁-C₁₂ alkyl group are preferable.

The arylalkoxy group may have substituent on the aromatic ring, and the number of carbon atoms is usually about 7 to 60. Concrete examples thereof include phenyl-C₁-C₁₂ alkoxy group, C₁-C₁₂ alkoxyphenyl-C₁-C₁₂ alkoxy group, C₁-C₁₂ alkyl phenyl-C₁-C₁₂ alkoxy group, 1-naphtyl-C₁-C₁₂ alkoxy group, 2-naphtyl-C₁-C₁₂ alkoxy group etc.; and C₁-C₁₂ alkoxy phenyl-C₁-C₁₂ alkoxy group and C₁-C₁₂ alkyl phenyl-C₁-C₁₂ alkoxy group are preferable.

The arylalkylthio group may have substituent on the aromatic ring, and the number of carbon atoms is usually about 7 to 60. Concrete examples thereof include phenyl-C₁-C₁₂ alkoxy group, C₁-C₁₂ alkoxyphenyl-C₁-C₁₂ alkoxy group, C₁-C₁₂ alkyl phenyl-C₁-C₁₂ alkoxy group, 1-naphtyl-C₁-C₁₂ alkoxy group, 2-naphtyl-C₁-C₁₂ alkoxy group etc.; and C₁-C₁₂ alkoxy phenyl-C₁-C₁₂ alkoxy group and C₁-C₁₂ alkyl phenyl-C₁-C₁₂ alkoxy group are preferable.

The arylalkylamino group has usually about 7 to 60 carbon atoms, and concrete examples thereof include phenyl-C₁-C₁₂ alkylamino group, C₁-C₁₂ alkoxyphenyl-C₁-C₁₂ alkylamino group, C₁-C₁₂ alkylphenyl-C₁-C₁₂ alkylamino group, di(C₁-C₁₂ alkoxy phenyl-C₁-C₁₂ alkyl) amino group, di(C₁-C₁₂ alkylphenyl-C₁-C₁₂ alkyl) amino group, 1-naphtyl-C₁-C₁₂ alkylamino group, 2-naphtyl-C₁-C₁₂ alkylamino group, etc.; and C₁-C₁₂ alkyl phenyl-C₁-C₁₂ alkylamino group and di(C₁-C₁₂ alkyl phenyl-C₁-C₁₂ alkyl)amino group are preferable.

Examples of the sulfonate group include benzenesulfonate group, p-toluenesulfonate group, methanesulfonate group, ethanesulfonate group, and trifluoromethanesulfonate group.

The heterocyclic ligand is a ligand which is constituted by bonding heterocycles, such as a pyridine ring, pyrrole ring, thiophene ring, oxazole, furan ring, and a benzene ring. Concrete examples thereof include phenylpyridine, 2-(para phenylphenyl)pyridine, 7-bromobenzo[h]quinoline, 2-(4-thiophene-2-yl)pyridine, 2-(4-phenylthiophene-2-yl)pyridine, 2-phenylbenzoxazole, 2-(paraphenylphenyl)benzoxazole, 2-phenylbenzothiazole, 2-(paraphenylphenyl)benzothiazole, 2-(benzothiophene-2-yl)pyridine, 1,10-phenanthroline, 2,3,7,8,12,13,17,18-octa ethyl-21H,23H-porphyrin, etc. It may be either a coordinate bond or a covalent bond.

As the carbonyl compound, exemplified are those having a coordinate bond to M by the oxygen atom, and examples thereof include ketones, such as carbon monoxide, and acetone, benzophenone; and diketones, such as, acetyl acetone, and acenaphtho quinone.

As the ether, exemplified are those having a coordinate bond to M by the oxygen atom, and examples thereof include dimethyl ether, diethyl ether, tetrahydrofuran, 1,2-dimethoxy ethane, etc.

As the amine, exemplified are those having a coordinate bond to M by the nitrogen atom, and examples thereof include: mono amines, such as trimethylamine, triethyl amine, tributyl amine, tribenzyl amine, triphenyl amine, dimethylphenyl amine, and methyldiphenyl amine; and diamines, such as 1,1,2,2-tetramethylethylene diamine, 1,1,2,2-tetraphenyl ethylene diamine, and 1,1,2,2-tetramethyl-o-phenylene diamine.

As the imine, exemplified are those having a coordinate bond to M by the nitrogen atom, and examples thereof include: mono imines, such as benzylidene aniline, benzylidene benzyl amine, and benzylidene methylamine; and diimines, such as dibenzylidene ethylene diamine, dibenzylidene-o-phenylene diamine, and 2,3-bis(anilino)butane.

As the phosphine, exemplified are those having a coordinate bond to M by the phosphorus atom, and examples thereof include: triphenyl phosphine, diphenyl phosphino ethane, and diphenyl phosphino propane. As the phosphite, exemplified are those having a coordinate bond to M by the phosphorus atom, and examples thereof include trimethylphosphite, triethyl phosphate, and triphenylphosphite.

As the sulfide, exemplified are those having a coordinate bond to M by the sulfur atom, and examples thereof include dimethyl sulfide, diethyl sulfide, diphenyl sulfide, and thioanisole.

M represents a metal atom having an atomic number of 50 or more and showing a possibility of the intersystem crossing between the singlet state and the triplet state in this complex by a spin-orbital mutual action.

As the multidentate ligand which is the combination of an alkyl group, alkoxy group, acyloxy group, alkylthio group, alkylamino group, aryl group, aryloxy group, arylthio group, arylamino group, arylalkyl group, arylalkoxy group, arylalkylthio group, arylalkylamino group, sulfonate group, cyano group, a heterocyclic ligand, a carbonyl compound, ether, amine, imine, phosphine, phosphate, and sulfide, exemplified are acetonates, such as acetylacetonate, dibenzomethylate, and thenoyl trifluoroacetonate.

Examples of the atoms represented by M include: a rhenium atom, osmium atom, iridium atom, platinum atom, gold atom, lanthanum atom, cerium atom, praseodymium atom, neodymium atom, promethium atom, samarium atom, europium atom, gadolinium atom, terbium atom, dysprosium atom, etc.; preferably a rhenium atom, osmium atom, iridium atom, platinum atom, gold atom, samarium atom, europium atom, gadolinium atom, terbium atom, and a dysprosium atom; and more preferably, an iridium atom, platinum atom, gold atom, and europium atom in view of light emitting efficiency.

H, as the atom which bonds with M, represents a ligand containing one or more atoms selected from a nitrogen atom, oxygen atom, carbon atom, sulfur atom, and phosphorus atom.

As the atom which bonds with M, the ligand containing one or more atoms selected from a nitrogen atom, oxygen atom, carbon atom, sulfur atom, and phosphorus atom is the same as those exemplified about K.

As H, the followings are exemplified. Wherein, * represents an atom which bonds with M.

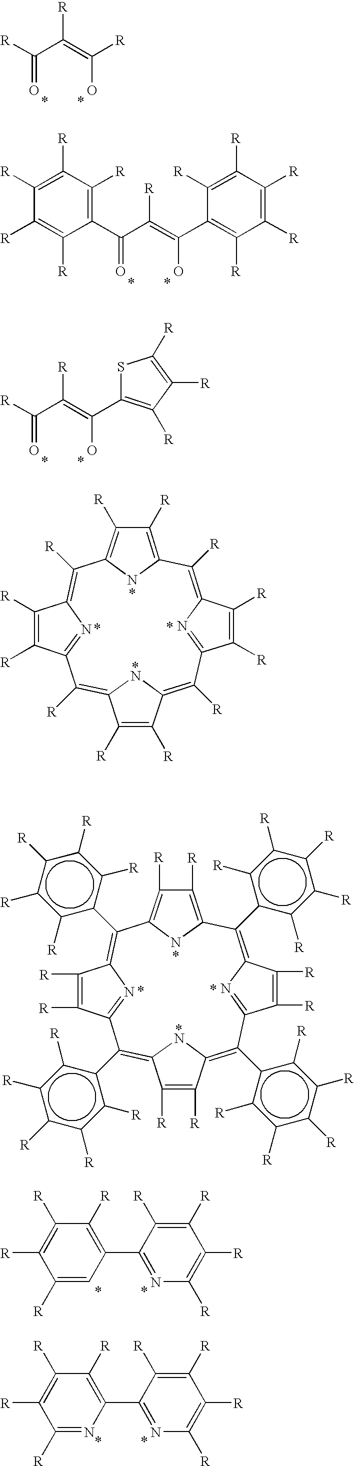

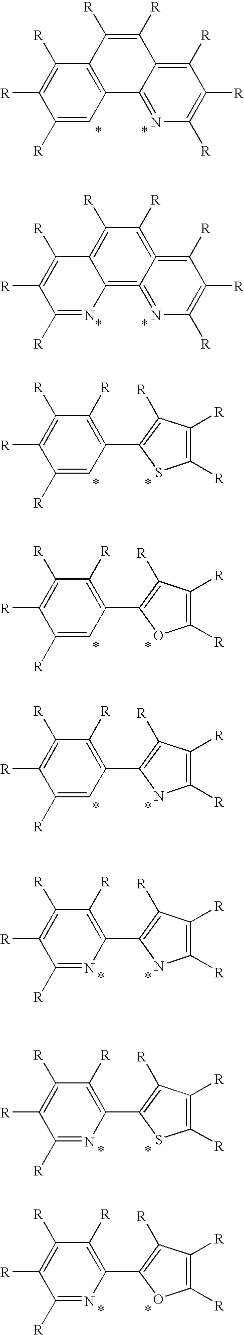

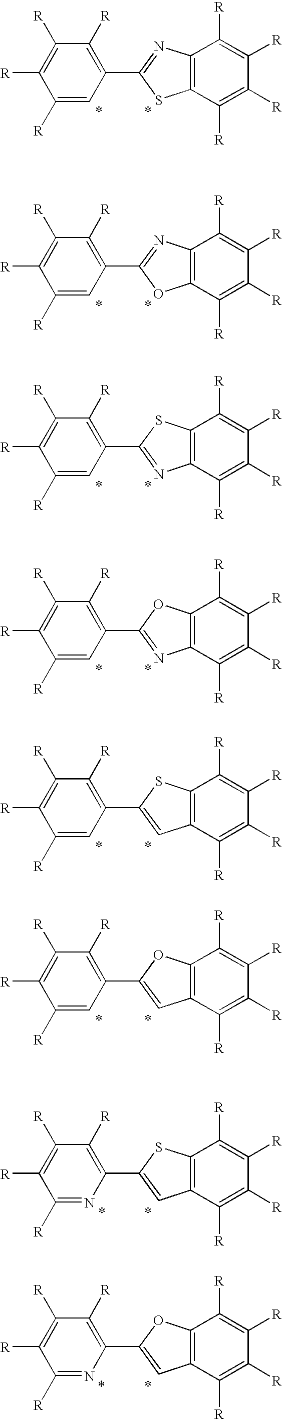

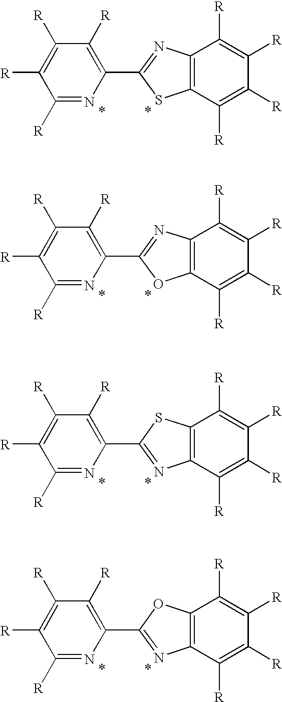

Wherein, R each independently represent a hydrogen atom, halogen atom, alkyl group, alkoxy group, alkylthio group, alkylamino group, alkylsilyl group, aryl group, aryloxy group, arylthio group, arylamino group, arylsilyl group, arylalkyl group, arylalkoxy group, arylalkylthio group, arylalkylamino group, arylalkylsilyl group, acyl group, acyloxy group, imine residue, amide group, arylalkenyl group, arylalkynyl group, cyano group, or monovalent heterocyclic group. R may be connected mutually to form a ring. In order to improve the solubility in a solvent, it is preferable that at least one of R contains a long chain alkyl group.

The concrete examples of alkyl group, alkoxy group, acyloxy group, alkylthio group, alkylamino group, aryl group, aryloxy group, arylthio group, arylamino group, arylalkyl group, arylalkoxy group, arylalkylthio group, and arylalkylamino group are the same as those of the above mentioned Y.

As the halogen atom, fluorine, chlorine, bromine, and iodine are exemplified.

The alkylsilyl group may be any of linear, branched or cyclic, and the number of carbon atoms is usually about 1 to 60. Concrete examples thereof include trimethylsilyl group, triethylsilyl group, tripropylsilyl group, tri-i-propylsilyl group, dimethyl-i-propylsilyl group, diethyl-i-propylsilyl group, t-butylsilyldimethylsilyl group, pentyldimethylsilyl group, hexyldimethylsilyl group, heptyldimethylsilyl group, octyldimethylsilyl group, 2-ethylhexyl-dimethylsilyl group, nonyldimethylsilyl group, decyldimethylsilyl group, 3,7-dimethyloctyl-dimethylsilyl group, lauryldimethylsilyl group etc.; and pentyl dimethylsilyl group, hexyl dimethyl silyl group, octyldimethylsilyl group, 2-ethylhexyl-dimethyl silyl group, decyldimethylsilyl group, and 3,7-dimethyloctyl dimethylsilyl group are preferable.

The aryl silyl group may have substituent on the aromatic ring, and the number of carbon atoms is usually about 3 to 60, and concrete examples thereof include triphenylsilyl group, tri-p-xylylsilyl group, tribenzylsilyl group, diphenylmethyl silyl group, t-butyldiphenylsilyl group, dimethylphenylsilyl group, etc.

The aryl alkylsilyl group usually has about 7 to 60 carbon atoms. Concrete examples thereof include phenyl-C₁-C₁₂ alkylsilyl group, C₁-C₁₂ alkoxyphenyl-C₁-C₁₂ alkylsilyl group, C₁-C₁₂ alkylphenyl-C₁-C₁₂ alkylsilyl group, 1-naphtyl-C₁-C₁₂ alkylsilyl group, 2-naphtyl-C₁-C₁₂ alkylsilyl group, phenyl-C₁-C₁₂ alkyldimethylsilyl group etc.; and C₁-C₁₂ alkoxy phenyl-C₁-C₁₂ alkylsilyl group and C₁-C₁₂ alkylphenyl-C₁-C₁₂ alkylsilyl group are preferable.

The acyl group usually has about 2 to 20 carbon atoms. Concrete examples thereof include acetyl group, propionyl group, butyryl group, isobutyryl group, pivaloyl group, benzoyl group, trifluoroacetyl group, pentafluorobenzoyl group, etc.

The acyloxy group usually has about 2 to 20 carbon atoms. Concrete examples thereof include acetoxy group, propionyloxy group, butyryloxy group, isobutyryloxy group, pivaloyloxy group, benzoyloxy group, trifluoroacetyloxy group, pentafluorobenzoyloxy group, etc.

The definition of the imine residue and the concrete examples are the same as those mentioned above.

The amide group has usually about 2 to 20 carbon atoms, and concrete examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoroacetamide group, dipentafluorobenzamide group, succine imide group, phthalic imide group, etc.

The arylalkenyl group has usually about 7 to 60 carbon atoms, and concrete examples thereof include phenyl-C₁-C₁₂ alkenyl group, C₁-C₁₂ alkoxyphenyl-C₁-C₁₂ alkenyl group, C₁-C₁₂ alkyl phenyl-C₁-C₁₂ alkenyl group, 1-naphtyl-C₁-C₁₂ alkenyl group, 2-naphtyl-C₁-C₁₂ alkenyl group etc.; and C₁-C₁₂ alkoxy phenyl-C₁-C₁₂ alkenyl group and C₁-C₁₂ alkylphenyl-C₁-C₁₂ alkenyl group are preferable.

The arylalkynyl group has usually about 7 to 60 carbon atoms, and concrete examples thereof include phenyl-C₁-C₁₂ alkynyl group, C₁-C₁₂ alkoxyphenyl-C₁-C₁₂ alkynyl group, C₁-C₁₂ alkyl phenyl-C₁-C₁₂ alkynyl group, 1-naphtyl-C₁-C₁₂ alkynyl group, 2-naphtyl-C₁-C₁₂ alkynyl group etc.; and C₁-C₁₂ alkoxy phenyl-C₁-C₁₂ alkynyl group and C₁-C₁₂ alkylphenyl-C₁-C₁₂ alkynyl group are preferable.

The monovalent heterocyclic group means an atomic group in which a hydrogen atom is removed from a heterocyclic compound, and usually has about 4 to 60 carbon atoms. Concrete examples thereof include thienyl group, C₁-C₁₂ alkylthienyl group, pyridyl group, pyroryl group, furyl group, C₁-C₁₂ alkylpyridyl group, etc.; and thienyl group, C₁-C₁₂ alkylthienyl group, pyridyl group, and C₁-C₁₂ alkylpyridyl group are preferable.

It is preferable that H bonds with M by at least one nitrogen atom or carbon atom in respect of the stability of a compound, and it is more preferable that H bonds with M at multidentate sites.

H is more preferably represented by the below formula (H-1) or (H-2). 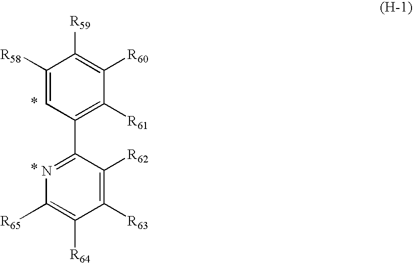
(wherein, R₅₈-R₆₅ each independently represent a hydrogen atom, halogen atom, alkyl group, alkoxy group, alkylthio group, alkylamino group, alkylsilyl group, aryl group, aryloxy group, arylthio group, arylamino group, arylsilyl group, arylalkyl group, arylalkoxy group, arylalkylthio group, arylalkylamino group, arylalkylsilyl group, acyl group, acyloxy group, imine residue, amide group, arylalkenyl group, arylalkynyl group, cyano group, and monovalent heterocyclic group, and * represents a bonding position with M.). 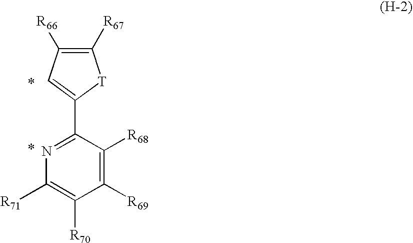
(Wherein, T represents an oxygen atom or a sulfur atom. R₆₆-R₇₁ each independently represent a hydrogen atom, halogen atom, alkyl group, alkoxy group, alkylthio group, alkylamino group, alkylsilyl group, aryl group, aryloxy group, arylthio group, arylamino group, arylsilyl group, arylalkyl group, arylalkoxy group, arylalkylthio group, arylalkylamino group, arylalkylsilyl group, acyl group, acyloxy group, imine residue, amide group, arylalkenyl group, arylalkynyl group, and cyano group, and * represents a bonding position with M.).

Moreover, the triplet light-emitting complex of the present invention may be a polymer compound containing a triplet complex. JP-A-2003-073480, JP-A-2003-073479, JP-A-2002-280183, JP-A-2003-77673, etc. disclose such a compound.

The composition of the present invention may contain two or more kinds of metal complexes showing light-emission from triplet excited state. Each metal complex may have the same metal each other, or may have a different metal. Moreover, each metal complex structure may have a different light-emission color mutually. For example, exemplified is a case where a metal complex which emits light in green, and a metal complex which emits light in red are contained in one polymer complex compound. It is preferable, since the light-emission color is controllable, by designing so that appropriate amounts of the metal complexes are contained, at this time.

The amount of the triplet light-emission compound in the composition in the present invention is usually 0.01-80 parts by weight preferably 0.1-60 parts by weight, based on 100 parts by weight of the polymer compound, although it is not limited, since it depends on the kind of polymer compound to be combined, and characteristics to be optimized.

When the compositions of the present invention are used for light-emitting material of polymer LED, the purity thereof exerts an influence on light emitting property, therefore, it is preferable that a monomer is purified by a method such as distillation, sublimation purification, re-crystallization and the like before being polymerized. Further, it is preferable to conduct a purification treatment such as re-precipitation purification, chromatographic separation and the like after the preparation. In addition, the polymer compound of the present invention can be used not only as a light-emitting material, but as an organic semiconductor material, an optical material, or a conductive material by doping.

The polymer complex compound which is another embodiment of the present invention contains a metal complex structure showing light-emission from triplet excited state in the molecular chain in addition to a specific repeating unit. Specifically, the polymer complex is characterized by comprising the repeating unit of the above formula (1), the repeating unit selected from the above formulas (12) and (13), and the metal complex structure showing light-emission from triplet excited state, and exhibit a visible light-emission in the solid state.

The definitions of formula (1), (12), and (13) and the concrete examples are the same as those of the polymer compound used for the above-mentioned complex composition.

Y in formula (1) is preferably O atom or S atom.

As the polymer complex compound of the present invention, Formula (1) is preferably a repeating unit selected from the above (1-1), (1-2), (1-3), (1-4), (1-5), (1-6), (1-7), (1-8), (1-9) and (1-10), more preferably, (1-4), (1-5), (1-6), (1-7), (1-8), (1-9), and (1-10), further preferably, (1-6), (1-7), (1-8), (1-9), and (1-10), and especially preferably (1-6).

Among the repeating units of formula (12) or (13), the above (12-1), (12-2), (12-3), (12-4), (12-5), (12-6), and (13-1) are preferable, and (12-2), (12-5), (12-6), and (13-1) are more preferable, and (13-1) and (12-6) further preferable.

The preferable combination among the above, comprises a metal complex structure showing light-emission from triplet excited state, and a repeating unit of (1-6), and a repeating unit selected from either (12-6) or (13-1).

Especially preferable one comprises a metal complex structure showing light-emission from triplet excited state, a repeating unit of (1-6), and a repeating unit of (12-6).

The metal complex structure showing light-emission from triplet excited state may be included in the polymer main chain, or may exist in the side chain, or may exist in the terminal.

As the metal complex structure showing light-emission from triplet excited state, structures of the below formula (16) are exemplified.
(L)ₒ₂-M-(Ar)ₘ₂ (16)

Wherein, M represents the same meaning as the above.

Ar is a ligand which bonds with M by one or more of a nitrogen atom, an oxygen atom, a carbon atom, a sulfur atom, and a phosphorus atoms, and has 1 or more connecting bonds which bond with the polymer chain of the polymer complex compound of the present invention at an arbitrary positions which do not bond with M of Ar.

The number of connecting bonds is usually 2, when the metal complex structure is contained in a polymer main chain, and is usually 1, when it exists in a side chain or a terminal.

Ar is, for example, a ligand constituted by a combination of heterocycles, such as a pyridine ring, a thiophene ring, and a benzoxazole ring, and a benzene ring. Concrete examples include phenyl pyridine, 2-(paraphenylphenyl)pyridine, 7-bromobenzo[h]quinoline, 2-(4-thiophene-2-yl)pyridine, 2-(4-phenylthiophene-2-yl)pyridine, 2-phenylbenzoxazole, 2-(paraphenylphenyl)benzoxazole, 2-phenylbenzothiazole, 2-(paraphenylphenyl)benzothiazole, 2-(benzothiophene-2-yl)pyridine, 7,8,12,13,17,18-hexakisethyl-21H,23H-porphyrin etc., and these may have substituent.

As the substituent of Ar, a halogen atom, alkyl group, alkenyl group, aralkyl group, arylthio group, arylalkenyl group, cyclic alkenyl group, alkoxy group, aryloxy group, the alkyloxy carbonyl group, aralkyloxy carbonyl group, aryloxy carbonyl group, aryl group, and monovalent heterocyclic group are exemplified, and the definition and the concrete example thereof are the same as those in the above.

As for M, it is preferable to bond with at least one carbon atom of Ar.

In formula (16), it is preferable that Ar is a tetradentate ligand which bonds with M by any four atoms selected from a nitrogen atom, an oxygen atom, a carbon atom, a sulfur atom, and a phosphorus atom. For example, specifically, 7,8,12,13,17,18-hexakisethyl-21H,23H-porphyrin is exemplified as a ligand in which four pyrrole rings are connected cyclically.

In the above formula (16), it is preferable that Ar is a bidentate ligand which bonds with M by two atoms selected from a nitrogen atom, an oxygen atom, a carbon atom, a sulfur atom, and a phosphorus atom, and forms 5 membered ring. It is more preferable that M bonds with at least one carbon atom, it is further preferable that Ar is a bidentate ligand of the below formula (16-1).

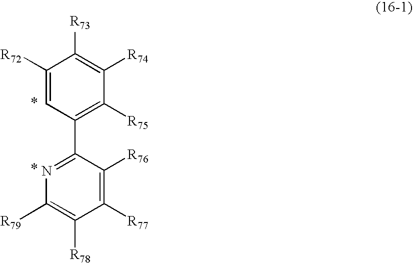

Wherein, R₇₂-R₇₉ each independently represent a hydrogen atom, halogen atom, alkyl group, alkenyl group, aralkyl group, arylthio group, arylalkenyl group, cyclic alkenyl group, alkoxy group, aryloxy group, alkyloxy carbonyl group, aralkyloxy carbonyl group, aryloxy carbonyl group, or aryl group. At least one of R₇₂-R₇₉ is a connecting bond with a polymer chain.

In the formula, L is a hydrogen atom, alkyl group, aryl group, heterocyclic ligand, acyloxy group, halogen atom, amide group, imide group, alkoxy group, alkylmercapto group, carbonyl ligand, alkene ligand, alkyne ligand, amine ligand, imine ligand, nitril ligand, isonitril ligand, phosphine ligand, phosphine oxide ligand, phosphite ligand, ether ligand, sulfone ligand, sulfoxide ligand, or sulfide ligand. m2 represents an integer of 1-5. o2 represents an integer of 0-5. In L, as the alkyl group, methyl group, ethyl group, propyl group, butyl group, cyclohexyl group, etc. are exemplified; and, as the aryl group, phenyl group, tolyl group, 1-naphtyl group, 2-naphtyl group, etc. are exemplified. The heterocyclic ligands may be either 0 valent or monovalent, and as those of 0 valent, 2,2′-bipyridyl, 1,10-phenanthroline, 2-(4-thiophene-2-yl)pyridine, 2-(benzothiophene-2-yl)pyridine, etc., are exemplified; and as those of monovalent, phenylpyridine, 2-(paraphenylphenyl)pyridine, 7-bromobenzo[h]quinoline, 2-(4-phenylthiophene-2-yl)pyridine, 2-phenyl benzoxazole, 2-(paraphenylphenyl)benzoxazole, 2-phenyl benzothiazole, 2-(paraphenylphenyl)benzothiazole, etc., are exemplified.

As the acyloxy group, although not being limited especially, acetoxy group, naphthenate group, and 2-ethyl hexanoate group are exemplified. As the halogen atom, although not being limited especially, a fluorine atom, a chlorine atom, a bromine atom, and an iodine atom are exemplified. As the amide group, although not being limited especially, dimethylamide group, diethylamide group, diisopropylamide group, dioctyl amide group, didecylamide group, didodecylamide group, bis (trimethylsilyl)amide group, diphenylamide group, N-methyl anilide, and anilide group are exemplified. As the imide group, although not being limited especially, benzophenone imide etc. are exemplified. As the alkoxy group, although not being limited especially, methoxy group, ethoxy group, propoxy group, butoxy group, and phenoxy group are exemplified. As the alkylmercapto group, although not being limited especially, methyl mercapto group, ethyl mercapto group, propyl mercapto group, butyl mercapto group, and phenyl mercapto group are exemplified. As the carbonyl ligand, exemplified are: carbon monoxide; ketones, such as, acetone, and benzophenone; diketones, such as acetyl acetone, and acenaphtho quinine; acetonate ligands, such as, acetylacetonate, dibenzomethylate, and thenoyltrifluoro acetonate, etc. As the alkene ligands, although not being limited especially, ethylene, propylene, butene, hexene, and decene are exemplified. As the alkyne ligands, although not being limited especially, acetylene, phenyl acetylene, and diphenyl acetylene are exemplified. As the amine ligands, although not being limited especially, triethyl amine and tributyl amine are exemplified. As the imine ligands, although not being limited especially, benzophenone imine or methylethylketoneimine are exemplified. As the nitril ligands, although not being limited especially, acetonitrile and benzonitril are exemplified. As the isonitril ligands, although not being limited especially, t-butyl isonitril and phenylisonitril are exemplified. As the phosphine ligands, although not being limited especially, triphenyl phosphine, tritolyl phosphine, tri cyclohexyl phosphine, and tributyl phosphine are exemplified. As the phosphine oxide ligands, although not being limited especially, tributylphosphine oxide and triphenylphosphine oxide are exemplified. As the phosphite ligands, although not being limited especially, triphenylphosphite, tritolylphosphite, tributyl phosphite, and triethylphosphite are exemplified. As the ether ligands, although not being limited especially, dimethyl ether, diethyl ether and tetrahydrofuran are exemplified. As the sulfone ligands, although not being limited especially, dimethyl sulfone and dibutyl sulfone are exemplified. As the sulfoxide ligands, although not being limited especially, dimethyl sulfoxide and dibutyl sulfoxide are exemplified. As the sulfide ligands, although not being limited especially, ethyl sulfide and butyl sulfide are exemplified.

As the metal complex structure showing light-emission from triplet excited state, residues in which hydrogen atoms corresponding to the number of bonds with a polymer chain are removed from the ligand of triplet light-emitting complex are exemplified. Concretely, residues in which Rs corresponding to the number of bonds with a polymer chain are removed from the examples of the triplet light-emitting complex shown by the above structure.

As above-mentioned, the metal complex structure showing light-emission from triplet excited state may be included in the polymer main chain, may exist in the side chain, or may exist in the terminal.

Examples of the case where the metal complex structure showing light-emission from triplet excited state is included in the main chain. Exemplified is a polymer compound which contains, preferably as a repeating unit, a structural unit having two connecting bonds in which two hydrogens are removed from a ligand of the triplet light-emitting complex (structural unit which is the residue wherein two Rs are removed from each of the concrete example of the triplet light-emitting complex specifically shown by the above structural formula).

As such a structural unit, followings are exemplified.

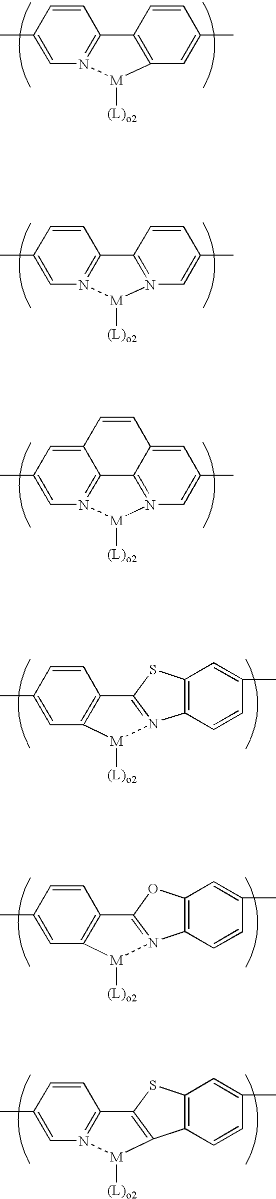

When at least one of the ligands contained in the metal complex structure of the polymer compound of the present invention includes the same structure as the repeating unit contained in a polymer main chain, it is preferable as the metal content in a polymer compound can be controlled. For example, after manufacturing a polymer compound, complex formation can be carried out with changing the amount of metal in order to control the metal content in a polymer compound, thus it is preferable.

Specifically, following structures are exemplified.

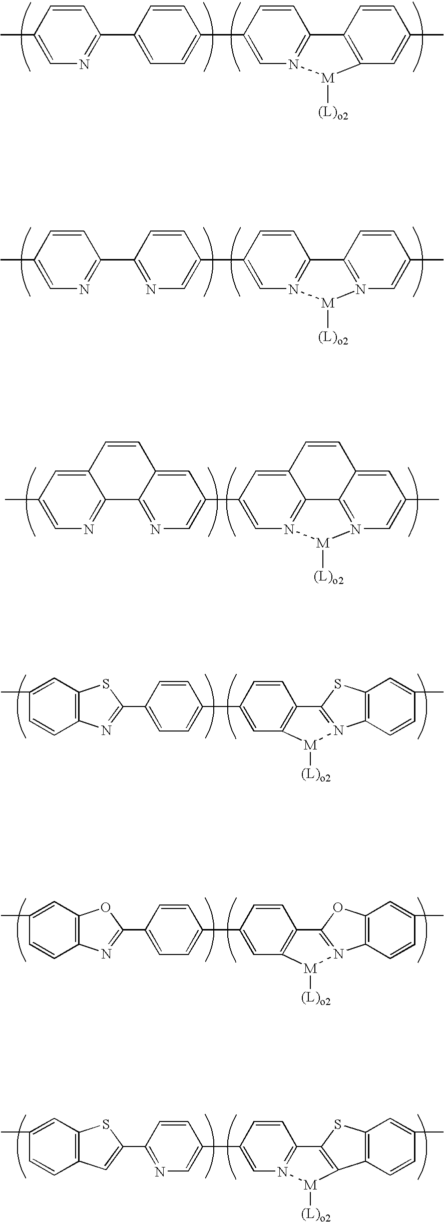

As the examples in which a metal complex structure showing light-emission from triplet excited state exists in a side chain, exemplified are the cases where a group having one connecting bond in which a hydrogen is removed from a ligand of the triplet light-emitting complex, (specifically, one of R is removed from each of the concrete example of the triplet light-emitting complex shown by the above structural formula) is connected with a polymer chain: directly with a single bond or double bond; through an atom, such as an oxygen atom, sulfur atom and selenium atom; or through a divalent connecting group, such as a methylene group, alkylene group, and an arylene group.

Among them, it is preferable to have a structure in which conjugation is connected with the metal complex structure showing light-emission from triplet excited state of side chains, such as a single bond, a double bond, and an arylene group.

As the structural unit (repeating unit) having such a side chain, exemplified are: substituent of Ar₁ or Ar₄ of the repeating unit selected from the above formula (2) or (4); substituent of X₂ in formula (4); and monovalent groups having metal complex structure whose R₁₅ and R₁₆ show light-emission from triplet excited state.

Specifically, following structural units are exemplified.

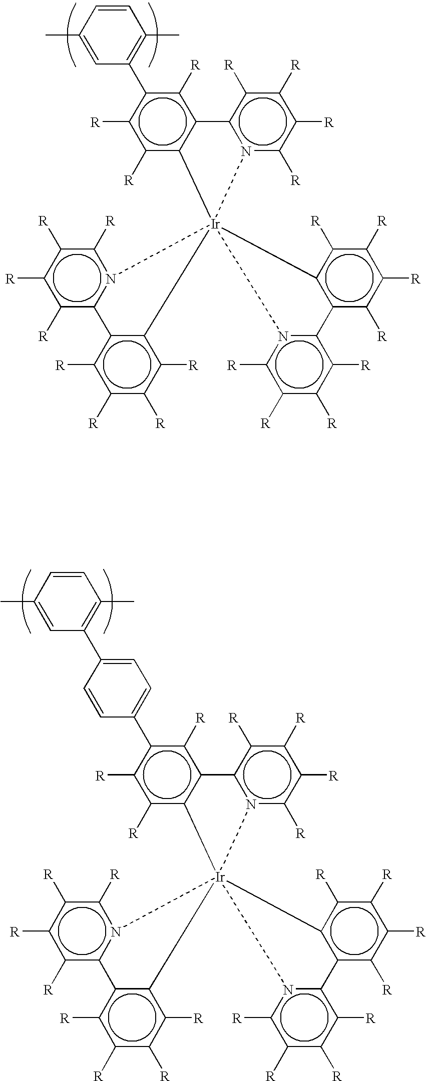

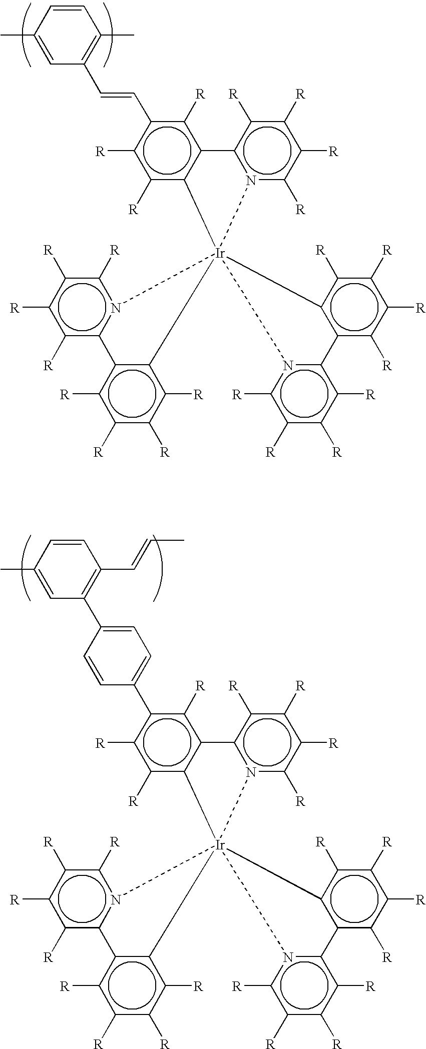

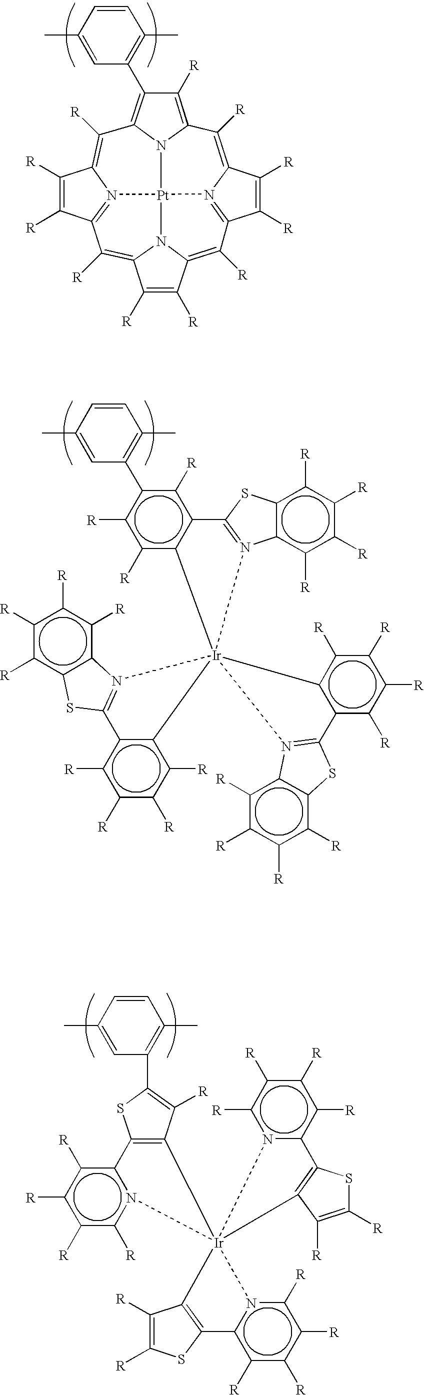

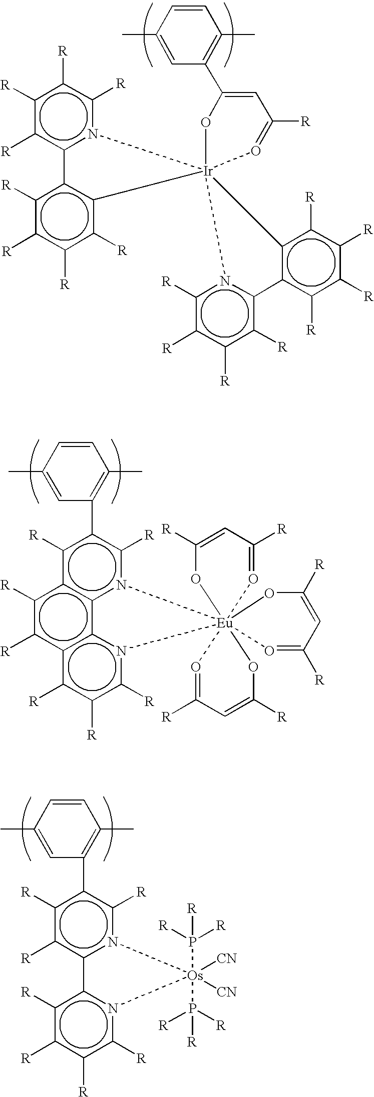

In the formula, the definition of R is the same as the above.

As the examples in which a metal complex structure showing light-emission from triplet excited state exists in the terminal of polymer main chain, exemplified is a group having one connecting bond in which a hydrogen is removed from a ligand of the triplet light-emitting complex, (specifically, one of R is removed from each of the concrete example of the triplet light-emitting complex shown by the above structural formula), and specifically, following groups are exemplified.

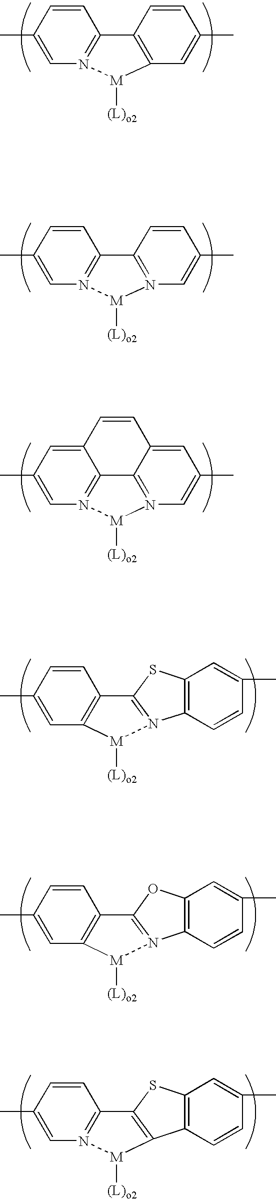

The polymer complex compound of the present invention may contain a repeating unit selected from the above (2) or (4), in addition to a repeating unit of formula (1), a repeating unit of formula (12) or (13), and a metal complex structure showing light-emission from and the triplet excited state.

When the polymer complex compound of the present invention contains the repeating unit selected from the above (2) or (4), it is preferable that the repeating unit having the metal complex structure showing light-emission from triplet excited state is 0.01% by mole to 10% by mole based on the total of the repeating unit selected from formula (1) and the above (2), or (4), and the structural unit (repeating unit) having the metal complex structure showing light-emission from triplet excited state.

Moreover, the repeating unit represented by formula (1) is preferably 10% by mole to 98% by mole, and the repeating unit of formula (12) or (13) is preferably 2% to 90%.

Among the polymer complex compound of the present invention, a conjugated polymer compound is preferable.

The polymer complex compound of the present invention may have 2 or more kinds of metal complex structures showing light-emission from triplet excited state. That is, the polymer complex compound of the present invention may have metal complex structures showing light-emission from triplet excited state in any two or more of the main chain, the side chain, or the terminal. Each metal complex structure may have the same metal each other, or may have different metals. Moreover, each metal complex structure may have light-emission colors which differs mutually. Exemplified is a case where a metal complex structure which emits light in green, and a metal complex structure which emits light in red are included in one polymer complex compound. Since a light-emission color is controllable by designing so that an appropriate amount of the metal complex structures may be included, it is preferable.

As for the end groups of the polymer complex compound of the present invention, if the polymerizable group remains intact, there is a possibility of reduction in light emitting property and life-time when made into an device, and they may be protected with a stable group. Those having a conjugated bond continuing to a conjugated structure of the main chain are preferable, and there are exemplified structures connected to an aryl group or heterocyclic compound group via a carbon-carbon bond. Specifically, substituents described as Chemical Formula 10 in JP-A-9-45478 are exemplified.

The polymer complex compound of the present invention may also be a random, block or graft copolymer, or a polymer having an intermediate structure thereof, for example, a random copolymer having block property. From the viewpoint for obtaining a polymer compound having high fluorescent quantum yield, random copolymers having block property and block or graft copolymers are preferable than complete random copolymers. Further, a polymer having a branched main chain and more than three terminals, and a dendrimer may also be included.

As for the polymer compound used for the present invention, it is preferable that the polystyrene reduced number average molecular weight is 10³-10⁸.

Next, the polymer light-emitting device (polymer LED) of the present invention will be explained. It is characterized by having a layer which contains the complex composition of the present invention, or the polymer complex compound of the present invention between the electrodes consisting of an anode and a cathode.

It is preferable that the layer containing the complex composition of the present invention or the polymer complex compound of the present invention is a light emitting layer.

Moreover, the polymer LED of the present invention include: a polymer LED having an electron transporting layer between a cathode and a light emitting layer; a polymer LED having an hole transporting layer between an anode and a light emitting layer; and a polymer LED having an electron transporting layer between an cathode and a light emitting layer, and a hole transporting layer between an anode and a light emitting layer.

Furthermore, exemplified are: a polymer-LED in which a layer containing a conductive polymer is disposed between at least one of the above electrodes and a light emitting layer adjacently to the electrode; and a polymer LED in which a buffer layer having a mean film thickness of 2 nm or less is disposed between at least one of the above electrodes and a light emitting layer adjacently to the electrode.

Specifically, the following structures a)-d) are exemplified.

a) anode/light emitting layer/cathode

b) anode/hole transporting layer/light emitting layer/cathode

c) anode/light emitting layer/electron transporting layer/cathode

d) anode/hole transporting layer/light emitting layer/electron transporting layer/cathode

(wherein, “/” indicates adjacent lamination of layers. Hereinafter, the same).

Herein, the light emitting layer is a layer having function to emit a light, the hole transporting layer is a layer having function to transport a hole, and the electron transporting layer is a layer having function to transport an electron. Herein, the electron transporting layer and the hole transporting layer are generically called a charge transporting layer.

The light emitting layer, hole transporting layer and electron transporting layer also may be used each independently in two or more layers.

Charge transporting layers disposed adjacent to an electrode, that having function to improve charge injecting efficiency from the electrode and having effect to decrease driving voltage of an device are particularly called sometimes a charge injecting layer (hole injecting layer, electron injecting layer) in general.

For enhancing adherence with an electrode and improving charge injection from an electrode, the above-described charge injecting layer or insulation layer having a thickness of 2 nm or less may also be provided adjacent to an electrode, and further, for enhancing adherence of the interface, preventing mixing and the like, a thin buffer layer may also be inserted into the interface of a charge transporting layer and light emitting layer.

The order and number of layers laminated and the thickness of each layer can be appropriately applied while considering light emitting efficiency and life of the device.

In the present invention, as the polymer LED having a charge injecting layer (electron injecting layer, hole injecting layer) provided, there are listed a polymer LED having a charge injecting layer provided adjacent to a cathode and a polymer LED having a charge injecting layer provided adjacent to an anode.

For example, the following structures e) to p) are specifically exemplified.

e) anode/charge injecting layer/light emitting layer/cathode

f) anode/light emitting layer/charge injecting layer/cathode

g) anode/charge injecting layer/light emitting layer/charge injecting layer/cathode

h) anode/charge injecting layer/hole transporting layer/light emitting layer/cathode

i) anode/hole transporting layer/light emitting layer/charge injecting layer/cathode

j) anode/charge injecting layer/hole transporting layer/light emitting layer/charge injecting layer/cathode

k) anode/charge injecting layer/light emitting layer/electron transporting layer/cathode

l) anode/light emitting layer/electron transporting layer/charge injecting layer/cathode

m) anode/charge injecting layer/light emitting layer/electron transporting layer/charge injecting layer/cathode

n) anode/charge injecting layer/hole transporting layer/light emitting layer/electron transporting layer/cathode

o) anode/hole transporting layer/light emitting layer/electron transporting layer/charge injecting layer/cathode

p) anode/charge injecting layer/hole transporting layer/light emitting layer/electron transporting layer/charge injecting layer/cathode

As the specific examples of the charge injecting layer, there are exemplified layers containing an conducting polymer, layers which are disposed between an anode and a hole transporting layer and contain a material having an ionization potential between the ionization potential of an anode material and the ionization potential of a hole transporting material contained in the hole transporting layer, layers which are disposed between a cathode and an electron transporting layer and contain a material having an electron affinity between the electron affinity of a cathode material and the electron affinity of an electron transporting material contained in the electron transporting layer, and the like.

When the above-described charge injecting layer is a layer containing an conducting polymer, the electric conductivity of the conducting polymer is preferably 10⁻⁵ S/cm or more and 10³ S/cm or less, and for decreasing the leak current between light emitting pixels, more preferably 10⁻⁵ S/cm or more and 10² S/cm or less, further preferably 10⁻⁵ S/cm or more and 10¹ S/cm or less.

Usually, to provide an electric conductivity of the conducting polymer of 10⁻⁵ S/cm or more and 10³ S/cm or less, a suitable amount of ions are doped into the conducting polymer.

Regarding the kind of an ion doped, an anion is used in a hole injecting layer and a cation is used in an electron injecting layer. As examples of the anion, a polystyrene sulfonate ion, alkylbenzene sulfonate ion, camphor sulfonate ion and the like are exemplified, and as examples of the cation, a lithium ion, sodium ion, potassium ion, tetrabutyl ammonium ion and the like are exemplified.

The thickness of the charge injecting layer is for example, from 1 nm to 100 nm, preferably from 2 nm to 50 nm.

Materials used in the charge injecting layer may properly be selected in view of relation with the materials of electrode and adjacent layers, and there are exemplified conducting polymers such as polyaniline and derivatives thereof, polythiophene and derivatives thereof, polypyrrole and derivatives thereof, poly(phenylene vinylene) and derivatives thereof, poly(thienylene vinylene) and derivatives thereof, polyquinoline and derivatives thereof, polyquinoxaline and derivatives thereof, polymers containing aromatic amine structures in the main chain or the side chain, and the like, and metal phthalocyanine (copper phthalocyanine and the like), carbon and the like.

The insulation layer having a thickness of 2 nm or less has function to make charge injection easy. As the material of the above-described insulation layer, metal fluoride, metal oxide, organic insulation materials and the like are listed. As the polymer LED having an insulation layer having a thickness of 2 nm or less, there are listed polymer LEDs having an insulation layer having a thickness of 2 nm or less provided adjacent to a cathode, and polymer LEDs having an insulation layer having a thickness of 2 nm or less provided adjacent to an anode.

Specifically, there are listed the following structures q) to ab) for example.

q) anode/insulation layer having a thickness of 2 nm or less/light emitting layer/cathode

r) anode/light emitting layer/insulation layer having a thickness of 2 nm or less/cathode

s) anode/insulation layer having a thickness of 2 nm or less/light emitting layer/insulation layer having a thickness of 2 nm or less/cathode

t) anode/insulation layer having a thickness of 2 nm or less/hole transporting layer/light emitting layer/cathode

u) anode/hole transporting layer/light emitting layer/insulation layer having a thickness of 2 nm or less/cathode

v) anode/insulation layer having a thickness of 2 nm or less/hole transporting layer/light emitting layer/insulation layer having a thickness of 2 nm or less/cathode

w) anode/insulation layer having a thickness of 2 nm or less/light emitting layer/electron transporting layer/cathode

x) anode/light emitting layer/electron transporting layer/insulation layer having a thickness of 2 nm or less/cathode

y) anode/insulation layer having a thickness of 2 nm or less/light emitting layer/electron transporting layer/insulation layer having a thickness of 2 nm or less/cathode

z) anode/insulation layer having a thickness of 2 nm or less/hole transporting layer/light emitting layer/electron transporting layer/cathode

aa) anode/hole transporting layer/light emitting layer/electron transporting layer/insulation layer having a thickness of 2 nm or less/cathode

ab) anode/insulation layer having a thickness of 2 nm or less/hole transporting layer/light emitting layer/electron transporting layer/insulation layer having a thickness of 2 nm or less/cathode

A hole preventing layer is a layer having a function of transporting electrons and confining the holes transported from anode, and the layer is prepared at the interface on the side cathode of the light emitting layer, and consists of a material having larger ionization potential than that of the light emitting layer, for example, a metal complex of bathocuproine, 8-hydroxy quinoline, or derivatives thereof.

The film thickness of the hole preventing layer, for example, is 1 nm to 100 nm, and preferably 2 nm to 50 nm.

Specifically, there are listed the following structures ac) to an) for example.

ac) anode/charge injection layer/light emitting layer/hole preventing layer/cathode

ad) anode/light emitting layer/hole preventing layer/charge injection layer/cathode

ae) anode/charge injection layer/light emitting layer/hole preventing layer/charge injection layer/cathode

af) anode/charge injection layer/hole transporting layer/light emitting layer/hole preventing layer/cathode

ag) anode/hole transporting layer/light emitting layer/hole preventing layer/charge injection layer/cathode

ah) anode/charge injection layer/hole transporting layer/light emitting layer/hole preventing layer/charge injection layer/cathode

ai) anode/charge injection layer/light emitting layer/hole preventing layer/charge transporting layer/cathode

aj) anode/light emitting layer/hole preventing layer/electron transporting layer/charge injection layer/cathode

ak) anode/charge injection layer/light emitting layer/hole preventing layer/electron transporting layer/charge injection layer/cathode

al) anode/charge injection layer/hole transporting layer/light emitting layer/hole preventing layer/charge transporting layer/cathode

am) anode/hole transporting layer/light emitting layer/hole preventing layer/electron transporting layer/charge injection layer/cathode

an) anode/charge injection layer/hole transporting layer/light emitting layer/hole preventing layer/electron transporting layer/charge injection layer/cathode

In producing a polymer LED, when a film is formed from a solution by using such complex composition or polymer complex compound of the present invention, only required is removal of the solvent by drying after coating of this solution, and even in the case of mixing of a charge transporting material and a light emitting material, the same method can be applied, causing an extreme advantage in production. As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

Regarding the thickness of the light emitting layer, the optimum value differs depending on material used, and may properly be selected so that the driving voltage and the light emitting efficiency become optimum values, and for example, it is from 1 nm to 1 μm, preferably from 2 nm to 500 nm, further preferably from 5 nm to 200 nm.

In the polymer LED of the present invention, light emitting materials other than the above-described polymeric fluorescent substance can also be mixed in a light emitting layer. Further, in the polymer LED of the present invention, the light emitting layer containing light emitting materials other than the above-described polymeric fluorescent substance may also be laminated with a light emitting layer containing the above-described complex composition, or polymer complex compound of the present invention.

As the light emitting material, known materials can be used. In a compound having lower molecular weight, there can be used, for example, naphthalene derivatives, anthracene or derivatives thereof, perylene or derivatives thereof; dyes such as polymethine dyes, xanthene dyes, coumarine dyes, cyanine dyes; metal complexes of 8-hydroxyquinoline or derivatives thereof, aromatic amine, tetraphenylcyclopentane or derivatives thereof, or tetraphenylbutadiene or derivatives thereof, and the like.

Specifically, there can be used known compounds such as those described in JP-A Nos. 57-51781, 59-194393 and the like, for example.

When the polymer LED of the present invention has a hole transporting layer, as the hole transporting materials used, there are exemplified polyvinylcarbazole or derivatives thereof, polysilane or derivatives thereof, polysiloxane derivatives having an aromatic amine in the side chain or the main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, poly(2,5-thienylenevinylene) or derivatives thereof, or the like.

Specific examples of the hole transporting material include those described in JP-A Nos. 63-70257, 63-175860, 2-135359, 2-135361, 2-209988, 3-37992 and 3-152184.

Among them, as the hole transporting materials used in the hole transporting layer, preferable are polymer hole transporting materials such as polyvinylcarbazole or derivatives thereof, polysilane or derivatives thereof, polysiloxane derivatives having an aromatic amine compound group in the side chain or the main chain, polyaniline or derivatives thereof, polythiophene or derivatives thereof, poly(p-phenylenevinylene) or derivatives thereof, poly(2,5-thienylenevinylene) or derivatives thereof, or the like, and further preferable are polyvinylcarbazole or derivatives thereof, polysilane or derivatives thereof and polysiloxane derivatives having an aromatic amine compound group in the side chain or the main chain. In the case of a hole transporting material having lower molecular weight, it is preferably dispersed in a polymer binder for use.

Polyvinylcarbazole or derivatives thereof are obtained, for example, by cation polymerization or radical polymerization from a vinyl monomer.

As the polysilane or derivatives thereof, there are exemplified compounds described in Chem. Rev., 89, 1359 (1989) and GB 2300196 published specification, and the like. For synthesis, methods described in them can be used, and a Kipping method can be suitably used particularly.

As the polysiloxane or derivatives thereof, those having the structure of the above-described hole transporting material having lower molecular weight in the side chain or main chain, since the siloxane skeleton structure has poor hole transporting property. Particularly, there are exemplified those having an aromatic amine having hole transporting property in the side chain or main chain.

The method for forming a hole transporting layer is not restricted, and in the case of a hole transporting layer having lower molecular weight, a method in which the layer is formed from a mixed solution with a polymer binder is exemplified. In the case of a polymer hole transporting material, a method in which the layer is formed from a solution is exemplified.

The solvent used for the film forming from a solution is not particularly restricted providing it can dissolve a hole transporting material. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like, from a solution.

The polymer binder mixed is preferably that does not disturb charge transport extremely, and that does not have strong absorption of a visible light is suitably used. As such polymer binder, polycarbonate, polyacrylate, poly(methyl acrylate), poly(methyl methacrylate), polystyrene, poly(vinyl chloride), polysiloxane and the like are exemplified.

Regarding the thickness of the hole transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the hole transporting layer is, for example, from 1 nm to 1 μm, preferably from 2 nm to 500 nm, further preferably from 5 nm to 200 nm.

When the polymer LED of the present invention has an electron transporting layer, known compounds are used as the electron transporting materials, and there are exemplified oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinoline derivatives, or metal complexes of 8-hydroxyquinoline or derivatives thereof, polyquinoline and derivatives thereof, polyquinoxaline and derivatives thereof, polyfluorene or derivatives thereof, and the like.

Specifically, there are exemplified those described in JP-A Nos. 63-70257, 63-175860, 2-135359, 2-135361, 2-209988, 3-37992 and 3-152184.

Among them, oxadiazole derivatives, benzoquinone or derivatives thereof, anthraquinone or derivatives thereof, or metal complexes of 8-hydroxyquinoline or derivatives thereof, polyquinoline and derivatives thereof, polyquinoxaline and derivatives thereof, polyfluorene or derivatives thereof are preferable, and 2-(4-biphenyl)-5-(4-t-butylphenyl)-1,3,4-oxadiazole, benzoquinone, anthraquinone, tris(8-quinolinol)aluminum and polyquinoline are further preferable.

The method for forming the electron transporting layer is not particularly restricted, and in the case of an electron transporting material having lower molecular weight, a vapor deposition method from a powder, or a method of film-forming from a solution or melted state is exemplified, and in the case of a polymer electron transporting material, a method of film-forming from a solution or melted state is exemplified, respectively.

The solvent used in the film-forming from a solution is not particularly restricted provided it can dissolve electron transporting materials and/or polymer binders. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film-forming method from a solution or melted state, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

The polymer binder to be mixed is preferably that which does not extremely disturb a charge transport property, and that does not have strong absorption of a visible light is suitably used. As such polymer binder, poly(N-vinylcarbazole), polyaniline or derivatives thereof, polythiophene or derivatives thereof, poly(p-phenylene vinylene) or derivatives thereof, poly(2,5-thienylene vinylene) or derivatives thereof, polycarbonate, polyacrylate, poly(methyl acrylate), poly(methyl methacrylate), polystyrene, poly(vinyl chloride), polysiloxane and the like are exemplified.

Regarding the thickness of the electron transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the electron transporting layer is, for example, from 1 nm to 1 μm, preferably from 2 nm to 500 nm, further preferably from 5 nm to 200 nm.

The substrate forming the polymer LED of the present invention may preferably be that does not change in forming an electrode and layers of organic materials, and there are exemplified glass, plastics, polymer film, silicon substrates and the like. In the case of a opaque substrate, it is preferable that the opposite electrode is transparent or semitransparent.

Usually, at least one of the electrodes consisting of an anode and a cathode, is transparent or semitransparent. It is preferable that the anode is transparent or semitransparent.

As the material of this anode, electron conductive metal oxide films, semitransparent metal thin films and the like are used. Specifically, there are used indium oxide, zinc oxide, tin oxide, and composition thereof, i.e. indium/tin/oxide (ITO), and films (NESA and the like) fabricated by using an electron conductive glass composed of indium/zinc/oxide, and the like, and gold, platinum, silver, copper and the like. Among them, ITO, indium/zinc/oxide, tin oxide are preferable. As the fabricating method, a vacuum vapor deposition method, sputtering method, ion plating method, plating method and the like are used. As the anode, there may also be used organic transparent conducting films such as polyaniline or derivatives thereof, polythiophene or derivatives thereof and the like.

The thickness of the anode can be appropriately selected while considering transmission of a light and electric conductivity, and for example, from 10 nm to 10 μm, preferably from 20 nm to 1 μm, further preferably from 50 nm to 500 nm.

Further, for easy charge injection, there may be provided on the anode a layer comprising a phthalocyanine derivative conducting polymers, carbon and the like, or a layer having an average film thickness of 2 nm or less comprising a metal oxide, metal fluoride, organic insulating material and the like.

As the material of a cathode used in the polymer LED of the present invention, that having lower work function is preferable. For example, there are used metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, or alloys comprising two of more of them, or alloys comprising one or more of them with one or more of gold, silver, platinum, copper, manganese, titanium, cobalt, nickel, tungsten and tin, graphite or graphite intercalation compounds and the like. Examples of alloys include a magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may be formed into a laminated structure of two or more layers.

The thickness of the cathode can be appropriately selected while considering transmission of a light and electric conductivity, and for example, from 10 nm to 10 μm, preferably from 20 nm to 1 μm, further preferably from 50 nm to 500 nm.

As the method for fabricating a cathode, there are used a vacuum vapor deposition method, sputtering method, lamination method in which a metal thin film is adhered under heat and pressure, and the like. Further, there may also be provided, between a cathode and an organic layer, a layer comprising an conducting polymer, or a layer having an average film thickness of 2 nm or less comprising a metal oxide, metal fluoride, organic insulation material and the like, and after fabrication of the cathode, a protective layer may also be provided which protects the polymer LED. For stable use of the polymer LED for a long period of time, it is preferable to provide a protective layer and/or protective cover for protection of the device in order to prevent it from outside damage.

As the protective layer, there can be used a polymeric compound, metal oxide, metal fluoride, metal borate and the like. As the protective cover, there can be used a glass plate, a plastic plate the surface of which has been subjected to lower-water-permeation treatment, and the like, and there is suitably used a method in which the cover is pasted with an device substrate by a thermosetting resin or light-curing resin for sealing. If space is maintained using a spacer, it is easy to prevent an device from being injured. If an inner gas such as nitrogen and argon is sealed in this space, it is possible to prevent oxidation of a cathode, and further, by placing a desiccant such as barium oxide and the like in the above-described space, it is easy to suppress the damage of an device by moisture adhered in the production process. Among them, any one means or more are preferably adopted.

The polymer LED of the present invention can be used for a flat light source, a segment display, a dot matrix display, and a liquid crystal display as a back light, etc.

For obtaining light emission in plane form using the polymer LED of the present invention, an anode and a cathode in the plane form may properly be placed so that they are laminated each other. Further, for obtaining light emission in pattern form, there is a method in which a mask with a window in pattern form is placed on the above-described plane light emitting device, a method in which an organic layer in non-light emission part is formed to obtain extremely large thickness providing substantial non-light emission, and a method in which any one of an anode or a cathode, or both of them are formed in the pattern. By forming a pattern by any of these methods and by placing some electrodes so that independent on/off is possible, there is obtained a display device of segment type which can display digits, letters, simple marks and the like. Further, for forming a dot matrix device, it may be advantageous that anodes and cathodes are made in the form of stripes and placed so that they cross at right angles. By a method in which a plurality of kinds of polymeric compounds emitting different colors of lights are placed separately or a method in which a color filter or luminescence converting filter is used, area color displays and multi color displays are obtained. A dot matrix display can be driven by passive driving, or by active driving combined with TFT and the like. These display devices can be used as a display of a computer, television, portable terminal, portable telephone, car navigation, view finder of a video camera, and the like.

Further, the above-described light emitting device in plane form is a thin self-light-emitting one, and can be suitably used as a flat light source for back-light of a liquid crystal display, or as a flat light source for illumination. Further, if a flexible plate is used, it can also be used as a curved light source or a display.

Hereafter, in order to explain the present invention in detail with showing examples, but the present invention is not limited to these.

The polystyrene reduced number average molecular weight was obtained by gel permeation chromatography (GPC: HLC-8220GPC produced by TOSOH, or SCL-10A produced by Shimadzu) using tetrahydrofuran as a solvent.

Column: two TOSOH TSKgel SuperHM-H+TSKgel SuperH2000 (4.6 mm I.d.×15 cm)

Detector: RI (SHIMADZU RID-10A) was used. As the mobile phase chloroform or tetrahydrofuran (THF) was used.

### SYNTHETIC EXAMPLE 1

### Synthesis of Compound A

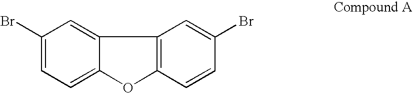

Under an inert atmosphere, benzofuran (23.2 g, 137.9 mmol) and acetic acid (232 g) were charged into a 1 L three-necked flask, and dissolved with stirring at room temperature, and then the temperature was raised to 75° C. After the temperature was raised, bromine (92.6 g, 579.3 mmol) diluted with acetic acid (54 g) was added dropwise. After the addition, it was stirred for 3 hours with keeping the temperature, and stood to cool. After confirmation of disappearance of the raw material by TLC, the reaction was terminated by adding aqueous solution of sodium thiosulfate, and it was stirred at room temperature for 1 hour. After stirring, the cake was collected by filtration, and washed further with aqueous solution of sodium thiosulfate and water, and then dried. The resultant crude product was recrystallized with hexane, and the desired product was obtained. (amount: 21.8 g, yield: 49%)

¹H-NMR(300 MHz/CDCl₃): δ7.44 (d, 2H), 7.57 (d, 2H), 8.03 (s, 2H)

### SYNTHETIC EXAMPLE 2

### Synthesis of Compound B

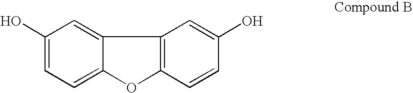

Under an inert atmosphere, compound A (16.6 g, 50.9 mmol) and tetrahydrofuran (293 g) were charged into a 500 ml four-necked flask, and cooled to −78° C. After adding dropwise n-butyllithium (80 ml <1.6 mol hexane solution> 127.3 mmol), it was stirred for 1 hour, with holding the temperature. This reaction liquid was added dropwise to a 1000 ml four-necked flask in which trimethoxy boronic acid (31.7 g, 305.5 mmol) and tetrahydrofuran (250 ml) were charged under an inert atmosphere, and cooled to −78° C. After the dropwise addition, it was raised to room temperature slowly, stirred at room temperature for 2 hours, and confirmed the disappearance of the raw material by TLC. The reaction-terminated mass was charged into a 2000 ml beaker which contains concentrated sulfuric acid (30 g) and water (600 ml), and the reaction was terminated. Toluene (300 ml) was added, and the organic layer was extracted, and further, water was added and washed. After distillation of the solvent, 8 g of the product and ethyl acetate (160 ml) were put into a 300 ml four-necked flask, then aqueous solution of 30% hydrogen-peroxide (7.09 g) was added, and it was stirred at 40° C. for 2 hours. This reaction liquid was charged into a 1000 ml beaker which contains a solution of iron(II) ammonium sulphate (71 g), and water (500 ml). After stirring, the organic layer was extracted and the organic layer was washed with water. By removing the solvent, 6.72 g of crude compound B was obtained.

MS Spectrum: M⁺ 200.0

### SYNTHETIC EXAMPLE 3

### Synthesis of Compound C

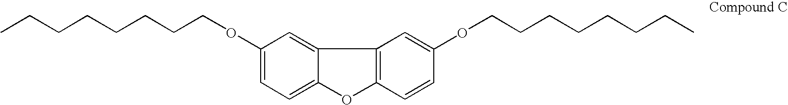

Under an inert atmosphere, into a 200 ml four-necked flask, Compound B (2.28 g, 11.4 mmol) which was prepared by the same method as Synthetic Example 2 and N,N-dimethylformamide (23 g) were charged, and dissolved with stirring at room temperature, potassiumcarbonate (9.45 g, 68.3 mmol) was added, and the temperature was raised to 60° C. After the temperature was raised, n-octylbromide (6.60 g, 34.2 mmol) diluted with N,N-dimethylformamide (11 g) was added dropwise. After the addition, the temperature was raised to 60° C., and it was stirred for 2 hours, with keeping the temperature, disappearance of the raw material was confirmed by TLC. The reaction was terminated by adding water (20 ml), and then toluene (20 ml) was added to extract the organic layer, and the organic layer was washed twice with water. After being dried with anhydrous sodium sulfate, the solvent was distilled off. By purifying the resultant crude product through a silica gel column, desired product was obtained. (Amount: 1.84 g, Yield: 38%)

MS Spectrum: M⁺ 425.3

### SYNTHETIC EXAMPLE 4

### Synthesis of Compound D

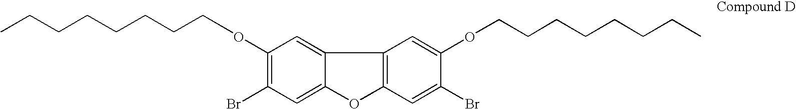

Under an inert atmosphere, into a 500 ml four-necked flask, Compound C (7.50 g, 17.7 mmol) which was synthesized by the same method as Synthetic Example 3 and N,N-dimethylformamide were charged, and dissolved with stirring at room temperature, then cooled by an ice bath. After cooling, N-bromosuccinimide (6.38 g, 35.9 mmol) diluted with N,N-dimethylformamide (225 ml) was added dropwise. After the dropwise addition, it was kept by an ice bath for 1 hour, and at room temperature for 18.5 hours, and raised the temperature to 40° C., then it was stirred for 6.5 hours with keeping the temperature. The disappearance of the raw materials was confirmed by liquid chromatography. The solvent was removed, and toluene (75 ml) was added to dissolve, the organic layer was washed 3 times with water. After being dried by anhydrous sodium sulfate, the solvent was distilled of f. By purifying the about half amount of the resultant crude product through a silica gel column and a liquid chromatography fractionation, the desired product was obtained. (Amount: 0.326 g)

¹H-NMR(300 MHz/CDCl₃): δ0.90 (t, 6H), 1.26 to 1.95 (m, 24H), 4.11 (t, 4H), 7.34 (s, 2H), 7.74 (s, 2H)

MS Spectrum: M⁺ 582.1

### SYNTHETIC EXAMPLE 5

### Synthesis of Polymer Compound 1-1

After charging 6.26 g of compound D, and 4.7 g of 2,2′-bipyridyl into a reaction container, inside of the reaction system was replaced by nitrogen. Into this, 350 g of tetrahydrofuran (THF) (dehydrated solvent) deaerated by argon gas bubbling, was added. Next, to this mixed solution, 8.3 g of bis(1,5-cyclooctadiene)nickel(0) {Ni(COD)₂} was added and stirred for 10 minutes at room temperature, then it was reacted at 60° C. for 3 hours. The reaction was conducted in nitrogen-gas atmosphere.

After the reaction, this solution was cooled, and then, a mixed solution of 25% aqueous ammonia 40 ml/methanol 200 ml/ion-exchanged water 200 ml was charged, and stirred for about 1 hour. Then, resulting precipitate was collected by filtration. The precipitate was dried under reduced-pressure, and dissolved in toluene 600 g. This solution was filtrated to remove insoluble material, and said solution was purified by passing through a column filled up with alumina. Next, the solution was washed with 1N hydrogen chloride. After partitioning, the toluene phase was washed with about 3% aqueous ammonia. After partitioning, the toluene phase was washed with ion-exchanged water. After partitioning, the toluene solution was collected. Next, this toluene solution was poured into methanol with stirring, and purified by reprecipitation. After collecting resulting precipitate, the precipitate was washed with methanol. The precipitate was dried under reduced-pressure, and 2.6 g of a polymer was obtained.

The polystyrene reduced number average molecular weight of the polymer was Mn=1.1×10⁵, and the polystyrene reduced weight average molecular weight was Mw=2.7×10⁵.
Polymer Compound 1-1 Polymer Comprising Substantially the Following Repeating Unit

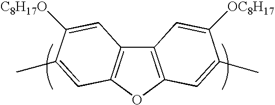

### EXAMPLE 1

0.8 wt % chloroform solution of a mixture was prepared, wherein said mixture was obtained by adding 5 wt % of iridium complex A (American Dye Source, Inc.-made) to Polymer Compound 1-1.

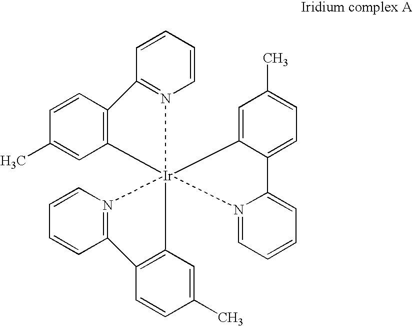

On a glass substrate on which ITO film was formed in a thickness of 150 nm by sputtering method, a film was formed by a thickness of 50 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 100 nm thickness was formed by spin-coating at a rotational rate of 2500 rpm, using the prepared chloroform solution.

Furthermore, after drying this at 80° C. under reduced pressure for 1 hour, an LED was fabricated, by depositing about 4 nm of LiF as the cathode buffer layer, about 5 nm of calcium as the cathode, and subsequently, about 80 nm of aluminum. Here, after the vacuum degree reached to 1×10⁻⁴ Pa or less, metal vapor deposition was started. By applying a voltage to the resultant device, EL light-emission having a peak at 520 nm was observed. This device showed light-emission of 100 cd/m² at about 16 V. Furthermore, the maximum light emitting efficiency was 4.5 cd/A.

### SYNTHETIC EXAMPLE 6

### Synthesis of Compound E

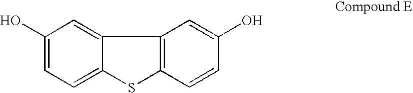

under an inert atmosphere, into a 1 L four-necked flask, 2,8-dibromodibenzothiophene 7 g and THF 280 ml were charged, and dissolved with stirring at room temperature, then cooled to −78° C. Then, n-butyl lithium 29 ml (1.6 mol hexane solution) was added dropwise. After the dropwise addition, it was stirred for 2 hours with keeping the temperature, and trimethoxy boronic acid 13 g was added dropwise. After the dropwise addition, the temperature was raised slowly to room temperature. After stirring at room temperature for 3 hours, the disappearance of the raw materials was confirmed by TLC. 5% sulfuric acid 100 ml was added to terminate the reaction, and it was stirred at room temperature for 12 hours. Water was added and washed and the organic layer was partitioned. After replacing the solvent by ethyl acetate, 30% aqueous hydrogen-peroxide 5 ml was added and it was stirred at 40° C. for 5 hours. The organic layer was partitioned, and washed with 10% aqueous solution of iron (II) ammonium sulfate, then dried, and by distilling off the solvent, brown solid 4.43 g was obtained. From LC-MS measurement, by-products, such as dimers, were also generated and the purity of Compound E was 77% (LC area percentage).

MS(APCI(−)):(M−H)⁻ 215

### SYNTHETIC EXAMPLE 7

### Synthesis of Compound F

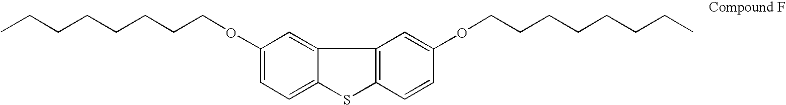

Under an inert atmosphere, into a 200 ml three-necked flask, 4.43 g of compound E, 25.1 g of n-octylbromide and 12.5 g (23.5 mmol) of potassiumcarbonate were charged. 50 ml of methylisobutylketone was added as a solvent, and it was refluxed with heating at 125° C. for 6 hours. After the reaction, the solvent was distilled off, and chloroform and water were added, the organic layer was partitioned, and further it was washed twice with water. After being dried with anhydrous sodium sulfate, by purifying through a silica gel column (eluent: toluene/cyclohexane=1/10), 8.49 g (97% of LC area percentage, 94% of yield) compound F was obtained.

¹H-NMR(300 MHz/CDCl₃): δ0.91 (t, 6H), 1.31 to 1.90 (m, 24H), 4.08 (t, 4H), 7.07 (dd, 2H), 7.55 (d, 2H), 7.68 (d, 2H)

### SYNTHETIC EXAMPLE 8

### Synthesis of Compound G

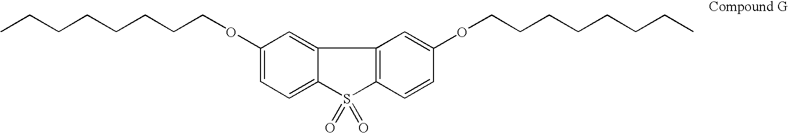

Into a 100 ml three-necked flask, 6.67 g of Compound F, and 40 ml of acetic acid were charged, and the temperature was raised to a bath temperature of 140° C. by an oil bath. Then, 13 ml of 30% aqueous hydrogen-peroxide was added from a condenser and vigorously stirred for 1 hour, and then the reaction was terminated by being added into 180 ml of cold water. After extracting with chloroform and drying, and distilling off the solvent, 6.96 g (90% of LC area percentage, 97% of yield) Compound G was obtained.

¹H-NMR (300 MHz/CDCl₃): δ0.90 (t, 6H), 1.26 to 1.87 (m, 24H), 4.06 (t, 4H), 7.19 (dd, 2H), 7.69 (d, 2H), 7.84 (d, 2H)

MS(APCI(+)):(M+H)⁺ 473

### SYNTHETIC EXAMPLE 9

### Synthesis of Compound H

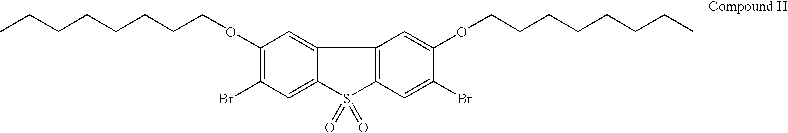

Under an inert atmosphere, into a 200 ml four-necked flask, 3.96 g of Compound G, and 15 ml of a mixed-solution of acetic acid/chloroform=1:1 were charged. and dissolved with stirring at 70° C. Then, 6.02 g of bromine dissolved in the 3 ml of the above solvent was added and stirred for 3 hours. Aqueous sodium-thiosulfate solution was added to remove the unreacted bromine, and chloroform and water were added, and the organic layer was partitioned and dried. The solvent was distilled off and by purifying through a silica gel column (eluent: chloroform/hexane=1/4), 4.46 g (98% of LC area percentage, 84% of yield) of Compound H was obtained.

¹H-NMR (300 MHz/CDCl₃): δ0.95 (t, 6H), 1.30 to 1.99 (m, 24H), 4.19 (t, 4H), 7.04 (s, 2H), 7.89 (s, 2H)

MS(FD⁺) M⁺ 630

### SYNTHETIC EXAMPLE 10

### Synthesis of Compound J

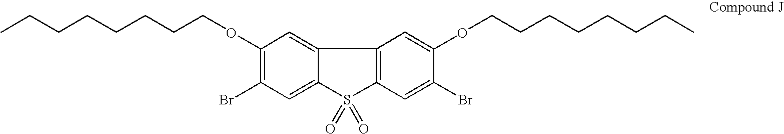

Under an inert atmosphere, into a 200 ml three-necked flask, 3.9 g of Compound H, and 50 ml of diethyl were charged, and the temperature was raised to 40° C. and stirred. Lithium aluminum hydride 1.17 g was added in small portions, and reacted for 5 hours. Excess of lithium aluminum hydride was decomposed by adding water in small portions, and it was washed with 5.7 ml of 36% hydrogen chloride. Chloroform and water were added, and the organic layer was partitioned and dried. By purifying through a silica gel column (eluent:chloroform/hexane=1/5), 1.8 g (99% of LC area percentage, 49% of yield) of Compound J was obtained.

¹H-NMR (300 MHz/CDCl₃): δ0.90 (t, 6H), 1.26 to 1.97 (m, 24H), 4.15 (t, 4H), 7.45 (s, 2H), 7.94 (s, 2H)

MS(FD⁺) M⁺ 598

According to MS (APCI (+)) method, peaks were observed at 615 and 598.

### SYNTHETIC EXAMPLE 11

### Synthesis of a Polymer Compound 1-2

Compound J 400 mg and 2,2′-bipyridyl 180 mg were dissolved in dehydrated tetrahydrofuran 20 mL, and to this solution, under nitrogen atmosphere, bis(1,5-cyclooctadiene)nickel(0) {Ni(COD)₂} 320 mg was added and the temperature was raised to 60° C., and reacted for 3 hours. After the reaction, this reaction liquid was cooled to room temperature, and added dropwise into a mixed solution of 25% aqueous ammonia 10 ml/methanol 120 ml/ion-exchanged water 50 ml, stirred for 30 minutes, and then, the deposited precipitate was filtrated and dried for 2 hours under reduced-pressure, and dissolved in toluene 30 ml. 1N hydrogen-chloride 30 mL was added, and stirred for 3 hours, the aqueous layer was removed, and 4% ammonia water 30 mL was added to the organic layer and stirred for 3 hours, the aqueous layer was removed. The organic layer was added dropwise to methanol 150 mL, stirred for 30 minutes, and the deposited precipitate was filtrated and dried under reduced-pressure for 2 hours, then dissolved in 30 mL toluene. By purifying it through an alumina column (amount of alumina 20 g), the collected toluene solution was added dropwise to methanol 100 mL, stirred for 30 minutes, to deposit precipitate. The deposited precipitate was filtrated and dried for 2 hours under reduced-pressure. The yield of the resultant polymer Compound 1-2 was 120 mg.

The polystyrene reduced number average molecular weight of Polymer Compound 1-2 was Mn=1.3×10⁵ and the weight average molecular weight of was Mw=2.8×10⁵.

Polymer Compound 1-2 Polymer Comprises Substantially the Following Repeating Unit.

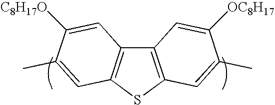

### EXAMPLE 2

A device was prepared as the same manner with the above Example 1, except using Polymer Compound 1-2 instead of Polymer Compound 1-1. The spin coating rotational rate at the time of film forming was 2000 rpm, and the film thickness was about 160 nm. By applying a voltage to the resultant device, EL light-emission having a peak at 520 nm was observed. This device showed light-emission of 100 cd/m at about 29 V. Furthermore, the maximum light emitting efficiency was 3.1 cd/A.

### EXAMPLE 3

0.8 wt % chloroform solution of a mixture was prepared, wherein said mixture was obtained by adding 5 wt % of iridium complex B to the above Polymer Compound 1-1. A device was prepared as the same manner with the above Example 1, with using this. The spin coating rotational rate at the time of film forming was 2500 rpm, and the film thickness was about 100 nm. By applying a voltage to the resultant device, EL light-emission having a peak at 620 nm was observed. This device showed light-emission of 100 cd/m² at about 18 V. Furthermore, the maximum light emitting efficiency was 1.6 cd/A.

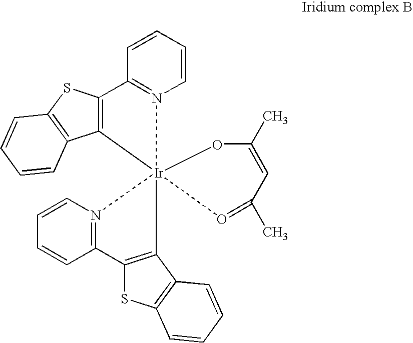

### COMPARATIVE EXAMPLE 1

0.8 wt % chloroform solution of a mixture was prepared, wherein said mixture was obtained by adding 5 wt % of iridium complex A to Polymer Compound R1 (the polystyrene reduced number average molecular weight is Mn=8.0×10⁴ and the weight average molecular weight is Mw=3.0×10⁵), and a device was prepared as the same manner with the above Example 1. The spin coating rotational rate at the time of film forming was 2600 rpm, and the film thickness was about 90 nm. By applying a voltage to the resultant device, EL light-emission having a peak at 508 nm was observed, but the maximum light emitting efficiency was 0.12 cd/A.

Meanwhile, Polymer Compound R1 was synthesized according to the method described in U.S. Pat. No. 6,512,083.
Polymer Compound R1: Homopolymer Substantially Comprises the Following Repeating Unit.

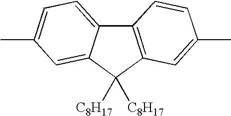

### SYNTHETIC EXAMPLE 12

### Synthesis of Polymer Compound 1-3

Compound J 419 mg, Compound K 146 mg and 2,2′-bipyridyl 310 mg were dissolved in dehydrated tetrahydrofuran 28 mL, and to this solution, under nitrogen atmosphere, bis(1,5-cyclooctadiene)nickel(0) {Ni(COD)₂} 550 mg was added and the temperature was raised to 60° C., and reacted for 3 hours. After the reaction, this reaction liquid was cooled to room temperature, and added dropwise into a mixed solution of 25% aqueous ammonia 13 ml/methanol 150 ml/ion-exchanged water 75 ml, stirred for 30 minutes, and then, the deposited precipitate was filtrated and dried for 2 hours under reduced-pressure, and dissolved in toluene 40 ml. 1N hydrogen-chloride 40 mL was added, and stirred for 3 hours, the aqueous layer was removed, and 4% ammonia water 40 mL was added to the organic layer and stirred for 3 hours, the aqueous layer was removed. The organic layer was added dropwise to methanol 200 mL, stirred for 30 minutes, and the deposited precipitate was filtrated and dried under reduced-pressure for 2 hours, then dissolved in 40 mL toluene. By purifying it through an alumina column (amount of alumina 10 g), the collected toluene solution was added dropwise to methanol 200 mL, and stirred for 30 minutes. The resultant methanol suspension solution was concentrated under reduced-pressure to about 20 ml, and 30 ml of methanol was added thereto to deposit precipitate. The deposited precipitate was filtrated and dried for 2 hours under reduced-pressure. The yield of the resultant Polymer Compound 1-3 was 190 mg.
The polystyrene reduced number average molecular weight of Polymer Compound 1-3 was Mn=4.5×10⁴ and the weight average molecular weight of was Mw=2.0×10⁵. 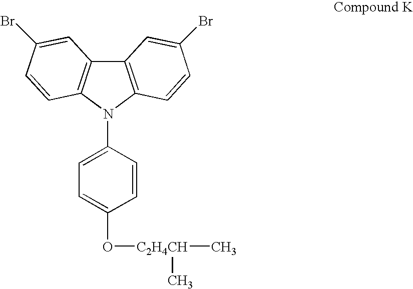
Polymer Compound 1-3 Polymer Substantially Comprises the Following Repeating Unit

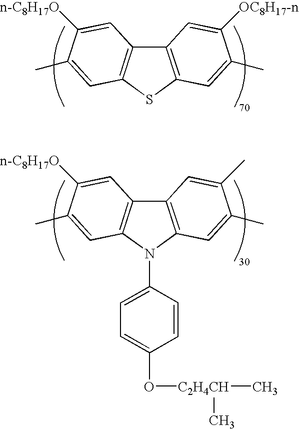

### EXAMPLE 4

A device was prepared as the same manner with the above Example 1, except using Polymer Compound 1-3 below instead of Polymer Compound 1-1. By spin coating with using a solution of poly(ethylenedioxythiophene)/polystyrene sulfone acid (Bayer Co., BaytronP), a film having a thickness of 50 nm was formed. 0.8 wt % chloroform solution of a mixture was prepared, wherein said mixture was obtained by adding 5 wt % of iridium complex A to Polymer Compound 1-3. Film molding was carried out at the rotation speed of 1600 rpm by spin coating. Aluminum was deposited in about 50 nm. By applying a voltage to the resultant device, EL light-emission having a peak at 516 nm was observed. This device showed light-emission of 100 cd/m² at about 7.9 V. Furthermore, the maximum light emitting efficiency was 8.3 cd/A.

### COMPARATIVE EXAMPLE 2

A device was prepared as the same manner with the above example, except not adding iridium Complex A to Polymer Compound 1-3. By applying a voltage to the resultant device, EL light-emission having a peak at 436 nm was observed. This device showed light-emission of 100 cd/m² at about 7.4 V. Furthermore, the maximum light emitting efficiency was 0.37 cd/A.

### SYNTHETIC EXAMPLE 13

### Polymer Compound 1-4

After charging 6.45 g of Compound J, 2.07 g of Compound L, and 5.5 g of 2,2′-bipyridyl into a reaction container, inside of the reaction system was replaced by nitrogen. Into this, 400 g of tetrahydrofuran (THF) (dehydrated solvent) deaerated by argon gas bubbling, was added. Next, to this mixed solution, 10.0 g of bis(1,5-cyclooctadiene)nickel(0) (Ni(COD)₂) was added and stirred for 10 minutes at room temperature, then it was reacted at 60° C. for 3 hours. The reaction was conducted in nitrogen-gas atmosphere.

After the reaction, this solution was cooled, and then, a mixed solution of 25% aqueous ammonia 100 ml/methanol 200 ml/ion-exchanged water 200 ml was charged, and stirred for about 1 hour. Then, resulting precipitate was collected by filtration. The precipitate was dried under reduced-pressure, and dissolved in toluene. This solution was filtrated to remove insoluble material, and washed with 1N hydrogen chloride. After partitioning, the toluene solution was collected. Next, this toluene solution was washed with about 3% aqueous ammonia, and partitioned, and the toluene solution was collected. Next, this toluene solution was washed with ion-exchanged water, and partitioned, and the toluene solution was collected. Reprecipitation purification was carried out by adding methanol to this toluene solution with stirring.

The resultant precipitate was collected, and dried under reduced-pressure, and 4.0 g of a polymer was obtained. This polymer is referred to as Polymer. The polystyrene reduced weight average molecular weight of the Polymer was 3.9×10⁵, and the polystyrene reduced number average molecular weight was 4.3×10⁴. 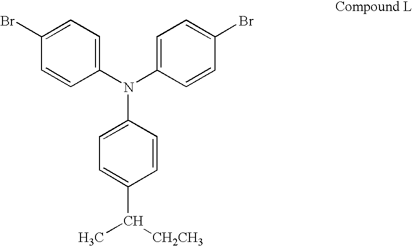
Polymer Compound 1-4 Copolymer Substantial Comprising the Following Repeating Unit.

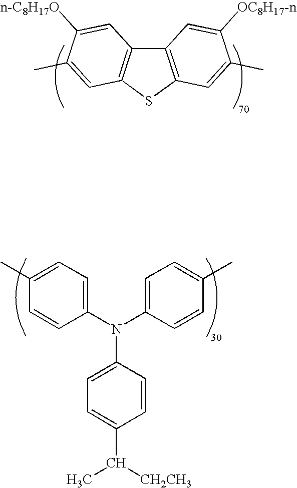

### EXAMPLE 5

A device was prepared as the same manner with the above Example 3, except using Polymer Compound 1-4 instead of Polymer Compound 1-1. The spin coating rotational rate at the time of film forming was 4000 rpm, and the film thickness was about 100 nm. By applying a voltage to the resultant device, EL light-emission having a peak at 620 nm was observed. This device showed light-emission of 100 cd/m² at about 7.2 V. Furthermore, the maximum light emitting efficiency was 0.7 cd/A.

### COMPARATIVE EXAMPLE 3

A device was prepared as the same manner with the above example, except not adding iridium complex B to Polymer Compound 1-4. By applying a voltage to the resultant device, EL light-emission having a peak at 452 nm was observed. This device showed light-emission of 100 cd/m² at about 7.7 V. Furthermore, the maximum light emitting efficiency was 0.5 cd/A.

### SYNTHETIC EXAMPLE 14

### Polymer Compound 1-5

After charging 0.61 g of Compound D, 0.22 g of Compound K, and 0.55 g of 2,2′-bipyridyl into a reaction container, inside of the reaction system was replaced by nitrogen. Into this, 50 g of tetrahydrofuran (dehydrated solvent) deaerated by argon gas bubbling, was added. Next, to this mixed solution, 11.0 g of bis(1,5-cyclooctadiene)nickel(0) was added and stirred for 10 minutes at room temperature, then it was reacted at 60° C. for 3 hours. The reaction was conducted in nitrogen-gas atmosphere.

After the reaction, this solution was cooled, and then, a mixed solution of 25% aqueous ammonia 10 ml/methanol 40 ml/ion-exchanged water 40 ml was charged, and stirred for about 1 hour. Then, resulting precipitate was collected by filtration. The precipitate was dried under reduced-pressure, and dissolved in toluene. This solution was filtrated to remove insoluble material, and said solution was purified by passing through a column filled up with alumina. Next, reprecipitation purification was carried out by pouring this toluene solution into methanol.

Next, resulting precipitate was filtrated and collected. This precipitate was dried under reduced-pressure, and 0.4 g of a polymer was obtained. This polymer is referred to as Polymer Compound. The polystyrene reduced weight average molecular weight of Polymer Compound was 4.6×10⁴, and the number average molecular weight was 6.5×10³.
Polymer Compound 1-5 Copolymer Substantially Comprising the Following Repeating Unit

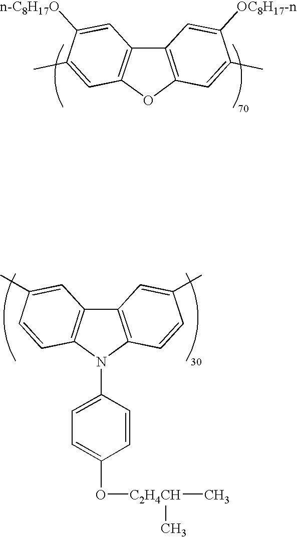

### EXAMPLE 6

A device was prepared as the same manner with the above Example 1, except using Polymer Compound 1-5 instead of Polymer Compound 1-1. The spin coating rotational rate at the time of film forming was 1400 rpm, and the film thickness was about 95 nm. By applying a voltage to the resultant device, EL light-emission having a peak at 516 nm was observed. This device showed light-emission of 100 cd/m² at about 8.5 V. Furthermore, the maximum light emitting efficiency was 6.2 cd/A.

### COMPARATIVE EXAMPLE 4

A device was prepared as the same manner with the above example, except not adding iridium complex A to Polymer Compound 1-5. By applying a voltage to the resultant device, EL light-emission having a peak at 444 nm was observed. This device showed light-emission of 100 cd/m² at about 6.1 V. Furthermore, the maximum light emitting efficiency was 0.6 cd/A.

### INDUSTRY AVAILABILITY

The light-emitting device using the composition of the present invention for a light emitting layer is excellent in light emitting efficiency. Therefore, the composition of the present invention can be used preferably as a light-emitting material of polymer LED etc., and can be used as a material for an polymer light-emitting element and an organic EL device using thereof.

1. A composition comprising a polymer compound having a polystyrene reduced number-average molecular weight of 10³-10⁸, and a compound showing light-emission from triplet excited state, and said polymer compound comprises a repeating unit of the following formula (1): 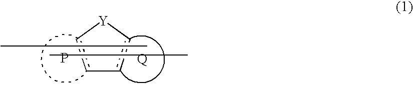
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q;
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.

2. A composition according to claim 1, wherein the repeating unit of the above formula (1) is a repeating unit of the below formula (1-1), (1-2) or (1-3), 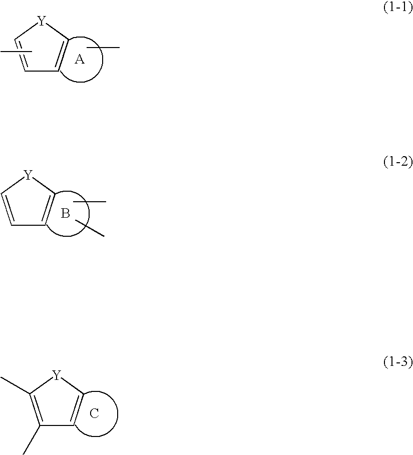
wherein, Ring A, Ring B, and Ring C each independently represent an aromatic ring;
Formulas (1-1), (1-2) and (1-3) respectively may have substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group; and
Y represents —O—, —S—, —Si(R₁)(R₂)—, —P(R₃)—, or —PR₄(═O)—, R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.

3. A composition according to claim 1, wherein the repeating of the above formula (1) is a repeating unit of the below formula (1-4) or the below formula (1-5): 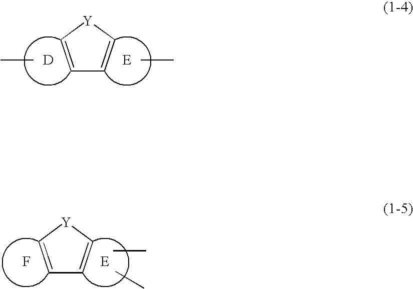
wherein, Ring D, Ring E, Ring F, and Ring G each independently may have substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, the acyloxy group, imine residue, amide group, acid imide group, a monovalent heterocyclic group, carboxyl group, substituted carboxyl group, and cyano group; and
Y represents —O—, —S—, —Si(R₁)(R₂)—, —P(R₃)—, or —PR₄(═O)—, R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.

4. A composition according to claim 1, wherein Y is O atom or S atom.

5. A composition according to claim 1, wherein Ring P, Ring Q, Ring A, Ring B, Ring C, Ring D, Ring E, Ring F, and Ring G are aromatic hydrocarbon rings.

6. A composition according to claim 5, wherein the repeating unit of the above formula (1-4) is a repeating unit selected from the below formulas (1-6), (1-7), (1-8), (1-9) and (1-10): 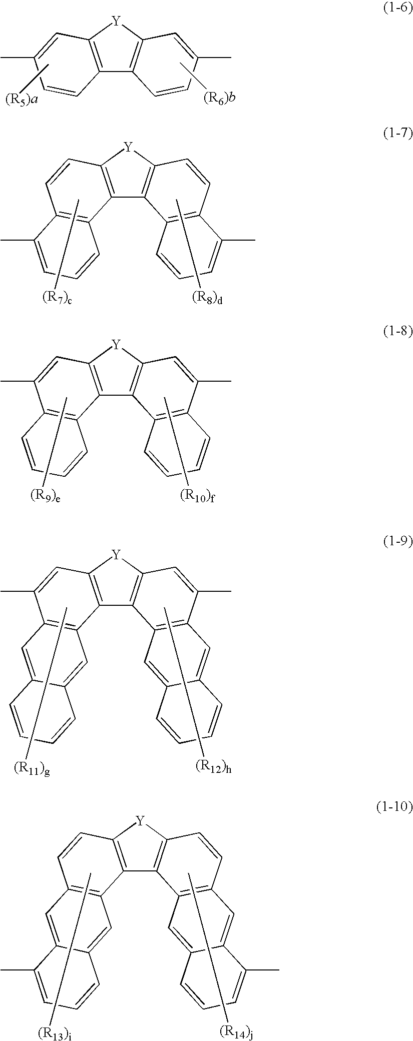
wherein, R₅, R₆, R₇, R₈, R₉, R₁₀, R₁₁, R₁₂, R₁₃, and R₁₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group, or substituted carboxyl group. a and b each independently represent an integer of 0-3. c, d, e, and f each independently represent an integer of 0-5. g, h, i, and j each independently represent an integer of 0-7;
when R₅, R₆, R₇, R₈, R₉, R₁₀, R₁₁, R₁₂, R₁₃, and R₁₄ are respectively in plural, they may be the same or different; and
Y represents —O—, —S—, —Si(R₁)(R₂)—, —P(R₃)—, or —PR₄(═O)—, R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom.

7. A composition according to claim 1, wherein the polymer compound has further a repeating unit of the below formula (2), formula (3), formula (4), or formula (5): 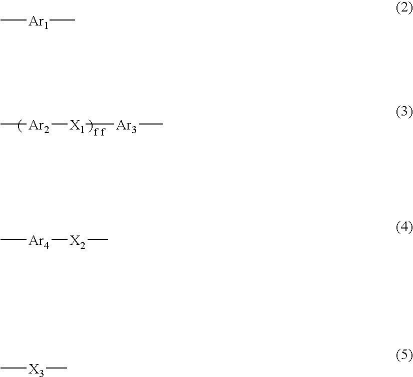
wherein, Ar₁, Ar₂, Ar₃, and Ar₄ each independently represent an arylene group, divalent heterocyclic group, or divalent group having metal complex structure;
X₁, X₂, and X₃ each independently represent —CR₁₅═CR₁₆—, —C≡C—, —N(R₁₇)—, or —(SiR₁₈R₁₉)m-. R₁₅ and R₁₆ each independently represent a hydrogen atom, alkyl group, aryl group, monovalent heterocyclic group, carboxyl group, substituted carboxyl group, or cyano group. R₁₇, R₁₈, and R₁ g each independently represent a hydrogen atom, alkyl group, aryl group, monovalent heterocyclic group, arylalkyl group, or substituted amino group;
ff shows 1 or 2;
m shows an integer of 1-12; and
when two or more R₁₅, R₁₆, R₁₇, R₁₈, and R₁₉ exist, respectively, they may be the same or different.

8. A composition according to claim 7, wherein the repeating unit of the above formula (2) is a repeating unit of the below formula (6), (7), (8), (9), (10), or (11): 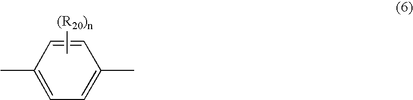
wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group;
n shows an integer of 0-4; and
when two or more R₂₀ exist, they may be the same or different; 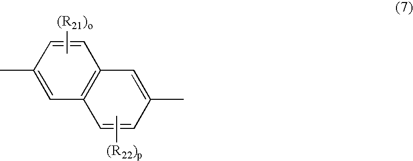
wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group;
o and p each independently show an integer of 0-3; and
when two or more R₂₁ and R₂₂ exist, respectively, they may be the same or different 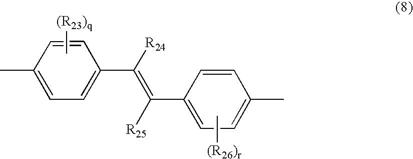
wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group;
q and r each independently show an integer of 0-4;
R₂₄ and R₂₅ each independently show a hydrogen atom, alkyl group, aryl group, monovalent heterocyclic group, carboxyl group, substituted carboxyl group, or cyano group; and
when two or more R₂₃ and R₂₆ exist, respectively, they may be the same or different 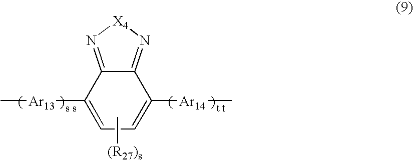
wherein, R₂₇ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group;
s shows an integer of 0-2;
Ar₁₃ and Ar₁₄ each independently show an arylene group, divalent heterocyclic group, or divalent group having metal complex structure;
ss and tt each independently show 0 or 1;
X₄ shows O, S, SO, SO₂, Se, or Te; and
when two or more R₂₇ exist, they may be the same or different 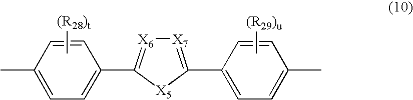
wherein, R₂₈ and R₂₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group;
t and u each independently show an integer of 0-4;
X₅ shows O, S, SO₂, Se, Te, N—R₃₀, or SiR₃₁R₃₂;
X₆ and X₇ each independently show N or C—R₃₃;
R₃₀, R₃₁, R₃₂, and R₃₃ each independently represent a hydrogen atom, alkyl group, aryl group, arylalkyl group, or monovalent heterocyclic group; and
when two or more R₂₈, R₂₉, and R₃₃ exist, respectively, they may be the same or different 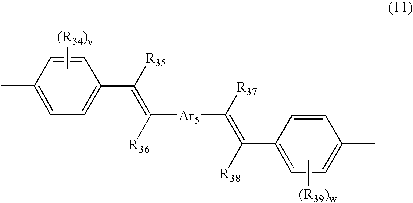
wherein, R₃₄ and R₃₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, a halogen atom, acyl group, the acyloxy group, imine residue, amide group, acid imide group, monovalent heterocyclic group, carboxyl group, substituted carboxyl group, or cyano group;
v and w each independently show an integer of 0-4;
R₃₅, R₃₆, R₃₇, and R₃₈ each independently represent a hydrogen atom, alkyl group, aryl group, a monovalent heterocyclic group, carboxyl group, substituted carboxyl group, or cyano group;
Ar₅ represents an arylene group, divalent heterocyclic group, or divalent group having metal complex structure; and
when two or more R₃₄ and R₃₉ exist, respectively, they may be the same or different.

9. A composition according to claim 7, wherein the repeating unit of the above formula (2) is a repeating unit of the below formula (12): 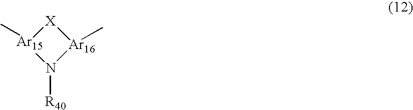
wherein, Ar₁₅ and Ar₁₆ each independently represent a trivalent aromatic hydrocarbon group or a trivalent heterocyclic group, R₄₀ represents an alkyl group, alkoxy group, alkylthio group, alkylsilyl group, alkylamino group, aryl group which may have a substituent, or a monovalent heterocyclic group;
X represents a single bond or the following groups 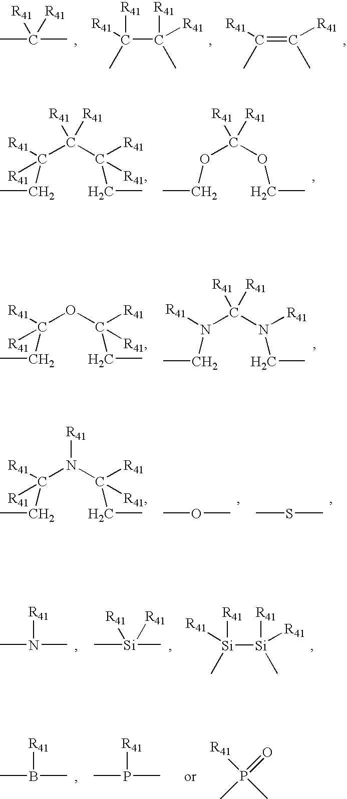
wherein, R₄₁ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group; and
when two or more R₄₁ exist, they may be the same or different.

10. A composition according to claim 7, wherein the repeating unit of the above formula (3) is a repeating unit of the below formula (13): 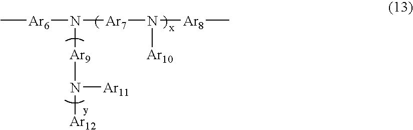
wherein, Ar₆, Ar₇, Ar₈, and Ar₉ each independently represent an arylene group or a divalent heterocyclic group;
Ar₁₀, Ar₁₁, and Ar₁₂ each independently represent an aryl group or a monovalent heterocyclic group;
Ar₆, Ar₇, Ar₈, Ar₉, and Ar₁₀ may have substituent; and
x and y each independently show 0 or 1, and 0≦x+y≦1.

11. A polymer complex compound having visible light-emission in the solid state, and including a repeating unit of the above formula (1), a repeating unit selected from the above formulas (12) and (13), and a metal complex structure showing light-emission from triplet excited state.

12. A polymer complex compound according to claim 11, wherein Y is O atom or S atom.

13. A composition according to claim 1, further comprising at least one kind of material selected from a hole transporting material, an electron transporting material, and a light-emitting material.

14. A composition comprising the polymer complex compound of claim 11, descriptions, and at least one kind of material selected from a hole transporting material, an electron transporting material, and a light-emitting material.

15. An ink composition comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—, R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom, or a polymer complex compound having visible light-emission in the solid state, and including a repeating unit of the above formula (1), a repeating unit selected from the above formulas (12) and (13), and a metal complex structure showing light-emission from triplet excited state.

16. An ink composition according to claim 14, wherein the viscosity is 1-100 mPa·s at 25° C.

17. A luminescent thin film comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom or a polymer complex compound having visible light-emission in the solid state, and including a repeating unit of the above formula (1), a repeating unit selected from the above formulas (12) and (13), and a metal complex structure showing light-emission from triplet excited state.

18. A conductive thin film comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained, and
Y represents —O—, —S—, —Si(R₁)(R₂)—, —P(R₁)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom or a polymer complex compound having visible light-emission in the solid state, and including a repeating unit of the above formula (1), a repeating unit selected from the above formulas (12) and (13), and a metal complex structure showing light-emission from triplet excited state.

19. An organic semiconductor thin film comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom or a polymer complex compound having visible light-emission in the solid state, and including a repeating unit of the above formula (1), a repeating unit selected from the above formulas (12) and (13), and a metal complex structure showing light-emission from triplet excited state.

20. A polymer light-emitting device, containing a layer comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom or a polymer complex compound having visible light-emission in the solid state, and including a repeating unit of the above formula (1), a repeating unit selected from the above formulas (12) and (13), and a metal complex structure showing light-emission from triplet excited state, between electrodes consisting of an anode and a cathode.

21. A polymer light-emitting device according to claim 20, wherein the layer comprising a composition comprising a polymer compound having a polystyrene reduced number-average molecular weight of 10³-10⁸, and a compound showing light-emission from triplet excited state, and said polymer compound comprises a repeating unit of the following formula (1):
wherein, Ring P and Ring Q each independently represent an aromatic ring, but Ring P may be either existent or non-existent:
when Ring P is existent, two connecting bonds respectively are on Ring P and/or Ring Q, and when Ring P is non-existent, two connecting bonds respectively are on 5 membered ring containing Y, and/or Ring Q
on an aromatic ring and/or a 5 membered ring containing Y, substituent selected from an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group may be contained; and
Y represents —O—, —S—, —Si(R₁)(R₂)—, —P(R₃)—, or —PR₄(═O)—. R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, or halogen atom or a polymer complex compound having visible light-emission in the solid state, and including a repeating unit of the above formula (1), a repeating unit selected from the above formulas (12) and (13), and a metal complex structure showing light-emission from triplet excited state, is a light emitting layer.

22. A polymer light-emitting device according to claim 21, wherein the light emitting layer further contains a hole transporting material, an electron transporting material, or a light-emitting material.

23. A flat light source comprising a polymer light-emitting device according to claim 20.

24. A segment display comprising a polymer light-emitting device according to claim 20.

25. A dot matrix display comprising a polymer light-emitting device according to claim 20.

26. A liquid crystal display comprising a polymer light-emitting device according to claim 20 as a back light.

27. Lighting using a polymer light-emitting device according to claim 20.
